(19) United States
(12) Patent Application Publication
(10) Pub. No.: US 2023/0059487 A1
(43) Pub. Date: Feb. 23, 2023

(54) PHOTOSENSITIVE MATERIAL, TRANSFER FILM, MANUFACTURING METHOD OF CIRCUIT WIRING, MANUFACTURING METHOD OF TOUCH PANEL, AND PATTERN FORMING METHOD

(71) Applicant: FUJIFILM Corporation, Tokyo (JP)

(72) Inventors: Kunihiko KODAMA, Fujinomiya-shi (JP); Keigo YAMAGUCHI, Fujinomiya-shi (JP); Masaya SUZUKI, Fujinomiya-shi (JP)

(73) Assignee: FUJIFILM Corporation, Tokyo (JP)

(21) Appl. No.: 17/946,148

(22) Filed: Sep. 16, 2022

Related U.S. Application Data
(63) Continuation of application No. PCT/JP2021/011068, filed on Mar. 18, 2021.

(30) Foreign Application Priority Data
Mar. 19, 2020 (JP) 2020-050195
Dec. 25, 2020 (JP) 2020-217917

(51) Int. Cl. G03F 7/038; G03F 7/32; G03F 7/34

(52) U.S. Cl. CPC G03F 7/0382; G03F 7/32; G03F 7/346; G06F 2203/04103

(57) ABSTRACT

The present invention provides a photosensitive material with which a film having a low relative permittivity can be formed. In addition, the present invention provides a pattern forming method, a manufacturing method of a circuit wiring, a manufacturing method of a touch panel, and a transfer film, which are related to the photosensitive material.

The photosensitive material of the present invention satisfies at least one requirement of the following requirement (V01) or the following requirement (W01).

(V01) the photosensitive material includes a polymer A having a carboxy group and a compound β which has a structure b0 in which an amount of the carboxy group included in the polymer A is reduced by exposure.

(W01) the photosensitive material includes a polymer Ab0 which is the polymer A and further has the structure b0 in which the amount of the carboxy group included in the polymer A is reduced by exposure.

### CROSS-REFERENCE TO RELATED APPLICATIONS

This application is a Continuation of PCT International Application No. PCT/JP2021/011068 filed on Mar. 18, 2021, which claims priority under 35 U.S.C. § 119(a) to Japanese Patent Application No. 2020-050195 filed on Mar. 19, 2020 and Japanese Patent Application No. 2020-217917 filed on Dec. 25, 2020. Each of the above applications is hereby expressly incorporated by reference, in its entirety, into the present application.

### BACKGROUND OF THE INVENTION

### 1. Field of the Invention

The present invention relates to a photosensitive material, a transfer film, a manufacturing method of a circuit wiring, a manufacturing method of a touch panel, and a pattern forming method.

### 2. Description of the Related Art

In a display device provided with a touch panel such as a capacitive input device (specifically, a display device such as an organic electroluminescence (EL) display device and a liquid crystal display device), a conductive pattern such as an electrode pattern corresponding to a sensor in a visual recognition portion and a wiring line for a peripheral wiring portion and a lead-out wiring portion is provided inside the touch panel.

On the conductive pattern, normally, for the purpose of preventing problems such as metal corrosion, increased electrical resistance between electrodes and drive circuits, and disconnection, a resin pattern is disposed as a protective film (permanent film). A photosensitive material is generally used to form the resin pattern.

For example, WO2013/084886A discloses a “photosensitive resin composition containing, on a base material, a binder polymer which has a carboxyl group having an acid value of 75 mgKOH/g or more, a photopolymerizable compound, and a photopolymerization initiator”.

### SUMMARY OF THE INVENTION

In the photosensitive resin composition (photosensitive material) as disclosed in WO2013/084886A, a film or the like for protecting an electrode such as a sensor film may be required to have a low relative permittivity.

In a case where the present inventors have studied on the above-described photosensitive material, it has been found that there is room for improvement in the relative permittivity of the film to be formed.

Therefore, an object of the present invention is to provide a photosensitive material with which a film having a low relative permittivity can be formed. Another object of the present invention is to provide a pattern forming method, a manufacturing method of a circuit wiring, a manufacturing method of a touch panel, and a transfer film, which are related to the photosensitive material.

As a result of intensive studies on the above-described objects, the present inventors have found that the above-described objects can be accomplished by the following configurations.

[1] A photosensitive material which satisfies at least one requirement of the following requirement (V01) or the following requirement (W01),

(V01) the photosensitive material includes a polymer A having a carboxy group and a compound β which has a structure b0 in which an amount of the carboxy group included in the polymer A is reduced by exposure,

(W01) the photosensitive material includes a polymer Ab0 which is the polymer A and further has the structure b0 in which the amount of the carboxy group included in the polymer A is reduced by exposure.

[2] The photosensitive material according to [1],

in which, in the requirement (V01), the compound β is a compound B, and the compound B is a compound in which the structure b0 is a structure b capable of accepting an electron from the carboxy group in a photoexcited state, and

in the requirement (W01), the polymer Ab0 is a polymer Ab, and the polymer Ab is a polymer in which the structure b0 is a structure b capable of accepting an electron from the carboxy group in a photoexcited state.

[3] The photosensitive material according to [1] or [2],

in which at least the requirement (V01) is satisfied, and

the compound β is an aromatic compound.

[4] The photosensitive material according to any one of [1] to [3],

in which at least the requirement (V01) is satisfied, and

the compound β is an aromatic compound having a substituent.

[5] The photosensitive material according to any one of [1] to [4],

in which at least the requirement (V01) is satisfied, and

the compound β is a compound satisfying one or more of the following requirements (1) to (4),

(1) the compound β has a polycyclic aromatic ring,

(2) the compound β has a heteroaromatic ring,

(3) the compound β has an aromatic carbonyl group,

(4) the compound β has an aromatic imide group.

[6] The photosensitive material according to any one of [1] to [5],

in which at least the requirement (V01) is satisfied, and

a molar absorption coefficient ε of the compound β at 365 nm is 1×10³ (cm·mol/L)⁻¹ or less.

[7] The photosensitive material according to any one of [1] to [6],

in which at least the requirement (V01) is satisfied, and

a ratio of a molar absorption coefficient ε of the compound β to light at a wavelength of 365 nm to a molar absorption coefficient ε′ of the compound β to light at a wavelength of 313 nm is 3 or less.

[8] The photosensitive material according to any one of [1] to [7],

in which at least the requirement (V01) is satisfied, and

a pKa of the compound β in a ground state is 2.0 or more.

[9] The photosensitive material according to any one of [1] to [8],

in which at least the requirement (V01) is satisfied, and

a pKa of the compound β in a ground state is 9.0 or less.

[10] The photosensitive material according to any one of [1] to [9],

in which at least the requirement (V01) is satisfied, and

the compound β is one or more kinds selected from the group consisting of pyridine and a pyridine derivative, quinoline and a quinoline derivative, and isoquinoline and an isoquinoline derivative.

[11] The photosensitive material according to any one of [1] to [10],

in which the polymer A has a repeating unit based on (meth)acrylic acid.

[12] The photosensitive material according to any one of [1] to [11],

in which the polymer A has a repeating unit having a polymerizable group.

[13] The photosensitive material according to any one of [1] to [12],

in which at least the requirement (V01) is satisfied,

in the requirement (V01), the compound β is a compound B, and the compound B is a compound in which the structure b0 is a structure b capable of accepting an electron from the carboxy group in a photoexcited state, and

in the photosensitive material, a total number of the structures b included in the compound B is 5 mol % or more with respect to a total number of carboxy groups included in the polymer A.

[14] The photosensitive material according to any one of [1] to [13], further comprising:

a polymerizable compound.

[15] The photosensitive material according to any one of [1] to [14], further comprising:

a photopolymerization initiator.

[16] The photosensitive material according to [15],

in which the photopolymerization initiator is one or more kinds selected from the group consisting of an oxime ester compound and an aminoacetophenone compound.

[17] A pattern forming method comprising, in the following order:

a step of forming a photosensitive layer on a base material using the photosensitive material according to [15] or [16];

a step of exposing the photosensitive layer in a patterned manner;

a step of developing the exposed photosensitive layer with an alkali developer to form a patterned photosensitive layer; and

a step of exposing the patterned photosensitive layer.

[18] A manufacturing method of a circuit wiring, comprising, in the following order:

a step of forming a photosensitive layer on a base material having a conductive layer using the photosensitive material according to [15] or [16];

a step of exposing the photosensitive layer in a patterned manner;

a step of developing the exposed photosensitive layer with an alkali developer to form a patterned photosensitive layer;

a step of exposing the patterned photosensitive layer to form an etching resist film; and

a step of etching the conductive layer in a region on which the etching resist film is not disposed.

[19] A manufacturing method of a touch panel, comprising, in the following order:

a step of forming a photosensitive layer on a base material having a conductive layer using the photosensitive material according to [15] or [16];

a step of exposing the photosensitive layer in a patterned manner;

a step of developing the exposed photosensitive layer with an alkali developer to form a patterned photosensitive layer; and

a step of exposing the patterned photosensitive layer to form a protective film or an insulating film of the conductive layer.

[20] A transfer film comprising:

a temporary support; and

a photosensitive layer formed of the photosensitive material according to any one of [1] to [16].

[21] The transfer film according to [20],

in which a transmittance of the photosensitive layer at 365 nm is 65% or more.

[22] The transfer film according to [20] or [21],

in which a ratio of a transmittance of the photosensitive layer at 365 nm to a transmittance of the photosensitive layer at 313 nm is 1.5 or more.

[23] The transfer film according to any one of [20] to [22],

in which a content of a carboxy group in the photosensitive layer is reduced at a reduction rate of 5 mol % or more by irradiation with an actinic ray or a radiation.

According to the present invention, it is possible to provide a photosensitive material with which a film having a low relative permittivity can be formed. In addition, according to the present invention, it is possible to provide a pattern forming method, a manufacturing method of a circuit wiring, a manufacturing method of a touch panel, and a transfer film, which are related to the photosensitive material.

### BRIEF DESCRIPTION OF THE DRAWINGS

FIG. 1 is a schematic view showing an example of a layer configuration of a transfer film according to an embodiment.

### DESCRIPTION OF THE PREFERRED EMBODIMENTS

Hereinafter, the present invention will be described in detail.

In the present specification, a numerical range expressed using “to” means a range that includes the preceding and succeeding numerical values of “to” as a lower limit value and an upper limit value, respectively.

In addition, in a numerical range described in a stepwise manner in the present specification, an upper limit value or a lower limit value described in a certain numerical range may be replaced with an upper limit value or a lower limit value in another numerical range described in a stepwise manner. In addition, regarding the numerical range described in the present specification, an upper limit value or a lower limit value described in a numerical range may be replaced with a value described in Examples.

In addition, a term “step” in the present specification includes not only an independent step but also a step that cannot be clearly distinguished from other steps, as long as the intended purpose of the step is achieved.

In the present specification, “transparent” means that an average transmittance of visible light having a wavelength of 400 nm to 700 urn is 80% or more, preferably 90% or more. Therefore, for example, a “transparent resin layer” refers to a resin layer having an average transmittance of visible light having a wavelength of 400 to 700 nm is 80% or more.

In addition, the average transmittance of visible light is a value measured by using a spectrophotometer, and for example, can be measured by using a spectrophotometer U-3310 manufactured by Hitachi, Ltd.

In the present specification, “actinic ray” or “radiation” means, for example, a bright line spectrum of a mercury lamp such as g-rays, h-rays and i-rays, far ultraviolet rays typified by an excimer laser, extreme ultraviolet rays (EUV light), X-rays, electron beams (EB), or the like. In addition, in the present invention, light means the actinic ray or the radiation.

Unless otherwise specified, “exposure” in the present specification encompasses not only exposure by a mercury lamp, far ultraviolet rays typified by an excimer laser, extreme ultraviolet rays, X-rays, EUV light, or the like, but also exposure of drawing by particle beams such as electron beams and ion beams.

In the present specification, a content ratio of each structural unit of a polymer is a molar ratio unless otherwise specified.

In addition, in the present specification, a refractive index is a value measured with an ellipsometer at a wavelength of 550 nm unless otherwise specified.

In the present specification, unless otherwise specified, a molecular weight in a case of a molecular weight distribution is a weight-average molecular weight.

In the present specification, a weight-average molecular weight of a resin is a weight-average molecular weight obtained by performing polystyrene conversion of a value measured by gel permeation chromatography (GPC).

In the present specification, “(meth)acrylic acid” is a concept including both acrylic acid and methacrylic acid, and “(meth)acryloyl group” is a concept including both an acryloyl group and a methacryloyl group.

In the present specification, unless otherwise specified, a thickness of a layer (film thickness) is an average thickness measured using a scanning electron microscope (SEM) for a thickness of 0.5 μm or more, and is an average thickness measured using a transmission electron microscope (TEM) for a thickness of less than 0.5 μm. The average thickness is an average thickness obtained by forming a section to be measured using an ultramicrotome, measuring thicknesses of any five points, and arithmetically averaging the values.

[Photosensitive Material]

A photosensitive material according to an embodiment of the present invention satisfies at least one requirement of the following requirement (V01) or the following requirement (W01).

(V01) the photosensitive material includes a polymer A having a carboxy group and a compound β which has a structure b0 in which an amount of the carboxy group included in the polymer A is reduced by exposure.

(W01) the photosensitive material includes a polymer Ab0 which is the polymer A and further has the structure b0 in which the amount of the carboxy group included in the polymer A is reduced by exposure.

A mechanism by which the objects of the present invention can be achieved through such configurations is not always clear, but is considered to be as follows by the present inventors.

That is, the structure b0 is introduced into the photosensitive material according to the embodiment of the present invention by including at least one of the compound or the polymer Ab0. The structure b0 can reduce the amount of the carboxy group included in the above-described polymer A by the exposure. More specifically, for example, the structure b0 eliminates the carboxy group, which is an acid group, from the polymer A as carbon dioxide. Since the polymer Ab0 is a form of the polymer A, the carboxy group to be eliminated may be the carboxy group in the polymer Ab0. In addition, the above-described carboxy group on which the structure b0 acts may be an anion.

In a case where the structure b0 reduces the amount of the carboxy group included in the above-described polymer A, polarity of the portion is lowered. That is, in a layer (photosensitive layer) formed of the photosensitive material according to the embodiment of the present invention, the polarity changes due to the elimination of the carboxy group in the polymer A at the exposed portion. Solubility in a developer changes at the place where the polarity changes, and in particular, solubility in the developer (alkali developer or organic solvent-based developer) changes in the exposed portion. For example, in the exposed portion, the solubility in an alkali developer decreases, and the solubility in an organic solvent-based developer increases. Utilizing such a change in solubility in the exposed portion, with the photosensitive material according to the embodiment of the present invention, it is possible to form a positive or negative tone patterned film. Hereinafter, the patterned film is also simply referred to as a pattern.

In addition, since the presence of the carboxy group contributes to increase in relative permittivity of the film, in the film (pattern) formed by negative tone development using the photosensitive material according to the embodiment of the present invention, at least a part of the carboxy groups in the exposed portion is eliminated as carbon dioxide. Therefore, it is considered that the relative permittivity of the obtained film is also reduced. In addition, even in the film (pattern) formed by positive tone development, by further exposing the remaining film (pattern) after development, at least a part of the carboxy groups in the polymer A in the film is eliminated as carbon dioxide as described above. Therefore, even in the film (pattern) formed by positive tone development, it is considered that the relative permittivity of the obtained film can be reduced.

In addition, as will be described later, it is also preferable that the photosensitive material according to the embodiment of the present invention includes a polymerizable compound.

In a case where the above-described carboxy group is eliminated as carbon dioxide, a radical is generated at a position on the polymer A where the carboxy group is eliminated as carbon dioxide, and with such a radical, radical polymerization of the polymerizable compound is initiated, and the polymer A in the exposed portion can be polymerized. Even in the film formed in such a manner, it is considered that, since at least a part of the carboxy groups in the exposed portion is eliminated as carbon dioxide, the relative permittivity is reduced.

Further, as will be described later, it is also preferable that the photosensitive material according to the embodiment of the present invention includes a polymerizable compound and a photopolymerization initiator.

In a case where the photosensitive material according to the embodiment of the present invention includes a photopolymerization initiator, the elimination of the carboxy group and the polymerization initiation reaction as described above can occur at different timings. For example, first, a photosensitive layer formed of such a photosensitive material may be subjected to a first exposure to a wavelength or an exposure amount at which the elimination of the carboxy group hardly occurs, and the polymerization based on the photopolymerization initiator may be allowed to proceed and be cured. Thereafter, the cured photosensitive layer may be subjected to a second exposure to cause the elimination of the carboxy group. Even in such a case, the carboxy group can be eliminated and a film having a reduced relative permittivity can be obtained.

The first exposure may be an exposure in a patterned shape, and a developing step of removing a non-exposed portion or exposed portion may be performed before the second exposure, and then the second exposure may be further performed to obtain a pattern (patterned film).

The film formed from the photosensitive material according to the embodiment of the present invention has a reduced relative permittivity as described above. In addition, the above-described film also has a reduced moisture permeability (water vapor transmission rate, WVTR). In addition, the photosensitive material according to the embodiment of the present invention has good pattern formability, and it is possible to suppress film loss of the film formed during pattern formation.

Hereinafter, various characteristics that the relative permittivity of the film formed from the photosensitive material can be reduced, the moisture permeability of the film formed from the photosensitive material can be reduced, the pattern formability of the photosensitive material is excellent, and the photosensitive material can suppress the film loss of the film formed during pattern formation are also referred to as the effects of the present invention, and the fact that one or more of these characteristics are more excellent is also referred to that the effects of the present invention are more excellent.

<Requirement (V01) and Requirement (W01)>

The photosensitive material according to the embodiment of the present invention satisfies at least one requirement of the following requirement (V01) or the following requirement (W01).

(V01) the photosensitive material includes a polymer A having a carboxy group and a compound β which has a structure b0 in which an amount of the carboxy group included in the polymer A is reduced by exposure.

(W01) the photosensitive material includes a polymer Ab0 which is the polymer A and further has the structure b0 in which the amount of the carboxy group included in the polymer A is reduced by exposure.

The photosensitive material according to the embodiment of the present invention may satisfy only the requirement (V01) and may not satisfy the requirement (W01), may satisfy only the requirement (W01) and may not satisfy the requirement (V01), or may satisfy both the requirement (V01) and the requirement (W01). Among these, it is preferable to satisfy at least the requirement (V01).

The above-described structure b0 is a structure which exhibits an action of reducing the amount of the carboxy group included in the polymer A in a case of being exposed. The structure b0 is preferably a structure which transitions from a ground state to an excited state by the exposure, and exhibits the action of reducing the carboxy group in the polymer A in the excited state. As the structure b0, for example, a structure (structure b) capable of accepting an electron from the carboxy group included in the polymer A in a photoexcited state by the exposure, or the like is preferable.

In a case where the structure b is exposed, acceptability of the electron increases, and the electron is transferred from the carboxy group of the polymer A. In a case of transferring the electron, the above-described carboxy group may be an anion. In addition, since the polymer Ab0 is a form of the polymer A, the carboxy group which transfers the electron to the structure b may be the carboxy group in the polymer Ab0.

In a case where the carboxy group transfers the electron to the structure b, the above-described carboxy group is unstable and to be carbon dioxide, and is eliminated. As a result, the amount of the above-described carboxy group in the polymer A is reduced by the exposure.

Among these, in the above-described requirement (V01), it is preferable that the above-described compound β is the compound B. The compound B is a suitable form of the compound β, and is a compound in which the structure b0 in the compound β is the structure b (structure capable of accepting an electron from the carboxy group in a photoexcited state).

In addition, in the above-described requirement (W01), it is also preferable that the above-described polymer Ab0 is the polymer Ab. The above-described polymer Ab is a suitable form of the polymer Ab0, and is a polymer in which the structure b0 in the polymer Ab0 is the structure b (structure capable of accepting an electron from the carboxy group in a photoexcited state).

Hereinafter, an estimation mechanism of the process in which the above-described carbon dioxide is generated and eliminated (decarboxylation process) (estimation mechanism capable of reducing the content of the carboxy group derived from the polymer A by the exposure starting from the structure b) will be described in detail by taking an aspect in which the polymer A is polyacrylic acid and the compound B is quinoline as an example.

As shown below, a carboxy group of the polyacrylic acid and a nitrogen atom of the quinoline form a hydrogen bond in the coexistence. In a case where the quinoline is exposed, acceptability of the electron increases, and the electron is transferred from the carboxy group of the polyacrylic acid (step 1: photoexcitation). In a case where the carboxy group included in the polyacrylic acid transfers the electron to the quinoline, the carboxy group is unstable and to be carbon dioxide, and is eliminated (step 2: decarboxylation reaction). After the above-described decarboxylation reaction, a radical is generated in the residue of the polyacrylic acid, and a radical reaction proceeds. The radical reaction can occur between the residues of the polyacrylic acid, between the residue of the polyacrylic acid and any polymerizable compound (monomer (M)), or with a hydrogen atom in the atmosphere (step 3: polarity conversion-crosslinking-polymerization reaction). After the radical reaction is completed, the compound B can be regenerated and contribute to the decarboxylation process of the polymer A again (step 4: regeneration of compound B (catalyst)).

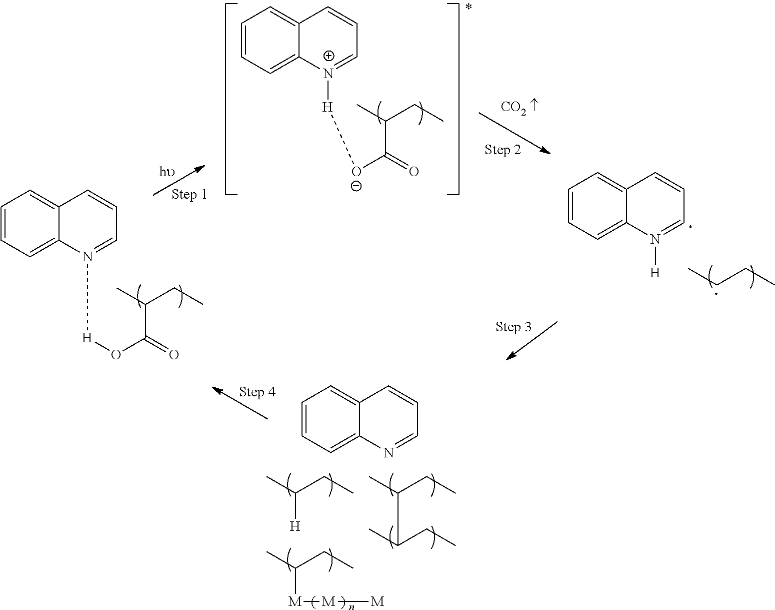

<Requirement (V) and Requirement (W)>

As described above, the structure b0 is preferably the structure b.

That is, the requirement (V01) is preferably the following requirement (V), and the requirement (W01) is preferably the following requirement (W).

(V) the photosensitive material includes a polymer A having a carboxy group, and a compound B having a structure b capable of accepting an electron from the carboxy group of the polymer A in a photoexcited state.

(W) the photosensitive material includes a polymer Ab which is the polymer A and further has a structure b capable of accepting an electron from the carboxy group of the polymer A in a photoexcited state.

The photosensitive material according to the embodiment of the present invention preferably satisfies at least one of the above-described requirement (V) or the above-described requirement (W).

The photosensitive material according to the embodiment of the present invention may satisfy only the requirement (V) and may not satisfy the requirement (W), may satisfy only the requirement (W) and may not satisfy the requirement (V), or may satisfy both the requirement (V) and the requirement (W). Among these, it is preferable to satisfy at least the requirement (V).

The polymer A (including the polymer Ab0 and the polymer Ab) and the compound β (including the compound B) will be described in detail later.

<Aspect>

The photosensitive material according to the embodiment of the present invention preferably has the following aspects, for example.

Aspect 1: aspect in which the photosensitive material satisfies at least one of the requirement (V01) or the requirement (W01) (preferably, the requirement (V) or the requirement (W)), and does not include a polymerizable compound and a photopolymerization initiator

Aspect 2: aspect in which the photosensitive material satisfies at least one of the requirement (V01) or the requirement (W01) (preferably, the requirement (V) or the requirement (W)), and further include a polymerizable compound and does not include a photopolymerization initiator

Aspect 3: aspect in which the photosensitive material satisfies at least one of the requirement (V01) or the requirement (W01) (preferably, the requirement (V) or the requirement (W)), and further include a polymerizable compound and a photopolymerization initiator

In the above-described aspect 1, the fact that the photosensitive material does not include a polymerizable compound means that the photosensitive material does not substantially include a polymerizable compound, and a content of the polymerizable compound may be less than 3% by mass, preferably 0% to 1% by mass and more preferably 0% to 0.1% by mass with respect to the total solid content of the photosensitive material.

In the above-described aspects 1 and 2, the fact that the photosensitive material does not include a photopolymerization initiator means that the photosensitive material does not substantially include a photopolymerization initiator, and a content of the photopolymerization initiator may be less than 0.1% by mass, preferably 0% to 0.05% by mass and more preferably 0% to 0.01% by mass with respect to the total solid content of the photosensitive material.

In the present specification, the solid content of the photosensitive material means a component in the photosensitive material, other than the solvent. In addition, even in a liquid component, the liquid component is regarded as a solid content in a case where the liquid component is not the solvent.

Hereinafter, the components included in the photosensitive material according to the embodiment of the present invention will be described in detail.

<Polymer A>

The photosensitive material includes a polymer A.

The polymer A is a polymer having a carboxy group.

Some or all of carboxy groups (—COOH) included in the polymer A may or may not be anionized in the photosensitive material, and both anionized carboxy group (—COO⁻) and non-anionized carboxy group are referred to as the carboxy group.

That is, the polymer A may or may not be anionized in the photosensitive material, and both anionized polymer A and non-anionized polymer A are referred to as the polymer A.

Usually, the polymer A is an alkali-soluble resin.

In the present disclosure, the “alkali-soluble” means that the dissolution rate obtained by the following method is 0.01 μm/sec or more.

A propylene glycol monomethyl ether acetate solution having a concentration of a target compound (for example, a resin) of 25% by mass is applied to a glass substrate, and then heated in an oven at 100° C. for 3 minutes to obtain a coating film (thickness: 2.0 μm) of the target compound. The above-described coating film is immersed in a 1% by mass aqueous solution of sodium carbonate (liquid temperature: 30° C.), thereby obtaining the dissolution rate (μm/sec) of the above-described coating film.

In a case where the target compound is not dissolved in propylene glycol monomethyl ether acetate, the target compound is dissolved in an organic solvent (for example, tetrahydrofuran, toluene, and ethanol) having a boiling point of lower than 200° C., other than propylene glycol monomethyl ether acetate.

The polymer A may further have an acid group other than the carboxy group as the acid group. Examples of the acid group other than the carboxy group include a phenolic hydroxyl group, a phosphoric acid group, and a sulfonic acid group.

From the viewpoint of developability, an acid value of the polymer A is preferably 60 to 300 mgKOH/g, more preferably 60 to 275 mgKOH/g, and still more preferably 75 to 250 mgKOH/g.

In the present specification, the acid value of the resin is a value measured by a titration method specified in JIS K0070 (1992).

The polymer A may have the structure b0 (preferably, the structure b). As described above, the structure b0 is a structure which exhibits an action of reducing the amount of the carboxy group included in the polymer A in a case of being exposed. The structure b0 is preferably a structure which transitions from a ground state to an excited state by the exposure, and exhibits the action of reducing the carboxy group in the polymer A in the excited state.

Examples of the structure b0 included in the polymer A include a structure (structure b) capable of accepting an electron from the carboxy group included in the polymer A in a photoexcited state.

The polymer A having the structure b0 is also particularly referred to as a polymer Ab0. The polymer A having the structure b is also particularly referred to as a polymer Ab. In addition, the polymer A having no structure b0 (including the structure b) is also particularly referred to as a polymer Aa. The polymer A may be the polymer Aa or the polymer Ab0 (preferably, the polymer Ab). In a case where the photosensitive material includes two or more kinds of the polymers A, one of the polymer Aa and the polymer Ab0 (preferably, the polymer Ab) may be included, or both may be included. In a case where the photosensitive material according to the embodiment of the present invention satisfies the requirement (W01) (preferably, the requirement (W)), the photosensitive material includes at least the polymer Ab0 (preferably, the polymer Ab).

The fact that the polymer Aa does not have the structure b0 means that the polymer A does not substantially have the structure b0, and for example, it is sufficient that a content of the structure b0 included in the polymer Aa is less than 1% by mass, preferably 0% to 0.5% by mass and more preferably 0% to 0.05% by mass with respect to the total mass of the polymer Aa.

A content of the structure b0 in the polymer Ab0 is preferably 1% by mass or more, more preferably 1% to 50% by mass, and still more preferably 5% to 40% by mass with respect to the total mass of the polymer Ab0.

A content of the structure b in the polymer Ab is preferably 1% by mass or more, more preferably 1% to 50% by mass, and still more preferably 5% to 40% by mass with respect to the total mass of the polymer Ab.

In a case where the polymer A includes the polymer Ab0 (preferably, the polymer Ab), a content of the polymer Ab0 (preferably, the polymer Ab) is preferably 5% to 100% by mass with respect to the total mass of the polymer A.

The structure b0 reduces the amount of the carboxy group included in the polymer A by light irradiation. For example, the structure b, which is a suitable form of the structure b0, is excited by light irradiation and accepts an electron from the carboxy group (preferably, anionized carboxy group) in the polymer A in the excited state. As a result, the carboxy group of the polymer A is to be a carboxy radical, and then the polymer A is decarboxylated.

Due to the action of the structure b0 (preferably, the structure b), it is considered that, in the exposed portion, the solubility of the polymer A in the developer changes (insolubilization in the alkali developer, or the like), and a pattern can be formed.

Here, examples of the structure b0 (preferably, the structure b) included in the polymer A include a heteroaromatic ring.

The above-described heteroaromatic ring may be monocyclic or polycyclic, and is preferably polycyclic. In the polycyclic heteroaromatic ring, a plurality of (for example, 2 to 5) aromatic ring structures are fused, and at least one of the plurality of aromatic ring structures has a heteroatom as a ring member atom.

The heteroaromatic ring has one or more heteroatoms (nitrogen atom, oxygen atom, sulfur atom, and the like) as a ring member atom, and the number thereof is preferably 1 to 4. In addition, the heteroaromatic ring preferably has one or more (for example, 1 to 4) nitrogen atoms as a ring member atoms.

The number of ring member atoms in the above-described heteroaromatic ring is preferably 5 to 15.

Examples of the above-described heteroaromatic ring include monocyclic heteroaromatic rings such as a pyridine ring, a pyrazine ring, a pyrimidine ring, and a triazine ring; heteroaromatic rings in which two rings are fused, such as a quinoline ring, an isoquinoline ring, a quinoxaline ring, and a quinazoline ring; and heteroaromatic rings in which three rings are fused, such as an acridine ring, a phenanthridine ring, a phenanthroline ring, and a phenazine ring.

The above-described heteroaromatic ring may have one or more (for example, 1 to 5) substituents, and examples of the substituent include an alkyl group, an aryl group, a halogen atom, an acyl group, an alkoxycarbonyl group, an arylcarbonyl group, a carbamoyl group, a hydroxy group, a cyano group, and a nitro group. In addition, in a case where the above-described aromatic ring has two or more substituents, a plurality of substituents may be bonded to each other to form a non-aromatic ring.

In addition, it is also preferable that the above-described heteroaromatic ring is directly bonded to a carbonyl group.

It is also preferable that the above-described heteroaromatic ring is bonded to an imide group to form a heteroaromatic imide group in the compound B. The imide group in the heteroaromatic imide group may or may not form an imide ring together with the heteroaromatic ring.

In the polymer A, in a case where a plurality of aromatic rings (for example, 2 to 5 aromatic rings) forms a series of aromatic ring structures bonded with a structure selected from the group consisting of a single bond, a carbonyl group, and a multiple bond (for example, a vinylene group which may have a substituent, —C≡—, —N═N—, and the like), and one or more of the plurality of aromatic rings constituting the series of aromatic ring structures are the above-described heteroaromatic ring, the entire series of aromatic ring structures is regarded as one structure b0 (including structure b).

A weight-average molecular weight of the polymer A is preferably 5000 or more and more preferably 10000 or more. The upper limit value of the weight-average molecular weight of the polymer A is not particularly limited, and may be 100000, preferably 50000 or less.

As a suitable aspect of the weight-average molecular weight of the polymer A, 5000 to 200000 is preferable, 10000 to 100000 is more preferable, and 11000 to 49000 is still more preferable.

(Repeating Unit Having Carboxy Group)

The polymer A preferably has a repeating unit having a carboxy group.

Examples of the repeating unit having a carboxy group include a repeating unit represented by General Formula (A).

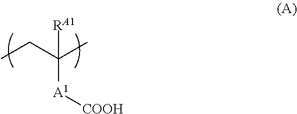

In General Formula (A), R^{A1} represents a hydrogen atom, a halogen atom, or an alkyl group. The above-described alkyl group may be linear or branched. The number of carbon atoms in the above-described alkyl group is preferably 1 to 5 and more preferably 1.

A¹ represents a single bond or a divalent linking group. Examples of the above-described divalent linking group include —CO—, —O—, —S—, —SO—, —SO₂—, —NR^{N}— (R^{N} is a hydrogen atom or an alkyl group having 1 to 5 carbon atoms), a hydrocarbon group (for example, an alkylene group, a cycloalkylene group, an alkenylene group, and an arylene group such as a phenylene group), and a linking group in which a plurality of these groups is linked.

Examples of a monomer from which the repeating unit having a carboxy group is derived include (meth)acrylic acid, crotonic acid, itaconic acid, maleic acid, fumaric acid, 2-(meth)acryloyloxyethyl succinic acid, and styrenecarboxylic acid, and (meth)acrylic acid is preferable.

That is, the repeating unit having a carboxy group is preferably a repeating unit based on (meth)acrylic acid.

The polymer A preferably has a repeating unit based on (meth)acrylic acid.

In the present specification, in a case of being expressed as repeating unit based on a specific monomer, a repeating unit derived from a specific monomer, or the like, the repeating unit may be any repeating unit having a structure in which the specific monomer is polymerized. For example, in a case where a repeating unit formed of a monomer different from the specific monomer is modified or deprotected to obtain a repeating unit having the same structure as the repeating unit having a structure in which the specific monomer is polymerized, the repeating unit obtained above is also expressed as the repeating unit based on a specific monomer or the repeating unit derived from a specific monomer.

A content of the repeating unit having a carboxy group in the polymer A is preferably 5 to 100 mol %, more preferably 10 to 65 mol %, and still more preferably 15 to 45 mol % with respect to all repeating units of the polymer A.

In addition, the content of the repeating unit having a carboxy group in the polymer A is preferably 1% to 100% by mass, more preferably 5% to 70% by mass, and still more preferably 12% to 50% by mass with respect to all repeating units of the polymer A.

All repeating units of the polymer A described above may be all repeating units only for the polymer Aa, may be all repeating units only for the polymer Ab0 (preferably, the polymer Ab), or may be all repeating units including both the polymer Aa and the polymer Ab0 (preferably, the polymer Ab).

The repeating unit having a carboxy group may be used alone, or in combination of two or more kinds thereof.

(Repeating Unit Having Polymerizable Group)

The polymer A also preferably has a repeating unit having a polymerizable group in addition to the above-described repeating units.

Examples of the polymerizable group include an ethylenically unsaturated group (for example, a (meth)acryloyl group, a vinyl group, a styryl group, and the like), and a cyclic ether group (for example, an epoxy group, an oxetanyl group, and the like), and an ethylenically unsaturated group is preferable and a (meth)acryloyl group is more preferable.

Examples of the repeating unit having a polymerizable group also include a repeating unit represented by General Formula (B).

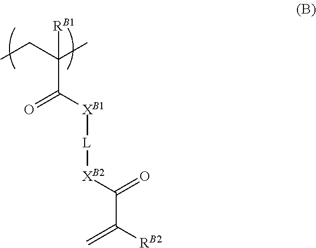

In General Formula (B), X^{B1} and X^{B2} each independently represent —O— or —NR^{N}—. R^{N} represents a hydrogen atom or an alkyl group. The above-described alkyl group may be linear or branched, and the number of carbon atoms therein is preferably 1 to 5.

L represents an alkylene group or an arylene group. The above-described alkylene group may be linear or branched, and the number of carbon atoms therein is preferably 1 to 5. The above-described arylene group may be monocyclic or polycyclic, and the number of carbon atoms therein is preferably 6 to 15. The above-described alkylene group and arylene group may have a substituent, and examples of the substituent include a hydroxyl group.

R^{B1} and R^{B2} each independently represent a hydrogen atom or an alkyl group. The above-described alkyl group may be linear or branched. The number of carbon atoms in the above-described alkyl group is preferably 1 to 5 and more preferably 1.

In a case where the polymer A has the repeating unit having a polymerizable group, a content thereof is preferably 3 to 60 mol %, more preferably 5 to 40 mol %, and still more preferably 10 to 30 mol % with respect to all repeating units of the polymer A.

The content of the repeating unit having a polymerizable group in the polymer A is preferably 1% to 70% by mass, more preferably 5% to 50% by mass, and still more preferably 12% to 45% by mass with respect to all repeating units of the polymer A.

All repeating units of the polymer A described above may be all repeating units only for the polymer Aa, may be all repeating units only for the polymer Ab0 (preferably, the polymer Ab), or may be all repeating units including both the polymer Aa and the polymer Ab0 (preferably, the polymer Ab).

The repeating unit having a polymerizable group may be used alone, or in combination of two or more kinds thereof.

(Repeating Unit Having Structure b0)

The polymer A also preferably has a repeating unit having the structure b0 (preferably, the structure b) in addition to the above-described repeating units.

The structure b0 and the structure b are as described above.

In the repeating unit having the structure b0 (preferably, the structure b), the structure b0 (preferably, the structure b) may be present in a main chain or may be present in a side chain, and is preferably present in the side chain. In a case where the structure b0 (preferably, the structure b) is present in the side chain, the structure b0 (preferably, the structure b) is bonded to a polymer main chain through a single bond or a linking group.

The repeating unit having the structure b0 (preferably, the structure b) is, for example, a repeating unit based on a monomer having a heteroaromatic ring (specifically, a (meth)acrylate monomer having a vinyl heteroaromatic ring such as a vinylpyridine and vinyl(iso)quinoline or a heteroaromatic ring, and the like).

Hereinafter, specific examples of the repeating unit having the structure b0 (preferably, the structure b) will be described, but the present invention is not limited thereto.

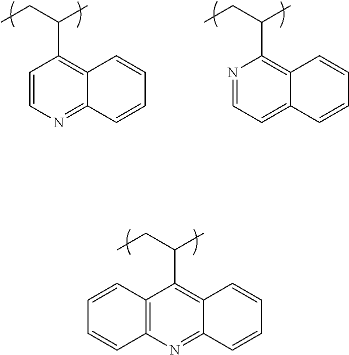

In a case where the polymer A has a repeating unit having the structure b0 (preferably, the structure b), a content thereof is preferably 3 to 75 mol %, more preferably 5 to 60 mol %, and still more preferably 10 to 50 mol % with respect to all repeating units of the polymer A.

In a case where the polymer A has a repeating unit having the structure b0 (preferably, the structure b), a content thereof is preferably 1% to 75% by mass, more preferably 3% to 60% by mass, and still more preferably 5% to 30% by mass with respect to all repeating units of the polymer A.

In a case where the polymer A includes the polymer Aa and the polymer Ab0 (preferably, the polymer Ab), all repeating units of the polymer A described above may be all repeating units only for the polymer Ab0 (preferably, the polymer Ab) or may be all repeating units including both the polymer Aa and the polymer Ab.

The repeating unit having the structure b0 (preferably, the structure b) may be used alone, or in combination of two or more kinds thereof.

(Repeating Unit Having Aromatic Ring)

The polymer A also preferably has a repeating unit having an aromatic ring (preferably, an aromatic hydrocarbon ring) in addition to the above-described repeating units.

Examples of the repeating unit having an aromatic ring include a repeating unit based on (meth)acrylate having an aromatic ring, styrene, or a polymerizable styrene derivative.

Examples of the (meth)acrylate having an aromatic ring include benzyl (meth)acrylate, phenethyl (meth)acrylate, and phenoxyethyl (meth)acrylate.

Examples of the styrene and the polymerizable styrene derivative include methylstyrene, vinyltoluene, tert-butoxystyrene, acetoxystyrene, 4-vinylbenzoic acid, styrene dimer, and styrene trimer.

As the repeating unit having an aromatic ring, a repeating unit represented by General Formula (C) is also preferable.

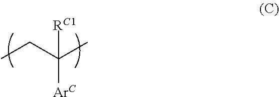

In General Formula (C), R^{C1} represents a hydrogen atom, a halogen atom, or an alkyl group. The above-described alkyl group may be linear or branched. The number of carbon atoms in the above-described alkyl group is preferably 1 to 5 and more preferably 1.

Ar^{C} represents a phenyl group or a naphthyl group. The above-described phenyl group and naphthyl group may have one or more kinds of substituents, and examples of the substituent include an alkyl group, an alkoxy group, an aryl group, a halogen atom, and a hydroxy group.

The repeating unit having an aromatic ring is described below.

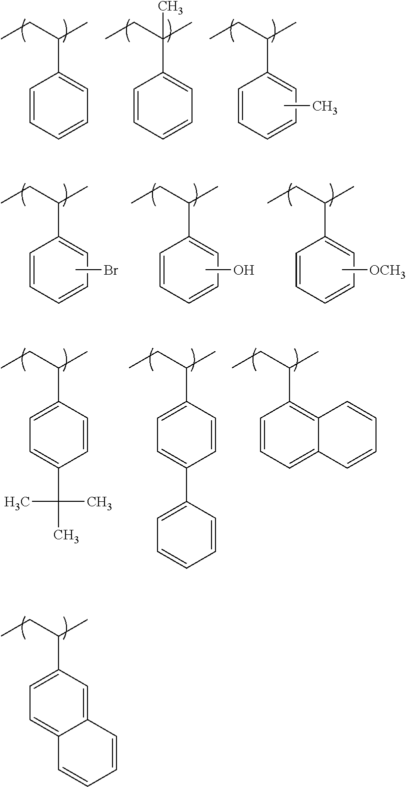

As the repeating unit having an aromatic ring, among these, the following structure is preferable.

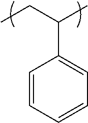

In a case where the polymer A has the repeating unit having an aromatic ring, a content thereof is preferably 5 to 80 mol %, more preferably 15 to 75 mol %, and still more preferably 30 to 70 mol % with respect to all repeating units of the polymer A.

In a case where the polymer A has the repeating unit having an aromatic ring, a content thereof is preferably 5% to 90% by mass, more preferably 10% to 80% by mass, and still more preferably 30% to 70% by mass with respect to all repeating units of the polymer A.

All repeating units of the polymer A described above may be all repeating units only for the polymer Aa, may be all repeating units only for the polymer Ab0 (preferably, the polymer Ab), or may be all repeating units including both the polymer Aa and the polymer Ab0 (preferably, the polymer Ab).

The repeating unit having an aromatic ring may be used alone, or in combination of two or more kinds thereof.

(Repeating Unit Having Alicyclic Structure)

The polymer A also preferably has a repeating unit having an alicyclic structure in addition to the above-described repeating units. The alicyclic ring structure may be monocyclic or polycyclic.

Examples of the alicyclic structure include a dicyclopentanyl ring structure, a dicyclopentenyl ring structure, an isobornyl ring structure, an adamantane ring structure, and a cyclohexyl ring structure.

Examples of a monomer from which the repeating unit having an alicyclic structure is derived include dicyclopentanyl (meth)acrylate, dicyclopentenyl (meth)acrylate, isobornyl (meth)acrylate, adamantyl (meth)acrylate, and cyclohexyl (meth)acrylate.

In a case where the polymer A includes the repeating unit having an alicyclic structure, a content thereof is preferably 3 to 70 mol %, more preferably 5 to 60 mol %, and still more preferably 10 to 55 mol % with respect to all repeating units of the polymer A.

In a case where the polymer A includes the repeating unit having an alicyclic structure, the content thereof is preferably 3% to 90% by mass, more preferably 5% to 70% by mass, and still more preferably 25% to 60% by mass with respect to all repeating units of the polymer A.

All repeating units of the polymer A described above may be all repeating units only for the polymer Aa, may be all repeating units only for the polymer Ab0 (preferably, the polymer Ab), or may be all repeating units including both the polymer Aa and the polymer Ab0 (preferably, the polymer Ab).

The repeating unit having an alicyclic structure may be used alone, or in combination of two or more kinds thereof.

(Other Repeating Units)

The polymer A may have other repeating units in addition to the above-described repeating units.

Examples of the other repeating units include (meth)acrylic acid alkyl esters, and examples of an alkyl group include an alkyl group having a chain structure. The chain structure may be a linear structure or a branched structure. The alkyl group may have a substituent such as a hydroxy group. Examples of the number of carbon atoms in the alkyl group include 1 to 50, preferably 1 to 10. Specific examples thereof include a repeating unit based on methyl (meth)acrylate, ethyl (meth)acrylate, butyl (meth)acrylate, or 2-ethylhexyl (meth)acrylate.

In a case where the polymer A includes other repeating units, a content thereof is preferably 1 to 70 mol %, more preferably 2 to 50 mol %, and still more preferably 3 to 20 mol % with respect to all repeating units of the polymer A.

In a case where the polymer A includes other repeating units, a content thereof is preferably 1% to 70% by mass, more preferably 2% to 50% by mass, and still more preferably 5% to 35% by mass with respect to all repeating units of the polymer A.

All repeating units of the polymer A described above may be all repeating units only for the polymer Aa, may be all repeating units only for the polymer Ab0 (preferably, the polymer Ab), or may be all repeating units including both the polymer Aa and the polymer Ab0 (preferably, the polymer Ab).

The other repeating units may be used alone, or in combination of two or more kinds thereof.

In the photosensitive material according to the embodiment of the present invention, a content of the polymer A is preferably 25% to 100% by mass with respect to the total solid content of the photosensitive material. However, in a case where the photosensitive material according to the embodiment of the present invention does not satisfy the requirement (W01) and/or the requirement (W), the content of the polymer A is preferably 25% to 99% by mass with respect to the total solid content of the photosensitive material.

Among these, in the photosensitive material of the aspect 1, the content of the polymer A is preferably 40% to 98% by mass, more preferably 50% to 96% by mass, and still more preferably 60% to 93% by mass with respect to the total solid content of the photosensitive material.

In the photosensitive material of the aspect 2, the content of the polymer A is preferably 30% to 85% by mass and more preferably 45% to 75% by mass with respect to the total solid content of the photosensitive material.

In the photosensitive material of the aspect 3, the content of the polymer A is preferably 30% to 85% by mass and more preferably 45% to 75% by mass with respect to the total solid content of the photosensitive material.

In a case where the polymer A includes the polymer Aa and the polymer Ab0 (preferably, the polymer Ab), the above-described content of the polymer A is the total content of both.

In the photosensitive material, from the viewpoint of patterning properties and reliability, a content of a residual monomer of monomers used to produce each repeating unit in the polymer A is preferably 5,000 ppm by mass or less, more preferably 2,000 ppm by mass or less, and still more preferably 500 ppm by mass or less with respect to the total mass of the polymer A. The lower limit is not particularly limited, but is preferably 1 ppm by mass or more and more preferably 10 ppm by mass or more.

From the viewpoint of patterning properties and reliability, the above-described content of the residual monomer is preferably 3,000 ppm by mass or less, more preferably 600 ppm by mass or less, and still more preferably 100 ppm by mass or less with respect to the total solid content of the photosensitive material. The lower limit is not particularly limited, but is preferably 0.1 ppm by mass or more and more preferably 1 ppm by mass or more.

It is preferable that the above-described amount of the residual monomer in a case of synthesizing the polymer A by the polymer reaction is also within the above-described range. For example, in a case where glycidyl acrylate is reacted with a carboxy group side chain to synthesize the polymer A, the content of glycidyl acrylate is preferably within the above-described range.

<Compound β>

The photosensitive material preferably includes a compound β.

The compound β is a compound having a structure (structure b0) in which the amount of the carboxy group included in the polymer A is reduced by the exposure. The structure b0 is as described above.

Among these, as the structure b0, a structure (structure b) capable of accepting an electron from the carboxy group included in the polymer A in a photoexcited state is preferable. That is, the compound β is preferably a compound B having a structure (structure b) capable of accepting an electron from the carboxy group included in the polymer A in a photoexcited state.

The compound β reduces the amount of the carboxy group included in the polymer A by light irradiation. For example, the compound B, which is a suitable form of the compound β, is excited by light irradiation and accepts an electron from the carboxy group (preferably, anionized carboxy group) in the polymer A in the excited state. As a result, the carboxy group of the polymer A is to be a carboxy radical, and then the polymer A is decarboxylated.

Due to the action of the compound β (preferably, the compound B), it is considered that, in the exposed portion, the solubility of the polymer A in the developer changes (insolubilization in the alkali developer, or the like), and a pattern can be formed.

The structure b0 (preferably, the structure b) included in the compound β (preferably, the compound B) may be a structure constituting the entire compound β (preferably, the compound B) or a partial structure constituting a part of the compound β (preferably, the compound B).

The compound β (preferably, the compound B) may be a high-molecular-weight compound or a low-molecular-weight compound, and is preferably a low-molecular-weight compound.

A molecular weight of the compound β (preferably, the compound B) as a low-molecular-weight compound is preferably less than 5000, more preferably less than 1000, still more preferably 65 to 300, and particularly preferably 75 to 250.

From the viewpoint that the effects of the present invention are more excellent, the compound β (preferably, the compound B) is preferably an aromatic compound. The above-described aromatic compound is also preferably an aromatic compound having a substituent.

Here, the aromatic compound is a compound having one or more aromatic rings.

Only one aromatic ring may be present in the compound β (preferably, the compound B), or a plurality of aromatic rings may be present therein. In a case where a plurality of aromatic rings is present, for example, the above-described aromatic rings may be present in the side chain or the like of the resin.

In the compound β (preferably, the compound B), the aromatic ring can be used as the above-described structure b capable of accepting an electron from the carboxy group included in the polymer A in a photoexcited state. The above-described aromatic ring may be an overall structure constituting the entire compound β (preferably, the compound B) or a partial structure constituting a part of the compound β (preferably, the compound B).

The above-described aromatic ring may be monocyclic or polycyclic, and is preferably polycyclic. For example, the polycyclic aromatic ring is an aromatic ring in which a plurality of (for example, 2 to 5) aromatic ring structures is fused, and at least one of the plurality of aromatic ring structures preferably has a heteroatom as a ring member atom.

The above-described aromatic ring may be a heteroaromatic ring, and it is preferable to have one or more (for example, 1 to 4) heteroatoms (nitrogen atom, oxygen atom, sulfur atom, and the like) as a ring member atom and it is more preferable to have one or more (for example, 1 to 4) nitrogen atoms as a ring member atom.

The number of ring member atoms in the above-described aromatic ring is preferably 5 to 15.

The compound β (preferably, the compound B) is preferably a compound having a 6-membered aromatic ring having a nitrogen atom as a ring member atom.

Examples of the above-described aromatic ring include monocyclic aromatic rings such as a pyridine ring, a pyrazine ring, a pyrimidine ring, and a triazine ring; aromatic rings in which two rings are fused, such as a quinoline ring, an isoquinoline ring, a quinoxaline ring, and a quinazoline ring; and aromatic rings in which three rings are fused, such as an acridine ring, a phenanthridine ring, a phenanthroline ring, and a phenazine ring.

The above-described aromatic ring may have one or more (for example, 1 to 5) substituents, and examples of the substituent include an alkyl group, an aryl group, a halogen atom, an acyl group, an alkoxycarbonyl group, an arylcarbonyl group, a carbamoyl group, a hydroxy group, a cyano group, an amino group, and a nitro group. In addition, in a case where the above-described aromatic ring has two or more substituents, a plurality of substituents may be bonded to each other to form a non-aromatic ring.

In addition, it is also preferable that the above-described aromatic ring is directly bonded to a carbonyl group to form an aromatic carbonyl group in the compound β (preferably, the compound B). It is also preferable that a plurality of aromatic rings is bonded through a carbonyl group.

It is also preferable that the above-described aromatic ring is bonded to an imide group to form an aromatic imide group in the compound β (preferably, the compound B). The imide group in the aromatic imide group may or may not form an imide ring together with the aromatic ring.

In a case where a plurality of aromatic rings (for example, 2 to 5 aromatic rings) forms a series of aromatic ring structures bonded with a structure selected from the group consisting of a single bond, a carbonyl group, and a multiple bond (for example, a vinylene group which may have a substituent, —C≡C—, —N═N—, and the like), the entire series of aromatic ring structures is regarded as one structure b.

In addition, it is preferable that one or more of aromatic rings constituting the series of aromatic ring structures are the above-described heteroaromatic rings.

From the viewpoint that the effects of the present invention are more excellent, the compound β (preferably, the compound B) is preferably a compound satisfying one or more (for example, 1 to 4) of the following requirements (1) to (4). Among these, it is preferable that at least the requirement (2) is satisfied, and it is preferable that the heteroatom of the heteroaromatic ring has at least a nitrogen atom.

(1) the compound β has a polycyclic aromatic ring.

(2) the compound β has a heteroaromatic ring.

(3) the compound β has an aromatic carbonyl group.

(4) the compound β has an aromatic imide group.

Specific examples of the compound β (preferably, the compound B) include monocyclic aromatic compounds such as pyridine and a pyridine derivative, pyrazine and a pyrazine derivative, pyrimidine and a pyrimidine derivative, and triazine and a triazine derivative; compounds in which two rings are fused to form an aromatic ring, such as quinoline and a quinoline derivative, isoquinoline and an isoquinoline derivative, quinoxaline and a quinoxaline derivative, and quinazoline and a quinazoline derivative; and compounds in which three or more rings are fused to form an aromatic ring, such as acridine and an acridine derivative, phenanthridine and a phenanthridine derivative, phenanthroline and a phenanthroline derivative, and phenazine and a phenazine derivative.

Among these, the compound β (preferably, the compound B) is preferably one or more kinds selected from the group consisting of pyridine and a pyridine derivative, quinoline and a quinoline derivative, and isoquinoline and an isoquinoline derivative, more preferably one or more kinds selected from the group consisting of quinoline and a quinoline derivative, and isoquinoline and an isoquinoline derivative, and still more preferably one or more kinds selected from the group consisting of isoquinoline and an isoquinoline derivative.

These compounds and derivatives thereof may further have a substituent, and as the substituent, an alkyl group, an aryl group, a halogen atom, an acyl group, an alkoxycarbonyl group, an arylcarbonyl group, a carbamoyl group, a hydroxy group, a cyano group, an amino group, or a nitro group is preferable, an alkyl group, an aryl group, a halogen atom, an acyl group, an alkoxycarbonyl group, an arylcarbonyl group, a carbamoyl group, a hydroxy group, a cyano group, or a nitro group is more preferable, an alkyl group, an aryl group, an acyl group, an alkoxycarbonyl group, an arylcarbonyl group, a carbamoyl group, a hydroxy group, a cyano group, or a nitro group is still more preferable, and an alkyl group (for example, a linear or branched alkyl group having 1 to 10 carbon atoms) is particularly preferable.

In addition, from the viewpoint of more excellent pattern forming ability and/or viewpoint that the moisture permeability of the pattern to be formed is further lowered, the compound β (preferably, the compound B) is preferably an aromatic compound having a substituent (compound having a substituent at a constituent atom of the aromatic ring included in the compound β (preferably, the compound B)), and more preferably a compound which satisfies one or more (for example, 1 to 4) of the above-described requirements (1) to (4) and further has a substituent.

As the position of the substituent, for example, in a case where the compound β (preferably, the compound B) is quinoline or a quinoline derivative, from the viewpoint of more excellent pattern forming ability and/or viewpoint that the moisture permeability of the pattern to be formed is further lowered, it is preferable to have a substituent at at least a 2-position or a 4-position on the quinoline ring. In addition, for example, in a case where the compound β (preferably, the compound B) is isoquinoline or an isoquinoline derivative, from the viewpoint of more excellent pattern forming ability and/or viewpoint that the moisture permeability of the pattern to be formed is further lowered, it is preferable to have a substituent at at least a 1-position on the isoquinoline ring. The substituent is preferably an alkyl group (for example, a linear or branched alkyl group having 1 to 10 carbon atoms).

In a case where the compound β (preferably, the compound B) is a polymer, the compound β may be a polymer in which the structure b0 (preferably, the structure b) is bonded to a polymer main chain through a single bond or a linking group.

The compound β (preferably, the compound B) as a polymer is obtained by, for example, polymerizing a monomer having a heteroaromatic ring (specifically, a (meth)acrylate monomer having a vinyl heteroaromatic ring and/or the structure b0 (preferably the structure b and more preferably a heteroaromatic ring)). If necessary, it may be copolymerized with another monomer.

From the viewpoint of more excellent pattern forming ability and/or viewpoint that the moisture permeability of the pattern to be formed is further lowered, a molar absorption coefficient (molar absorption coefficient ε) of the compound β (preferably, the compound B) to light having a wavelength of 365 nm is, for example, 1×10³ (cm·mol/L)⁻¹ or less, preferably 5×10² (cm·mol/L)⁻¹ or less, and more preferably 1×10² (cm·mol/L)⁻¹ or less. The lower limit of the above-described molar absorption coefficient ε is not particularly limited, and for example, is more than 0 (cm·mol/L)⁻¹.

The fact that the molar absorption coefficient ε of the compound β (preferably, the compound B) is within the above-described range is particularly advantageous in a case where the photosensitive layer formed of the photosensitive material is exposed through the temporary support (preferably, a PET film). That is, since the molar absorption coefficient is moderately low, even in a case of being exposed through the temporary support, generation of bubbles due to the decarboxylation can be controlled, and deterioration of the pattern shape can be prevented.

In addition, in a case where the photosensitive material according to the embodiment of the present invention is used for producing a permanent film, coloration of the film can be suppressed by setting the molar absorption coefficient ε of the compound β (preferably, the compound B) within the above-described range.

As the compound having such a molar absorption coefficient ε, the above-described monocyclic aromatic compound or the above-described aromatic compound in which two rings are fused to form an aromatic ring is preferable, and pyridine and a pyridine derivative, quinoline and a quinoline derivative, or isoquinoline and an isoquinoline derivative is preferable.

In addition, from the viewpoint of more excellent pattern forming ability and/or viewpoint that the moisture permeability of the pattern to be formed is further lowered, a ratio of the molar absorption coefficient (molar absorption coefficient ε) of the compound β (preferably, the compound B) at 365 nm to a molar absorption coefficient (molar absorption coefficient ε′) of the compound β (preferably, the compound B) at 313 nm (that is, a ratio represented by molar absorption coefficient ε/molar absorption coefficient ε′) is preferably 3 or less, more preferably 2 or less, and still more preferably less than 1. The lower limit value thereof is not particularly limited, and for example, is 0.01 or more.

The molar absorption coefficient (molar absorption coefficient ε) of the compound β (preferably, the compound B) to light having a wavelength of 365 nm and the molar absorption coefficient (molar absorption coefficient ε′) of the compound β (preferably, the compound B) to light having a wavelength of 313 nm are a molar absorption coefficient measured by dissolving the compound β (preferably, the compound B) in acetonitrile. In a case where the compound β (preferably, the compound B) is insoluble in acetonitrile, a solvent for dissolving the compound β (preferably, the compound B) may be appropriately changed.

Specific examples of the compound β (preferably, the compound B) include 5,6,7,8-tetrahydroquinoline, 4- acetylpyridine, 4-benzoylpyridine, 1-phenylisoquinoline, 1-n-butylisoquinoline, 1-n-butyl-4-methylisoquinoline, 1-methylisoquinoline, 2,4,5,7-tetramethylquinoline, 2-methyl-4-methoxyquinoline, 2,4-dimethylquinoline, phenanthridine, 9-methylacridine, 9-phenylacridine, pyridine, isoquinoline, quinoline, acridine, 4-aminopyridine, and 2-chloropyridine.

A lower limit value of a pKa of the compound β (preferably, the compound B) in a ground state is preferably 0.5 or more, and from the viewpoint of more excellent pattern forming ability and/or viewpoint that the moisture permeability of the pattern to be formed is further lowered, is more preferably 2.0 or more. In addition, an upper limit value of the pKa of the compound β (preferably, the compound B) in a ground state is preferably 10.0 or less, and from the viewpoint of more excellent pattern forming ability and/or viewpoint that the moisture permeability of the pattern to be formed is further lowered, is more preferably 9.0 or less. From the viewpoint of more excellent pattern forming ability and/or viewpoint that the moisture permeability of the pattern to be formed is further lowered, the upper limit value of the pKa of the compound β (preferably, the compound B) in a ground state is more preferably to be smaller, still more preferably 8.0 or less, and particularly preferably 7.0 or less. The pKa of the compound β (preferably, the compound B) in a ground state is intended to be a pKa of the compound β (preferably, the compound B) in an unexcited state, and can be determined by acid titration. In a case where the compound β (preferably, the compound B) is a nitrogen-containing aromatic compound, the pKa of the compound β (preferably, the compound B) in a ground state is intended to be a pKa of a conjugate acid of the compound β (preferably, the compound B) in a ground state.

In addition, in a case where the photosensitive material according to the embodiment of the present invention is applied to form a photosensitive layer, from the viewpoint of being less likely to volatilize in the coating process and having more excellent residual ratio in the photosensitive layer (as a result, from the viewpoint of more excellent pattern forming ability and/or viewpoint that the moisture permeability of the pattern to be formed is further lowered), a molecular weight of the compound β (preferably, the compound B) is preferably 120 or more, more preferably 130 or more, and still more preferably 180 or more. The upper limit value of the molecular weight of the compound β (preferably, the compound B) is not particularly limited, but is, for example, 50,000 or less.

In addition, in a case where the compound β (preferably, the compound B) is a compound exhibiting a cationic state (for example, a nitrogen-containing aromatic compound), an energy level of highest occupied molecular orbital (HOMO) of the compound β (preferably, the compound B) in the cationic state is preferably −8.5 eV or less, and from the viewpoint of more excellent pattern forming ability and/or viewpoint that the moisture permeability of the pattern to be formed is further lowered, is more preferably −7.8 eV or less. The lower limit value thereof is not particularly limited, but is more preferably −13.6 eV or more.

In the present specification, the energy level of HOMO (HOMO in the first electron excited state) of the compound β (preferably, the compound B) in the cationic state is calculated by the quantum chemical calculation program Gaussian 09 (Gaussian 09, Revision A.02, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jalamillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford Conn., 2009.).

As a calculation method, a time-dependent density functional theory using B3LYP as a functional and 6-31+G(d,p) as a basis function is used. In addition, in order to incorporate a solvent effect, a PCM method based on a chloroform parameter set in Gaussian 09 is also used in combination. By this method, a structure optimization calculation of the first electron excited state is performed to obtain a structure with the minimum energy, and the energy of HOMO in the structure is calculated.

Hereinafter, the HOMO energy level (eV) of a representative example of the compound β (preferably, the compound B) in a cationic state is shown. The molecular weight is also shown.

TABLE 1
First table

| | Molecular | HOMO energy level in |
|---|---|---|
| Compound β | weight | cationic state (eV) |
| Isoquinoline | 129 | −8.08 |
| Quinoline | 129 | −8.30 |
| Acridine | 179 | −7.70 |
| 2,4-Dimethylquinoline | 157 | −8.13 |
| 1-Me-isoquinoline | 143 | −7.97 |
| Pyridine | 79 | −9.63 |

From the viewpoint that the effects of the present invention are more excellent, a content of the compound β (preferably, the compound B) in the photosensitive material according to the embodiment of the present invention is preferably 0.1% to 50% by mass with respect to the total solid content of the photosensitive material.

Among these, in the photosensitive material of the aspect 1, the content of the compound β (preferably, the compound B) is, for example, 0.2% to 45% by mass, preferably 2.0% to 40% by mass, more preferably 4% to 35% by mass, and still more preferably 8% to 30% by mass with respect to the total solid content of the photosensitive material.

In the photosensitive material of the aspect 2, the content of the compound β (preferably, the compound B) is preferably 0.5% to 20% by mass and more preferably 1.0% to 10% by mass with respect to the total solid content of the photosensitive material.

In the photosensitive material of the aspect 3, the content of the compound β (preferably, the compound B) is preferably 0.3% to 20% by mass and more preferably 0.5% to 8% by mass with respect to the total solid content of the photosensitive material.

The compound β (preferably, the compound B) may be used alone, or in combination of two or more kinds thereof.

In addition, a preferred range of the total content of the repeating unit having the structure b0 (preferably, the structure b) in the compound β (preferably, the compound B) and the polymer A is also the same as the above-described preferred range of the content of the compound β (preferably, the compound B).

From the viewpoint that the effects of the present invention are more excellent, in the photosensitive material, the total number of structures b0 (preferably, structures b) included in the compound β (preferably, the compound B) is preferably 1 mol % or more, more preferably 3 mol % or more, still more preferably 5 mol % or more, particularly preferably 10 mol % or more, and most preferably 20 mol % or more with respect to the total number of carboxy groups included in the polymer A.

The upper limit of the total number of structures b0 (preferably, structures b) included in the compound β (preferably, the compound B) is not particularly limited, but from the viewpoint of quality of the film to be obtained, is preferably 200 mol % or less, more preferably 100 mol % or less, and still more preferably 80 mol % or less with respect to the total number of carboxy groups included in the polymer A.

In a case where the photosensitive material includes a compound having a carboxy group, other than the polymer A, it is preferable that the total number of structures b0 (preferably, structures b) included in the compound β (preferably, the compound B) within the above-described range with respect to the total number of all carboxy groups in the photosensitive material.

In addition, a preferred range of the total number of the total number of structures b0 (preferably, structures b) included in the compound β (preferably, the compound B) and the total number of structures b0 (preferably, structures b) which can be included in the polymer A is the same as the above-described preferred range of the total number of structures b0 included in the compound β (structures b included in the compound B).

<Polymerizable Compound>

The photosensitive material according to the embodiment of the present invention also preferably includes a polymerizable compound.

Among these, the photosensitive materials of the aspect 2 and the aspect 3 include the polymerizable compound as an essential component.

The polymerizable compound is preferably a component different from the polymer A, and for example, is preferably a compound having a molecular weight (a weight-average molecular weight in a case of having a molecular weight distribution) of less than 5,000 and also preferably a polymerizable monomer.

The polymerizable compound is a polymerizable compound having one or more (for example, 1 to 15) ethylenically unsaturated groups in one molecule.

The polymerizable compound preferably includes a bi- or higher functional polymerizable compound.

Here, the bi- or higher functional polymerizable compound means a polymerizable compound having two or more (for example, 2 to 15) ethylenically unsaturated groups in one molecule.

Examples of the ethylenically unsaturated group include a (meth)acryloyl group, a vinyl group, and a styryl group, and a (meth)acryloyl group is preferable.

The polymerizable compound is preferably (meth)acrylate.

The photosensitive material preferably includes a bifunctional polymerizable compound (preferably, bifunctional (meth)acrylate) and a tri- or higher functional polymerizable compound (preferably, tri- or higher functional (meth)acrylate).

The bifunctional polymerizable compound is not particularly limited and can be appropriately selected from a known compound.

Examples of the bifunctional polymerizable compound include tricyclodecane dimethanol di(meth)acrylate, 1,9-nonanediol di(meth)acrylate, and 1,6-hexanediol di(meth)acrylate.

More specifically, examples of the bifunctional polymerizable compound include tricyclodecane dimethanol diacrylate (A-DCP manufactured by Shin-Nakamura Chemical Co., Ltd.), tricyclodecane dimethanol dimethacrylate (DCP manufactured by Shin-Nakamura Chemical Co., Ltd.), 1,9-nonanediol diacrylate (A-NOD-N manufactured by Shin-Nakamura Chemical Co., Ltd.), and 1,6-hexanediol diacrylate (A-HD-N manufactured by Shin-Nakamura Chemical Co., Ltd.).

The tri- or higher functional polymerizable compound is not particularly limited and can be appropriately selected from a known compound.

Examples of the tri- or higher functional polymerizable compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

In addition, examples of the polymerizable compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like), and ethoxylated glycerin triacrylate (A-GLY-9E manufactured by Shin-Nakamura Chemical Co., Ltd., or the like).

Examples of the polymerizable compound also include urethane (meth)acrylate (preferably, tri- or higher functional urethane (meth)acrylate). The lower limit of the number of functional groups is more preferably 6 or more and still more preferably 8 or more. For example, the upper limit of the number of functional groups may be 20 or less.

Examples of the tri- or higher functional urethane (meth)acrylate include 8UX-015A (manufactured by Taisei Fine Chemical Co., Ltd.); UA-32P, U-15HA, and UA-1100H (manufactured by Shin-Nakamura Chemical Co., Ltd.); AH-600 (manufactured by KYOEISHA CHEMICAL Co., LTD.); and UA-306H, UA-306T, UA-306I, UA-510H, and UX-5000 (manufactured by Nippon Kayaku Co., Ltd.).

In addition, from the viewpoint of improving developability and sweat resistance of the cured film, the polymerizable compound preferably includes a polymerizable monomer having an acid group.

Examples of the acid group include a phosphoric acid group, a sulfonic acid group, and a carboxy group, and a carboxy group is preferable.

Examples of the polymerizable compound having an acid group include a tri- or tetra-functional polymerizable compound having an acid group (compound obtained by introducing a carboxy group to pentaerythritol tri- and tetra-acrylate [PETA] skeleton (acid value=80 to 120 mgKOH/g)), and a penta- to hexa-functional polymerizable compound having an acid group (compound obtained by introducing a carboxy group to dipentaerythritol penta- and hexa-acrylate [DPHA] skeleton (acid value=25 to 70 mgKOH/g)).

The tri- or higher functional polymerizable compound having an acid group may be used in combination with the bifunctional polymerizable compound having an acid group, as necessary.

As the polymerizable compound having an acid group, at least one selected from the group consisting of bi- or higher functional polymerizable compound having a carboxy group and a carboxylic acid anhydride thereof is preferable. As a result, the sweat resistance of the cured film is improved.

The bi- or higher functional polymerizable compound having a carboxy group is not particularly limited, and can be appropriately selected from known compounds.

Examples of the bi- or higher functional polymerizable compound having a carboxy group include ARONIX (registered trademark) TO-2349 (manufactured by Toagosei Co., Ltd.), ARONIX M-520 (manufactured by Toagosei Co., Ltd.), and ARONIX M-510 (manufactured by Toagosei Co., Ltd.).

Examples of the polymerizable compound having an acid group also include polymerizable compounds having an acid group, which are described in paragraphs 0025 to 0030 of JP2004-239942A. The content of this publication is incorporated in this specification.

A weight-average molecular weight (Mw) of the polymerizable compound which can be included in the photosensitive material is preferably 200 to 3000, more preferably 250 to 2600, and still more preferably 280 to 2200.

In a case where the photosensitive material includes a polymerizable compound, among all polymerizable compounds included in the photosensitive material, a molecular weight of a polymerizable compound having the smallest molecular weight is preferably 250 or more and more preferably 280 or more.

In a case where the photosensitive material according to the embodiment of the present invention includes a polymerizable compound, a content thereof is preferably 3% to 70% by mass, more preferably 10% to 70% by mass, and particularly preferably 20% to 55% by mass with respect to the total solid content of the photosensitive material.

In a case where the photosensitive material according to the embodiment of the present invention includes a polymerizable compound, a mass proportion of the polymerizable compound to the polymer A (mass of polymerizable compound/mass of polymer A) is preferably 0.2 to 2.0 and more preferably 0.4 to 0.9.

The polymerizable compound may be used alone, or in combination of two or more kinds thereof.

In addition, in a case where the photosensitive material according to the embodiment of the present invention includes a bifunctional polymerizable compound and a tri- or higher functional polymerizable compound, a content of the bifunctional polymerizable compound is preferably 10% to 90% by mass, more preferably 20% to 85% by mass, and still more preferably 30% to 80% by mass with respect to all polymerizable compounds included in the photosensitive material.

In addition, in this case, a content of the tri- or higher functional polymerizable compound is preferably 10% to 90% by mass, more preferably 15% to 80% by mass, and still more preferably 20% to 70% by mass with respect to all polymerizable compounds included in the photosensitive material.

In addition, in a case where the photosensitive material according to the embodiment of the present invention includes a bi- or higher functional polymerizable compound, this photosensitive material may further include a monofunctional polymerizable compound.

However, in a case where the photosensitive material according to the embodiment of the present invention includes a bi- or higher functional polymerizable compound, it is preferable that, among the polymerizable compounds which are included in the photosensitive material, a main component is the bi- or higher functional polymerizable compound.

Specifically, in a case where the photosensitive material according to the embodiment of the present invention includes a bi- or higher functional polymerizable compound, a content of the bi- or higher functional polymerizable compound is preferably 60% to 100% by mass, more preferably 80% to 100% by mass, and still more preferably 90% to 100% by mass with respect to the total content of polymerizable compounds included in the photosensitive material.

In addition, in a case where the photosensitive material according to the embodiment of the present invention includes a polymerizable compound having an acid group (preferably, a bi- or higher functional polymerizable compound having a carboxy group or a carboxylic acid anhydride thereof), a content of the polymerizable compound having an acid group is preferably 1% to 50% by mass, more preferably 1% to 20% by mass, and still more preferably 1% to 10% by mass with respect to the total solid content of the photosensitive material.

<Photopolymerization Initiator>

The photosensitive material according to the embodiment of the present invention also preferably includes a photopolymerization initiator.

Among these, the photosensitive material of the aspect 3 includes the photopolymerization initiator as an essential component.

The photopolymerization initiator may be a photoradical polymerization initiator, a photocationic polymerization initiator, or a photoanionic polymerization initiator, but a photoradical polymerization initiator is preferable.

The photopolymerization initiator is not particularly limited, and a known photopolymerization initiator can be used.

The photopolymerization initiator is preferably one or more kinds selected from the group consisting of an oxime ester compound (photopolymerization initiator having an oxime ester structure) and an aminoacetophenone compound (photopolymerization initiator having an aminoacetophenone structure), and more preferably includes both compounds. In a case of including both compounds, a content of the oxime ester compound is preferably 5% to 90% by mass and more preferably 15% to 50% by mass with respect to the total content of both compounds. Other photopolymerization initiators may be further used in combination, and examples thereof include a hydroxyacetophenone compound, an acylphosphine oxide compound, and a bistriphenylimidazole compound.

In addition, as the photopolymerization initiator, for example, polymerization initiators described in paragraphs 0031 to 0042 of JP2011-095716A and paragraphs 0064 to 0081 of JP2015-014783A may be used.

Specific examples of the photopolymerization initiator include the following photopolymerization initiators.

Examples of the oxime ester compound include 1,2-octanedione, 1-[4-(phenylthio)phenyl-,2-(O-benzoyloxime)] (product name: IRGACURE OXE-01; IRGACURE series are manufactured by BASF SE), etanone,1-[9-ethyl-6-(2-methylbenzoyl)-9H-carbazol-3-yl]-,1-(0-acetyloxime) (product name: IRGACURE OXE-02, manufactured by BASF SE), [8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) (product name: IRGACURE OXE-03, manufactured by BASF SE), 1-[4-[4-(2-benzofuranylcarbonyl)phenyl]thio]phenyl]-4-methylpentanone-1-(O-acetyloxime) (product name: IRGACURE OXE-04, manufactured by BASF SE, and product name: Lunar 6, manufactured by DKSH Management Ltd.), 1-[4-(phenylthio)phenyl]-3-cyclopentylpropan-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by Changzhou Tronly New Electronic Materials Co., Ltd.).

Examples of the aminoacetophenone compound include 2-(dimethylamino)-2-[(4-methylphenyl)methyl]-1-[4-(4-morpholinyl)phenyl]-1-butanone (product name: Omnirad 379EG; Omnirad series are manufactured by IGM Resins B.V.), 2-methyl-1-(4-methylthiophenyl)-2-morpholinopropan-1-one (product name: Omnirad 907), and APi-307 (1-(biphenyl-4-yl)-2-methyl-2-morpholinopropan-1-one, manufactured by Shenzhen UV-ChemTech Co., Ltd.).

Examples of other photopolymerization initiators include 2-hydroxy-1-{4-[4-(2-hydroxy-2-methyl-propionyl)-benzyl]phenyl}-2-methyl-propan-1-one (product name: Omnirad 127), 2-benzyl-2-dimethylamino-1-(4-morpholinophenyl)-butanone-1 (product name: Omnirad 369), 2-hydroxy-2-methyl-1-phenyl-propan-1-one (product name: Omnirad 1173), 1-hydroxy-cyclohexyl-phenyl-ketone (product name: Omnirad 184), 2,2-dimethoxy-1,2-diphenylethane-1-one (product name: Omnirad 651), 2,4,6-trimethylbenzoyl-diphenylphosphine oxide (product name: Omnirad TPO H), and bis(2,4,6-trimethylbenzoyl) phenylphosphine oxide (product name: Omnirad 819).

In a case where the photosensitive material according to the embodiment of the present invention includes a photopolymerization initiator, a content thereof is preferably 0.1% to 15% by mass, more preferably 0.5% to 10% by mass, and particularly preferably 1% to 5% by mass with respect to the total solid content of the photosensitive material.

The photopolymerization initiator may be used alone, or in combination of two or more kinds thereof.

<Surfactant>

The photosensitive material according to the embodiment of the present invention may include a surfactant.

Examples of the surfactant include an anionic surfactant, a cationic surfactant, a nonionic surfactant, and an amphoteric surfactant, and a nonionic surfactant is preferable.

Examples of the nonionic surfactant include polyoxyethylene higher alkyl ethers, polyoxyethylene higher alkylphenyl ethers, polyoxyethylene glycol higher fatty acid diesters, silicone-based surfactants, and fluorine-based surfactants.

As the surfactant, for example, surfactants described in paragraphs 0120 to 0125 of WO2018/179640A can also be used.

In addition, as the surfactant, surfactants described in paragraph 0017 of JP4502784B and surfactants described in paragraphs 0060 to 0071 of JP2009-237362A can also be used.

Examples of a commercially available product of the fluorine-based surfactant include: MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON 5-382, SC-101, SC-103, SC-104, SC-105, SC-1068, SC-381, SC-383, S-393, and KH-40 (all of which are manufactured by AGC Inc.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily (Feb. 22, 2016) and Nikkei Business Daily (Feb. 23, 2016)), for example, MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound is also preferably used.

In addition, as the fluorine-based surfactant, a block polymer can also be used.

In addition, as the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used.

In addition, as the fluorine-based surfactant, a fluorine-containing polymer having an ethylenically unsaturated bond-containing group in the side chain can also be used. Examples thereof include MEGAFACE RS-101, RS-102, RS-718K, and RS-72-K (all of which are manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (all of which are manufactured by BASF SE), TETRONIC 304, 701, 704, 901, 904, and 150R1 (all of which are manufactured by BASF SE), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil & Fat Co., Ltd.), and OLFINE E1010 and SURFYNOL 104, 400, and 440 (all of which are manufactured by Nissin Chemical Co., Ltd.).

Examples of the silicone-based surfactant include a linear polymer consisting of a siloxane bond and a modified siloxane polymer with an organic group introduced in the side chain or the terminal.

Specific examples of the surfactant include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of which are manufactured by Shin-Etsu Silicone Co., Ltd.), F-4440, TSF-4300, TSF-4445, TSF-4460, and TSF-4452 (all of which are manufactured by Momentive Performance Materials Co., Ltd.), and BYK307, BYK323, and BYK330 (all of which are manufactured by BYK Chemie).

A content of the surfactant is preferably 0.0001% to 10% by mass, more preferably 0.001% to 5% by mass, and still more preferably 0.005% to 3% by mass with respect to the total solid content of the photosensitive material.

The surfactant may be used alone, or in combination of two or more kinds thereof.

<Solvent>

From the viewpoint of forming the photosensitive layer by coating, the photosensitive material according to the embodiment of the present invention may include a solvent.

As the solvent, a generally used solvent can be used without particular limitation.

As the solvent, an organic solvent is preferable.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, 2-propanol, and a mixed solvent thereof.

As the solvent, a mixed solvent of methyl ethyl ketone and propylene glycol monomethyl ether acetate, a mixed solvent of diethylene glycol ethyl methyl ether and propylene glycol monomethyl ether acetate, or a mixed solvent of methyl ethyl ketone, propylene glycol monomethyl ether, and propylene glycol monomethyl ether acetate is preferable.

In a case where the photosensitive material according to the embodiment of the present invention includes a solvent, the solid content of the photosensitive material is preferably 5% to 80% by mass, more preferably 8% to 40% by mass, and still more preferably 10% to 30% by mass. That is, in a case where the photosensitive material according to the embodiment of the present invention includes a solvent, the content of the solvent is preferably 20% to 95% by mass, more preferably 60% to 95% by mass, and still more preferably 70% to 95% by mass with respect to the total mass of the photosensitive material.

In a case where the photosensitive material according to the embodiment of the present invention includes a solvent, from the viewpoint of coating properties, a viscosity (25° C.) of the photosensitive material is preferably 1 to 50 mPa-s, more preferably 2 to 40 mPa-s, and still more preferably 3 to 30 mPa-s.

The viscosity is measured using, for example, a VISCOMETER TV-22 (manufactured by TOKI SANGYO CO., LTD.).

In a case where the photosensitive material according to the embodiment of the present invention includes a solvent, from the viewpoint of coating properties, a surface tension (25° C.) of the photosensitive material is preferably 5 to 100 mN/m, more preferably 10 to 80 mN/m, and still more preferably 15 to 40 mN/m.

The surface tension is measured using, for example, Automatic Surface Tensiometer CBVP-Z (manufactured by Kyowa Interface Science Co., Ltd.).

As the solvent, solvents described in paragraphs 0054 and 0055 of US2005/282073A can also be used, and the contents of these publications are incorporated in the present specification.

In addition, as the solvent, an organic solvent (high-boiling-point solvent) having a boiling point of 180° C. to 250° C. can also be used as necessary.

In a case where the photosensitive material according to the embodiment of the present invention forms a photosensitive layer (photosensitive layer formed of the photosensitive material) in a transfer film or the like, which will be described later, it is also preferable that the photosensitive layer does not substantially include the solvent. The fact “does not substantially include the solvent” means that the content of the solvent may be less than 1% by mass, preferably 0% to 0.5% by mass and more preferably 0% to 0.001% by mass with respect to the total mass of the photosensitive material (photosensitive layer).

<Other Components>

The photosensitive material according to the embodiment of the present invention may include a component other than the above-described components.

As other components, for example, a known additive such as a metal oxidation inhibitor described later, metal oxide particles, an antioxidant, a dispersing agent, an acid proliferation agent, a development promoter, a conductive fiber, a colorant, a thermal radical polymerization initiator, a thermal acid generator, an ultraviolet absorber, a thickener, a crosslinking agent, and an organic or inorganic anti-precipitation agent may further be included.

Preferred aspects of these components are described in paragraphs 0165 to 0184 of JP2014-085643A, and the contents of these publications are incorporated in the present specification.

The photosensitive material may include impurities.

Examples of the impurities include sodium, potassium, magnesium, calcium, iron, manganese, copper, aluminum, titanium, chromium, cobalt, nickel, zinc, tin, halogen, and ions of these. Among these, halide ion, sodium ion, and potassium ion are easily mixed as impurities, so that the following content is particularly preferable.

A content of impurities in the photosensitive material is preferably 80 ppm by mass or less, more preferably 10 ppm by mass or less, and still more preferably 2 ppm by mass or less with respect to the total mass of the photosensitive material. The content of impurities in the photosensitive material may be 1 ppb by mass or more or 0.1 ppm by mass or more with respect to the total mass of the photosensitive material.

Examples of a method of setting the impurities in the above-described range include selecting a raw material having a low content of impurities as a raw material for the photosensitive material, preventing the impurities from being mixed in a case of forming the photosensitive material, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

In the photosensitive material, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low. A content of these compounds in the photosensitive material is preferably 100 ppm by mass or less, more preferably 20 ppm by mass or less, and still more preferably 4 ppm by mass or less with respect to the total mass of the photosensitive material.

The lower limit of the above-described content may be 10 ppb by mass or more or 100 ppb by mass or more with respect to the total mass of the photosensitive material. The content of these compounds can be suppressed in the same manner as in the above-described metal as impurities. In addition, the compounds can be quantified by a known measurement method.

From the viewpoint of improving patterning properties, a content of water in the photosensitive material is preferably 0.01% to 1.0% by mass and more preferably 0.05% to 0.5% by mass with respect to the total mass of the photosensitive material.

[Transfer Film]

A transfer film according to an embodiment of the present invention includes a temporary support and a photosensitive layer formed of the photosensitive material according to the embodiment of the present invention (hereinafter, also simply referred to as a “photosensitive layer”).

The transfer film according to the embodiment of the present invention can be suitably used for forming a film (pattern) on a base material. In a case where a film is formed on a base material using the transfer film according to the embodiment of the present invention, for example, the photosensitive layer of the transfer film according to the embodiment of the present invention is transferred to the base material on which the film (pattern) is to be formed, and the photosensitive layer transferred onto the base material is subjected to treatments such as exposure and development to form the film (pattern) on the base material.

According to the transfer film according to the embodiment of the present invention, the same effects as those of the photosensitive material according to the embodiment of the present invention can be realized. That is, a film having a reduced relative permittivity can be formed on the base material.

Therefore, the transfer film according to the embodiment of the present invention is particularly suitable for use as a film for forming a protective film for a touch panel.

Hereinafter, the transfer film according to the embodiment of the present invention will be described in detail.

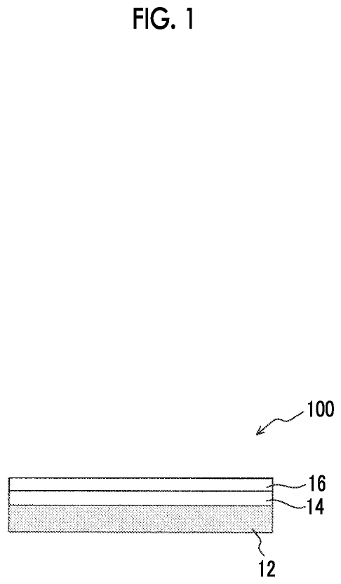

FIG. 1 is a schematic cross-sectional view showing an example of an embodiment of the transfer film according to the present invention.

A transfer film 100 shown in FIG. 1 has a configuration in which a temporary support 12, a photosensitive layer (photosensitive layer formed of the photosensitive material according to the embodiment of the present invention) 14, and a cover film 16 are laminated in this order.

The cover film 16 may be omitted.

<Temporary Support>

The temporary support is a support which supports the photosensitive layer and can be peeled off from the photosensitive layer.

From the viewpoint that the photosensitive layer can be exposed through the temporary support in a case where the photosensitive layer is exposed in a patterned manner, the temporary support preferably has light-transmitting property.

Here, the “has light-transmitting property” means that a transmittance of light having a main wavelength used for the exposure (either the pattern exposure or the entire exposure) is 50% or more. From the viewpoint of more excellent exposure sensitivity, the transmittance of the light having the main wavelength used for the exposure is preferably 60% or more, and more preferably 70% or more. Examples of a method for measuring the transmittance include a measuring method using MCPD Series manufactured by OTSUKA ELECTRONICS Co., Ltd.

Specific examples of the temporary support include a glass substrate, a resin film, and paper, and from the viewpoint of more excellent strength and flexibility, a resin film is preferable. Examples of the resin film include a polyethylene terephthalate (PET) film, a cellulose triacetate film, a polystyrene film, and a polycarbonate film. Among these, a biaxially stretched polyethylene terephthalate film is preferable.

From the viewpoint of pattern formability during pattern exposure through the temporary support and transparency of the temporary support, it is preferable that the number of particles, foreign substances, and defects included in the temporary support is small. The number of particles, foreign substances, and defects having a diameter of 2 μm or more is preferably 50 pieces/10 mm² or less, more preferably 10 pieces/10 mm² or less, and still more preferably 3 pieces/10 mm² or less. The lower limit is not particularly limited, but can be 1 piece/10 mm² or more.

From the viewpoint of further improving handleability, the temporary support preferably has a layer in which 1 pieces/mm² or more particles with a diameter of 0.5 to 5 μm are present on a surface opposite to the side where the photosensitive layer is formed, and it is more preferable to have a layer in which 1 to 50 pieces/mm² particles with a diameter of 0.5 to 5 μm are present.

A thickness of the temporary support is not particularly limited, but from the viewpoint of ease of handling and excellent general-purpose properties, is preferably 5 to 200 μm and more preferably 10 to 150 μm.

From the viewpoint of strength as a support, flexibility required for bonding to a substrate for forming a circuit wiring, and light-transmitting property required in the first exposing step, the thickness of the temporary support can be appropriately selected according to the material.

Preferred aspects of the temporary support are described in, for example, paragraphs 0017 and 0018 of JP2014-085643A, paragraphs 0019 to 0026 of JP2016-027363A, paragraphs 0041 to 0057 of WO2012/081680A1, and paragraphs 0029 to 0040 of WO2018/179370A1, and the contents of these publications are incorporated in the present specification.

As the temporary support, for example, COSMOSHINE (registered trademark) A4100 manufactured TOYOBO Co., Ltd., LUMIRROR (registered trademark) 16FB40 manufactured by Toray Industries, Inc., or LUMIRROR (registered trademark) 16QS62 (16KS40) manufactured by Toray Industries, Inc. may be used.

In addition, particularly preferred examples of the temporary support include a biaxial stretching polyethylene terephthalate film having a thickness of 16 μm, a biaxial stretching polyethylene terephthalate film having a thickness of 12 μm, and a biaxial stretching polyethylene terephthalate film having a thickness of 9 μm.

<Photosensitive Layer>

The photosensitive layer in the transfer film is a layer formed of the photosensitive material according to the embodiment of the present invention, and for example, the photosensitive layer is preferably a layer substantially composed of only the solid content components of the above-described photosensitive material. That is, it is preferable that the photosensitive material constituting the photosensitive layer includes the solid content components (components other than the solvent) which can be included in the above-described photosensitive material in the above-described contents.

However, in a case where a photosensitive material including a solvent is applied and dried to form a photosensitive layer, the photosensitive layer may include the solvent because the solvent remains in the photosensitive layer even after drying.

The photosensitive layer includes the polymer A, and has a mechanism in which the content of the carboxy group derived from the polymer A is reduced by exposure.

In the photosensitive layer, it is preferable that the content of the carboxy group in the photosensitive layer is reduced by irradiation with an actinic ray or a radiation at a reduction rate of 5 mol % or more with respect to the content of the carboxy group in the photosensitive layer before the irradiation, more preferable to be reduced at a reduction rate of 10 mol % or more, still more preferable to be reduced at a reduction rate of 20 mol % or more, even more preferable to be reduced at a reduction rate of 31 mol % or more, particularly preferable to be reduced at a reduction rate of 40 mol % or more, more particularly preferable to be reduced at a reduction rate of 51 mol % or more, and most preferable to be reduced at a reduction rate of 71 mol % or more. The upper limit value thereof is not particularly limited, and for example, is 100 mol % or less.

A reduction rate of the content of the carboxy group derived from the polymer A in the photosensitive layer can be calculated by measuring the amount of the carboxy group in the photosensitive layer before and after the exposure. In a case of measuring the amount of the carboxy group in the photosensitive layer before the exposure, for example, the amount thereof can be analyzed and quantified by potentiometric titration. In addition, in a case of measuring the amount of the carboxy group in the photosensitive layer after the exposure, the hydrogen atom of the carboxy group is substituted with a metal ion such as lithium, and the amount thereof can be calculated by analyzing and quantifying the amount of this metal ion by inductively coupled plasma optical emission spectrometer (ICP-OES).

In addition, the reduction rate of the content of the carboxy group derived from the polymer A in the photosensitive layer can also be obtained by measuring an infrared (IR) spectrum of the photosensitive layer before and after the exposure and calculating a reduction rate of a peak derived from the carboxy group. The reduction rate of the content of the carboxy group can be obtained by calculating a reduction rate of a peak of C═O stretching and contracting (peak of 1710 cm⁻¹) of the carboxy group.

(Average Thickness of Photosensitive Layer)

An average thickness of the photosensitive layer is preferably 0.5 to 20 μm. In a case where the average thickness of the photosensitive layer is 20 μm or less, resolution of the pattern is more excellent, and in a case where the average thickness of the photosensitive layer is 0.5 μm or more, it is preferable from the viewpoint of pattern linearity. The average thickness of the photosensitive layer is more preferably 0.8 to 15 μm and still more preferably 1.0 to 10 μm. Specific examples of the average thickness of the photosensitive layer include 3.0 μm, 5.0 μm, and 8.0 μm.

(Method for Forming Photosensitive Layer)

The photosensitive layer can be formed by, for example, preparing a photosensitive material including each of the above-described solid content components (components other than a solvent) and a solvent, and applying and drying the photosensitive material. It is also possible to prepare a photosensitive material by dissolving each component in a solvent in advance and then mixing the obtained solution at a predetermined proportion. The photosensitive material including a solvent, prepared as described above, is preferably filtered using, for example, a filter having a pore size of 0.2 to 30 μm.

The photosensitive layer can be formed by applying the photosensitive material including a solvent to a temporary support or a cover film, and drying the photosensitive material.

The application method is not particularly limited, and examples thereof include known methods such as a slit coating, a spin coating, a curtain coating, and an inkjet coating.

In addition, in a case where a layer of high refractive index and/or other layers, which are described later, are formed on the temporary support or the cover film, the photosensitive layer may be formed on the layer of high refractive index and/or other layers.

From the viewpoint of more excellent pattern forming ability and/or viewpoint that the moisture permeability of the pattern to be formed is further lowered, a transmittance of the photosensitive layer at 365 nm (transmittance to light having a wavelength of 365 nm) is preferably 20% or more, more preferably 65% or more, and still more preferably 90% or more. The upper limit value thereof is not particularly limited, and is 100% or less.

In addition, from the viewpoint of more excellent pattern forming ability and/or viewpoint that the moisture permeability of the pattern to be formed is further lowered, a ratio of the transmittance of the photosensitive layer at 365 nm (transmittance to light having a wavelength of 365 nm) to a transmittance of the photosensitive layer at 313 nm (transmittance to light having a wavelength of 313 nm) (ratio represented by transmittance of photosensitive layer at 365 nm/transmittance of photosensitive layer at 313 nm) is preferably 1 or more and more preferably 1.5 or more. The upper limit value thereof is not particularly limited, and for example, is 1000 or less.

Such a photosensitive layer is more preferably a photosensitive layer which is formed of a photosensitive material satisfying at least one of the above-described requirement (V) or the above-described requirement (W).

In addition, among these, the photosensitive layer is more preferably a photosensitive layer formed of a photosensitive material satisfying any of the above-described aspects 1 to 3.

A visible light transmittance of the photosensitive layer at a film thickness of approximately 1.0 μm is preferably 80% or more, more preferably 90% or more, and most preferably 95% or more.

As the visible light transmittance, it is preferable that an average transmittance at a wavelength of 400 to 800 nm, the minimum value of the transmittance at a wavelength of 400 to 800 nm, and a transmittance at a wavelength of 400 nm all satisfy the above.

Examples of a preferred value of the visible light transmittance of the photosensitive layer at a film thickness of approximately 1.0 μm include 87%, 92%, and 98%.

From the viewpoint of suppressing residue during development, a dissolution rate of the photosensitive layer in a 1.0% by mass sodium carbonate aqueous solution is preferably 0.01 μm/sec or more, more preferably 0.10 μm/sec or more, and still more preferably 0.20 μm/sec or more. In addition, from the viewpoint of edge shape of the pattern, it is preferable to be 5.0 μm/sec or less. Examples of a specific preferred numerical value include 1.8 μm/sec, 1.0 μm/sec, and 0.7 μm/sec.

The dissolution rate of the photosensitive layer in a 1.0% by mass sodium carbonate aqueous solution per unit time is measured as follows.

A photosensitive layer (within a film thickness of 1.0 to 10 μm) formed on a glass substrate, from which the solvent has been sufficiently removed, is subjected to a shower development with a 1.0% by mass sodium carbonate aqueous solution at 25° C. until the photosensitive layer is dissolved completely (however, the maximum time is 2 minutes).

The dissolution rate of the photosensitive layer is obtained by dividing the film thickness of the photosensitive layer by the time required for the photosensitive layer to dissolve completely. In a case where the photosensitive layer is not dissolved completely in 2 minutes, the dissolution rate of the photosensitive layer is calculated in the same manner as above, from the amount of change in film thickness up to 2 minutes.

For development, a shower nozzle of ¼ MiNJJX030PP manufactured by H.IKEUCHI Co., Ltd. is used, and a spraying pressure of the shower is set to 0.08 MPa. Under the above-described conditions, a shower flow rate per unit time is set to 1,800 mL/min.

From the viewpoint of pattern formability, the number of foreign substances having a diameter of 1.0 μm or more in the photosensitive layer is preferably 10 pieces/mm² or less, and more preferably 5 pieces/mm² or less.

The number of foreign substances is measured as follows.

Any 5 regions (1 mm×1 mm) on a surface of the photosensitive layer are visually observed from a normal direction of the surface of the photosensitive layer with an optical microscope, the number of foreign substances having a diameter of 1.0 μm or more in each region is measured, and the values are arithmetically averaged to calculate the number of foreign substances.

Examples of a specific preferred numerical value include 0 pieces/mm², 1 pieces/mm², 4 pieces/mm², and 8 pieces/mm².

From the viewpoint of suppressing generation of aggregates during development, a haze of a solution obtained by dissolving 1.0 cm³ of the photosensitive layer in 1.0 liter of a 1.0% by mass sodium carbonate aqueous solution at 30° C. is preferably 60% or less, more preferably 30% or less, still more preferably 10% or less, and most preferably 1% or less.

The haze is measured as follows.

First, a 1.0% by mass sodium carbonate aqueous solution is prepared, and a liquid temperature is adjusted to 30° C. 1.0 cm³ of the photosensitive layer is added to 1.0 L of the sodium carbonate aqueous solution. The solution is stirred at 30° C. for 4 hours, being careful not to mix air bubbles. After stirring, the haze of the solution in which the photosensitive resin layer is dissolved is measured. The haze is measured using a haze meter (product name “NDH4000”, manufactured by Nippon Denshoku Industries Co., Ltd.), a liquid measuring unit, and a liquid measuring cell having an optical path length of 20 mm.

Examples of a specific preferred numerical value include 0.4%, 1.0%, 9%, and 24%.

<Layer of High Refractive Index>

The transfer film also preferably has a layer of high refractive index.

The layer of high refractive index is preferably disposed adjacent to the photosensitive layer, and is also preferably disposed on a side opposite to the temporary support in a case of being viewed from the photosensitive layer.

The layer of high refractive index is not particularly limited except that the layer has a refractive index of 1.50 or more at a wavelength of 550 nm.

The above-described refractive index of the layer of high refractive index is preferably 1.55 or more and more preferably 1.60 or more.

The upper limit of the refractive index of the layer of high refractive index is not particularly limited, but is preferably 2.10 or less, more preferably 1.85 or less, still more preferably 1.78 or less, and particularly preferably 1.74 or less.

In addition, it is preferable that the refractive index of the layer of high refractive index is higher than the refractive index of the photosensitive layer.

The layer of high refractive index may have photocuring properties (that is, photosensitivity), may have thermosetting properties, or may have both photocuring properties and thermosetting properties.

The aspect in which the layer of high refractive index has photosensitivity, has an advantage, from a viewpoint of collectively patterning the photosensitive layer and the layer of high refractive index transferred onto the base material by photolithography at one time, after the transferring.

The layer of high refractive index preferably has alkali solubility (for example, solubility with respect to weak alkali aqueous solution).

In addition, the layer of high refractive index is preferably a transparent layer.

A film thickness of the layer of high refractive index is preferably 500 nm or less, more preferably 110 nm or less, and still more preferably 100 nm or less.

In addition, the film thickness of the layer of high refractive index is preferably 20 nm or more, more preferably 55 nm or more, still more preferably 60 nm or more, and particularly preferably 70 nm or more.

After the transferring, the layer of high refractive index may be sandwiched between a transparent electrode pattern (preferably, an ITO pattern) and the photosensitive layer to form a laminate together with the transparent electrode pattern and the photosensitive layer. In this case, by reducing a difference in refractive index between the transparent electrode pattern and the layer of high refractive index and a difference in refractive index between the layer of high refractive index and the photosensitive layer, a light reflection is further reduced. As a result, covering property of the transparent electrode pattern is further improved.

For example, in a case where the transparent electrode pattern, the layer of high refractive index, and the photosensitive layer are laminated in this order, this transparent electrode pattern is less likely to be visually recognized in a case of being viewed from the transparent electrode pattern side.

The refractive index of the layer of high refractive index is preferably adjusted in accordance with the refractive index of the transparent electrode pattern.

For example, in a case where the transparent electrode pattern is formed of an oxide of In and Sn (ITO), the refractive index of the transparent electrode pattern is in a range of 1.8 to 2.0, and the refractive index of the layer of high refractive index is preferably 1.60 or more. The upper limit of the refractive index of the layer of high refractive index in this case is not particularly limited, but is preferably 2.1 or less, more preferably 1.85 or less, still more preferably 1.78 or less, and particularly preferably 1.74 or less.

For example, in a case where the transparent electrode pattern is formed of an oxide of In and Zn (Indium Zinc Oxide; IZO), the refractive index of the transparent electrode pattern is more than 2.0, and the refractive index of the layer of high refractive index is preferably 1.70 to 1.85.

A method for controlling the refractive index of the layer of high refractive index is not particularly limited, and examples thereof include a method using a resin having a predetermined refractive index alone, a method using a resin and metal oxide particles or metal particles, and a method using a composite body of a metal salt and a resin.

The type of the metal oxide particles or the metal particles is not particularly limited, and known metal oxide particles or metal particles can be used. The metal of the metal oxide particles or the metal particles also includes semimetal such as B, Si, Ge, As, Sb, or Te.

From the viewpoint of transparency, for example, an average primary particle diameter of the particles (metal oxide particles or metal particles) is preferably 1 to 200 nm and more preferably 3 to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

Specifically, as the metal oxide particles, at least one selected from the group consisting of zirconium oxide particles (ZrO₂ particles), Nb₂O₅ particles, titanium oxide particles (TiO₂ particles), silicon dioxide particles (SiO₂ particles), and composite particles thereof is preferable.

Among these, for example, from the viewpoint that the refractive index of the layer of high refractive index can be easily adjusted to 1.6 or more, the metal oxide particles are more preferably at least one selected from the group consisting of zirconium oxide particles and titanium oxide particles.

In a case where the layer of high refractive index includes metal oxide particles, the layer of high refractive index may include only one kind of metal oxide particles, or may include two or more kinds thereof.

From the viewpoint that covering property of a concealed object such as the electrode pattern is improved and visibility of the concealed object can be effectively improved, a content of the particles (metal oxide particles or metal particles) is preferably 1% to 95% by mass, more preferably 20% to 90% by mass, and still more preferably 40% to 85% by mass with respect to the total mass of the layer of high refractive index.

In a case where titanium oxide is used as the metal oxide particles, a content of the titanium oxide particles is preferably 1% to 95% by mass, more preferably 20% to 90% by mass, and still more preferably 40% to 85% by mass with respect to the total mass of the layer of high refractive index.

Examples of a commercially available product of the metal oxide particles include calcined zirconium oxide particles (manufactured by CIK-Nano Tek., product name: ZRPGM15WT %-F04), calcined zirconium oxide particles (manufactured by CIK-Nano Tek., product name: ZRPGM15WT %-F74), calcined zirconium oxide particles (manufactured by CIK-Nano Tek., product name: ZRPGM15WT %-F75), calcined zirconium oxide particles (manufactured by CIK-Nano Tek., product name: ZRPGM15WT %-F76), zirconium oxide particles (NanoUse OZ-S30M, manufactured by Nissan Chemical Corporation), and zirconium oxide particles (NanoUse OZ-S30K, manufactured by Nissan Chemical Corporation).

The layer of high refractive index preferably includes one or more kinds selected from the group consisting of inorganic particles (metal oxide particles, metal particles, or the like) having a refractive index 1.50 or more (more preferably 1.55 or more and still more preferably 1.60 or more), a resin having a refractive index 1.50 or more (more preferably 1.55 or more and still more preferably 1.60 or more), and a polymerizable compound having a refractive index 1.50 or more (more preferably 1.55 or more and still more preferably 1.60 or more).

According to this aspect, the refractive index of the layer of high refractive index is easily adjusted to 1.50 or more (more preferably 1.55 or more and particularly preferably 1.60 or more).

In addition, the layer of high refractive index preferably includes a binder polymer, a polymerizable monomer, and particles.

With regard to the components of the layer of high refractive index, components of a curable transparent resin layer described in paragraphs 0019 to 0040 and 0144 to 0150 of JP2014-108541A, and components of a transparent layer described in paragraphs 0024 to 0035 and 0110 to 0112 of JP2014-010814A, and components of a composition including ammonium salt described in paragraphs 0034 to 0056 of WO2016/009980A can be referred to.

In addition, it is also preferable that the layer of high refractive index includes a metal oxidation inhibitor.

The metal oxidation inhibitor is a compound which can be used to surface-treat a member that is in direct contact with the layer including the metal oxidation inhibitor (for example, a conductive member formed on the base material) (however, the compound β is excluded).

In a case where the layer of high refractive index includes a metal oxidation inhibitor, during transferring the layer of high refractive index onto the base material (that is, an object to be transferred), a member that is in direct contact with the layer of high refractive index (for example, a conductive member formed on the base material) can be surface-treated. This surface treatment imparts a metal oxide inhibiting function (protection properties) with respect to the member that is in direct contact with the layer of high refractive index.

The metal oxidation inhibitor is preferably a compound having an aromatic ring having a nitrogen atom. The compound having an aromatic ring having a nitrogen atom may have a substituent.

The metal oxidation inhibitor is preferably a compound having a 5-membered aromatic ring having a nitrogen atom as a ring member atom.

The aromatic ring including a nitrogen atom is preferably an imidazole ring, a triazole ring, a tetrazole ring, a thiazole ring, a thiadiazole ring, or a fused ring of any one of these rings and another aromatic ring, and more preferably an imidazole ring, a triazole ring, a tetrazole ring, or a fused ring of any one of these rings and another aromatic ring.

The “another aromatic ring” forming the fused ring may be a homocyclic ring or a heterocyclic ring, is preferably a homocyclic ring, more preferably a benzene ring or a naphthalene ring, and still more preferably a benzene ring.

As the metal oxidation inhibitor, imidazole, benzimidazole, tetrazole, 5-amino-1H-tetrazole, mercaptothiadiazole, or benzotriazole is preferable, and imidazole, benzimidazole, 5-amino-1H-tetrazole, or benzotriazole is more preferable.

A commercially available product may be used as the metal oxidation inhibitor, and as the commercially available product, for example, BT120 manufactured by JOHOKU CHEMICAL CO., LTD., which includes benzotriazole, can be preferably used.

In a case where the layer of high refractive index includes a metal oxidation inhibitor, a content of the metal oxidation inhibitor is preferably 0.1% to 20% by mass, more preferably 0.5% to 10% by mass, and still more preferably 1% to 5% by mass with respect to the total solid content of the layer of high refractive index.

The layer of high refractive index may include a component other than the above-described components.

Examples of other components which can be included in the layer of high refractive index include components same as those which can be included in the photosensitive material according to the embodiment of the present invention.

The layer of high refractive index also preferably includes a surfactant.

A method for forming the layer of high refractive index is not particularly limited.

Examples of the method for forming the layer of high refractive index include a forming method in which a composition for forming the layer of high refractive index in an aspect of including an aqueous solvent is applied to the above-described photosensitive layer which has been formed on the temporary support, and the composition is dried as necessary.

The composition for forming the layer of high refractive index can include each component of the above-described layer of high refractive index.

For example, the composition for forming the layer of high refractive index includes a binder polymer, a polymerizable monomer, particles, and an aqueous solvent.

In addition, as the composition for forming the layer of high refractive index, a composition including ammonium salt, described in paragraphs 0034 to 0056 of WO2016/009980A, is also preferable.

The photosensitive layer and the layer of high refractive index are preferably achromatic. Specifically, in CIE1976 (L*, a*, b*) color space of the total reflection (incidence angle: 8°, light source: D-65 (visual field: 2°)), the L* value is preferably 10 to 90, the a* value is preferably −1.0 to 1.0, and the b* value is preferably −1.0 to 1.0.

<Cover Film>

The transfer film according to the embodiment of the present invention may further have a cover film on a side of the photosensitive layer opposite to the temporary support.

In a case where the transfer film according to the embodiment of the present invention includes a layer of high refractive index, the cover film is preferably disposed on a side opposite to the temporary support (that is, a side opposite to the photosensitive layer) in a case of being viewed from the layer of high refractive index. In this case, for example, the transfer film is a laminate in which “temporary support/photosensitive layer/layer of high refractive index/cover film” are laminated in this order.

The cover film preferably has 5 pieces/m² or less of the number of fisheyes with a diameter of 80 μm or more in the cover film. The “fisheye” means that, in a case where a material is hot-melted, kneaded, extruded, biaxially stretched, cast or the like to produce a film, foreign substances, undissolved substances, oxidatively deteriorated substances, and/or the like of the material are incorporated into the film.

The number of particles having a diameter of 3 μm or more included in the cover film is preferably 30 particles/mm² or less, more preferably 10 particles/mm² or less, and still more preferably 5 particles/mm² or less. As a result, it is possible to suppress defects caused by ruggedness due to the particles included in the cover film being transferred to the photosensitive resin layer.

An arithmetic average roughness Ra of a surface of the cover film is preferably 0.01 μm or more, more preferably 0.02 μm or more, and still more preferably 0.03 μm or more. In a case where Ra is within such a range, for example, in a case where the transfer film has a long shape, take-up property in a case of winding the transfer film can be improved.

In addition, from the viewpoint of suppressing defects during transfer, Ra is preferably less than 0.50 μm, more preferably 0.40 μm or less, and still more preferably 0.30 μm or less.

Examples of the cover film include a polyethylene terephthalate film, a polypropylene film, a polystyrene film, and a polycarbonate film.

As the cover film, for example, films described in paragraphs 0083 to 0087 and 0093 of JP2006-259138A may be used.

As the cover film, for example, ALPHAN (registered trademark) FG-201 manufactured by Oji F-Tex Co., Ltd., ALPHAN (registered trademark) E-201F manufactured by Oji F-Tex Co., Ltd., Cerapeel (registered trademark) 25WZ manufactured by TORAY ADVANCED FILM CO., LTD., or LUMIRROR (registered trademark) 16QS62 (16KS40) manufactured by Toray Industries, Inc. may be used.

<Other Layers>

The transfer film may include a layer other than the above-described layers (hereinafter, also referred to as “other layers”). Examples of the other layers include an interlayer and a thermoplastic resin layer, and known ones can be appropriately adopted.

A preferred aspect of the thermoplastic resin layer is described in paragraphs 0189 to 0193 of JP2014-085643A, and preferred aspects of layers other than the above each are described in paragraphs 0194 to 0196 of JP2014-085643A, and the contents of these publications are incorporated in the present specification.

<Manufacturing Method of Transfer Film>

A manufacturing method of the transfer film is not particularly limited, and a known manufacturing method can be adopted.

The manufacturing method of the transfer film preferably includes a step of forming a photosensitive layer by applying and drying a photosensitive material including a solvent on a temporary support, and more preferably includes a step of further disposing a cover film on the photosensitive layer after the step of forming the photosensitive layer.

In addition, after the step of forming the photosensitive layer, a step of forming a layer of high refractive index by applying and drying a composition for forming the layer of high refractive index may be included. In this case, after the step of forming the layer of high refractive index, it is preferable to further include a step of disposing a cover film on the layer of high refractive index.

[Pattern Forming Method]

A pattern forming method related to the present invention (also referred to as a “pattern forming method according to an embodiment of the present invention”) is not particularly limited as long as it is a pattern forming method using the photosensitive material according to the embodiment of the present invention, but it is preferable to include a step of forming a photosensitive layer on a base material using the photosensitive material according to the embodiment of the present invention, a step of exposing the photosensitive layer in a patterned manner, and a step of developing the exposed photosensitive layer (alkali development or organic solvent development). In a case where the above-described development is an organic solvent development, it is preferable to include a step of further exposing the obtained pattern.

In forming the photosensitive layer on the base material using the photosensitive material according to the embodiment of the present invention, a method in which the above-described transfer film is produced using the photosensitive material, and such a transfer film is used to form the photosensitive layer on the base material may be used. Specifically, examples of such a method include a method in which a surface of the photosensitive layer in the above-described transfer film on an opposite side of the temporary support side is brought into contact with the base material to bond the transfer film and the base material, and then the photosensitive layer in the transfer film is used as the photosensitive layer on the base material.

Examples of specific embodiments of the pattern forming method according to the present invention include the pattern forming methods of the embodiment 1 and the embodiment 2.

Hereinafter, each step of the pattern forming methods of the embodiment 1 and the embodiment 2 will be described in detail.

<Pattern Forming Method of Embodiment 1>

A pattern forming method of an embodiment 1 includes steps X1 to X3. The following step X2 corresponds to a step of reducing the content of the carboxy group derived from the polymer A in the photosensitive layer by the exposure. However, in a case where a developer in the step X3 is an organic solvent-based developer, a step X4 is further included after the step X3.

Step X1: step of forming a photosensitive layer on a base material using the photosensitive material according to the embodiment of the present invention

Step X2: step of exposing the photosensitive layer in a patterned manner

Step X3: step of developing the photosensitive layer exposed in a patterned manner with a developer

Step X4: step of further exposing the pattern formed by the development after the developing step of the step X3

In a case where an alkali developer is used as the developer in the step X3, the above-described photosensitive layer is preferably the photosensitive material of the aspect 1 or the aspect 2. In a case where an organic solvent-based developer is used as the developer in the step X3, the above-described photosensitive layer is preferably the photosensitive material of the aspect 1.

In addition, the pattern forming method of the embodiment 1 is preferably adopted to a transfer film including a photosensitive layer X formed of the photosensitive material of the aspect 1 or the aspect 2 described above.

(Step X1)

The pattern forming method of the embodiment 1 includes a step of forming a photosensitive layer on a base material using the photosensitive material according to the embodiment of the present invention.

Base Material

The base material is not particularly limited, and examples thereof include a glass substrate, a silicon substrate, a resin substrate, and a substrate having a conductive layer. Examples of the substrate included in the substrate having a conductive layer include a glass substrate, a silicon substrate, and a resin substrate.

The above-described base material is preferably transparent.

A refractive index of the above-described base material is preferably 1.50 to 1.52.

The above-described base material may be composed of a translucent substrate such as a glass substrate, and for example, tempered glass typified by Gorilla glass of Corning can also be used. In addition, as the material included in the above-described base material, materials used in JP2010-086684A, JP2010-152809A, and JP2010-257492A are also preferable.

In a case where the above-described base material includes a resin substrate, as the resin substrate, it is more preferable to use a resin film having a small optical distortion and/or a high transparency. Specific examples of the material include polyethylene terephthalate (PET), polyethylene naphthalate, polycarbonate, triacetyl cellulose, and a cycloolefin polymer.

As the substrate included in the substrate having a conductive layer, from the viewpoint of manufacturing by roll-to-roll method, a resin substrate is preferable and a resin film is more preferable.

Examples of the conductive layer include any conductive layer used for general circuit wiring or touch panel wiring.

As the conductive layer, from the viewpoint of conductivity and fine line formability, one or more layers selected from the group consisting of a metal layer, a conductive metal oxide layer, a graphene layer, a carbon nanotube layer, and a conductive polymer layer are preferable, a metal layer is more preferable, and a copper layer or a silver layer is still more preferable.

In addition, the conductive layer in the substrate having a conductive layer may be one layer or two or more layers.

In a case where the substrate having a conductive layer includes two or more conductive layers, it is preferable that each conductive layer is a conductive layer formed of different materials.

Examples of a material of the conductive layer include simple substances of metal and conductive metal oxides.

Examples of the simple substance of metal include Al, Zn, Cu, Fe, Ni, Cr, Mo, Ag, and Au.

Examples of the conductive metal oxide include indium tin oxide (ITO), indium zinc oxide (IZO), and SiO₂. The “conductive” means that a volume resistivity is less than 1×10⁶ Ω·cm, and the volume resistivity is preferably less than 1×10⁴ Ω·cm.

In a case where the number of conductive layers in the substrate having a conductive layer is 2 or more, it is preferable that at least one conductive layer among the conductive layers includes the conductive metal oxide.

The conductive layer is preferably an electrode pattern corresponding to a sensor in a visual recognition portion used for a capacitive touch panel or a wiring line for a peripheral wiring portion.

In addition, the conductive layer is preferably a transparent layer.

Procedure of Step X1

The step X1 is not particularly limited as long as the photosensitive layer can be formed on the base material by using the photosensitive material according to the embodiment of the present invention.

For example, a photosensitive material including a solvent may be applied to the base material to form a coating film, and the coating film may be dried to form the photosensitive layer on the base material. Examples of such a method of forming the photosensitive layer on the base material include the same method as the method for forming the photosensitive layer described in the transfer film above.

In addition, it is also preferable that the photosensitive material used for forming the photosensitive layer on the base material in the step X1 is the photosensitive material included in the above-described transfer film (photosensitive layer included in the transfer film). That is, it is also preferable that the photosensitive layer formed in the step X1 is a layer formed by using the above-described transfer film.

In a case where the photosensitive layer is formed on the base material by using the transfer film, the step X1 is preferably a step of bringing a surface of the photosensitive layer in the transfer film on an opposite side of the temporary support side into contact with the base material to bond the transfer film and the base material. Such a step is also particularly referred to as a step X1b.

The step X1b is preferably a bonding step of pressurization by a roll or the like and heating. A known laminator such as a laminator, a vacuum laminator, and an auto-cut laminator can be used for the bonding.

The step X1b is preferably performed by a roll-to-roll method, and therefore, the base material to which the transfer film is bonded is preferably a resin film or a resin film having a conductive layer.

Hereinafter, the roll-to-roll method will be described.

The roll-to-roll method refers to a method in which, as the base material, a base material which can be wound up and unwound is used, a step (also referred to as an “unwinding step”) of unwinding the base material or a structure including the base material is included before any of the steps included in the pattern forming method according to the embodiment of the present invention, a step (also referred to as a “winding step”) of winding the base material is included after any of the steps, and at least one of the steps (preferably, all steps or all steps other than the heating step) is performed while transporting the base material.

An unwinding method in the unwinding step and a winding method in the winding step are not particularly limited, and a known method may be used in the manufacturing method to which the roll-to-roll method is adopted.

(Step X2)

The pattern forming method of the embodiment 1 includes a step (step X2) of exposing the photosensitive layer in a patterned manner after the above-described step X1. The step X2 corresponds to a step of reducing the content of the carboxy group derived from the polymer A in the photosensitive layer by the exposure. More specifically, it is preferable that, by using light having a wavelength which excites the structure b0 (preferably, the structure b) in the photosensitive layer, the photosensitive layer is exposed in a patterned manner.

The above-described structure b0 (preferably, the structure b) in the photosensitive layer may be a structure of the compound β (preferably, the compound B) included in the photosensitive layer, may be a structure of the polymer A (polymer Ab0, preferably, the polymer Ab) included in the photosensitive layer, or may be both.

Detailed arrangement and specific size of the pattern in the exposing step are not particularly limited.

For example, in a case where the pattern forming method of the embodiment 1 is adopted to the manufacturing of a circuit wiring, from the viewpoint of improving display quality of a display device (for example, a touch panel) including an input device having the circuit wiring manufactured by the pattern forming method of the embodiment 1, and viewpoint of reducing an area occupied by a lead-out wiring as much as possible, at least a part of the pattern (in particular, a portion of the electrode pattern of the touch panel and the lead-out wiring) is preferably a thin line having a width of 100 μm or less, and more preferably a thin line having a width of 70 μm or less.

As a light source used for the exposure, any light source which irradiates light in a wavelength range capable of reducing the content of the carboxy group derived from the polymer A in the photosensitive layer (light having a wavelength which excites the structure b0 (preferably, the structure b) in the photosensitive layer; examples thereof include light in a wavelength range such as 254 nm, 313 nm, 365 nm, and 405 nm) can be appropriately selected. Specific examples thereof include an ultra-high pressure mercury lamp, a high pressure mercury lamp, a metal halide lamp, and a light emitting diode (LED).

An exposure amount is preferably 10 to 10000 mJ/cm² and more preferably 50 to 3000 mJ/cm².

In a case where the step X1 is the step X1b, in the step X2, the temporary support may be peeled off from the photosensitive layer and then the pattern exposure may be performed, or before peeling off the temporary support, the pattern exposure may be performed through the temporary support and then the temporary support may be peeled off. In order to prevent mask contamination due to contact between the photosensitive layer and the mask and to avoid an influence of foreign substance adhering to the mask on the exposure, it is preferable to perform the pattern exposure without peeling off the temporary support. The pattern exposure may be an exposure through a mask and a direct exposure using a laser or the like.

(Step X3)

The pattern forming method of the embodiment 1 includes a step (step X3) of, after the above-described step X2, developing the photosensitive layer exposed in a patterned manner with a developer (alkali developer or organic solvent-based developer).

By reducing the content of the carboxy group in the photosensitive layer of the exposed portion, a difference in solubility (dissolution contrast) in the developer may occur between the exposed portion and the non-exposed portion of the photosensitive layer which has undergone the step X2. By forming the dissolution contrast in the photosensitive layer, it is possible to form a pattern in the step X3. In a case where the developer in the above-described step X3 is an alkali developer, the non-exposed portion is removed and a negative pattern is formed by performing the above-described step X3. On the other hand, in a case where the developer in the above-described step X3 is an organic solvent-based developer, the exposed portion is removed and a positive pattern is formed by performing the above-described step X3. For the obtained positive pattern, it is necessary to perform a treatment for reducing the content of the carboxy group derived from the polymer A by the step X4 described later.

Alkali Developer

The alkali developer is not particularly limited as long as the non-exposed portion of the photosensitive resin layer can be removed, and a known developer such as a developer described in JP1993-072724A (JP-H5-072724A) can be used.

As the alkali developer, for example, an alkali aqueous solution-based developer including a compound having a pKa of 7 to 13 at a concentration of 0.05 to 5 mol/liter (L) is preferable.

In addition, the alkali developer may further include a water-soluble organic solvent, a surfactant, and the like. As the alkali developer, for example, developers described in paragraph 0194 of WO2015/093271A are preferable.

Organic Solvent-Based Developer

The organic solvent-based developer is not particularly limited as long as it can remove the exposed portion of the photosensitive resin layer, and for example, a developer including an organic solvent such as a ketone-based solvent, an ester-based solvent, an alcohol-based solvent, an amide-based solvent, an ether-based solvent, and a hydrocarbon-based solvent can be used.

In the organic solvent-based developer, a plurality of organic solvents may be mixed, or may be mixed with an organic solvent other than the above or water and used. However, in order to fully exert the effects of the present invention, a moisture content of the organic solvent-based developer as a whole is preferably less than 10% by mass, and the organic solvent-based developer is more preferably substantially free of the moisture. A concentration of the organic solvent (in a case of mixing a plurality of organic solvents, a total thereof) in the organic solvent-based developer is preferably 50% by mass or more, more preferably 60% by mass or more, still more preferably 85% by mass or more, particularly preferably 90% by mass or more, and most preferably 95% by mass or more. The upper limit value thereof is, for example, 100% by mass or less.

A development method is not particularly limited, and may be any of a puddle development, a shower development, a spin development, a dip development, or the like. Here, as the shower development, unnecessary portions can be removed by spraying the developer on the photosensitive resin layer after the exposure with a shower. In addition, after the development, it is also preferable to spray a washing agent and the like with a shower and rub with a brush and the like to remove the developing residue. A liquid temperature of the developer is preferably 20° C. to 40° C.

The pattern forming method of the embodiment 1 may further include a post-baking step of heat-treating a pattern including the photosensitive layer obtained by development.

The post-baking is preferably performed in an environment of 8.1 to 121.6 kPa, and more preferably performed in an environment of 50.66 kPa or more. On the other hand, it is more preferably performed in an environment of 111.46 kPa or less, and still more preferably performed in an environment of 101.3 kPa or less.

A temperature of the post-baking is preferably 80° C. to 250° C., more preferably 110° C. to 170° C., and still more preferably 130° C. to 150° C.

A time of the post-baking is preferably 1 to 60 minutes, more preferably 2 to 50 minutes, and still more preferably 5 to 40 minutes.

The post-baking may be performed in an air environment or a nitrogen replacement environment.

(Step X4)

In a case where the developer in the above-described step X3 is an organic solvent-based developer, the step X4 is performed on the obtained positive pattern. The step X4 corresponds to a step of exposing the positive pattern obtained in the step X3 to reduce the content of the carboxy group derived from the polymer A. More specifically, it is preferable that, by using light having a wavelength which excites the structure b0 (preferably, the structure b) in the photosensitive layer, the photosensitive layer is exposed in a patterned manner.

A light source and exposure amount used for the exposure are the same as the light source and exposure amount described in the step X1, and preferred aspects thereof are also the same.

<Pattern Forming Method of Embodiment 2>

A pattern forming method of an embodiment 2 includes a step Y1, a step Y2P, and a step Y3 in this order, and further includes a step Y2Q (step of further exposing the photosensitive layer exposed in the step Y2P) between the step Y2P and the step Y3 or after the step Y3.

Step Y1: step of forming a photosensitive layer on a base material using the photosensitive material according to the embodiment of the present invention

Step Y2P: step of exposing the photosensitive layer

Step Y2Q: step of further exposing the exposed photosensitive layer

Step Y3: step of developing the photosensitive layer with a developer

The pattern forming method of the embodiment 2 is preferably adopted to a case where the photosensitive layer further includes a photopolymerization initiator and a polymerizable compound. Therefore, the pattern forming method of the embodiment 2 is preferably adopted to the photosensitive material of the aspect 3 described above.

Hereinafter, the pattern forming method of the embodiment 2 will be described, but the step Y1 and the step Y3 are the same as the step X1 and the step X3, respectively, so that the description thereof will be omitted.

It is sufficient that the step Y3 is performed at least after the step Y2P, and the step Y3 may be performed between the step Y2P and the step Y2Q.

The pattern forming method of the embodiment 2 may further include, after the step Y3, a post-baking step of heat-treating a pattern including the photosensitive layer obtained by development. The post-baking step can be performed by the same method as the post-baking step which may be included in the above-described pattern forming method of the embodiment 1. In a case where the step Y3 is performed between the step Y2P and the step Y2Q, the post-baking step may be performed before the step Y2Q or after the step Y2Q as long as it is performed after the step Y3.

(Step Y2P and Step Y2Q)

The pattern forming method of the embodiment 2 includes a step (step Y2P) of exposing the photosensitive layer through the step Y1 and a step (step Y2Q) of further exposing the exposed photosensitive layer.

One of the exposure treatments (the step Y2P and the step Y2Q) is an exposure for mainly reducing the content of the carboxy group of the polymer A by the exposure, and the other one of the exposure treatments (the step Y2P and the step Y2Q) is an exposure for mainly causing a polymerization reaction of the polymerizable compound based on the photopolymerization initiator. In addition, the exposure treatments (the step Y2P and the step Y2Q) may be either the entire exposure or the pattern exposure, but any one of the exposure treatments is the pattern exposure.

For example, in a case where the step Y2P is a pattern exposure for reducing the content of the carboxy group of the polymer A by the exposure, the developer used in the step Y3 may be an alkali developer or an organic solvent-based developer. However, in a case of developing with an organic solvent-based developer, the step Y2Q is usually performed after the step Y3, and in the developed photosensitive layer (pattern), the polymerization reaction of the polymerizable compound based on the photopolymerization initiator occurs, and the content of the carboxy group derived from the polymer A is reduced.

In addition, for example, in a case where the step Y2P is a pattern exposure for causing a polymerization reaction of the polymerizable compound based on the photopolymerization initiator, the developer used in the step Y3 is usually an alkali developer. In this case, the step Y2Q may be performed before or after the step Y3, and the step Y2Q in a case of being performed before the step Y3 is usually a pattern exposure.

In the step Y2P and the step Y2Q, as a light source used for the exposure, any light source which irradiates light in a wavelength range capable of reducing the content of the carboxy group of the polymer A in the photosensitive layer (light having a wavelength which excites the structure b0 (preferably, the structure b) in the photosensitive layer; examples thereof include light in a wavelength range such as 254 nm, 313 nm, 365 nm, and 405 nm) or light in a wavelength range capable of causing a reaction of the polymerizable compound based on the photopolymerization initiator in the photosensitive layer (light having a wavelength which exposes the photopolymerization initiator; examples thereof include 254 nm, 313 nm, 365 nm, and 405 nm) can be appropriately selected. Specific examples thereof include an ultra-high pressure mercury lamp, a high pressure mercury lamp, a metal halide lamp, and a light emitting diode (LED).

In the exposure for reducing the content of the carboxy group of the polymer A in the photosensitive layer, an exposure amount is preferably 10 to 10000 mJ/cm², and more preferably 50 to 3000 mJ/cm².

In the exposure for causing a reaction of the polymerizable compound based on the photopolymerization initiator in the photosensitive layer, an exposure amount is preferably 5 to 200 mJ/cm², and more preferably 10 to 150 mJ/cm².

In a case where the step Y1 is performed in the same method as shown as the step X1b, in the step Y2P and/or the step Y2Q, the temporary support may be peeled off from the photosensitive layer and then the pattern exposure may be performed, or before peeling off the temporary support, the pattern exposure may be performed through the temporary support and then the temporary support may be peeled off. In order to prevent mask contamination due to contact between the photosensitive layer and the mask and to avoid an influence of foreign substance adhering to the mask on the exposure, it is preferable to perform the pattern exposure without peeling off the temporary support. The pattern exposure may be an exposure through a mask and a direct exposure using a laser or the like.

Detailed arrangement and specific size of the pattern in the exposing step are not particularly limited.

For example, in a case where the pattern forming method of the embodiment 2 is adopted to the manufacturing of a circuit wiring, from the viewpoint of improving display quality of a display device (for example, a touch panel) including an input device having the circuit wiring manufactured by the pattern forming method of the embodiment 2, and viewpoint of reducing an area occupied by a lead-out wiring as much as possible, at least a part of the pattern (in particular, a portion of the electrode pattern of the touch panel and the lead-out wiring) is preferably a thin line having a width of 100 μm or less, and more preferably a thin line having a width of 70 μm or less.

(Suitable Aspect)

Among these, as the pattern forming method of the embodiment 2, it is preferable that the step Y2P is a step Y2A, the step Y2Q is a step Y2B, a step Y1, a step Y2A, a step Y3, and a step Y2B are included in this order. One of the step Y2A and the step Y2B is an exposing step for reducing the content of the carboxy group of the polymer A by the exposure, and the other is an exposing step for causing a reaction between the photopolymerization initiator and the polymerizable compound.

Step Y1: step of forming a photosensitive layer on a base material using the photosensitive material according to the embodiment of the present invention (preferably, a step of bringing a surface of the photosensitive layer in the transfer film on an opposite side of the temporary support side into contact with the base material to bond the transfer film and the base material)

Step Y2A: step of exposing the photosensitive layer in a patterned manner

Step Y3: step of developing the photosensitive layer with an alkali developer to form a patterned photosensitive layer

Step Y2B: step of exposing the patterned photosensitive layer

The above-described step Y2A is preferably an exposing step for causing a reaction between the photopolymerization initiator and the polymerizable compound, and the above-described step Y2B is preferably an exposing step for reducing the content of the carboxy group derived from the polymer A by the exposure.

<Optional Step which May be Included in Pattern Forming Methods of Embodiment 1 and Embodiment 2>

The pattern forming methods of the embodiment 1 and the embodiment 2 may include optional steps (other steps) in addition to those described above. Examples thereof include the following steps, but the other steps are not limited to these steps.

(Cover Film Peeling Step)

In the above-described pattern forming method, in a case where the photosensitive layer is formed on the base material using the transfer film and the transfer film has a cover film, it is preferable to include a step (hereinafter, also referred to as a “cover film peeling step”) of peeling off the cover film of the transfer film. A method of peeling off the cover film is not particularly limited, and a known method can be adopted.

(Step of Reducing Visible Light Reflectivity)

In a case where the substrate is the substrate having a conductive layer, the above-described pattern forming method may further include a step of performing a treatment of reducing a visible light reflectivity of the conductive layer. In a case where the above-described substrate is a substrate having a plurality of conductive layers, the treatment of reducing the visible light reflectivity may be performed on some conductive layers or all conductive layers.

Examples of the treatment of reducing the visible light reflectivity include an oxidation treatment. For example, by oxidizing copper to copper oxide, the visible light reflectivity of the conductive layer can be reduced due to blackening.

Preferred aspects of the treatment of reducing the visible light reflectivity are described in paragraphs 0017 to 0025 of JP2014-150118A, and paragraphs 0041, 0042, 0048, and 0058 of JP2013-206315A, and the contents of these publications are incorporated in the present specification.

(Etching Step)

In a case where the substrate is the substrate having a conductive layer, the above-described pattern forming method preferably includes a step (etching step) of etching, using the pattern formed by the step X3 (or the step X4) and the step Y3 as an etching resist film, the conductive layer in a region where the etching resist film is not disposed.

As a method of the etching treatment, a method by wet etching, which is described in paragraphs 0048 to 0054 of JP2010-152155A, a method by dry etching such as a known plasma etching, or the like can be adopted.

For example, examples of the method of the etching treatment include a wet etching method by immersing in an etchant, which is generally performed. As the etchant used for the wet etching, an acidic type or alkaline type etchant may be appropriately selected according to the etching target.

Examples of the acidic type etchant include aqueous solutions of acidic component alone, such as hydrochloric acid, sulfuric acid, hydrofluoric acid, and phosphoric acid, and mixed aqueous solutions of an acidic component and a salt such as ferric chloride, ammonium fluoride, and potassium permanganate. As the acidic component, a component in which a plurality of acidic components is combined may be used.

Examples of the alkaline type etchant include aqueous solutions of alkaline component alone, such as sodium hydroxide, potassium hydroxide, ammonia, organic amine, and a salt of organic amine such as tetramethylammonium hydroxide, and mixed aqueous solutions of an alkaline component and a salt such as potassium permanganate. As the alkaline component, a component in which a plurality of alkaline components is combined may be used.

A temperature of the etchant is not particularly limited, but is preferably 45° C. or lower. In a manufacturing method of a circuit wiring according to an embodiment of the present invention, the pattern formed by the step X3 (or the step X4) and the step Y3 used as the etching resist film preferably exhibits particularly excellent resistance to the acidic and alkaline etchant in a temperature range of 45° C. or lower. With the above-described configuration, the etching resist film is prevented from peeling off during the etching step, and a portion where the etching resist film does not exist is selectively etched.

After the etching step, in order to prevent contamination of the process line, a washing step of washing the etched substrate and a drying step of drying the washed substrate may be performed as necessary.

The film used as the etching resist film may be removed, or may not be removed and be used as a protective film (permanent film) for a conductive layer of a circuit wiring.

### Other Embodiments

As the above-described pattern forming method, it is also preferable to use a substrate having a plurality of conductive layers on both surfaces and sequentially or simultaneously form a pattern on the conductive layers formed on both surfaces.

With such a configuration, it is possible to form a first conductive pattern is formed on one surface of the substrate and form a second conductive pattern on the other surface. It is also preferable to form from both surfaces of the base material by the roll-to-roll.

<Pattern>

The pattern formed by the above-described pattern forming methods of the embodiment 1 and the embodiment 2 has reduced content of the carboxy group, so that polarity is low, and relative permittivity is low.

The content of the carboxy group in the above-described pattern is preferably reduced by 5 mol % or more, more preferably reduced by 10 mol % or more, still more preferably reduced by 20 mol % or more, even more preferably reduced by 31 mol % or more, particularly preferably reduced by 40 mol % or more, more particularly preferably reduced by 51 mol % or more, and most preferably reduced by 71 mol % or more with respect to the content of the carboxy group in the photosensitive layer formed in the step X1 or the step Y1. The upper limit value thereof is not particularly limited, and for example, is 100 mol % or less.

The moisture permeability of the above-described pattern is preferably reduced by 5% or more, more preferably reduced by 10% or more, and still more preferably reduced by 20% or more with respect to the moisture permeability of the photosensitive layer formed in the step X1 or the step Y1. The upper limit value thereof is not particularly limited, and for example, is 100% or less.

The relative permittivity of the above-described pattern is preferably reduced by 5% or more, more preferably reduced by 10% or more, and still more preferably reduced by 15% or more with respect to the relative permittivity of the photosensitive layer formed in the step X1 or the step Y1. The upper limit value thereof is not particularly limited, and for example, is 100% or less.

An average thickness of the pattern formed by the above-described pattern forming method is preferably 0.5 to 20 μm. The average thickness of the pattern is more preferably 0.8 to 15 μm and still more preferably 1.0 to 10 μm.

The pattern formed by the above-described pattern forming method is preferably achromatic. Specifically, in CIE1976 (L*, a*, b*) color space, the total reflection (incidence angle: 8°, light source: D-65 (visual field: 2°)) preferably has a pattern L* value of 10 to 90, preferably has a pattern a* value of −1.0 to 1.0, and preferably has a pattern b* value of −1.0 to 1.0.

The use of the pattern formed by the above-described pattern forming method is not particularly limited, and can be used as various protective films or insulating films.

Specific examples thereof include the use as a protective film (permanent film) which protects a conductive pattern, the use as a interlayer insulating film between conductive patterns, and the use as an etching resist film in the manufacturing of the circuit wiring. Among these, since the above-described pattern has a reduced relative permittivity, it is preferably used as a protective film (permanent film) which protects the conductive pattern or an interlayer insulating film between the conductive patterns. In addition, after using the pattern as an etching resist film, it may be used as it as a protective film (permanent film).

The above-described pattern can be used as a protective film (permanent film) which protects a conductive pattern such as an electrode pattern corresponding to a sensor in a visual recognition portion and a wiring line for a peripheral wiring portion and a lead-out wiring portion is provided inside the touch panel, or as an interlayer insulating film between conductive patterns.

[Manufacturing Method of Circuit Wiring]

The present invention also relates to a manufacturing method of a circuit wiring.

The manufacturing method of a circuit wiring related to the present invention (also referred to as a “manufacturing method of a circuit wiring according to an embodiment of the present invention) is not particularly limited as long as it is a manufacturing method of a circuit wiring using the above-described photosensitive material, but it is preferable to include, in the following order, a step (photosensitive layer forming step) of forming a photosensitive layer on a conductive layer in a substrate having a conductive layer using a photosensitive material (preferably, the photosensitive material of the aspect 3), a step (first exposing step) of exposing the photosensitive layer in a patterned manner, a step (alkali developing step) of developing the exposed photosensitive layer with an alkali developer to form a patterned photosensitive layer, a step (second exposing step) of exposing the patterned photosensitive layer to form an etching resist film, and a step (etching step) of etching the conductive layer in a region on which the etching resist film is not disposed.

The above-described photosensitive layer forming step is also preferably a step (bonding step) of bringing a surface of the photosensitive layer in the above-described transfer film on an opposite side of the temporary support side into contact with a conductive layer in a substrate having a conductive layer to bond the transfer film and the substrate having a conductive layer.

In the manufacturing method of a circuit wiring according to the embodiment of the present invention, all of the photosensitive layer forming step, the first exposing step, the alkali developing step, and the second exposing step can be performed by the same procedure as in the step Y1, the step Y2A, the step Y3, and the step Y2B of the above-described pattern forming method of the embodiment 2. In addition, the substrate having a conductive layer, which is used in the manufacturing method of a circuit wiring according to the embodiment of the present invention, is the same as the substrate having a conductive layer, which is used in the above-described step X1. In addition, the manufacturing method of a circuit wiring according to the embodiment of the present invention may include a step other than the above-described steps. Examples of other steps include the same steps as the optional step which may be included in the pattern forming methods of the embodiment 1 and the embodiment 2.

In the manufacturing method of a circuit wiring according to the embodiment of the present invention, five steps of the above-described bonding step, the above-described first exposing step, the above-described developing step, the above-described second exposing step, and the above-described etching step are regarded as one set, and it is also preferable to repeat the set a plurality of times.

The film used as the etching resist film can also be used as a protective film (permanent film) for the formed circuit wiring.

[Manufacturing Method of Touch Panel]

The present invention also relates to a manufacturing method of a touch panel.

A manufacturing method of a touch panel related to the present invention (also referred to as a “manufacturing method of a touch panel according to an embodiment of the present invention) is not particularly limited as long as it is a manufacturing method of a touch panel using the above-described photosensitive material, but it is preferable to include, in the following order, a step (photosensitive layer forming step) of forming a photosensitive layer on a conductive layer (preferably, a patterned conductive layer; specifically, a touch panel electrode pattern or a conductive pattern such as a wiring pattern) in a substrate having the conductive layer using a photosensitive material (preferably, the photosensitive material of the aspect 3), a step (first exposing step) of exposing the photosensitive layer in a patterned manner, a step (alkali developing step) of developing the exposed photosensitive layer with an alkali developer to form a patterned photosensitive layer, and a step (second exposing step) of exposing the patterned photosensitive layer to form a protective film or an insulating film of the conductive layer.

The protective film formed by the second exposing step has a function as a film which protects the surface of the conductive layer. In addition, the insulating film has a function as an interlayer insulating film between conductive layers. In a case where the second exposing step is a step of forming an insulating film of the conductive layer, it is preferable that the manufacturing method of a touch panel according to the embodiment of the present invention further includes a step of forming a conductive layer (preferably, a patterned conductive layer; specifically, a touch panel electrode pattern or a conductive pattern such as a wiring line) on the insulating film formed by the second exposing step.

The above-described photosensitive layer forming step is also preferably a step (bonding step) of bringing a surface of the photosensitive layer in the above-described transfer film on an opposite side of the temporary support side into contact with a conductive layer in a substrate having a conductive layer to bond the transfer film and the substrate having a conductive layer.

In the manufacturing method of a touch panel according to the embodiment of the present invention, all of the photosensitive layer forming step, the first exposing step, the alkali developing step, and the second exposing step can be performed by the same procedure as in the step Y1, the step Y2A, the step Y3, and the step Y2B of the above-described pattern forming method of the embodiment 2. In addition, the substrate having a conductive layer, which is used in the manufacturing method of a touch panel according to the embodiment of the present invention, is the same as the substrate having a conductive layer, which is used in the above-described step X1. Examples of other steps include the same steps as the optional step which may be included in the pattern forming methods of the embodiment 1 and the embodiment 2.

As the manufacturing method of a touch panel according to the embodiment of the present invention, a known manufacturing method of a touch panel can be referred to for configurations other than those described above.

The touch panel manufactured by the manufacturing method of a touch panel according to the embodiment of the present invention preferably has a transparent substrate, an electrode, and a protective film (protective layer).

As a detection method in the touch panel, any known method such as a resistive film method, a capacitance method, an ultrasonic method, an electromagnetic induction method, and an optical method may be used. Among these, a capacitance method is preferable.

Examples of the touch panel type include a so-called in-cell type (for example, those shown in FIGS. 5, 6, 7, and 8 of JP2012-517051B), a so-called on-cell type (for example, one described in FIG. 19 of JP2013-168125A and those described in FIGS. 1 and 5 of JP2012-089102A), an one glass solution (OGS) type, a touch-on-lens (TOL) type (for example, one described in FIG. 2 of JP2013-054727A), other configurations (for example, those described in FIG. 6 of JP2013-164871A), and various out-cell types (so-called GG, G1-G2, GFF, GF2, GF1, G1F, and the like).

### EXAMPLES

Hereinafter, the present invention will be described in detail with reference to Examples. The material, the amount used, the proportion, the process contents, the process procedure, and the like shown in the following examples can be appropriately changed, within a range not departing from the gist of the present disclosure. Therefore, the scope of the present invention is not limited to the specific examples described below. “part” and “%” are based on mass unless otherwise specified.

In the following Examples, unless otherwise specified, H03-L31 manufactured by Eye Graphics Co., Ltd. was used as a high-pressure mercury lamp. The above-described high-pressure mercury lamp has strong line spectrum at 254 nm, 313 nm, 405 nm, and 436 nm with a wavelength of 365 nm as a main wavelength.

Unless otherwise specified, USH-2004 MB manufactured by Ushio Inc. was used as an ultra-high pressure mercury lamp. The above-described ultra-high pressure mercury lamp has strong line spectrum at 313 nm, 365 nm, 405 nm, and 436 nm.

### Example 1 System

<Preparation of Photosensitive Material>

A styrene/acrylic acid copolymer (acid value: 200, Mw: 8500, manufactured by Toagosei Co., Ltd., ARUFON UC3910 (product name)) as the polymer A having a carboxy group and the compound β shown in Second table were mixed and dissolved in a mixed solvent of propylene glycol monomethyl ether acetate/methyl ethyl ketone=50/50 (mass ratio) so that a blending amount shown in Second table shown in the latter part was satisfied and a concentration of solid contents of the finally obtained photosensitive material was 25% by mass, thereby obtaining a mixed solution. MEGAFACE F551 (fluorine-containing nonionic surfactant manufactured by DIC Corporation) was added to the above-described mixed solution as a surfactant so that a concentration was 100 ppm by mass with respect to the total solid content of the photosensitive material, thereby preparing a photosensitive material of each of Examples or Comparative Examples.

The blending amount (part by mass) shown in the table is the solid content of each component.

<Evaluation of Physical Properties of Compound β>

(Measurement of pKa of Compound β in Ground State)

The pKa of the compound β in a ground state was measured by the following method using an automatic titrator manufactured by HIRANUMA Co., Ltd. In a case where the compound β was a nitrogen-containing aromatic compound, the pKa of the compound β in a ground state is intended to be a pKa of a conjugate acid of the compound β.

0.1 g of the compound β was dissolved in 20 ml of methanol, and 20 ml of ultrapure water was added thereto. This mixture was titrated using a 0.1 N-HCL aqueous solution, and the pH at ½ of the titration amount required up to the equivalence point was defined as the pKa (pKa of the compound β in a ground state).

(Measurement and Evaluation of ε365 and ε365/ε313)

A molar absorption coefficient ((cm·mol/L)⁻¹, “ε365”) of the compound β at 365 nm and a molar absorption coefficient ((cm·mol/L)⁻¹, “ε313”) of the compound β at 313 nm were obtained, and a value (8365/313) obtained by divided ε365 by ε313 was obtained.

The ε365 and ε313 of the compound β are molar absorption coefficients measured by dissolving the compound β in acetonitrile. In a case where the compound β was insoluble in acetonitrile, a solvent for dissolving the compound β may be appropriately changed.

<Evaluation of Photosensitive Material>

(Production of Photosensitive Layer)

The photosensitive material of each of Examples and Comparative Examples was spin-coated on a silicon wafer, and then the obtained coating film was dried on a hot plate at 80° C. to obtain a photosensitive layer having a film thickness of 5 μm.

The obtained photosensitive layer was evaluated as follows.

(Evaluation of Carboxy Group Consumption Rate (IR Measurement))

The obtained photosensitive layer was entirely exposed using a high-pressure mercury lamp. The integrated exposure amount measured with a 365 nm illuminance meter was 1000 mJ/cm². Light emitted from the above-described high-pressure mercury lamp has strong line spectrum at 254 nm, 313 nm, 405 nm, and 436 nm with a wavelength of 365 nm as a main wavelength.

Infrared (IR) spectra of the photosensitive layer were measured before and after the exposure, and a carboxy group consumption rate (mol %) was calculated from a reduction rate of a peak of C═O stretching and contracting (peak of 1710 cm⁻¹) of the carboxy group.

As the carboxy group consumption rate is higher, the decarboxylation reaction is more proceeding.

The results are shown in Second table (see the column of “Carboxy group consumption rate (mol %) [IR measurement]”).

(Evaluation of Carboxy Group Consumption Rate (Measurement of Ashing))

A carboxy group consumption rate was measured by the following procedure.

Measurement of Carboxy Group Amount of Photosensitive Layer after Exposure (Measurement of Carboxy Group Amount after Exposure)

The photosensitive layer obtained in the upper part was exposed under the following exposure conditions.

<<Exposure Conditions>>

The obtained photosensitive layer was entirely exposed using a high-pressure mercury lamp. The integrated exposure amount measured with a 365 nm illuminance meter was 1000 mJ/cm². Light emitted from the above-described high-pressure mercury lamp has strong line spectrum at 254 nm, 313 nm, 405 nm, and 436 nm with a wavelength of 365 nm as a main wavelength.

Next, a total of approximately 20 mg of the photosensitive layer after exposure was scraped off and frozen and pulverized, 150 μL of N-methyl-2-pyrrolidone (NMP) was added thereto, and the mixture was stirred in an aqueous solution of lithium carbonate (Li₂CO₃) (1.2 g/100 mL; lithium carbonate was dissolved in ultrapure water and then filtered through a filter) for 6 days.

After the stirring, particles are settled by ultracentrifugation (140,000 rpm×30 min), the supernatant was replaced with ultrapure water (replacement was repeated 5 times), and the obtained precipitate was dried to dryness and used as an analysis sample (production of a sample in which n=2). This analysis sample was analyzed by ICP-OES (Optima 7300DV manufactured by PerkinElmer Inc.).

The above-described ICP-OES measurement was carried out according to the following procedure.

Approximately 1.5 mg to 2 mg of the above-described analytical sample was weighed (n=3), 5 mL of a 60% HNO₃ aqueous solution was added thereto, and MW Teflon ashing (microwave sample decomposition device UltraWAVE max: 260° C.) was performed.

After the ashing, ultrapure water was added thereto to be 50 mL, and the amount of Li was quantified by an absolute calibration curve method using ICP-OES (Optima 7300DV manufactured by PerkinElmer Inc.).

Measurement of Carboxy Group Amount of Photosensitive Material Before Exposure (Measurement of Carboxy Group Amount Before Exposure)

According to the following procedure, the carboxy group amount of the photosensitive material of each of Examples or Comparative Examples, which was used for forming the above-described photosensitive layer, was measured.

1 g of the photosensitive material was dissolved in 63 ml of tetrahydrofuran, and 12 ml of ultrapure water was added thereto. Next, the obtained solution was titrated with a 0.1 N-NaOH aqueous solution using an automatic titrator manufactured by HIRANUMA Co., Ltd. The carboxy group amount in the photosensitive material was calculated by converting the carboxy group amount obtained by the titration into a concentration of solid contents.

Calculation of Decarboxylation Rate

Based on the measurement results of the carboxy group amount before and after the exposure described above, a decarboxylation rate was calculated by the following expression.

{(Carboxy group amount before exposure−Carboxy group amount after exposure)/Carboxy group amount before exposure}×100(%) Decarboxylation rate (%):

Based on the obtained numerical values, evaluation was performed according to the following evaluation standard.

However, in a case of the above-described method, there was a detection limit. In a case where the content of the carboxy group was 1.05 mmol/g or less, 90% or more of Li can be substituted. In a region beyond that, a calibration curve was produced using a crosslinked polymer having a known acid value and calculated.

Evaluation Standard

A: decarboxylation rate was 71 mol % or more.

B: decarboxylation rate was 50 mol % or more and less than 71 mol %.

C: decarboxylation rate was 31 mol % or more and less than 50 mol %.

D: decarboxylation rate was 5 mol % or more and less than 31 mol %.

E: decarboxylation rate was less than 5 mol %.

The results are shown in Second table (see the column of “Carboxy group consumption rate [measurement of ashing]).

(Pattern Formability Evaluation 1)

The obtained photosensitive layer was exposed to a high-pressure mercury lamp through any of masks (1) to (3) below. The integrated exposure amount measured with a 365 nm illuminance meter was 1000 mJ/cm².

(1) mask having a line size=25 μm and a line:space=1:1

(2) mask having a line size=50 μm and a line:space=1:1

(3) mask having a line size=250 μm and a line:space=1:1

The exposed photosensitive layer was dip-developed with a 1% by mass sodium carbonate aqueous solution for 30 seconds, and then was rinsed with pure water for 20 seconds and dried to obtain a pattern (line-and-space pattern).

Line-and-space patterns with line widths and space widths of 25 μm, 50 μm, or 250 μm, which were produced as described above, were observed and evaluated as follows.

A: line-and-space pattern was resolved (photosensitive layer in the space portion was removed), and the pattern was not reduced.

B: line-and-space pattern was resolved, but the pattern was slightly reduced.

C: line-and-space pattern was resolved, but the pattern was greatly reduced.

D: line-and-space pattern was not resolved (photosensitive layer in the space portion remained, or the pattern was completely dissolved and disappeared).

(Relative Permittivity Evaluation 1)

The photosensitive material was spin-coated on an aluminum substrate having a thickness of 0.1 mm, and then the obtained coating film was dried on a hot plate at 80° C. to produce a photosensitive layer having a thickness of 8 μm.

The obtained photosensitive layer was entirely exposed using a high-pressure mercury lamp. The integrated exposure amount measured with a 365 nm illuminance meter was 1000 mJ/cm².

For the photosensitive layer after exposure, a relative permittivity at 1 kHz was measured in an environment of 23° C. and 50% RH using an LCR meter 4284A and a dielectric test fixture 16451B manufactured by Agilent Technologies, Inc.

A relative permittivity of the photosensitive layer formed of the photosensitive material of Comparative Example 1A after exposure was set to 100%, and in comparison with this, the reduction rate was calculated to determine how much the relative permittivity of the photosensitive layer formed of the photosensitive material of each of Examples was reduced after exposure, and evaluated according to the following standard.

As the value of the reduction rate was larger, the relative permittivity as compared with Comparative Example 1A was lower, which is useful as an insulating film.

A: reduction rate was 15% or more.

B: reduction rate was 10% or more and less than 15%.

C: reduction rate was 5% or more and less than 10%.

D: reduction rate was less than 5%.

(Relative Permittivity Evaluation 1 Before and After Exposure)

A photosensitive layer after exposure was produced in the same manner as in (Relative permittivity evaluation 1) described above. In this case, the relative permittivity of each photosensitive layer was measured before and after exposure in the same manner as in (Relative permittivity evaluation 1) described above.

A relative permittivity of each photosensitive layer before exposure was set to 100%, and how much the permittivity of each photosensitive layer was reduced by the exposure was calculated and evaluated according to the following standard.

It can be determined that, as the reduction rate was larger, the reduction in permittivity was further lowered due to the decarboxylation reaction by the exposure.

A: reduction rate was 15% or more.

B: reduction rate was 10% or more and less than 15%.

C: reduction rate was 5% or more and less than 10%.

D: reduction rate was less than 5%.

<Evaluation of Transfer Film (Photosensitive Transfer Material)>

(Production of Transfer Film)

To a polyethylene terephthalate film (manufactured by Toray Industries, Inc., 16KS40 (16QS62)) having a thickness of 16 μm (temporary support), the photosensitive material of each of Examples or Comparative Examples was applied using a slit-shaped nozzle such that a thickness after drying was adjusted to 5 μm, and the photosensitive material was dried at 100° C. for 2 minutes to form a photosensitive layer.

A polyethylene terephthalate film (manufactured by Toray Industries, Inc., 16KS40 (16QS62)) having a thickness of 16 μm (cover film) was pressure-bonded onto the obtained photosensitive layer to produce a transfer film of Example 1 system.

(Evaluation of Carboxy Group Consumption Rate (IR Measurement))

By peeling off the cover film from the transfer film produced above and laminating the transfer film on a silicon wafer, the photosensitive layer of the transfer film was transferred to a surface of the silicon wafer. Laminating conditions were that a temperature of a substrate for a touch panel was 40° C., a temperature of a rubber roller (that is, a laminating temperature) was 110° C., a linear pressure was 3 N/cm, and a transportation speed was 2 m/min.

The photosensitive layer after transfer was exposed under the following exposure conditions.

<<Exposure Conditions>>

After peeling off the temporary support, the photosensitive layer was entirely exposed using a high-pressure mercury lamp. The integrated exposure amount measured with a 365 nm illuminance meter was 1000 mJ/cm². Light emitted from the above-described high-pressure mercury lamp has strong line spectrum at 254 nm, 313 nm, 405 nm, and 436 nm with a wavelength of 365 nm as a main wavelength.

IR spectra of the photosensitive layer were measured before and after the exposure, and a carboxy group consumption rate (mol %) was calculated from a reduction rate of a peak of C═O stretching and contracting (peak of 1710 cm⁻¹) of the carboxy group.

As the carboxy group consumption rate is higher, the decarboxylation reaction is more proceeding.

The results are shown in Table 1 (see the column of “Carboxy group consumption rate (mol %) [IR measurement]”).

(Evaluation of Carboxy Group Consumption Rate (Measurement of Ashing))

By peeling off the cover film from the transfer film produced above and laminating the transfer film on 10×10 cm² glass (Eagle XG manufactured by Corning), the photosensitive layer of the transfer film was transferred to a surface of the glass. Laminating conditions were that a temperature of a substrate for a touch panel was 40° C., a temperature of a rubber roller (that is, a laminating temperature) was 110° C., a linear pressure was 3 N/cm, and a transportation speed was 2 m/min.

Measurement of Carboxy Group Amount of Photosensitive Layer after Exposure (Measurement of Carboxy Group Amount after Exposure)

The photosensitive layer after transfer was exposed under the following exposure conditions.

<<Exposure Conditions>>

After peeling off the temporary support, the photosensitive layer was entirely exposed using a high-pressure mercury lamp. The integrated exposure amount measured with a 365 nm illuminance meter was 1000 mJ/cm². Light emitted from the above-described high-pressure mercury lamp has strong line spectrum at 254 nm, 313 nm, 405 nm, and 436 nm with a wavelength of 365 nm as a main wavelength.

Next, a total of approximately 20 mg of the photosensitive layer after exposure was scraped off and frozen and pulverized, 150 μL of N-methyl-2-pyrrolidone (NMP) was added thereto, and the mixture was stirred in an aqueous solution of lithium carbonate (Li₂CO₃) (1.2 g/100 mL; lithium carbonate was dissolved in ultrapure water and then filtered through a filter) for 6 days.

After the stirring, particles are settled by ultracentrifugation (140,000 rpm×30 min), the supernatant was replaced with ultrapure water (replacement was repeated 5 times), and the obtained precipitate was dried to dryness and used as an analysis sample (production of a sample in which n=2). This analysis sample was analyzed by ICP-OES (Optima 7300DV manufactured by PerkinElmer Inc.).

The above-described ICP-OES measurement was carried out according to the following procedure.

Approximately 1.5 mg to 2 mg of the above-described analytical sample was weighed (n=3), 5 mL of a 60% HNO₃ aqueous solution was added thereto, and MW Teflon ashing (microwave sample decomposition device UltraWAVE max: 260° C.) was performed.

After the ashing, ultrapure water was added thereto to be 50 mL, and the amount of Li was quantified by an absolute calibration curve method using ICP-OES (Optima 7300DV manufactured by PerkinElmer Inc.).

Measurement of Carboxy Group Amount of Photosensitive Layer Before Exposure (Measurement of Carboxy Group Amount Before Exposure)

According to the following procedure, the carboxy group amount of the photosensitive layer of each of Examples or Comparative Examples was measured.

1 g of the photosensitive layer before exposure was scraped off and dissolved in 63 ml of tetrahydrofuran, and 12 ml of ultrapure water was added thereto. Next, the obtained solution was titrated with a 0.1 N-NaOH aqueous solution using an automatic titrator manufactured by HIRANUMA Co., Ltd. The carboxy group amount in the photosensitive layer was calculated by converting the carboxy group amount obtained by the titration into a concentration of solid contents.

Calculation of Decarboxylation Rate

Based on the measurement results of the carboxy group amount before and after the exposure described above, a decarboxylation rate was calculated by the following expression.

{(Carboxy group amount before exposure−Carboxy group amount after exposure)/Carboxy group amount before exposure}×100(%) Decarboxylation rate (%):

Based on the obtained numerical values, evaluation was performed according to the following evaluation standard.

However, in a case of the above-described method, there was a detection limit. In a case where the content of the carboxy group was 1.05 mmol/g or less, 90% or more of Li can be substituted. In a region beyond that, a calibration curve was produced using a crosslinked polymer having a known acid value and calculated.

Evaluation Standard

A: decarboxylation rate was 71 mol % or more.

B: decarboxylation rate was 50 mol % or more and less than 71 mol %.

C: decarboxylation rate was 31 mol % or more and less than 50 mol %.

D: decarboxylation rate was 5 mol % or more and less than 31 mol %.

E: decarboxylation rate was less than 5 mol %.

The results are shown in First (see the column of “Carboxy group consumption rate [measurement of ashing]).

(Transmittance at 365 nm)

Using an ultraviolet-visible spectrophotometer UV1800 manufactured by Shimadzu Corporation, a transmittance of the photosensitive layer at 365 nm was measured, and evaluation was performed based on the following evaluation standard.

A: transmittance was 90% or more.

B: transmittance was 65% or more and less than 90%.

C: transmittance was 20% or more and less than 65%.

D: transmittance was less than 20%.

(Transmittance at 365 nm/Transmittance at 313 nm)

Using an ultraviolet-visible spectrophotometer UV1800 manufactured by Shimadzu Corporation, a transmittance of the photosensitive layer at 365 nm and a transmittance of the photosensitive layer at 313 nm were measured, and a values calculated by dividing the transmittance at 365 nm by the transmittance at 313 nm was evaluated as follows.

A: 1.5 or more

B: 1 or more and less than 1.5

C: less than 1

(Laminate Suitability Evaluation)

By peeling off the cover film from the transfer film produced above and laminating the transfer film on a PET film (substrate for a touch panel) laminated with a copper foil manufactured by GEOMATEC Co., Ltd., the photosensitive layer of the transfer film was transferred to a surface of the copper foil to obtain a laminate having a laminated structure of “temporary support/photosensitive layer/copper foil/substrate (PET film)”. Laminating conditions were that a temperature of a substrate for a touch panel was 40° C., a temperature of a rubber roller (that is, a laminating temperature) was 110° C., a linear pressure was 3 N/cm, and a transportation speed was 2 m/min. The copper foil is a film which is assumed as a wiring line of a touch panel.

An area where the photosensitive layer was closely attached to the copper foil without bubbles and floating was visually evaluated, and based on the following expression, a proportion (%) of the closely attached area was obtained and evaluated according to the following standard. It can be said that, as the closely attached area (%) was larger, a laminate suitability was more excellent.

Proportion of closely attached area (%)=Area of closely attached photosensitive layer÷Area of laminated transfer film×100

A: proportion of the closely attached area (%) was 95% or more.

B: proportion of the closely attached area (%) was less than 95%.

(Pattern Formability Evaluation 2)

Next, the temporary support was peeled off from the above-described laminate, and the exposed photosensitive layer was exposed to light using a high-pressure mercury lamp. In the case of exposure, the exposure was performed through any of masks (1) to (3) below. The integrated exposure amount measured with a 365 nm illuminance meter was 1000 mJ/cm².

(1) mask having a line size=25 μm and a line:space=1:1

(2) mask having a line size=50 μm and a line:space=1:1

(3) mask having a line size=250 μm and a line:space=1:1

Next, the exposed photosensitive layer was developed for 40 seconds using a 1% by mass sodium carbonate aqueous solution (liquid temperature: 32° C.) as a developer. After the development, the photosensitive layer was rinsed with pure water for 20 seconds, and then air was blown to remove water, thereby obtaining a pattern (line-and-space pattern).

Line-and-space patterns with line widths and space widths of 25 μm, 50 μm, or 250 μm, which were produced as described above were evaluated in the same manner as in (Pattern formability evaluation 1) described above.

(Relative Permittivity Evaluation 2)

By peeling off the cover film from the transfer film produced above and laminating the transfer film on an aluminum substrate having a thickness of 0.1 mm under the same conditions as (Laminate suitability evaluation) described above, a laminate having a laminated structure of “temporary support/photosensitive layer/aluminum substrate” was obtained. Next, the temporary support was peeled off from the laminate. The exposed photosensitive layer was entirely exposed to light using a high-pressure mercury lamp. The integrated exposure amount measured with a 365 nm illuminance meter was 1000 mJ/cm².

For the photosensitive layer after exposure, a relative permittivity at 1 kHz was measured in an environment of 23° C. and 50% RH using an LCR meter 4284A and a dielectric test fixture 16451B manufactured by Agilent Technologies, Inc.

A relative permittivity of the photosensitive layer formed of the photosensitive material of Comparative Example 1A after exposure was set to 100%, and in comparison with this, the reduction rate was calculated to determine how much the relative permittivity of the photosensitive layer formed of the photosensitive material of each of Examples was reduced after exposure, and evaluated according to the following standard.

As the value of the reduction rate was larger, the relative permittivity as compared with Comparative Example 1A was lower, which is useful as an insulating film.

A: reduction rate was 15% or more.

B: reduction rate was 10% or more and less than 15%.

C: reduction rate was 5% or more and less than 10%.

D: reduction rate was less than 5%.

(Relative Permittivity Evaluation 2 Before and After Exposure)

A photosensitive layer after exposure was produced in the same manner as in (Relative permittivity evaluation 2) described above. In this case, the relative permittivity of each photosensitive layer was measured before and after exposure in the same manner as in (Relative permittivity evaluation 2) described above.

A relative permittivity of each photosensitive layer before exposure was set to 100%, and how much the permittivity of each photosensitive layer was reduced by the exposure was calculated and evaluated according to the following standard.

It can be determined that, as the reduction rate was larger, the reduction in permittivity was further lowered due to the decarboxylation reaction by the exposure.

A: reduction rate was 15% or more.

B: reduction rate was 10% or more and less than 15%.

C: reduction rate was 5% or more and less than 10%.

D: reduction rate was less than 5%.

(Evaluation of Moisture Permeability (WVTR))

Production of Sample for Measuring Moisture Permeability

To a polyethylene terephthalate (PET) film having a thickness of 75 μm (temporary support), the photosensitive material of each of Examples or Comparative Examples was applied using a slit-shaped nozzle, and the photosensitive material was dried to form a photosensitive layer having a thickness of 8 μm, thereby obtaining a transfer film for sample production.

Next, the transfer film for same production was laminated on PTFE (tetrafluoroethylene resin) membrane filter FP-100-100 manufactured by Sumitomo Electric Industries, Ltd., to form a laminate A having a layer structure of “temporary support/photosensitive layer having a thickness of 8 μm/membrane filter”. Laminating conditions were that a temperature of the membrane filter was 40° C., a temperature of a laminating roll was 110° C., a linear pressure was 3 N/cm, and a transportation speed was 2 m/min.

Next, the temporary support was peeled off from the laminate A.

A procedure in which the transfer film for sample production was further laminated on the exposed photosensitive layer of the laminate A in the same manner as described above, and the temporary support was peeled off from the obtained laminate was repeated 4 times to form a laminate B having a laminated structure of “photosensitive layer having a total film thickness of 40 μm/membrane filter”.

The photosensitive layer of the obtained laminate B was entirely exposed using a high-pressure mercury lamp. The integrated exposure amount measured with a 365 nm illuminance meter was 1000 mJ/cm².

Accordingly, a sample for measuring moisture permeability, which had a laminated structure of “exposed photosensitive layer having a total film thickness of 40 μm/membrane filter”, was obtained.

Measurement of Moisture Permeability (WVTR)

The measurement of the moisture permeability was performed by a cup method using the sample for measuring moisture permeability, with reference to JIS-Z-0208 (1976). Hereinafter, the details will be described.

First, a circular sample having a diameter of 70 mm was cut from the sample for measuring moisture permeability. Next, 20 g of dried calcium chloride was put in a measurement cup, and covered with the circular sample, and accordingly, a lid-attached measurement cup was prepared.

This lid-attached measurement cup was left in a constant-temperature and constant-humidity tank for 24 hours under the condition of 65° C. with 90% RH. A water vapor transmission rate (WVTR) of the circular sample (unit: g/(m² day)) was calculated from a change in mass of the lid-attached measurement cup before and after the leaving.

The measurement described above was performed three times and an average value of the WVTRs in three times of the measurement was calculated.

A moisture permeability was evaluated based on the reduction rate (%) of the WVTR of each of Examples in a case where the WVTR of Comparative Example 1A was set to 100%. As the value of the reduction rate is larger, the moisture permeability was further lowered as compared with Comparative Example 1A, which is preferable as a protective film. In the following evaluation standard, A or B is preferable, and A is more preferable.

In the above-described measurement, the WVTR of the circular sample having a laminated structure of “exposed photosensitive layer having a total film thickness of 40 μm/membrane filter” was measured as described above. However, the WVTR of the membrane filter is extremely higher than the WVTR of the exposed photosensitive layer, and accordingly, in the above-described measurement, the WVTR of the exposed photosensitive layer is substantially measured.

A: reduction rate of the WVTR was 20% or more.

B: reduction rate of the WVTR was 10% or more and less than 20%.

C: reduction rate of the WVTR was 7.5% or more and less than 10%.

D: reduction rate of the WVTR was 5% or more and less than 7.5%.

E: reduction rate of the WVTR was less than 5%.

<Result>

Second table below shows types and blending amounts of the polymer A and the compound β in the photosensitive material of each of Examples and Comparative Examples in Example 1 system, and the test results thereof.

In the table, the column of “Amount” indicates the blending amounts (part by mass) of the polymer A and the compound β added to the photosensitive material. The above-described blending amount (part by mass) is the amount of the polymer A and the compound β itself (solid content) blended to the photosensitive material.

In the table, the column of “Molar ratio with respect to carboxy group of polymer A (mol %)” indicates a proportion (mol %) of the total number of structures (structures b0) included in the compound β, in which the amount of the carboxy group of the polymer A is reduced (preferably, structures (structures b) capable of accepting an electron from the carboxy group of the polymer A in a photoexcited state) to the total number of carboxy groups included in the polymer A in the photosensitive material.

The column of “365” indicates a molar absorption coefficient ((cm·mol/L)⁻¹) of the compound β to light having a wavelength of 365 nm in acetonitrile.

The column of “ε365/ε313” indicates a value obtained by dividing the molar absorption coefficient ((cm·mol/L)⁻¹) of the compound β to light having a wavelength of 365 nm by a molar absorption coefficient ((cm·mol/L)⁻¹) of the compound β to light having a wavelength of 313 nm. All molar absorption coefficients are values in acetonitrile.

The column of “Transmittance at 365 nm” indicates the transmittance of the photosensitive layer to light having a wavelength of 365 nm.

The column of “Transmittance at 365 nm/transmittance at 313 nm” indicates a value obtained by dividing the transmittance of the photosensitive layer to light having a wavelength of 365 nm by the transmittance of the photosensitive layer to light having a wavelength of 313 nm.

TABLE 2
Second table (1)

| | Blending characteristics of photosensitive material | | | | | | | |
|---|---|---|---|---|---|---|---|---|
| | | | Compound β | | | | | |
| | | | | | | | | Molar ratio with |
| | | | | pKa in | | | | respect to carboxy |
| | Polymer A | | | ground | | ε365/ | | group of polymer A |
| | Type | Amount | Type | state | ε365 | ε313 | Amount | (mol %) |
| Example 1-1 | Styrene/ | 100 | 5,6,7,8- | 5.9 | <10 | <1 | 25.9 | 50 |
| | acrylic | | Tetrahydroquinoline | | | | | |
| Example 1-2 | acid | 100 | 4-Acetylpyridine | 3.1 | <10 | <1 | 23.6 | 50 |
| Example 1-3 | copolymer | 100 | 4-Benzoylpyridine | 2.9 | 69 | <1 | 35.6 | 50 |
| Example 1-4 | UC3910 | 100 | Isoquinoline | 4.7 | <10 | <1 | 25.1 | 50 |
| Example 1-5 | | 100 | Quinoline | 4.2 | <10 | <1 | 25.1 | 50 |
| Example 1-6 | | 100 | Acridine | 4.7 | 4900 | >3 | 34.9 | 50 |
| Example 1-7 | | 100 | Phenanthridine | 3.8 | 500 | <1 | 34.9 | 50 |
| Example 1-8 | | 100 | Isoquinoline | 4.7 | <10 | <1 | 10.0 | 20 |
| Example 1-9 | | 100 | Isoquinoline | 4.7 | <10 | <1 | 5.0 | 10 |
| Example 1-10 | | 100 | Isoquinoline | 4.7 | <10 | <1 | 2.5 | 5 |
| Example 1-11 | | 100 | Isoquinoline | 4.7 | <10 | <1 | 1.5 | 3 |
| Comparative | | 100 | None | — | — | — | — | — |
| Example 1A | | | | | | | | |

| | Evaluation of photosensitive material | | | | | | |
|---|---|---|---|---|---|---|---|
| | | | | | | | Change in |
| | Carboxy group | Carboxy group | | | | | relative |
| | consumption rate | consumption rate | Pattern formability | | | | permittivity |
| | (mol %) [IR | [measurement | 25 | 50 | 250 | Relative | before and |
| | measurement] | of ashing] | μm | μm | μm | permittivity | after exposure |
| Example 1-1 | 55 | B | A | A | A | B | B |
| Example 1-2 | 50 | B | B | A | A | B | B |
| Example 1-3 | 45 | C | A | A | A | B | B |
| Example 1-4 | 70 | B | B | A | A | A | A |
| Example 1-5 | 60 | B | B | A | A | A | A |
| Example 1-6 | 30 | D | C | B | B | B | B |
| Example 1-7 | 35 | C | C | B | A | B | B |
| Example 1-8 | 60 | B | B | A | A | A | A |
| Example 1-9 | 40 | C | B | A | A | A | A |
| Example 1-10 | 20 | D | B | B | A | B | B |
| Example 1-11 | 10 | D | C | C | B | C | C |
| Comparative | 0 | E | D | D | D | Standard | D |
| Example 1A | | | | | | | |

TABLE 3
Second table (2)

| | Blending characteristics of photosensitive material | | | | | | | | | |
|---|---|---|---|---|---|---|---|---|---|---|
| | | | Compound β | | | | | | | |
| | | | | | | | | Molar ratio | Evaluation of photosensitive material | |
| | | | | | | | | with respect to | Carboxy group | Carboxy group |
| | | | | pKa in | | | | carboxy group | consumption rate | consumption rate |
| | Polymer A | | | ground | | ε365/ | | of polymer A | (mol %) [IR | [measurement |
| | Type | Amount | Type | state | ε365 | ε313 | Amount | (mol %) | measurement] | of ashing] |
| Example 1-1 | Styrene/ | 100 | 5,6,7,8- | 5.9 | <10 | <1 | 25.9 | 50 | 55 | B |
| | acrylic | | Tetrahydroquinoline | | | | | | | |
| Example 1-2 | acid | 100 | 4-Acetylpyridine | 3.1 | <10 | <1 | 23.6 | 50 | 50 | B |
| Example 1-3 | copolymer | 100 | 4-Benzoylpyridine | 2.9 | 69 | <1 | 35.6 | 50 | 45 | C |
| Example 1-4 | UC3910 | 100 | Isoquinoline | 4.7 | <10 | <1 | 25.1 | 50 | 70 | B |
| Example 1-5 | | 100 | Quinoline | 4.2 | <10 | <1 | 25.1 | 50 | 60 | B |
| Example 1-6 | | 100 | Acridine | 4.7 | 4900 | >3 | 34.9 | 50 | 30 | D |
| Example 1-7 | | 100 | Phenanthridine | 3.8 | 500 | <1 | 34.9 | 50 | 35 | C |
| Example 1-8 | | 100 | Isoquinoline | 4.7 | <10 | <1 | 10.0 | 20 | 60 | B |
| Example 1-9 | | 100 | Isoquinoline | 4.7 | <10 | <1 | 5.0 | 10 | 40 | C |
| Example 1-10 | | 100 | Isoquinoline | 4.7 | <10 | <1 | 2.5 | 5 | 20 | D |
| Example 1-11 | | 100 | Isoquinoline | 4.7 | <10 | <1 | 1.5 | 3 | 10 | D |
| Comparative | | 100 | None | — | — | — | — | — | 0 | E |
| Example 1A | | | | | | | | | | |

| | Evaluation of photosensitive material | | | | | | | | |
|---|---|---|---|---|---|---|---|---|---|
| | | | | | | | | Change in | |
| | | Transmittance | | Pattern | | | | relative | |
| | | at 365 nm/ | | formability | | | | permittivity | |
| | Transmittance | transmittance | Laminate | 25 | 50 | 250 | Relative | before and | Moisture |
| | at 365 nm | at 313 nm | suitability | μm | μm | μm | permittivity | after exposure | permeability |
| Example 1-1 | A | A | A | A | A | A | B | B | A |
| Example 1-2 | A | A | A | B | A | A | B | B | A |
| Example 1-3 | A | A | A | A | A | A | B | B | A |
| Example 1-4 | A | A | A | B | A | A | A | A | A |
| Example 1-5 | A | A | A | B | A | A | A | A | B |
| Example 1-6 | C | C | A | C | B | B | B | B | B |
| Example 1-7 | A | A | A | C | B | A | B | B | B |
| Example 1-8 | A | A | A | B | A | A | A | A | A |
| Example 1-9 | A | A | A | B | A | A | A | A | A |
| Example 1-10 | A | A | A | B | B | A | B | B | B |
| Example 1-11 | A | A | A | C | C | B | C | C | C |
| Comparative | A | B | A | D | D | D | Standard | D | Standard |
| Example 1A | | | | | | | | | |

From the results shown in the above tables, it was confirmed that the objects of the present invention could be achieved by using the photosensitive material according to the embodiment of the present invention.

In addition, from the viewpoint that the effects of the present invention are more excellent, in the photosensitive material, it was confirmed that the total number of structures b0 (preferably, structures b) included in the compound β was preferably 3 mol % or more, more preferably 5 mol % or more, and still more preferably 10 mol % or more with respect to the total number of carboxy groups included in the polymer A (refer to the comparison of results of Examples 1-4, 1-8, 1-9, 1-10, and 1-11).

In addition, in the photosensitive layer of the transfer film according to the embodiment of the present invention, in a case where the compound β was a compound in which a molar absorption coefficient to light having a wavelength of 365 nm was 1×10³ (cm·mol/L)⁻¹ or less (preferably, in a case where the compound β was a compound in which a molar absorption coefficient to light having a wavelength of 365 nm was 1×10² (cm·mol/L)⁻¹ or less), it was confirmed that the pattern formability was more excellent (refer to the comparison of the results of Examples 1-1 to 1-7).

In addition, in the photosensitive layer of the transfer film according to the embodiment of the present invention, in a case where the ratio represented by molar absorption coefficient ((cm·mol/L)⁻¹) of the compound β to light having a wavelength of 365 nm/molar absorption coefficient ((cm·mol/L)⁻¹) of the compound β to light having a wavelength of 313 nm was 3 or less, it was confirmed that the pattern formability was more excellent (refer to the comparison of the results of Examples 1-1 to 1-7).

### Example 2 System

<Preparation and Evaluation of Photosensitive Material>

Materials shown in Third table shown in the latter part were mixed and dissolved in a mixed solvent of propylene glycol monomethyl ether acetate/methyl ethyl ketone=50/50 (mass ratio) so that a blending ratio shown in Third table shown in the latter part was satisfied and a concentration of solid contents of the finally obtained photosensitive material was 25% by mass, thereby obtaining a photosensitive material.

For the obtained photosensitive material (photosensitive materials of Examples 2-1 to 2-8) of Example 2 system, in a case where the carboxy group consumption rate (mol %) was confirmed by IR measurement in the same manner as shown in Example 1, the carboxy group consumption rate was all 20 mol % or more.

In addition, for the obtained photosensitive material of each of Examples and Comparative Examples in Example 2 system, the carboxy group consumption rate, pattern formability of the photosensitive material, relative permittivity, and change in relative permittivity before and after exposure, and the laminate suitability of the transfer film, pattern formability, relative permittivity, change in relative permittivity before and after exposure, and moisture permeability were evaluated in the same manner as shown in Example 1 system. In addition, for the photosensitive layer in the transfer film, the carboxy group consumption rate, transmittance to light at 365 nm, and ratio of the transmittance to light at 365 nm to the transmittance to light at 313 nm were also evaluated in the same manner as shown in Example 1 system. In addition, the physical properties of ε365/ε313 of the compound β included in the photosensitive material and the photosensitive layer were evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Example 2A.

Third table below shows blending of the solid content of the photosensitive material of each of Examples and Comparative Examples in Example 2 system, and the test results thereof.

In the table, the value described in the column of “Solid content blending” indicates the content (part by mass) of each solid content component included in the photosensitive material of each of Examples or Comparative Examples. The value in parentheses in the compound β indicates a proportion (mol %) of the total number of structures (structures b0) included in the compound β, in which the amount of the carboxy group of the polymer A is reduced (preferably, structures (structures b) capable of accepting an electron from the carboxy group of the polymer A in a photoexcited state) to the total number of carboxy groups included in the polymer A in the photosensitive material.

In addition, the value (ε365) in brackets, which is written in the component name of the compound β3, indicates a molar absorption coefficient ((cm·mol/L)⁻¹) of the compound β to light having a wavelength of 365 nm in acetonitrile.

In addition, the value (pKa in a ground state) in brackets, which is written in the component name of the compound β, is intended to be the pKa of the compound β in a ground state. The measuring methods are as described above.

In addition, the column of “ε365/ε313” in the evaluation of the photosensitive material and the evaluation of the transfer film indicates a value obtained by dividing the molar absorption coefficient ((cm·mol/L)⁻¹) of the compound β to light having a wavelength of 365 nm by a molar absorption coefficient ((cm·mol/L)⁻¹) of the compound β to light having a wavelength of 313 nm. All molar absorption coefficients are values in acetonitrile.

In addition, the column of “Transmittance at 365 nm” in the evaluation of the transfer film indicates the transmittance of the photosensitive layer to light having a wavelength of 365 nm.

In addition, the column of “Transmittance at 365 nm/transmittance at 313 nm” in the evaluation of the transfer film indicates a value obtained by dividing the transmittance of the photosensitive layer to light having a wavelength of 365 nm by the transmittance of the photosensitive layer to light having a wavelength of 313 nm.

TABLE 4
Third table

| | | | | | | | | | | | Comparative |
|---|---|---|---|---|---|---|---|---|---|---|---|
| | | | Example | | | | | | | | Example |
| | | | 2-1 | 2-2 | 2-3 | 2-4 | 2-5 | 2-6 | 2-7 | 2-8 | 2A |
| Solid | Polymer A | UC3910 | 60 | 60 | 60 | 60 | 60 | 60 | 70 | 50 | 60 |
| content | Compound | 5,6,7,8-Tetrahydroquinoline | 6.2 (20) | | | | | | | | |
| blending | β (in | “ε365: <10” | | | | | | | | | |
| | parentheses: | “pKa in ground state: 5.9” | | | | | | | | | |
| | molar ratio | 4-Acetylpyridine | | 5.7 (20) | | | 5.7 (20) | 5.7 (20) | | | |
| | with respect | “ε365: <10” | | | | | | | | | |
| | to carboxy | “pKa in ground state: 3.1” | | | | | | | | | |
| | group of | Isoquinoline | | | 6.0 (20) | | | | 3.5 (10) | 2.5 (10) | |
| | polymer A | “ε365: <10” | | | | | | | | | |
| | (mol %)) | “pKa in ground state: 4.69” | | | | | | | | | |
| | | Acridine | | | | 8.4 (20) | | | | | |
| | | “ε365: 4900” | | | | | | | | | |
| | | “pKa in ground state: 4.67” | | | | | | | | | |
| | Polymerizable | DPHA | 12.6 | 12.6 | 12.6 | 12.6 | | 12.5 | | | 12.6 |
| | compound | A-NOD-N | 25 | 25 | 25 | 25 | | 12.5 | | | 25 |
| | | DTMPT | | | | | | 12.6 | 27.6 | 12.5 | |
| | | A-DCP | | | | | 25 | | | 22.5 | |
| | | TMPT | | | | | 12.6 | | | 12.6 | |
| | Surfactant | F551 | 0.1 | 0.1 | 0.1 | 0.1 | 0.1 | 0.1 | 0.1 | 0.1 | 0.1 |
| Evaluation | ε365/ε313 | | <1 | <1 | <1 | >3 | <1 | <1 | <1 | <1 | — |
| of photo- | Carboxy group consumption rate | | B | B | B | D | B | B | C | C | E |
| sensitive | [measurement of ashing] | | | | | | | | | | |
| material | Pattern | 25 μm | A | B | B | C | B | B | B | B | D |
| | formability | 50 μm | A | A | A | B | A | A | A | A | D |
| | | 250 μm | A | A | A | A | A | A | A | A | D |
| | Relative permittivity | | B | B | A | C | B | B | A | A | Standard |
| | Change in relative permittivity | | B | B | A | C | B | B | A | A | D |
| | before and after exposure | | | | | | | | | | |
| Evaluation | ε365/ε313 | | <1 | <1 | <1 | >3 | <1 | <1 | <1 | <1 | — |
| of transfer | Carboxy group consumption rate | | B | B | B | D | B | B | C | C | E |
| film | [measurement of ashing] | | | | | | | | | | |
| | Transmittance at 365 nm | | A | A | A | C | A | A | A | A | A |
| | Transmittance at 365 nm/ | | A | A | A | C | A | A | A | A | B |
| | transmittance at 313 nm | | | | | | | | | | |
| | Laminate suitability | | A | A | A | A | A | A | A | A | A |
| | Pattern | 25 μm | A | B | B | C | B | B | B | B | D |
| | formability | 50 μm | A | A | A | B | A | A | A | A | D |
| | | 250 μm | A | A | A | A | A | A | A | A | D |

| | | | | | | | | | |
|---|---|---|---|---|---|---|---|---|---|
| Relative permittivity | B | B | A | C | B | B | A | A | Standard |
| Change in relative permittivity | B | B | A | C | B | B | A | A | D |
| before and after exposure | | | | | | | | | |
| Moisture permeability | A | A | A | B | A | A | A | A | Standard |

UC3910: ARUFON UC3910 (manufactured by Toagosei Co., Ltd.)

DPHA: dipentaerythritol hexaacrylate (A-DPH manufactured by Shin-Nakamura Chemical Co., Ltd.)

A-NOD-N: 1,9-nonanediol diacrylate (A-NOD-N manufactured by Shin-Nakamura Chemical Co., Ltd.)

DTMPT: ditrimethylolpropane tetraacrylate (KAYARAD T-1420 (T) manufactured by Nippon Kayaku Co., Ltd.)

A-DCPP: dicyclopentane dimethanol diacrylate (A-DCP manufactured by Shin-Nakamura Chemical Co., Ltd.)

TMPT: trimethylolpropane triacrylate (A-TMPT manufactured by Shin-Nakamura Chemical Co., Ltd.)

F551: MEGAFACE F551 (manufactured by DIC Corporation)

From the results in the above tables, it was confirmed that, even in a case where the photosensitive material included a polymerizable compound, the objects of the present invention could be achieved with the photosensitive material according to the embodiment of the present invention.

In addition, it was confirmed that conditions under which the effects of the present invention are more excellent were the same as those confirmed for Example 1 system.

### Example 3 System

<Preparation and Evaluation of Photosensitive Material>

Materials shown in Fourth table shown in the latter part were mixed and dissolved in a mixed solvent of propylene glycol monomethyl ether acetate/methyl ethyl ketone=50/50 (mass ratio) so that a blending amount shown in Fourth table shown in the latter part was satisfied and a concentration of solid contents of the finally obtained photosensitive material was 25% by mass, thereby obtaining a photosensitive material.

In preparing the photosensitive material, using a solution of a resin A or a solution of a resin B, which were obtained by a method described later as “Synthesizing method of resin A” or “Synthesizing method of resin B”, the resin A or the resin B was introduced into the photosensitive material.

For the obtained photosensitive material (photosensitive materials of Examples 3-1 to 3-12) of Example 3 system, in a case where the carboxy group consumption rate (molar ratio) was confirmed by IR measurement in the same manner as (Evaluation of the carboxy group consumption rate (IR measurement)) shown in Example 1, the carboxy group consumption rate was all 20 mol % or more.

Further, before the exposure of 1000 mJ/cm² using the high-pressure mercury lamp in (Evaluation of the carboxy group consumption rate (IR measurement)) shown in Example 1 system, an exposure of 100 mJ/cm² using an ultra-high pressure mercury lamp was performed, and then a test was also conducted in which an exposure of 1000 mJ/cm² was performed using the high-pressure mercury lamp. Even in a case where the exposure of 100 mJ/cm² was performed in advance in this way, the carboxy group consumption rate before and after the exposure of 1000 mJ/cm² was all 20 mol % or more regardless of which of the photosensitive material of Example 3 system (photosensitive materials of Examples 3-1 to 3-12) was used.

In addition, for the obtained photosensitive material of each of Examples and Comparative Examples in Example 3 system, the carboxy group consumption rate, relative permittivity of the photosensitive material, and change in relative permittivity before and after exposure, and the laminate suitability of the transfer film, relative permittivity, change in relative permittivity before and after exposure, and moisture permeability were evaluated in the same manner as shown in Example 1 system. In addition, for the photosensitive layer in the transfer film, the carboxy group consumption rate, transmittance to light at 365 nm, and ratio of the transmittance to light at 365 nm to the transmittance to light at 313 nm were also evaluated in the same manner as shown in Example 1 system. In addition, the physical properties of E365/313 of the compound β included in the photosensitive material and the photosensitive layer were evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Example 3A.

In addition, the pattern formability of the photosensitive material of each of Examples or Comparative Examples in Example 3 system was evaluated. As a specific procedure for evaluating the pattern formability, the same procedure as (Pattern formability evaluation 1) of Example 1 system described above was performed, except that the pattern forming method was changed as follows.

The photosensitive material of each of Examples and Comparative Examples was spin-coated on a silicon wafer, and then the obtained coating film was dried on a hot plate at 80° C. to obtain a photosensitive layer having a film thickness of 5 μm.

The obtained photosensitive layer was exposed to an ultra-high pressure mercury lamp through the same masks as in Example 1 system. The integrated exposure amount measured with a 365 nm illuminance meter was 100 mJ/cm².

Next, the exposed photosensitive layer in a patterned manner was developed for 40 seconds using a 1% by mass sodium carbonate aqueous solution (liquid temperature: 32° C.) as a developer. After the development, the photosensitive layer was rinsed with pure water for 20 seconds, and then air was blown to remove water, thereby obtaining a pattern.

The obtained pattern was entirely exposed using a high-pressure mercury lamp. The integrated exposure amount measured with a 365 nm illuminance meter was 1000 mJ/cm².

Line-and-space patterns with line widths and space widths of 25 μm, 50 μm, or 250 μm, which were produced as described above, were evaluated based on the evaluation standard described in (Pattern formability evaluation 1) of Example 1 system described above.

In addition, the pattern formability of the transfer film of each of Examples or Comparative Examples in Example 3 system was evaluated. As a specific procedure for evaluating the pattern formability, the same procedure as (Pattern formability evaluation 2) of Example 1 system described above was performed, except that the pattern forming method was changed as follows.

By peeling off the cover film from the produced transfer film and laminating the transfer film on a COP film (substrate for a touch panel) laminated with a copper foil manufactured by GEOMATEC Co., Ltd., the photosensitive layer of the transfer film was transferred to a surface of the copper foil to obtain a laminate having a laminated structure of “temporary support/photosensitive layer/copper foil/substrate (COP film)”. Laminating conditions were that a temperature of a substrate for a touch panel was 40° C., a temperature of a rubber roller (that is, a laminating temperature) was 110° C., a linear pressure was 3 N/cm, and a transportation speed was 2 m/min. Here, the copper foil is a film which is assumed as a wiring line of a touch panel.

The laminating property was good.

Next, using a proximity type exposure machine (Hitachi High-Technologies Corporation) equipped with an ultra-high pressure mercury lamp, a distance between a surface of the exposure mask and a surface of the temporary support was set to 125 μm, and the photosensitive layer of the above-described laminate was exposed in a patterned manner under the condition of an exposure amount of 100 mJ/cm² (i-line) with the ultra-high pressure mercury lamp through the temporary support.

The mask was a line-and-space pattern mask similar to that of Example 1 system. After the exposure, the temporary support was peeled off from the laminate.

Next, the photosensitive layer of the laminate, from which the temporary support was peeled off, was developed for 40 seconds using a 1% by mass sodium carbonate aqueous solution (liquid temperature: 32° C.) as a developer. After the development, the photosensitive layer was rinsed with pure water for 20 seconds, and then air was blown to remove water, thereby obtaining a pattern.

The obtained pattern was entirely exposed using a high-pressure mercury lamp. The integrated exposure amount measured with a 365 nm illuminance meter was 1000 mJ/cm².

Line-and-space patterns with line widths and space widths of 25 μm, 50 μm, or 250 μm, which were produced as described above, were evaluated based on the evaluation standard described in (Pattern formability evaluation 1) of Example 1 system described above.

<Evaluation of Relative Permittivity Under Double Exposure Conditions>

In Example 3 system, the relative permittivity was also evaluated under the double exposure conditions. The evaluation of the relative permittivity under the first exposure condition means the evaluation of the relative permittivity evaluated under the same conditions as in (Relative permittivity evaluation 2) shown in Example 1 system described above.

For the photosensitive material of Example 3 system, a transfer film was produced in the same manner as in (Production of transfer film) shown in Example 1 system. By peeling off the cover film from the obtained transfer film and laminating the transfer film on an aluminum substrate having a thickness of 0.1 mm under the same conditions as (Laminate suitability evaluation) described above, a laminate having a laminated structure of “temporary support/photosensitive layer/aluminum substrate” was obtained.

As the first exposure to the above-described laminate, the photosensitive layer was entirely exposed through the temporary support using an ultra-high pressure mercury lamp. In the first exposure, the integrated exposure amount measured with a 365 nm illuminance meter was 100 mJ/cm². Since the first exposure was through the temporary support (polyethylene terephthalate), most of light having a wavelength of 320 nm or less was blocked. Therefore, it is considered that those having a large molar absorption coefficient to light having a wavelength of 365 nm (for example, 1×10³ (cm·mol/L)⁻¹ or more) are preferentially involved in the reaction.

Thereafter, the temporary support was peeled off from the above-described laminate, and as the second exposure, the photosensitive layer was entirely exposed using a high-pressure mercury lamp. In the second exposure, the integrated exposure amount measured with a 365 nm illuminance meter was 1000 mJ/cm².

For the photosensitive layer exposed in this way, the relative permittivity was measured in the same manner as in (Relative permittivity evaluation 2) shown in Example 1 system described above.

However, the standard of the relative permittivity was the relative permittivity of Comparative Example 3A under the double exposure conditions.

Fourth table below shows blending of the solid content of the photosensitive material of each of Examples and Comparative Examples in Example 3 system, and the test results thereof.

The same description in Fourth table as in Third table has the same meaning as described to Third table.

TABLE 5
Forth table

| | | | Example | | | | | | | |
|---|---|---|---|---|---|---|---|---|---|---|
| | | | 3-1 | 3-2 | 3-3 | 3-4 | 3-5 | 3-6 | 3-7 | 3-8 |
| Solid | Polymer A | Resin A | 60 | 60 | 60 | 60 | | | | |
| content | | Resin B | | | | | 60 | 60 | 60 | 60 |
| blending | Compound | 5,6,7,8-Tetrahydroquinoline | 2.7 (20) | | | | 2.7 (20) | | | |
| | β (in | “ε365: <10” | | | | | | | | |
| | parentheses: | “pKa in ground state: 5.9” | | | | | | | | |
| | molar ratio | 4-Acetylpyridine | | 2.4 (20) | | | | 2.4 (20) | | |
| | with respect | “ε365: <10” | | | | | | | | |
| | to carboxy | “pKa in ground state: 3.1” | | | | | | | | |
| | group of | Isoquinoline | | | 2.2 (20) | | | | 2.2 (20) | |
| | polymer A | “ε365: <10” | | | | | | | | |
| | having acid | “pKa in ground state: 4.69” | | | | | | | | |
| | group | Acridine | | | | 3.6 (20) | | | | 3.6 (20) |
| | (mol %)) | “ε365: 4900” | | | | | | | | |
| | | “pKa in ground state: 4.67” | | | | | | | | |
| | Polymerizable | DPHA | 12.6 | 12.6 | 12.6 | 12.6 | 12.6 | 12.6 | 12.6 | 12.6 |
| | compound | A-NOD-N | 25 | 25 | 25 | 25 | 25 | 25 | 25 | 25 |
| | | DTMPT | | | | | | | | |
| | | A-DCP | | | | | | | | |
| | | TMPT | | | | | | | | |
| | Photopolymerization | OXE-02 | 0.8 | 0.8 | 0.8 | 0.8 | 0.8 | 0.8 | 0.8 | 0.8 |
| | initiator | Omn907 | 1.5 | 1.5 | 1.5 | 1.5 | 1.5 | 1.5 | 1.5 | 1.5 |
| | Surfactant | F551 | 0.1 | 0.1 | 0.1 | 0.1 | 0.1 | 0.1 | 0.1 | 0.1 |
| Evaluation | ε365/ε313 | | <1 | <1 | <1 | >3 | <1 | <1 | <1 | >3 |
| of photo- | Carboxy group consumption rate | | C | C | C | D | C | C | C | D |
| sensitive | [measurement of ashing] | | | | | | | | | |
| material | Pattern | 25 μm | A | A | A | A | A | A | A | A |
| | formability | 50 μm | A | A | A | A | A | A | A | A |
| | | 250 μm | A | A | A | A | A | A | A | A |
| | Relative permittivity | | B | B | A | C | B | B | A | C |
| | Change in relative permittivity | | B | B | A | C | B | B | A | C |
| | before and after exposure | | | | | | | | | |
| Evaluation | ε365/ε313 | | <1 | <1 | <1 | >3 | <1 | <1 | <1 | >3 |
| of transfer | Carboxy group consumption rate | | C | C | C | D | C | C | C | D |
| film | [measurement of ashing] | | | | | | | | | |
| | Transmittance at 365 nm | | A | A | A | C | A | A | A | C |
| | Transmittance at 365 nm/ | | A | A | A | C | A | A | A | C |
| | transmittance at 313 nm | | | | | | | | | |
| | Laminate suitability | | A | A | A | A | A | A | A | A |
| | Pattern | 25 μm | A | A | A | A | A | A | A | A |
| | formability | 50 μm | A | A | A | A | A | A | A | A |
| | | 250 μm | A | A | A | A | A | A | A | A |

| | | | | | | | | |
|---|---|---|---|---|---|---|---|---|
| Relative permittivity | B | B | A | C | B | B | A | C |
| Change in relative permittivity | B | B | A | C | B | B | A | C |
| before and after exposure | | | | | | | | |
| Moisture permeability | A | A | A | B | A | A | A | B |
| Change in relative permittivity | B | B | A | C | B | B | A | C |
| after double exposure | | | | | | | | |

| | | | | | | | Comparative | |
|---|---|---|---|---|---|---|---|---|
| | | | Example | | | | Example | |
| | | | 3-9 | 3-10 | 3-11 | 3-12 | 3A | 3B |
| Solid | Polymer A | Resin A | | | | | 60 | |
| content | | Resin B | 60 | 60 | 70 | 50 | | 60 |
| blending | Compound | 5,6,7,8-Tetrahydroquinoline | | | | | | |
| | β (in | “ε365: <10” | | | | | | |
| | parentheses: | “pKa in ground state: 5.9” | | | | | | |
| | molar ratio | 4-Acetylpyridine | 2.4 (20) | 2.4 (20) | | | | |
| | with respect | “ε365: <10” | | | | | | |
| | to carboxy | “pKa in ground state: 3.1” | | | | | | |
| | group of | Isoquinoline | | | 1.5 (10) | 1.1 (10) | | |
| | polymer A | “ε365: <10” | | | | | | |
| | having acid | “pKa in ground state: 4.69” | | | | | | |
| | group | Acridine | | | | | | |
| | (mol %)) | “ε365: 4900” | | | | | | |
| | | “pKa in ground state: 4.67” | | | | | | |
| | Polymerizable | DPHA | | 12.5 | | | 12.6 | 12.6 |
| | compound | A-NOD-N | | 12.5 | | | 25 | 25 |
| | | DTMPT | | 12.6 | 27.6 | 12.5 | | |
| | | A-DCP | 25 | | | 22.5 | | |
| | | TMPT | 12.6 | | | 12.6 | | |
| | Photopolymerization | OXE-02 | 0.8 | 0.8 | 0.8 | 0.8 | 0.8 | 0.8 |
| | initiator | Omn907 | 1.5 | 1.5 | 1.5 | 1.5 | 1.5 | 1.5 |
| | Surfactant | F551 | 0.1 | 0.1 | 0.1 | 0.1 | 0.1 | 0.1 |
| Evaluation | ε365/ε313 | | <1 | <1 | <1 | <1 | — | — |
| of photo- | Carboxy group consumption rate | | C | C | C | C | E | E |
| sensitive | [measurement of ashing] | | | | | | | |
| material | Pattern | 25 μm | A | A | A | A | B | B |
| | formability | 50 μm | A | A | A | A | B | B |
| | | 250 μm | A | A | A | A | B | B |

| | | | | | | | |
|---|---|---|---|---|---|---|---|
| | Relative permittivity | B | B | A | A | Standard | D |
| | Change in relative permittivity | B | B | A | A | D | D |
| | before and after exposure | | | | | | |
| Evaluation | ε365/ε313 | <1 | <1 | <1 | <1 | — | — |
| of transfer | Carboxy group consumption rate | C | C | C | C | E | E |
| film | [measurement of ashing] | | | | | | |
| | Transmittance at 365 nm | A | A | A | A | A | A |
| | Transmittance at 365 nm/ | A | A | A | A | B | B |
| | transmittance at 313 nm | | | | | | |
| | Laminate suitability | A | A | A | A | A | A |

| | | | | | | | |
|---|---|---|---|---|---|---|---|
| Pattern | 25 μm | A | A | A | A | B | B |
| formability | 50 μm | A | A | A | A | B | B |
| | 250 μm | A | A | A | A | B | B |

| | | | | | | |
|---|---|---|---|---|---|---|
| Relative permittivity | B | B | A | A | Standard | D |
| Change in relative permittivity | B | B | A | A | D | D |
| before and after exposure | | | | | | |
| Moisture permeability | A | A | A | A | Standard | D |
| Change in relative permittivity | B | B | A | A | Standard | D |
| after double exposure | | | | | | |

Resin A: resin having the following structure (acid value: 94.5 mgKOH/g)

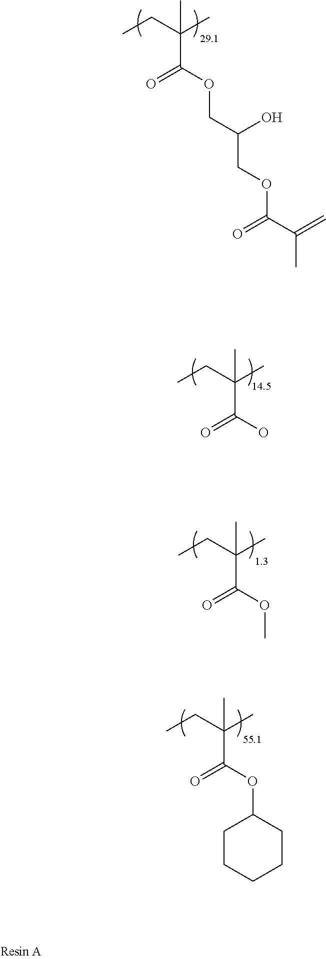

ratio is mass ratio

weight-average molecular weight: 27000

dispersity: 2.9

Synthesizing Method of Resin A

200 g of propylene glycol monomethyl ether and 50 g of propylene glycol monomethyl ether acetate poured into a flask and heated to 90° C. under a nitrogen stream. To this liquid, a solution in which 192.9 g of cyclohexyl methacrylate, 4.6 g of methyl methacrylate, and 89.3 g of methacrylic acid had been dissolved in 60 g of propylene glycol monomethyl ether acetate and a solution in which 9.2 g of a polymerization initiator V-601 (manufactured by FUJIFILM Wako Pure Chemical Corporation) had been dissolved in 114.8 g of propylene glycol monomethyl ether acetate was simultaneously added dropwise over 3 hours. After completion of the dropwise addition, a solution in which 2 g of V-601 had been dissolved in 10 g of propylene glycol monomethyl ether acetate was added thereto three times every hour. Thereafter, the reaction was continued for another 3 hours. The reaction solution was diluted with 168.7 g of propylene glycol monomethyl ether acetate. The reaction solution was heated to 100° C. under an air stream, and 1.5 g of tetraethylammonium bromide and 0.67 g of p-methoxyphenol were added thereto. 63.4 g of glycidyl methacrylate (Blemmer GH manufactured by NOF Corporation) was added dropwise thereto over 20 minutes. The reaction was continued at 100° C. for 6 hours to obtain a solution of a resin A. The concentration of solid contents of the obtained solution was 36.2%. The weight-average molecular weight in terms of standard polystyrene in GPC was 27000, the dispersity was 2.9, and the acid value of the polymer was 94.5 mgKOH/g. The amount of residual monomer measured by gas chromatography was less than 0.1% by mass with respect to the solid content of the polymer in any of the monomers.

Resin B: resin having the following structure (acid value: 94.5 mgKOH/g)

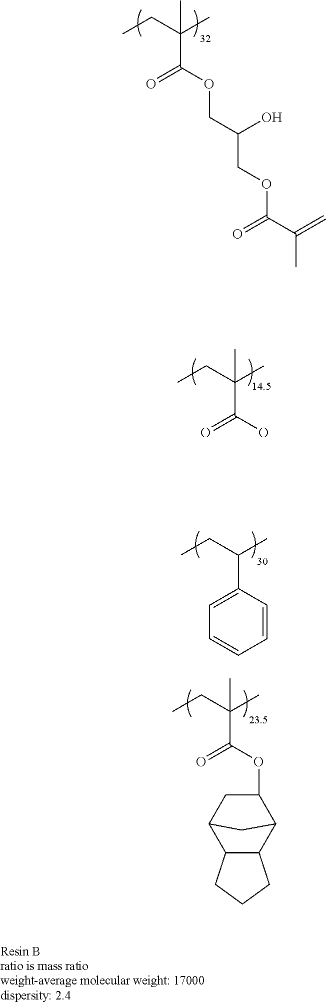

Synthesizing Method of Resin B

82.4 g of propylene glycol monomethyl ether was charged into a flask and heated to 90° C. under a nitrogen stream. To this liquid, a solution in which 38.4 g of styrene, 30.1 g of dicyclopentanyl methacrylate, and 34.0 g of methacrylic acid had been dissolved in 20 g of propylene glycol monomethyl ether and a solution in which 5.4 g of a polymerization initiator V-601 (manufactured by FUJIFILM Wako Pure Chemical Corporation) had been dissolved in 43.6 g of propylene glycol monomethyl ether acetate was simultaneously added dropwise over 3 hours. After the dropwise addition, 0.75 g of V-601 was added three times every hour. Thereafter, the reaction was continued for another 3 hours. Thereafter, the reaction solution was diluted with 58.4 g of propylene glycol monomethyl ether acetate and 11.7 g of propylene glycol monomethyl ether. The reaction solution was heated to 100° C. under an air stream, and 0.53 g of tetraethylammonium bromide and 0.26 g of p-methoxyphenol were added thereto. 25.5 g of glycidyl methacrylate (Blemmer GH manufactured by NOF Corporation) was added dropwise thereto over 20 minutes. The reaction was continued at 100° C. for 7 hours to obtain a solution of a resin B. The concentration of solid contents of the obtained solution was 36.2%. The weight-average molecular weight in terms of standard polystyrene in GPC was 17000, the dispersity was 2.4, and the acid value of the polymer was 94.5 mgKOH/g. The amount of residual monomer measured by gas chromatography was less than 0.1% by mass with respect to the solid content of the polymer in any of the monomers.

DPHA: dipentaerythritol hexaacrylate (A-DPH manufactured by Shin-Nakamura Chemical Co., Ltd.)

A-NOD-N: 1,9-nonanediol diacrylate (A-NOD-N manufactured by Shin-Nakamura Chemical Co., Ltd.)

DTMPT: ditrimethylolpropane tetraacrylate (KAYARAD T-1420 (T) manufactured by Nippon Kayaku Co., Ltd.)

A-DCPP: dicyclopentane dimethanol diacrylate (A-DCP manufactured by Shin-Nakamura Chemical Co., Ltd.)

TMPT: trimethylolpropane triacrylate (A-TMPT manufactured by Shin-Nakamura Chemical Co., Ltd.)

F551: MEGAFACE F551 (manufactured by DIC Corporation)

OXE-02: Irgacure OXE02 (manufactured by BASF SE, oxime ester compound; molar absorption coefficient to light having a wavelength of 365 nm in acetonitrile: 2700 (cm·mol/L)⁻¹)

Omn907: Omnirad 907 (manufactured by IGM Resins B.V., aminoacetophenone compound; molar absorption coefficient to light having a wavelength of 365 nm in acetonitrile: 120 (cm·mol/L)⁻¹)

As shown in the tables, it was confirmed that, even in a case where the photosensitive material included a photopolymerization initiator, the objects of the present invention could be achieved with the photosensitive material according to the embodiment of the present invention.

In addition, it was confirmed that conditions under which the effects of the present invention are more excellent were the same as those confirmed for Example 1 system.

[Evaluation of Layer which has Photosensitive Layer Formed of Photosensitive Material of Example 3 System and Second Resin Layer Under Condition of Double Exposure]

<Manufacturing of Transfer Film>

(Formation of Photosensitive Layer)

To a polyethylene terephthalate film (manufactured by Toray Industries, Inc., 16KS40) having a thickness of 16 μm (temporary support), the photosensitive material liquid of each of Examples shown in Example 3 system was applied using a slit-shaped nozzle such that a thickness after drying was adjusted to 5 μm, and the photosensitive material was dried at 100° C. for 2 minutes to form a photosensitive layer.

(Formation of Second Resin Layer)

Next, a coating liquid for a second resin layer formed by the following formulation 201 was applied to the photosensitive layer such that a thickness after drying was adjusted to 70 nm, dried for 1 minute at 80° C., and further dried for 1 minute at 110° C. to form a second resin layer disposed in direct contact with the photosensitive layer. The film thickness of the second resin layer was 70 nm, and the refractive index was 1.68.

The formulation 201 was prepared using a resin having an acid group and an ammonia aqueous solution, and the resin having an acid group was neutralized with the ammonia aqueous solution. That is, the coating liquid for a second resin layer was an aqueous resin composition including an ammonium salt of the resin having an acid group.

Coating Liquid for Second Resin Layer: Formulation 201 (Aqueous Resin Composition)
Acrylic resin (resin having an acid group, copolymer resin of methacrylic acid/allyl methacrylate, weight-average molecular weight: 25,000, compositional ratio (molar ratio)=40/60, solid content: 99.8%): 0.29 parts
ARONIX TO-2349 (monomer having a carboxy group, manufactured by Toagosei Co., Ltd.): 0.04 parts
NanoUse OZ-S30M (ZrO₂ particles, solid content: 30.5%, methanol 69.5%, refractive index: 2.2, average particle diameter: approximately 12 nm, manufactured by Nissan Chemical Corporation): 4.80 parts
BT120 (benzotriazole, manufactured by Johoku Chemical Industry Co., Ltd.): 0.03 parts
MEGAFACE F444 (fluorine-based surfactant, manufactured by DIC Corporation): 0.01 parts
Ammonia aqueous solution (2.5% by mass): 7.80 parts
Distilled water: 24.80 parts
Methanol: 76.10 parts

(Pattern Formation)

For a laminate obtained as described above, in which the photosensitive layer and the second resin layer which was disposed to be directly adjacent to the photosensitive layer were provided on the temporary support in this order, a polyethylene terephthalate film (manufactured by Toray Industries, Inc., 16KS40) having a thickness of 16 μm (cover film) was pressure-bonded onto the second resin layer. As a result, a transfer film (photosensitive transfer material) which had a photosensitive layer formed of the photosensitive material of each of Examples of Example 3 system and a second resin layer was produced.

By peeling off the cover film from the transfer film produced above and laminating the transfer film on a PET film (substrate for a touch panel) laminated with a copper foil manufactured by GEOMATEC Co., Ltd., the photosensitive layer of the transfer film was transferred to a surface of the copper foil to obtain a laminate having a laminated structure of “temporary support/photosensitive layer/second resin layer/copper foil/substrate (PET film)”. Laminating conditions were that a temperature of a substrate for a touch panel was 40° C., a temperature of a rubber roller (that is, a laminating temperature) was 110° C., a linear pressure was 3 N/cm, and a transportation speed was 2 m/min. Here, the copper foil is a film which is assumed as a wiring line of a touch panel.

The laminating property was as good as that of each transfer film of Example 3 system, which did not have the second resin layer.

Next, using a proximity type exposure machine (Hitachi High-Technologies Corporation) equipped with an ultra-high pressure mercury lamp, a distance between a surface of an exposure mask (quartz exposure mask having a pattern for forming a protective layer) and a surface of the temporary support was set to 125 μm, and the photosensitive layer of the above-described laminate was exposed in a patterned manner under the condition of an exposure amount of 100 mJ/cm² (i-line) with the ultra-high pressure mercury lamp through the temporary support.

During the exposure, the exposure was performed through a mask having a line size of 50 μm and a line:space of 1:1 or a mask having a line size of 250 μm and a line:space of 1:1.

After the exposure, the temporary support was peeled off from the laminate.

Next, the photosensitive layer of the laminate, from which the temporary support was peeled off, was developed for 40 seconds using a 1% by mass sodium carbonate aqueous solution (liquid temperature: 32° C.) as a developer. After the development, the photosensitive layer was rinsed with pure water for 20 seconds, and then air was blown to remove water, thereby obtaining a pattern. The obtained pattern was entirely exposed using a high-pressure mercury lamp. The integrated exposure amount measured with a 365 nm illuminance meter was 1000 mJ/cm².

In a case where line-and-space patterns with line widths and space widths of 50 μm or 250 μm, which were produced as described above were evaluated in the same manner as in (Pattern formability evaluation 1) described above, the evaluation results were as good as those in the case where the patterns were formed and evaluated in the same manner for each transfer film of Example 3 system, which had no second resin layer.

That is, the photosensitive material according to the embodiment of the present invention, which includes the polymerizable compound and the photopolymerization initiator, has good pattern formability even under the two-step exposure conditions.

In a case where the same evaluations as the evaluations under the condition of double exposure of a layer having the photosensitive layer which was formed of the photosensitive material of Example 3 system and the second resin layer was performed, except that a PET film on which an ITO film assuming a transparent electrode of a touch panel was used instead of the PET film on which the copper foil was laminated, good laminating property and pattern formability were exhibited same as the case of using the PET film on which the copper foil was laminated.

### Example 4 System

Fifth table below shows structures of the polymers A which were used in Example 4 system. The polymer A was synthesized by a known method.

In the following, as a representative example, a method for synthesizing a polymer of a compound No. 1 will be shown.

(Synthesis of Polymer of Compound No. 1)

PGMEA (60 parts) and PGME (240 parts) were poured into a flask having a capacity of 2000 mL. The obtained liquid was heated to 90° C. while stirring at a stirring speed of 250 rpm (round per minute; the same applies hereinafter).

For a preparation of a dropping liquid (1), styrene (47.7 parts), methyl methacrylate (1.3 parts), and methacrylic acid (51 parts) were mixed and then diluted with PGMEA (60 parts) to obtain the dropping liquid (1).

For a preparation of a dropping liquid (2), V-601 (dimethyl 2,2′-azobis(2-methylpropionate) (9.637 parts) was dissolved in PGMEA (136.56 parts) to obtain the dropping liquid (2).

The dropping liquid (1) and the dropping liquid (2) were simultaneously added dropwise to the above-described flask having a capacity of 2000 mL (specifically, the flask having a capacity of 2000 mL containing the liquid heated to 90° C.) over 3 hours. After the dropwise addition, V-601 (2.401 g) was added to the flask three times every hour. Thereafter, the reaction solution was further stirred at 90° C. for 3 hours.

Thereafter, the obtained solution (reaction solution) in the above-described flask was diluted with PGMEA (178 parts). Next, tetraethylammonium bromide (1.8 parts) and hydroquinone monomethyl ether (0.8 parts) were added to the reaction solution. Thereafter, the reaction solution was heated to 100° C.

Next, glycidyl methacrylate was added dropwise to the reaction solution over 1 hour such that an added amount was composition of the compound No. 1 in Fifth table. The above-described reaction solution was reacted at 100° C. for 6 hours to obtain a solution of a polymer (concentration of solid contents: 36.3% by mass).

As shown in Fifth table, the weight-average molecular weight of the polymer A shown in Fifth table was in a range of 10,000 to 50,000.

In addition, numerical values of each structural unit in Fifth table indicate a mass ratio.

In the column of the polymer A in Fifth table, abbreviations for each monomer forming the structural unit of the polymer are as follows. GMA-MAA means a constitutional unit in which glycidyl methacrylate is added to a constitutional unit derived from methacrylic acid, and GMA-AA means a constitutional unit in which glycidyl methacrylate is added to a constitutional unit derived from acrylic acid.

St: styrene

CHMA: cyclohexyl methacrylate

CHA: cyclohexyl acrylate

MMA: methyl methacrylate

EA: ethyl acrylate

BzMA: benzyl methacrylate

BzA: benzyl acrylate

HEMA: 2-hydroxyethyl methacrylate

HEA: 2-hydroxyethyl acrylate

MAA: methacrylic acid

AA: acrylic acid

TABLE 6
Fifth table
Polymer A

| | Structural unit (mass ratio) | | | | | | | | | | | | | Weight-average |
|---|---|---|---|---|---|---|---|---|---|---|---|---|---|---|
| Compound | | | | | | | | | | GMA- | GMA- | | | molecular weight |
| No. | St | CHMA | CHA | MMA | EA | BzMA | BzA | HEMA | HEA | MAA | AA | MAA | AA | (Mw) |
| 1 | 47.7 | | | 1.3 | | | | | | 32 | | 19 | | 18000 |
| 2 | 30 | | | 30 | | | | | | | | 40 | | 22000 |
| 3 | 30 | | | 30 | | | | | | | | | 40 | 25000 |
| 4 | 30 | | | | 30 | | | | | | | 40 | | 19000 |
| 5 | 30 | | | | 30 | | | | | | | | 40 | 20000 |
| 6 | 53.5 | | | | | | | | | | 32 | | 14.5 | 16000 |
| 7 | 49 | | | | | | | | | 32 | | 19 | | 15000 |
| 8 | 49 | | | | | 32 | | | | | | 19 | | 17000 |
| 9 | 53.5 | | | | | | 32 | | | | | | 14.5 | 14000 |
| 10 | 35.5 | | | | | 13.5 | | | | 32 | | 19 | | 28000 |
| 11 | 40 | | | | | | 14 | | | | 32 | | 14.5 | 29000 |
| 12 | 35.5 | | | | | | | 13.5 | | 32 | | 19 | | 30000 |
| 13 | 40 | | | | | | | | 13.5 | | 32 | | 14.5 | 32000 |
| 14 | | 81 | | | | | | | | | | 19 | | 27000 |
| 15 | | | 85.5 | | | | | | | | | | 14.5 | 28000 |
| 16 | | 49 | | | | | | | | 32 | | 19 | | 23000 |
| 17 | | | 53.5 | | | | | | | | 32 | | 14.5 | 23000 |
| 18 | | 49 | | | | 32 | | | | | | 19 | | 24000 |
| 19 | | | 53.5 | | | | 32 | | | | | | 14.5 | 30000 |
| 20 | | 49 | | | | | | 32 | | | | 19 | | 33000 |
| 21 | | | 53.5 | | | | | | 32 | | | | 14.5 | 40000 |
| 22 | | 35.5 | | | | 13.5 | | | | 32 | | 19 | | 38000 |
| 23 | | | 40 | | | | 14 | | | | 32 | | 14.5 | 35000 |
| 24 | | 35.5 | | | | | | 13.5 | | 32 | | 19 | | 49000 |
| 25 | | | 40 | | | | | | 13.5 | | 32 | | 14.5 | 45000 |
| 26 | 85 | | | | | | | | | | | | 15 | 11000 |

<Preparation and Evaluation of Photosensitive Material>

Materials shown in Sixth table shown in the latter part were mixed and dissolved in a mixed solvent of propylene glycol monomethyl ether acetate/methyl ethyl ketone=50/50 (mass ratio) so that a blending amount shown in Sixth table shown in the latter part was satisfied and a concentration of solid contents of the finally obtained photosensitive material was 25% by mass, thereby obtaining a photosensitive material.

In Sixth table below, each number of Examples and Comparative Examples is indicated by a head number+a serial number. That is, Example 4-1-1 corresponds to an example in which the head number is 4-1 and the serial number is 1. In addition, Comparative Example 4A-1 corresponds to an example in which the head number is 4A and the serial number is 1.

In addition, for the obtained photosensitive material of each of Examples and Comparative Examples in Example 4 system, the carboxy group consumption rate, pattern formability of the photosensitive material, relative permittivity, and change in relative permittivity before and after exposure, and the laminate suitability of the transfer film, pattern formability, relative permittivity, change in relative permittivity before and after exposure, and moisture permeability were evaluated in the same manner as shown in Example 1 system. In addition, the carboxy group consumption rate, transmittance to light at 365 nm, and ratio of the transmittance to light at 365 nm to the transmittance to light at 313 nm of the photosensitive layer in the transfer film were also evaluated in the same manner as shown in Example 1 system. In addition, the physical properties of ε365/ε313 of the compound β included in the photosensitive material and the photosensitive layer were evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Examples having the same serial number. That is, for example, in a case of Example 4-1-1, since the serial number is 1, Comparative Example 4A-1 having the serial number corresponds to the standard. In addition, for example, in a case of Example 4-27-51, since the serial number is 51, Comparative Example 4A-51 having the serial number corresponds to the standard.

Hereinafter, Sixth table below shows blending of the solid content of the photosensitive material of each of Examples and Comparative Examples in Example 4 system, and the test results thereof.

In the tables, the “Compound No.” in the column of “Polymer A” corresponds to “Compound No.” shown in Fifth table described above.

In the table, the value described in the column of “Part by mass” indicates the content (part by mass) of the solid content component of each component. The above-described blending amount (part by mass) is the amount of “Polymer A” and “Compound β” itself (solid content) added to the photosensitive material.

In addition, in the tables, the value of “Molar ratio with respect to carboxy group of polymer A (mol %)” in the compound β indicates a proportion (mol %) of the total number of structures (structures b0) included in the compound β, in which the amount of the carboxy group of the polymer A is reduced (preferably, structures (structures b) capable of accepting an electron from the carboxy group included in the polymer A in a photoexcited state) to the total number of carboxy groups included in the polymer A in the photosensitive material.

In addition, the column of “ε365/ε313” in the evaluation of the photosensitive material and the evaluation of the transfer film indicates a value obtained by dividing the molar absorption coefficient ((cm·mol/L)⁻¹) of the compound β to light having a wavelength of 365 nm by a molar absorption coefficient ((cm·mol/L)⁻¹) of the compound β to light having a wavelength of 313 nm. All molar absorption coefficients are values in acetonitrile.

In addition, the column of “Transmittance at 365 nm” in the evaluation of the transfer film indicates the transmittance of the photosensitive layer to light having a wavelength of 365 nm.

In addition, the column of “Transmittance at 365 nm/transmittance at 313 nm” in the evaluation of the transfer film indicates a value obtained by dividing the transmittance of the photosensitive layer to light having a wavelength of 365 nm by the transmittance of the photosensitive layer to light having a wavelength of 313 nm.

In addition, in Sixth table, types of the compound β used for preparing the photosensitive material are indicated by symbols.

The correspondence between the type of the compound β and the symbol is as shown below. In the following, the method for measuring “pKa in ground state” described for each compound β is as described above. The “ε365” indicates a molar absorption coefficient ((cm·mol/L)⁻¹) of the compound β to light having a wavelength of 365 nm in acetonitrile.

| Symbol; | Type | pKa in ground state | ε365 |
|---|---|---|---|
| B1; | isoquinoline | 4.69 | <10 |
| B2; | quinoline | 4.15 | <10 |
| B3; | acridine | 4.67 | 4900 |
| B4; | 1-n-butylisoquinoline | 5.27 | <10 |
| B5; | 1-n-butyl-4-methylisoquinoline | 5.9 | <10 |
| B6; | 1-Me-isoquinoline | 5.31 | <10 |
| B7; | 2,4,5,7-tetramethylquinoline | 6.23 | <10 |
| B8; | 2-methyl-4-methoxyquinoline | 6.51 | <10 |
| B9; | 9-methylacridine | 5.4 | 6300 |
| B10; | 9-phenylacridine | 4.04 | >10000 |
| B11; | pyridine | 5.25 | <10 |
| B12: | 2,4-dimethylquinoline | 5.67 | <10 |
| B13; | 4-aminopyridine | 9.20 | <100 |
| B14; | 2-chloropyridine | 0.70 | <10 |

TABLE 7
Sixth table (1)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-1- | 1 | 1 | 100 | B1 | 5.7 | 20 | B | <1 | B | A | A | A | A |
| | | 2 | 2 | 100 | B1 | 12.0 | 20 | B | <1 | B | A | A | A | A |
| | | 3 | 3 | 100 | B1 | 14.0 | 20 | B | <1 | B | A | A | A | A |
| | | 4 | 4 | 100 | B1 | 12.0 | 20 | B | <1 | B | A | A | A | A |
| | | 5 | 5 | 100 | B1 | 14.0 | 20 | B | <1 | B | A | A | A | A |
| | | 6 | 6 | 100 | B1 | 5.1 | 20 | B | <1 | B | A | A | A | A |
| | | 7 | 7 | 100 | B1 | 5.7 | 20 | B | <1 | B | A | A | A | A |
| | | 8 | 8 | 100 | B1 | 5.7 | 20 | B | <1 | B | A | A | A | A |
| | | 9 | 9 | 100 | B1 | 5.1 | 20 | B | <1 | B | A | A | A | A |
| | | 10 | 10 | 100 | B1 | 5.7 | 20 | B | <1 | B | A | A | A | A |
| | | 11 | 11 | 100 | B1 | 5.1 | 20 | B | <1 | B | A | A | A | A |
| | | 12 | 12 | 100 | B1 | 5.7 | 20 | B | <1 | B | A | A | A | A |
| | | 13 | 13 | 100 | B1 | 5.1 | 20 | B | <1 | B | A | A | A | A |
| | | 14 | 14 | 100 | B1 | 5.7 | 20 | B | <1 | B | A | A | A | A |
| | | 15 | 15 | 100 | B1 | 5.1 | 20 | B | <1 | B | A | A | A | A |
| | | 16 | 16 | 100 | B1 | 5.7 | 20 | B | <1 | B | A | A | A | A |
| | | 17 | 17 | 100 | B1 | 5.1 | 20 | B | <1 | B | A | A | A | A |
| | | 18 | 18 | 100 | B1 | 5.7 | 20 | B | <1 | B | A | A | A | A |
| | | 19 | 19 | 100 | B1 | 5.1 | 20 | B | <1 | B | A | A | A | A |
| | | 20 | 20 | 100 | B1 | 5.7 | 20 | B | <1 | B | A | A | A | A |
| | | 21 | 21 | 100 | B1 | 5.1 | 20 | B | <1 | B | A | A | A | A |
| | | 22 | 22 | 100 | B1 | 5.7 | 20 | B | <1 | B | A | A | A | A |
| | | 23 | 23 | 100 | B1 | 5.1 | 20 | B | <1 | B | A | A | A | A |
| | | 24 | 24 | 100 | B1 | 5.7 | 20 | B | <1 | B | A | A | A | A |
| | | 25 | 25 | 100 | B1 | 5.1 | 20 | B | <1 | B | A | A | A | A |
| | | 26 | 26 | 100 | B1 | 5.2 | 20 | B | <1 | B | A | A | A | A |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-1- | 1 | B | A | A | A | <1 | B | A | A | A | A | A |
| | | 2 | B | A | A | A | <1 | B | A | A | A | A | A |
| | | 3 | B | A | A | A | <1 | B | A | A | A | A | A |
| | | 4 | B | A | A | A | <1 | B | A | A | A | A | A |
| | | 5 | B | A | A | A | <1 | B | A | A | A | A | A |
| | | 6 | B | A | A | A | <1 | B | A | A | A | A | A |
| | | 7 | B | A | A | A | <1 | B | A | A | A | A | A |
| | | 8 | B | A | A | A | <1 | B | A | A | A | A | A |
| | | 9 | B | A | A | A | <1 | B | A | A | A | A | A |
| | | 10 | B | A | A | A | <1 | B | A | A | A | A | A |
| | | 11 | B | A | A | A | <1 | B | A | A | A | A | A |
| | | 12 | B | A | A | A | <1 | B | A | A | A | A | A |
| | | 13 | B | A | A | A | <1 | B | A | A | A | A | A |
| | | 14 | B | A | A | A | <1 | B | A | A | A | A | A |
| | | 15 | B | A | A | A | <1 | B | A | A | A | A | A |
| | | 16 | B | A | A | A | <1 | B | A | A | A | A | A |
| | | 17 | B | A | A | A | <1 | B | A | A | A | A | A |
| | | 18 | B | A | A | A | <1 | B | A | A | A | A | A |
| | | 19 | B | A | A | A | <1 | B | A | A | A | A | A |
| | | 20 | B | A | A | A | <1 | B | A | A | A | A | A |
| | | 21 | B | A | A | A | <1 | B | A | A | A | A | A |
| | | 22 | B | A | A | A | <1 | B | A | A | A | A | A |
| | | 23 | B | A | A | A | <1 | B | A | A | A | A | A |
| | | 24 | B | A | A | A | <1 | B | A | A | A | A | A |
| | | 25 | B | A | A | A | <1 | B | A | A | A | A | A |
| | | 26 | B | A | A | A | <1 | B | A | A | A | A | A |

TABLE 8
Sixth table (2)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-2- | 1 | 1 | 100 | B2 | 5.7 | 20 | B | <1 | B | A | A | A | A |
| | | 2 | 2 | 100 | B2 | 12.0 | 20 | B | <1 | B | A | A | A | A |
| | | 3 | 3 | 100 | B2 | 14.0 | 20 | B | <1 | B | A | A | A | A |
| | | 4 | 4 | 100 | B2 | 12.0 | 20 | B | <1 | B | A | A | A | A |
| | | 5 | 5 | 100 | B2 | 14.0 | 20 | B | <1 | B | A | A | A | A |
| | | 6 | 6 | 100 | B2 | 5.1 | 20 | B | <1 | B | A | A | A | A |
| | | 7 | 7 | 100 | B2 | 5.7 | 20 | B | <1 | B | A | A | A | A |
| | | 8 | 8 | 100 | B2 | 5.7 | 20 | B | <1 | B | A | A | A | A |
| | | 9 | 9 | 100 | B2 | 5.1 | 20 | B | <1 | B | A | A | A | A |
| | | 10 | 10 | 100 | B2 | 5.7 | 20 | B | <1 | B | A | A | A | A |
| | | 11 | 11 | 100 | B2 | 5.1 | 20 | B | <1 | B | A | A | A | A |
| | | 12 | 12 | 100 | B2 | 5.7 | 20 | B | <1 | B | A | A | A | A |
| | | 13 | 13 | 100 | B2 | 5.1 | 20 | B | <1 | B | A | A | A | A |
| | | 14 | 14 | 100 | B2 | 5.7 | 20 | B | <1 | B | A | A | A | A |
| | | 15 | 15 | 100 | B2 | 5.1 | 20 | B | <1 | B | A | A | A | A |
| | | 16 | 16 | 100 | B2 | 5.7 | 20 | B | <1 | B | A | A | A | A |
| | | 17 | 17 | 100 | B2 | 5.1 | 20 | B | <1 | B | A | A | A | A |
| | | 18 | 18 | 100 | B2 | 5.7 | 20 | B | <1 | B | A | A | A | A |
| | | 19 | 19 | 100 | B2 | 5.1 | 20 | B | <1 | B | A | A | A | A |
| | | 20 | 20 | 100 | B2 | 5.7 | 20 | B | <1 | B | A | A | A | A |
| | | 21 | 21 | 100 | B2 | 5.1 | 20 | B | <1 | B | A | A | A | A |
| | | 22 | 22 | 100 | B2 | 5.7 | 20 | B | <1 | B | A | A | A | A |
| | | 23 | 23 | 100 | B2 | 5.1 | 20 | B | <1 | B | A | A | A | A |
| | | 24 | 24 | 100 | B2 | 5.7 | 20 | B | <1 | B | A | A | A | A |
| | | 25 | 25 | 100 | B2 | 5.1 | 20 | B | <1 | B | A | A | A | A |
| | | 26 | 26 | 100 | B2 | 5.2 | 20 | B | <1 | B | A | A | A | A |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-2- | 1 | B | A | A | A | <1 | B | A | A | A | A | B |
| | | 2 | B | A | A | A | <1 | B | A | A | A | A | B |
| | | 3 | B | A | A | A | <1 | B | A | A | A | A | B |
| | | 4 | B | A | A | A | <1 | B | A | A | A | A | B |
| | | 5 | B | A | A | A | <1 | B | A | A | A | A | B |
| | | 6 | B | A | A | A | <1 | B | A | A | A | A | B |
| | | 7 | B | A | A | A | <1 | B | A | A | A | A | B |
| | | 8 | B | A | A | A | <1 | B | A | A | A | A | B |
| | | 9 | B | A | A | A | <1 | B | A | A | A | A | B |
| | | 10 | B | A | A | A | <1 | B | A | A | A | A | B |
| | | 11 | B | A | A | A | <1 | B | A | A | A | A | B |
| | | 12 | B | A | A | A | <1 | B | A | A | A | A | B |
| | | 13 | B | A | A | A | <1 | B | A | A | A | A | B |
| | | 14 | B | A | A | A | <1 | B | A | A | A | A | B |
| | | 15 | B | A | A | A | <1 | B | A | A | A | A | B |
| | | 16 | B | A | A | A | <1 | B | A | A | A | A | B |
| | | 17 | B | A | A | A | <1 | B | A | A | A | A | B |
| | | 18 | B | A | A | A | <1 | B | A | A | A | A | B |
| | | 19 | B | A | A | A | <1 | B | A | A | A | A | B |
| | | 20 | B | A | A | A | <1 | B | A | A | A | A | B |
| | | 21 | B | A | A | A | <1 | B | A | A | A | A | B |
| | | 22 | B | A | A | A | <1 | B | A | A | A | A | B |
| | | 23 | B | A | A | A | <1 | B | A | A | A | A | B |
| | | 24 | B | A | A | A | <1 | B | A | A | A | A | B |
| | | 25 | B | A | A | A | <1 | B | A | A | A | A | B |
| | | 26 | B | A | A | A | <1 | B | A | A | A | A | B |

TABLE 9
Sixth table (3)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-3- | 1 | 1 | 100 | B3 | 7.9 | 20 | D | <3 | C | B | B | B | B |
| | | 2 | 2 | 100 | B3 | 16.7 | 20 | D | <3 | C | B | B | B | B |
| | | 3 | 3 | 100 | B3 | 19.4 | 20 | D | <3 | C | B | B | B | B |
| | | 4 | 4 | 100 | B3 | 16.7 | 20 | D | <3 | C | B | B | B | B |
| | | 5 | 5 | 100 | B3 | 19.4 | 20 | D | <3 | C | B | B | B | B |
| | | 6 | 6 | 100 | B3 | 7.0 | 20 | D | <3 | C | B | B | B | B |
| | | 7 | 7 | 100 | B3 | 7.9 | 20 | D | <3 | C | B | B | B | B |
| | | 8 | 8 | 100 | B3 | 7.9 | 20 | D | <3 | C | B | B | B | B |
| | | 9 | 9 | 100 | B3 | 7.0 | 20 | D | <3 | C | B | B | B | B |
| | | 10 | 10 | 100 | B3 | 7.9 | 20 | D | <3 | C | B | B | B | B |
| | | 11 | 11 | 100 | B3 | 7.0 | 20 | D | <3 | C | B | B | B | B |
| | | 12 | 12 | 100 | B3 | 7.9 | 20 | D | <3 | C | B | B | B | B |
| | | 13 | 13 | 100 | B3 | 7.0 | 20 | D | <3 | C | B | B | B | B |
| | | 14 | 14 | 100 | B3 | 7.9 | 20 | D | <3 | C | B | B | B | B |
| | | 15 | 15 | 100 | B3 | 7.0 | 20 | D | <3 | C | B | B | B | B |
| | | 16 | 16 | 100 | B3 | 7.9 | 20 | D | <3 | C | B | B | B | B |
| | | 17 | 17 | 100 | B3 | 7.0 | 20 | D | <3 | C | B | B | B | B |
| | | 18 | 18 | 100 | B3 | 7.9 | 20 | D | <3 | C | B | B | B | B |
| | | 19 | 19 | 100 | B3 | 7.0 | 20 | D | <3 | C | B | B | B | B |
| | | 20 | 20 | 100 | B3 | 7.9 | 20 | D | <3 | C | B | B | B | B |
| | | 21 | 21 | 100 | B3 | 7.0 | 20 | D | <3 | C | B | B | B | B |
| | | 22 | 22 | 100 | B3 | 7.9 | 20 | D | <3 | C | B | B | B | B |
| | | 23 | 23 | 100 | B3 | 7.0 | 20 | D | <3 | C | B | B | B | B |
| | | 24 | 24 | 100 | B3 | 7.9 | 20 | D | <3 | C | B | B | B | B |
| | | 25 | 25 | 100 | B3 | 7.0 | 20 | D | <3 | C | B | B | B | B |
| | | 26 | 26 | 100 | B3 | 7.3 | 20 | D | <3 | C | B | B | B | B |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-3- | 1 | D | C | C | A | <3 | C | B | B | B | B | B |
| | | 2 | D | C | C | A | <3 | C | B | B | B | B | B |
| | | 3 | D | C | C | A | <3 | C | B | B | B | B | B |
| | | 4 | D | C | C | A | <3 | C | B | B | B | B | B |
| | | 5 | D | C | C | A | <3 | C | B | B | B | B | B |
| | | 6 | D | C | C | A | <3 | C | B | B | B | B | B |
| | | 7 | D | C | C | A | <3 | C | B | B | B | B | B |
| | | 8 | D | C | C | A | <3 | C | B | B | B | B | B |
| | | 9 | D | C | C | A | <3 | C | B | B | B | B | B |
| | | 10 | D | C | C | A | <3 | C | B | B | B | B | B |
| | | 11 | D | C | C | A | <3 | C | B | B | B | B | B |
| | | 12 | D | C | C | A | <3 | C | B | B | B | B | B |
| | | 13 | D | C | C | A | <3 | C | B | B | B | B | B |
| | | 14 | D | C | C | A | <3 | C | B | B | B | B | B |
| | | 15 | D | C | C | A | <3 | C | B | B | B | B | B |
| | | 16 | D | C | C | A | <3 | C | B | B | B | B | B |
| | | 17 | D | C | C | A | <3 | C | B | B | B | B | B |
| | | 18 | D | C | C | A | <3 | C | B | B | B | B | B |
| | | 19 | D | C | C | A | <3 | C | B | B | B | B | B |
| | | 20 | D | C | C | A | <3 | C | B | B | B | B | B |
| | | 21 | D | C | C | A | <3 | C | B | B | B | B | B |
| | | 22 | D | C | C | A | <3 | C | B | B | B | B | B |
| | | 23 | D | C | C | A | <3 | C | B | B | B | B | B |
| | | 24 | D | C | C | A | <3 | C | B | B | B | B | B |
| | | 25 | D | C | C | A | <3 | C | B | B | B | B | B |
| | | 26 | D | C | C | A | <3 | C | B | B | B | B | B |

TABLE 10
Sixth table (4)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-4- | 1 | 1 | 100 | B4 | 8.2 | 20 | A | <1 | A | A | A | A | A |
| | | 2 | 2 | 100 | B4 | 17.2 | 20 | A | <1 | A | A | A | A | A |
| | | 3 | 3 | 100 | B4 | 20.0 | 20 | A | <1 | A | A | A | A | A |
| | | 4 | 4 | 100 | B4 | 17.2 | 20 | A | <1 | A | A | A | A | A |
| | | 5 | 5 | 100 | B4 | 20.0 | 20 | A | <1 | A | A | A | A | A |
| | | 6 | 6 | 100 | B4 | 7.3 | 20 | A | <1 | A | A | A | A | A |
| | | 7 | 7 | 100 | B4 | 8.2 | 20 | A | <1 | A | A | A | A | A |
| | | 8 | 8 | 100 | B4 | 8.2 | 20 | A | <1 | A | A | A | A | A |
| | | 9 | 9 | 100 | B4 | 7.3 | 20 | A | <1 | A | A | A | A | A |
| | | 10 | 10 | 100 | B4 | 8.2 | 20 | A | <1 | A | A | A | A | A |
| | | 11 | 11 | 100 | B4 | 7.3 | 20 | A | <1 | A | A | A | A | A |
| | | 12 | 12 | 100 | B4 | 8.2 | 20 | A | <1 | A | A | A | A | A |
| | | 13 | 13 | 100 | B4 | 7.3 | 20 | A | <1 | A | A | A | A | A |
| | | 14 | 14 | 100 | B4 | 8.2 | 20 | A | <1 | A | A | A | A | A |
| | | 15 | 15 | 100 | B4 | 7.3 | 20 | A | <1 | A | A | A | A | A |
| | | 16 | 16 | 100 | B4 | 8.2 | 20 | A | <1 | A | A | A | A | A |
| | | 17 | 17 | 100 | B4 | 7.3 | 20 | A | <1 | A | A | A | A | A |
| | | 18 | 18 | 100 | B4 | 8.2 | 20 | A | <1 | A | A | A | A | A |
| | | 19 | 19 | 100 | B4 | 7.3 | 20 | A | <1 | A | A | A | A | A |
| | | 20 | 20 | 100 | B4 | 8.2 | 20 | A | <1 | A | A | A | A | A |
| | | 21 | 21 | 100 | B4 | 7.3 | 20 | A | <1 | A | A | A | A | A |
| | | 22 | 22 | 100 | B4 | 8.2 | 20 | A | <1 | A | A | A | A | A |
| | | 23 | 23 | 100 | B4 | 7.3 | 20 | A | <1 | A | A | A | A | A |
| | | 24 | 24 | 100 | B4 | 8.2 | 20 | A | <1 | A | A | A | A | A |
| | | 25 | 25 | 100 | B4 | 7.3 | 20 | A | <1 | A | A | A | A | A |
| | | 26 | 26 | 100 | B4 | 7.5 | 20 | A | <1 | A | A | A | A | A |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-4- | 1 | A | A | A | A | <1 | A | A | A | A | A | A |
| | | 2 | A | A | A | A | <1 | A | A | A | A | A | A |
| | | 3 | A | A | A | A | <1 | A | A | A | A | A | A |
| | | 4 | A | A | A | A | <1 | A | A | A | A | A | A |
| | | 5 | A | A | A | A | <1 | A | A | A | A | A | A |
| | | 6 | A | A | A | A | <1 | A | A | A | A | A | A |
| | | 7 | A | A | A | A | <1 | A | A | A | A | A | A |
| | | 8 | A | A | A | A | <1 | A | A | A | A | A | A |
| | | 9 | A | A | A | A | <1 | A | A | A | A | A | A |
| | | 10 | A | A | A | A | <1 | A | A | A | A | A | A |
| | | 11 | A | A | A | A | <1 | A | A | A | A | A | A |
| | | 12 | A | A | A | A | <1 | A | A | A | A | A | A |
| | | 13 | A | A | A | A | <1 | A | A | A | A | A | A |
| | | 14 | A | A | A | A | <1 | A | A | A | A | A | A |
| | | 15 | A | A | A | A | <1 | A | A | A | A | A | A |
| | | 16 | A | A | A | A | <1 | A | A | A | A | A | A |
| | | 17 | A | A | A | A | <1 | A | A | A | A | A | A |
| | | 18 | A | A | A | A | <1 | A | A | A | A | A | A |
| | | 19 | A | A | A | A | <1 | A | A | A | A | A | A |
| | | 20 | A | A | A | A | <1 | A | A | A | A | A | A |
| | | 21 | A | A | A | A | <1 | A | A | A | A | A | A |
| | | 22 | A | A | A | A | <1 | A | A | A | A | A | A |
| | | 23 | A | A | A | A | <1 | A | A | A | A | A | A |
| | | 24 | A | A | A | A | <1 | A | A | A | A | A | A |
| | | 25 | A | A | A | A | <1 | A | A | A | A | A | A |
| | | 26 | A | A | A | A | <1 | A | A | A | A | A | A |

TABLE 11
Sixth table (5)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-5- | 1 | 1 | 100 | B5 | 8.8 | 20 | A | <1 | A | A | A | A | A |
| | | 2 | 2 | 100 | B5 | 18.5 | 20 | A | <1 | A | A | A | A | A |
| | | 3 | 3 | 100 | B5 | 21.5 | 20 | A | <1 | A | A | A | A | A |
| | | 4 | 4 | 100 | B5 | 18.5 | 20 | A | <1 | A | A | A | A | A |
| | | 5 | 5 | 100 | B5 | 21.5 | 20 | A | <1 | A | A | A | A | A |
| | | 6 | 6 | 100 | B5 | 7.8 | 20 | A | <1 | A | A | A | A | A |
| | | 7 | 7 | 100 | B5 | 8.8 | 20 | A | <1 | A | A | A | A | A |
| | | 8 | 8 | 100 | B5 | 8.8 | 20 | A | <1 | A | A | A | A | A |
| | | 9 | 9 | 100 | B5 | 7.8 | 20 | A | <1 | A | A | A | A | A |
| | | 10 | 10 | 100 | B5 | 8.8 | 20 | A | <1 | A | A | A | A | A |
| | | 11 | 11 | 100 | B5 | 7.8 | 20 | A | <1 | A | A | A | A | A |
| | | 12 | 12 | 100 | B5 | 8.8 | 20 | A | <1 | A | A | A | A | A |
| | | 13 | 13 | 100 | B5 | 7.8 | 20 | A | <1 | A | A | A | A | A |
| | | 14 | 14 | 100 | B5 | 8.8 | 20 | A | <1 | A | A | A | A | A |
| | | 15 | 15 | 100 | B5 | 7.8 | 20 | A | <1 | A | A | A | A | A |
| | | 16 | 16 | 100 | B5 | 8.8 | 20 | A | <1 | A | A | A | A | A |
| | | 17 | 17 | 100 | B5 | 7.8 | 20 | A | <1 | A | A | A | A | A |
| | | 18 | 18 | 100 | B5 | 8.8 | 20 | A | <1 | A | A | A | A | A |
| | | 19 | 19 | 100 | B5 | 7.8 | 20 | A | <1 | A | A | A | A | A |
| | | 20 | 20 | 100 | B5 | 8.8 | 20 | A | <1 | A | A | A | A | A |
| | | 21 | 21 | 100 | B5 | 7.8 | 20 | A | <1 | A | A | A | A | A |
| | | 22 | 22 | 100 | B5 | 8.8 | 20 | A | <1 | A | A | A | A | A |
| | | 23 | 23 | 100 | B5 | 7.8 | 20 | A | <1 | A | A | A | A | A |
| | | 24 | 24 | 100 | B5 | 8.8 | 20 | A | <1 | A | A | A | A | A |
| | | 25 | 25 | 100 | B5 | 7.8 | 20 | A | <1 | A | A | A | A | A |
| | | 26 | 26 | 100 | B5 | 8.1 | 20 | A | <1 | A | A | A | A | A |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-5- | 1 | A | A | A | A | <1 | A | A | A | A | A | A |
| | | 2 | A | A | A | A | <1 | A | A | A | A | A | A |
| | | 3 | A | A | A | A | <1 | A | A | A | A | A | A |
| | | 4 | A | A | A | A | <1 | A | A | A | A | A | A |
| | | 5 | A | A | A | A | <1 | A | A | A | A | A | A |
| | | 6 | A | A | A | A | <1 | A | A | A | A | A | A |
| | | 7 | A | A | A | A | <1 | A | A | A | A | A | A |
| | | 8 | A | A | A | A | <1 | A | A | A | A | A | A |
| | | 9 | A | A | A | A | <1 | A | A | A | A | A | A |
| | | 10 | A | A | A | A | <1 | A | A | A | A | A | A |
| | | 11 | A | A | A | A | <1 | A | A | A | A | A | A |
| | | 12 | A | A | A | A | <1 | A | A | A | A | A | A |
| | | 13 | A | A | A | A | <1 | A | A | A | A | A | A |
| | | 14 | A | A | A | A | <1 | A | A | A | A | A | A |
| | | 15 | A | A | A | A | <1 | A | A | A | A | A | A |
| | | 16 | A | A | A | A | <1 | A | A | A | A | A | A |
| | | 17 | A | A | A | A | <1 | A | A | A | A | A | A |
| | | 18 | A | A | A | A | <1 | A | A | A | A | A | A |
| | | 19 | A | A | A | A | <1 | A | A | A | A | A | A |
| | | 20 | A | A | A | A | <1 | A | A | A | A | A | A |
| | | 21 | A | A | A | A | <1 | A | A | A | A | A | A |
| | | 22 | A | A | A | A | <1 | A | A | A | A | A | A |
| | | 23 | A | A | A | A | <1 | A | A | A | A | A | A |
| | | 24 | A | A | A | A | <1 | A | A | A | A | A | A |
| | | 25 | A | A | A | A | <1 | A | A | A | A | A | A |
| | | 26 | A | A | A | A | <1 | A | A | A | A | A | A |

TABLE 12
Sixth table (6)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-6- | 1 | 1 | 100 | B6 | 6.3 | 20 | A | <1 | A | A | A | A | A |
| | | 2 | 2 | 100 | B6 | 13.3 | 20 | A | <1 | A | A | A | A | A |
| | | 3 | 3 | 100 | B6 | 15.5 | 20 | A | <1 | A | A | A | A | A |
| | | 4 | 4 | 100 | B6 | 13.3 | 20 | A | <1 | A | A | A | A | A |
| | | 5 | 5 | 100 | B6 | 15.5 | 20 | A | <1 | A | A | A | A | A |
| | | 6 | 6 | 100 | B6 | 5.6 | 20 | A | <1 | A | A | A | A | A |
| | | 7 | 7 | 100 | B6 | 6.3 | 20 | A | <1 | A | A | A | A | A |
| | | 8 | 8 | 100 | B6 | 6.3 | 20 | A | <1 | A | A | A | A | A |
| | | 9 | 9 | 100 | B6 | 5.6 | 20 | A | <1 | A | A | A | A | A |
| | | 10 | 10 | 100 | B6 | 6.3 | 20 | A | <1 | A | A | A | A | A |
| | | 11 | 11 | 100 | B6 | 5.6 | 20 | A | <1 | A | A | A | A | A |
| | | 12 | 12 | 100 | B6 | 6.3 | 20 | A | <1 | A | A | A | A | A |
| | | 13 | 13 | 100 | B6 | 5.6 | 20 | A | <1 | A | A | A | A | A |
| | | 14 | 14 | 100 | B6 | 6.3 | 20 | A | <1 | A | A | A | A | A |
| | | 15 | 15 | 100 | B6 | 5.6 | 20 | A | <1 | A | A | A | A | A |
| | | 16 | 16 | 100 | B6 | 6.3 | 20 | A | <1 | A | A | A | A | A |
| | | 17 | 17 | 100 | B6 | 5.6 | 20 | A | <1 | A | A | A | A | A |
| | | 18 | 18 | 100 | B6 | 6.3 | 20 | A | <1 | A | A | A | A | A |
| | | 19 | 19 | 100 | B6 | 5.6 | 20 | A | <1 | A | A | A | A | A |
| | | 20 | 20 | 100 | B6 | 6.3 | 20 | A | <1 | A | A | A | A | A |
| | | 21 | 21 | 100 | B6 | 5.6 | 20 | A | <1 | A | A | A | A | A |
| | | 22 | 22 | 100 | B6 | 6.3 | 20 | A | <1 | A | A | A | A | A |
| | | 23 | 23 | 100 | B6 | 5.6 | 20 | A | <1 | A | A | A | A | A |
| | | 24 | 24 | 100 | B6 | 6.3 | 20 | A | <1 | A | A | A | A | A |
| | | 25 | 25 | 100 | B6 | 5.6 | 20 | A | <1 | A | A | A | A | A |
| | | 26 | 26 | 100 | B6 | 5.8 | 20 | A | <1 | A | A | A | A | A |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-6- | 1 | A | A | A | A | <1 | A | A | A | A | A | A |
| | | 2 | A | A | A | A | <1 | A | A | A | A | A | A |
| | | 3 | A | A | A | A | <1 | A | A | A | A | A | A |
| | | 4 | A | A | A | A | <1 | A | A | A | A | A | A |
| | | 5 | A | A | A | A | <1 | A | A | A | A | A | A |
| | | 6 | A | A | A | A | <1 | A | A | A | A | A | A |
| | | 7 | A | A | A | A | <1 | A | A | A | A | A | A |
| | | 8 | A | A | A | A | <1 | A | A | A | A | A | A |
| | | 9 | A | A | A | A | <1 | A | A | A | A | A | A |
| | | 10 | A | A | A | A | <1 | A | A | A | A | A | A |
| | | 11 | A | A | A | A | <1 | A | A | A | A | A | A |
| | | 12 | A | A | A | A | <1 | A | A | A | A | A | A |
| | | 13 | A | A | A | A | <1 | A | A | A | A | A | A |
| | | 14 | A | A | A | A | <1 | A | A | A | A | A | A |
| | | 15 | A | A | A | A | <1 | A | A | A | A | A | A |
| | | 16 | A | A | A | A | <1 | A | A | A | A | A | A |
| | | 17 | A | A | A | A | <1 | A | A | A | A | A | A |
| | | 18 | A | A | A | A | <1 | A | A | A | A | A | A |
| | | 19 | A | A | A | A | <1 | A | A | A | A | A | A |
| | | 20 | A | A | A | A | <1 | A | A | A | A | A | A |
| | | 21 | A | A | A | A | <1 | A | A | A | A | A | A |
| | | 22 | A | A | A | A | <1 | A | A | A | A | A | A |
| | | 23 | A | A | A | A | <1 | A | A | A | A | A | A |
| | | 24 | A | A | A | A | <1 | A | A | A | A | A | A |
| | | 25 | A | A | A | A | <1 | A | A | A | A | A | A |
| | | 26 | A | A | A | A | <1 | A | A | A | A | A | A |

TABLE 13
Sixth table (7)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-7- | 1 | 1 | 100 | B7 | 8.2 | 20 | A | <1 | A | A | A | A | A |
| | | 2 | 2 | 100 | B7 | 17.2 | 20 | A | <1 | A | A | A | A | A |
| | | 3 | 3 | 100 | B7 | 20.0 | 20 | A | <1 | A | A | A | A | A |
| | | 4 | 4 | 100 | B7 | 17.2 | 20 | A | <1 | A | A | A | A | A |
| | | 5 | 5 | 100 | B7 | 20.0 | 20 | A | <1 | A | A | A | A | A |
| | | 6 | 6 | 100 | B7 | 7.3 | 20 | A | <1 | A | A | A | A | A |
| | | 7 | 7 | 100 | B7 | 8.2 | 20 | A | <1 | A | A | A | A | A |
| | | 8 | 8 | 100 | B7 | 8.2 | 20 | A | <1 | A | A | A | A | A |
| | | 9 | 9 | 100 | B7 | 7.3 | 20 | A | <1 | A | A | A | A | A |
| | | 10 | 10 | 100 | B7 | 8.2 | 20 | A | <1 | A | A | A | A | A |
| | | 11 | 11 | 100 | B7 | 7.3 | 20 | A | <1 | A | A | A | A | A |
| | | 12 | 12 | 100 | B7 | 8.2 | 20 | A | <1 | A | A | A | A | A |
| | | 13 | 13 | 100 | B7 | 7.3 | 20 | A | <1 | A | A | A | A | A |
| | | 14 | 14 | 100 | B7 | 8.2 | 20 | A | <1 | A | A | A | A | A |
| | | 15 | 15 | 100 | B7 | 7.3 | 20 | A | <1 | A | A | A | A | A |
| | | 16 | 16 | 100 | B7 | 8.2 | 20 | A | <1 | A | A | A | A | A |
| | | 17 | 17 | 100 | B7 | 7.3 | 20 | A | <1 | A | A | A | A | A |
| | | 18 | 18 | 100 | B7 | 8.2 | 20 | A | <1 | A | A | A | A | A |
| | | 19 | 19 | 100 | B7 | 7.3 | 20 | A | <1 | A | A | A | A | A |
| | | 20 | 20 | 100 | B7 | 8.2 | 20 | A | <1 | A | A | A | A | A |
| | | 21 | 21 | 100 | B7 | 7.3 | 20 | A | <1 | A | A | A | A | A |
| | | 22 | 22 | 100 | B7 | 8.2 | 20 | A | <1 | A | A | A | A | A |
| | | 23 | 23 | 100 | B7 | 7.3 | 20 | A | <1 | A | A | A | A | A |
| | | 24 | 24 | 100 | B7 | 8.2 | 20 | A | <1 | A | A | A | A | A |
| | | 25 | 25 | 100 | B7 | 7.3 | 20 | A | <1 | A | A | A | A | A |
| | | 26 | 26 | 100 | B7 | 7.5 | 20 | A | <1 | A | A | A | A | A |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-7- | 1 | A | A | A | A | <1 | A | A | A | A | A | A |
| | | 2 | A | A | A | A | <1 | A | A | A | A | A | A |
| | | 3 | A | A | A | A | <1 | A | A | A | A | A | A |
| | | 4 | A | A | A | A | <1 | A | A | A | A | A | A |
| | | 5 | A | A | A | A | <1 | A | A | A | A | A | A |
| | | 6 | A | A | A | A | <1 | A | A | A | A | A | A |
| | | 7 | A | A | A | A | <1 | A | A | A | A | A | A |
| | | 8 | A | A | A | A | <1 | A | A | A | A | A | A |
| | | 9 | A | A | A | A | <1 | A | A | A | A | A | A |
| | | 10 | A | A | A | A | <1 | A | A | A | A | A | A |
| | | 11 | A | A | A | A | <1 | A | A | A | A | A | A |
| | | 12 | A | A | A | A | <1 | A | A | A | A | A | A |
| | | 13 | A | A | A | A | <1 | A | A | A | A | A | A |
| | | 14 | A | A | A | A | <1 | A | A | A | A | A | A |
| | | 15 | A | A | A | A | <1 | A | A | A | A | A | A |
| | | 16 | A | A | A | A | <1 | A | A | A | A | A | A |
| | | 17 | A | A | A | A | <1 | A | A | A | A | A | A |
| | | 18 | A | A | A | A | <1 | A | A | A | A | A | A |
| | | 19 | A | A | A | A | <1 | A | A | A | A | A | A |
| | | 20 | A | A | A | A | <1 | A | A | A | A | A | A |
| | | 21 | A | A | A | A | <1 | A | A | A | A | A | A |
| | | 22 | A | A | A | A | <1 | A | A | A | A | A | A |
| | | 23 | A | A | A | A | <1 | A | A | A | A | A | A |
| | | 24 | A | A | A | A | <1 | A | A | A | A | A | A |
| | | 25 | A | A | A | A | <1 | A | A | A | A | A | A |
| | | 26 | A | A | A | A | <1 | A | A | A | A | A | A |

TABLE 14
Sixth table (8)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-8- | 1 | 1 | 100 | B8 | 7.7 | 20 | A | <1 | A | A | A | A | A |
| | | 2 | 2 | 100 | B8 | 16.1 | 20 | A | <1 | A | A | A | A | A |
| | | 3 | 3 | 100 | B8 | 18.7 | 20 | A | <1 | A | A | A | A | A |
| | | 4 | 4 | 100 | B8 | 16.1 | 20 | A | <1 | A | A | A | A | A |
| | | 5 | 5 | 100 | B8 | 18.7 | 20 | A | <1 | A | A | A | A | A |
| | | 6 | 6 | 100 | B8 | 6.8 | 20 | A | <1 | A | A | A | A | A |
| | | 7 | 7 | 100 | B8 | 7.7 | 20 | A | <1 | A | A | A | A | A |
| | | 8 | 8 | 100 | B8 | 7.7 | 20 | A | <1 | A | A | A | A | A |
| | | 9 | 9 | 100 | B8 | 6.8 | 20 | A | <1 | A | A | A | A | A |
| | | 10 | 10 | 100 | B8 | 7.7 | 20 | A | <1 | A | A | A | A | A |
| | | 11 | 11 | 100 | B8 | 6.8 | 20 | A | <1 | A | A | A | A | A |
| | | 12 | 12 | 100 | B8 | 7.7 | 20 | A | <1 | A | A | A | A | A |
| | | 13 | 13 | 100 | B8 | 6.8 | 20 | A | <1 | A | A | A | A | A |
| | | 14 | 14 | 100 | B8 | 7.7 | 20 | A | <1 | A | A | A | A | A |
| | | 15 | 15 | 100 | B8 | 6.8 | 20 | A | <1 | A | A | A | A | A |
| | | 16 | 16 | 100 | B8 | 7.7 | 20 | A | <1 | A | A | A | A | A |
| | | 17 | 17 | 100 | B8 | 6.8 | 20 | A | <1 | A | A | A | A | A |
| | | 18 | 18 | 100 | B8 | 7.7 | 20 | A | <1 | A | A | A | A | A |
| | | 19 | 19 | 100 | B8 | 6.8 | 20 | A | <1 | A | A | A | A | A |
| | | 20 | 20 | 100 | B8 | 7.7 | 20 | A | <1 | A | A | A | A | A |
| | | 21 | 21 | 100 | B8 | 6.8 | 20 | A | <1 | A | A | A | A | A |
| | | 22 | 22 | 100 | B8 | 7.7 | 20 | A | <1 | A | A | A | A | A |
| | | 23 | 23 | 100 | B8 | 6.8 | 20 | A | <1 | A | A | A | A | A |
| | | 24 | 24 | 100 | B8 | 7.7 | 20 | A | <1 | A | A | A | A | A |
| | | 25 | 25 | 100 | B8 | 6.8 | 20 | A | <1 | A | A | A | A | A |
| | | 26 | 26 | 100 | B8 | 7.0 | 20 | A | <1 | A | A | A | A | A |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-8- | 1 | A | A | A | A | <1 | A | A | A | A | A | A |
| | | 2 | A | A | A | A | <1 | A | A | A | A | A | A |
| | | 3 | A | A | A | A | <1 | A | A | A | A | A | A |
| | | 4 | A | A | A | A | <1 | A | A | A | A | A | A |
| | | 5 | A | A | A | A | <1 | A | A | A | A | A | A |
| | | 6 | A | A | A | A | <1 | A | A | A | A | A | A |
| | | 7 | A | A | A | A | <1 | A | A | A | A | A | A |
| | | 8 | A | A | A | A | <1 | A | A | A | A | A | A |
| | | 9 | A | A | A | A | <1 | A | A | A | A | A | A |
| | | 10 | A | A | A | A | <1 | A | A | A | A | A | A |
| | | 11 | A | A | A | A | <1 | A | A | A | A | A | A |
| | | 12 | A | A | A | A | <1 | A | A | A | A | A | A |
| | | 13 | A | A | A | A | <1 | A | A | A | A | A | A |
| | | 14 | A | A | A | A | <1 | A | A | A | A | A | A |
| | | 15 | A | A | A | A | <1 | A | A | A | A | A | A |
| | | 16 | A | A | A | A | <1 | A | A | A | A | A | A |
| | | 17 | A | A | A | A | <1 | A | A | A | A | A | A |
| | | 18 | A | A | A | A | <1 | A | A | A | A | A | A |
| | | 19 | A | A | A | A | <1 | A | A | A | A | A | A |
| | | 20 | A | A | A | A | <1 | A | A | A | A | A | A |
| | | 21 | A | A | A | A | <1 | A | A | A | A | A | A |
| | | 22 | A | A | A | A | <1 | A | A | A | A | A | A |
| | | 23 | A | A | A | A | <1 | A | A | A | A | A | A |
| | | 24 | A | A | A | A | <1 | A | A | A | A | A | A |
| | | 25 | A | A | A | A | <1 | A | A | A | A | A | A |
| | | 26 | A | A | A | A | <1 | A | A | A | A | A | A |

TABLE 15
Sixth table (9)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-9- | 1 | 1 | 100 | B9 | 8.5 | 20 | C | >3 | B | B | A | B | B |
| | | 2 | 2 | 100 | B9 | 18.0 | 20 | C | >3 | B | B | A | B | B |
| | | 3 | 3 | 100 | B9 | 20.9 | 20 | C | >3 | B | B | A | B | B |
| | | 4 | 4 | 100 | B9 | 18.0 | 20 | C | >3 | B | B | A | B | B |
| | | 5 | 5 | 100 | B9 | 20.9 | 20 | C | >3 | B | B | A | B | B |
| | | 6 | 6 | 100 | B9 | 7.6 | 20 | C | >3 | B | B | A | B | B |
| | | 7 | 7 | 100 | B9 | 8.5 | 20 | C | >3 | B | B | A | B | B |
| | | 8 | 8 | 100 | B9 | 8.5 | 20 | C | >3 | B | B | A | B | B |
| | | 9 | 9 | 100 | B9 | 7.6 | 20 | C | >3 | B | B | A | B | B |
| | | 10 | 10 | 100 | B9 | 8.5 | 20 | C | >3 | B | B | A | B | B |
| | | 11 | 11 | 100 | B9 | 7.6 | 20 | C | >3 | B | B | A | B | B |
| | | 12 | 12 | 100 | B9 | 8.5 | 20 | C | >3 | B | B | A | B | B |
| | | 13 | 13 | 100 | B9 | 7.6 | 20 | C | >3 | B | B | A | B | B |
| | | 14 | 14 | 100 | B9 | 8.5 | 20 | C | >3 | B | B | A | B | B |
| | | 15 | 15 | 100 | B9 | 7.6 | 20 | C | >3 | B | B | A | B | B |
| | | 16 | 16 | 100 | B9 | 8.5 | 20 | C | >3 | B | B | A | B | B |
| | | 17 | 17 | 100 | B9 | 7.6 | 20 | C | >3 | B | B | A | B | B |
| | | 18 | 18 | 100 | B9 | 8.5 | 20 | C | >3 | B | B | A | B | B |
| | | 19 | 19 | 100 | B9 | 7.6 | 20 | C | >3 | B | B | A | B | B |
| | | 20 | 20 | 100 | B9 | 8.5 | 20 | C | >3 | B | B | A | B | B |
| | | 21 | 21 | 100 | B9 | 7.6 | 20 | C | >3 | B | B | A | B | B |
| | | 22 | 22 | 100 | B9 | 8.5 | 20 | C | >3 | B | B | A | B | B |
| | | 23 | 23 | 100 | B9 | 7.6 | 20 | C | >3 | B | B | A | B | B |
| | | 24 | 24 | 100 | B9 | 8.5 | 20 | C | >3 | B | B | A | B | B |
| | | 25 | 25 | 100 | B9 | 7.6 | 20 | C | >3 | B | B | A | B | B |
| | | 26 | 26 | 100 | B9 | 7.8 | 20 | C | >3 | B | B | A | B | B |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-9- | 1 | C | C | C | A | >3 | B | B | A | B | B | B |
| | | 2 | C | C | C | A | >3 | B | B | A | B | B | B |
| | | 3 | C | C | C | A | >3 | B | B | A | B | B | B |
| | | 4 | C | C | C | A | >3 | B | B | A | B | B | B |
| | | 5 | C | C | C | A | >3 | B | B | A | B | B | B |
| | | 6 | C | C | C | A | >3 | B | B | A | B | B | B |
| | | 7 | C | C | C | A | >3 | B | B | A | B | B | B |
| | | 8 | C | C | C | A | >3 | B | B | A | B | B | B |
| | | 9 | C | C | C | A | >3 | B | B | A | B | B | B |
| | | 10 | C | C | C | A | >3 | B | B | A | B | B | B |
| | | 11 | C | C | C | A | >3 | B | B | A | B | B | B |
| | | 12 | C | C | C | A | >3 | B | B | A | B | B | B |
| | | 13 | C | C | C | A | >3 | B | B | A | B | B | B |
| | | 14 | C | C | C | A | >3 | B | B | A | B | B | B |
| | | 15 | C | C | C | A | >3 | B | B | A | B | B | B |
| | | 16 | C | C | C | A | >3 | B | B | A | B | B | B |
| | | 17 | C | C | C | A | >3 | B | B | A | B | B | B |
| | | 18 | C | C | C | A | >3 | B | B | A | B | B | B |
| | | 19 | C | C | C | A | >3 | B | B | A | B | B | B |
| | | 20 | C | C | C | A | >3 | B | B | A | B | B | B |
| | | 21 | C | C | C | A | >3 | B | B | A | B | B | B |
| | | 22 | C | C | C | A | >3 | B | B | A | B | B | B |
| | | 23 | C | C | C | A | >3 | B | B | A | B | B | B |
| | | 24 | C | C | C | A | >3 | B | B | A | B | B | B |
| | | 25 | C | C | C | A | >3 | B | B | A | B | B | B |
| | | 26 | C | C | C | A | >3 | B | B | A | B | B | B |

TABLE 16
Sixth table (10)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-10- | 1 | 1 | 100 | B10 | 11.3 | 20 | D | >3 | B | B | B | C | C |
| | | 2 | 2 | 100 | B10 | 23.8 | 20 | D | >3 | B | B | B | C | C |
| | | 3 | 3 | 100 | B10 | 27.6 | 20 | D | >3 | B | B | B | C | C |
| | | 4 | 4 | 100 | B10 | 23.8 | 20 | D | >3 | B | B | B | C | C |
| | | 5 | 5 | 100 | B10 | 27.6 | 20 | D | >3 | B | B | B | C | C |
| | | 6 | 6 | 100 | B10 | 10.0 | 20 | D | >3 | B | B | B | C | C |
| | | 7 | 7 | 100 | B10 | 11.3 | 20 | D | >3 | B | B | B | C | C |
| | | 8 | 8 | 100 | B10 | 11.3 | 20 | D | >3 | B | B | B | C | C |
| | | 9 | 9 | 100 | B10 | 10.0 | 20 | D | >3 | B | B | B | C | C |
| | | 10 | 10 | 100 | B10 | 11.3 | 20 | D | >3 | B | B | B | C | C |
| | | 11 | 11 | 100 | B10 | 10.0 | 20 | D | >3 | B | B | B | C | C |
| | | 12 | 12 | 100 | B10 | 11.3 | 20 | D | >3 | B | B | B | C | C |
| | | 13 | 13 | 100 | B10 | 10.0 | 20 | D | >3 | B | B | B | C | C |
| | | 14 | 14 | 100 | B10 | 11.3 | 20 | D | >3 | B | B | B | C | C |
| | | 15 | 15 | 100 | B10 | 10.0 | 20 | D | >3 | B | B | B | C | C |
| | | 16 | 16 | 100 | B10 | 11.3 | 20 | D | >3 | B | B | B | C | C |
| | | 17 | 17 | 100 | B10 | 10.0 | 20 | D | >3 | B | B | B | C | C |
| | | 18 | 18 | 100 | B10 | 11.3 | 20 | D | >3 | B | B | B | C | C |
| | | 19 | 19 | 100 | B10 | 10.0 | 20 | D | >3 | B | B | B | C | C |
| | | 20 | 20 | 100 | B10 | 11.3 | 20 | D | >3 | B | B | B | C | C |
| | | 21 | 21 | 100 | B10 | 10.0 | 20 | D | >3 | B | B | B | C | C |
| | | 22 | 22 | 100 | B10 | 11.3 | 20 | D | >3 | B | B | B | C | C |
| | | 23 | 23 | 100 | B10 | 10.0 | 20 | D | >3 | B | B | B | C | C |
| | | 24 | 24 | 100 | B10 | 11.3 | 20 | D | >3 | B | B | B | C | C |
| | | 25 | 25 | 100 | B10 | 10.0 | 20 | D | >3 | B | B | B | C | C |
| | | 26 | 26 | 100 | B10 | 10.4 | 20 | D | >3 | B | B | B | C | C |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-10- | 1 | D | C | C | A | >3 | B | B | B | C | C | B |
| | | 2 | D | C | C | A | >3 | B | B | B | C | C | B |
| | | 3 | D | C | C | A | >3 | B | B | B | C | C | B |
| | | 4 | D | C | C | A | >3 | B | B | B | C | C | B |
| | | 5 | D | C | C | A | >3 | B | B | B | C | C | B |
| | | 6 | D | C | C | A | >3 | B | B | B | C | C | B |
| | | 7 | D | C | C | A | >3 | B | B | B | C | C | B |
| | | 8 | D | C | C | A | >3 | B | B | B | C | C | B |
| | | 9 | D | C | C | A | >3 | B | B | B | C | C | B |
| | | 10 | D | C | C | A | >3 | B | B | B | C | C | B |
| | | 11 | D | C | C | A | >3 | B | B | B | C | C | B |
| | | 12 | D | C | C | A | >3 | B | B | B | C | C | B |
| | | 13 | D | C | C | A | >3 | B | B | B | C | C | B |
| | | 14 | D | C | C | A | >3 | B | B | B | C | C | B |
| | | 15 | D | C | C | A | >3 | B | B | B | C | C | B |
| | | 16 | D | C | C | A | >3 | B | B | B | C | C | B |
| | | 17 | D | C | C | A | >3 | B | B | B | C | C | B |
| | | 18 | D | C | C | A | >3 | B | B | B | C | C | B |
| | | 19 | D | C | C | A | >3 | B | B | B | C | C | B |
| | | 20 | D | C | C | A | >3 | B | B | B | C | C | B |
| | | 21 | D | C | C | A | >3 | B | B | B | C | C | B |
| | | 22 | D | C | C | A | >3 | B | B | B | C | C | B |
| | | 23 | D | C | C | A | >3 | B | B | B | C | C | B |
| | | 24 | D | C | C | A | >3 | B | B | B | C | C | B |
| | | 25 | D | C | C | A | >3 | B | B | B | C | C | B |
| | | 26 | D | C | C | A | >3 | B | B | B | C | C | B |

TABLE 17
Sixth table (11)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-11- | 1 | 1 | 100 | B11 | 3.5 | 20 | D | <1 | C | C | C | C | C |
| | | 2 | 2 | 100 | B11 | 7.4 | 20 | D | <1 | C | C | C | C | C |
| | | 3 | 3 | 100 | B11 | 8.6 | 20 | D | <1 | C | C | C | C | C |
| | | 4 | 4 | 100 | B11 | 7.4 | 20 | D | <1 | C | C | C | C | C |
| | | 5 | 5 | 100 | B11 | 8.6 | 20 | D | <1 | C | C | C | C | C |
| | | 6 | 6 | 100 | B11 | 3.1 | 20 | D | <1 | C | C | C | C | C |
| | | 7 | 7 | 100 | B11 | 3.5 | 20 | D | <1 | C | C | C | C | C |
| | | 8 | 8 | 100 | B11 | 3.5 | 20 | D | <1 | C | C | C | C | C |
| | | 9 | 9 | 100 | B11 | 3.1 | 20 | D | <1 | C | C | C | C | C |
| | | 10 | 10 | 100 | B11 | 3.5 | 20 | D | <1 | C | C | C | C | C |
| | | 11 | 11 | 100 | B11 | 3.1 | 20 | D | <1 | C | C | C | C | C |
| | | 12 | 12 | 100 | B11 | 3.5 | 20 | D | <1 | C | C | C | C | C |
| | | 13 | 13 | 100 | B11 | 3.1 | 20 | D | <1 | C | C | C | C | C |
| | | 14 | 14 | 100 | B11 | 3.5 | 20 | D | <1 | C | C | C | C | C |
| | | 15 | 15 | 100 | B11 | 3.1 | 20 | D | <1 | C | C | C | C | C |
| | | 16 | 16 | 100 | B11 | 3.5 | 20 | D | <1 | C | C | C | C | C |
| | | 17 | 17 | 100 | B11 | 3.1 | 20 | D | <1 | C | C | C | C | C |
| | | 18 | 18 | 100 | B11 | 3.5 | 20 | D | <1 | C | C | C | C | C |
| | | 19 | 19 | 100 | B11 | 3.1 | 20 | D | <1 | C | C | C | C | C |
| | | 20 | 20 | 100 | B11 | 3.5 | 20 | D | <1 | C | C | C | C | C |
| | | 21 | 21 | 100 | B11 | 3.1 | 20 | D | <1 | C | C | C | C | C |
| | | 22 | 22 | 100 | B11 | 3.5 | 20 | D | <1 | C | C | C | C | C |
| | | 23 | 23 | 100 | B11 | 3.1 | 20 | D | <1 | C | C | C | C | C |
| | | 24 | 24 | 100 | B11 | 3.5 | 20 | D | <1 | C | C | C | C | C |
| | | 25 | 25 | 100 | B11 | 3.1 | 20 | D | <1 | C | C | C | C | C |
| | | 26 | 26 | 100 | B11 | 3.2 | 20 | D | <1 | C | C | C | C | C |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-11- | 1 | D | B | B | A | <1 | C | C | C | C | C | B |
| | | 2 | D | B | B | A | <1 | C | C | C | C | C | B |
| | | 3 | D | B | B | A | <1 | C | C | C | C | C | B |
| | | 4 | D | B | B | A | <1 | C | C | C | C | C | B |
| | | 5 | D | B | B | A | <1 | C | C | C | C | C | B |
| | | 6 | D | B | B | A | <1 | C | C | C | C | C | B |
| | | 7 | D | B | B | A | <1 | C | C | C | C | C | B |
| | | 8 | D | B | B | A | <1 | C | C | C | C | C | B |
| | | 9 | D | B | B | A | <1 | C | C | C | C | C | B |
| | | 10 | D | B | B | A | <1 | C | C | C | C | C | B |
| | | 11 | D | B | B | A | <1 | C | C | C | C | C | B |
| | | 12 | D | B | B | A | <1 | C | C | C | C | C | B |
| | | 13 | D | B | B | A | <1 | C | C | C | C | C | B |
| | | 14 | D | B | B | A | <1 | C | C | C | C | C | B |
| | | 15 | D | B | B | A | <1 | C | C | C | C | C | B |
| | | 16 | D | B | B | A | <1 | C | C | C | C | C | B |
| | | 17 | D | B | B | A | <1 | C | C | C | C | C | B |
| | | 18 | D | B | B | A | <1 | C | C | C | C | C | B |
| | | 19 | D | B | B | A | <1 | C | C | C | C | C | B |
| | | 20 | D | B | B | A | <1 | C | C | C | C | C | B |
| | | 21 | D | B | B | A | <1 | C | C | C | C | C | B |
| | | 22 | D | B | B | A | <1 | C | C | C | C | C | B |
| | | 23 | D | B | B | A | <1 | C | C | C | C | C | B |
| | | 24 | D | B | B | A | <1 | C | C | C | C | C | B |
| | | 25 | D | B | B | A | <1 | C | C | C | C | C | B |
| | | 26 | D | B | B | A | <1 | C | C | C | C | C | B |

TABLE 18
Sixth table (12)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-12- | 1 | 1 | 100 | B12 | 0.3 | 1 | C | <1 | C | B | B | C | C |
| | | 2 | 2 | 100 | B12 | 0.7 | 1 | C | <1 | C | B | B | C | C |
| | | 3 | 3 | 100 | B12 | 0.8 | 1 | C | <1 | C | B | B | C | C |
| | | 4 | 4 | 100 | B12 | 0.7 | 1 | C | <1 | C | B | B | C | C |
| | | 5 | 5 | 100 | B12 | 0.8 | 1 | C | <1 | C | B | B | C | C |
| | | 6 | 6 | 100 | B12 | 0.3 | 1 | C | <1 | C | B | B | C | C |
| | | 7 | 7 | 100 | B12 | 0.3 | 1 | C | <1 | C | B | B | C | C |
| | | 8 | 8 | 100 | B12 | 0.3 | 1 | C | <1 | C | B | B | C | C |
| | | 9 | 9 | 100 | B12 | 0.3 | 1 | C | <1 | C | B | B | C | C |
| | | 10 | 10 | 100 | B12 | 0.3 | 1 | C | <1 | C | B | B | C | C |
| | | 11 | 11 | 100 | B12 | 0.3 | 1 | C | <1 | C | B | B | C | C |
| | | 12 | 12 | 100 | B12 | 0.3 | 1 | C | <1 | C | B | B | C | C |
| | | 13 | 13 | 100 | B12 | 0.3 | 1 | C | <1 | C | B | B | C | C |
| | | 14 | 14 | 100 | B12 | 0.3 | 1 | C | <1 | C | B | B | C | C |
| | | 15 | 15 | 100 | B12 | 0.3 | 1 | C | <1 | C | B | B | C | C |
| | | 16 | 16 | 100 | B12 | 0.3 | 1 | C | <1 | C | B | B | C | C |
| | | 17 | 17 | 100 | B12 | 0.3 | 1 | C | <1 | C | B | B | C | C |
| | | 18 | 18 | 100 | B12 | 0.3 | 1 | C | <1 | C | B | B | C | C |
| | | 19 | 19 | 100 | B12 | 0.3 | 1 | C | <1 | C | B | B | C | C |
| | | 20 | 20 | 100 | B12 | 0.3 | 1 | C | <1 | C | B | B | C | C |
| | | 21 | 21 | 100 | B12 | 0.3 | 1 | C | <1 | C | B | B | C | C |
| | | 22 | 22 | 100 | B12 | 0.3 | 1 | C | <1 | C | B | B | C | C |
| | | 23 | 23 | 100 | B12 | 0.3 | 1 | C | <1 | C | B | B | C | C |
| | | 24 | 24 | 100 | B12 | 0.3 | 1 | C | <1 | C | B | B | C | C |
| | | 25 | 25 | 100 | B12 | 0.3 | 1 | C | <1 | C | B | B | C | C |
| | | 26 | 26 | 100 | B12 | 0.3 | 1 | C | <1 | C | B | B | C | C |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-12- | 1 | C | A | A | A | <1 | C | B | B | C | C | B |
| | | 2 | C | A | A | A | <1 | C | B | B | C | C | B |
| | | 3 | C | A | A | A | <1 | C | B | B | C | C | B |
| | | 4 | C | A | A | A | <1 | C | B | B | C | C | B |
| | | 5 | C | A | A | A | <1 | C | B | B | C | C | B |
| | | 6 | C | A | A | A | <1 | C | B | B | C | C | B |
| | | 7 | C | A | A | A | <1 | C | B | B | C | C | B |
| | | 8 | C | A | A | A | <1 | C | B | B | C | C | B |
| | | 9 | C | A | A | A | <1 | C | B | B | C | C | B |
| | | 10 | C | A | A | A | <1 | C | B | B | C | C | B |
| | | 11 | C | A | A | A | <1 | C | B | B | C | C | B |
| | | 12 | C | A | A | A | <1 | C | B | B | C | C | B |
| | | 13 | C | A | A | A | <1 | C | B | B | C | C | B |
| | | 14 | C | A | A | A | <1 | C | B | B | C | C | B |
| | | 15 | C | A | A | A | <1 | C | B | B | C | C | B |
| | | 16 | C | A | A | A | <1 | C | B | B | C | C | B |
| | | 17 | C | A | A | A | <1 | C | B | B | C | C | B |
| | | 18 | C | A | A | A | <1 | C | B | B | C | C | B |
| | | 19 | C | A | A | A | <1 | C | B | B | C | C | B |
| | | 20 | C | A | A | A | <1 | C | B | B | C | C | B |
| | | 21 | C | A | A | A | <1 | C | B | B | C | C | B |
| | | 22 | C | A | A | A | <1 | C | B | B | C | C | B |
| | | 23 | C | A | A | A | <1 | C | B | B | C | C | B |
| | | 24 | C | A | A | A | <1 | C | B | B | C | C | B |
| | | 25 | C | A | A | A | <1 | C | B | B | C | C | B |
| | | 26 | C | A | A | A | <1 | C | B | B | C | C | B |

TABLE 19
Sixth table (13)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-13- | 1 | 1 | 100 | B12 | 1.7 | 5 | B | <1 | B | B | A | B | B |
| | | 2 | 2 | 100 | B12 | 3.7 | 5 | B | <1 | B | B | A | B | B |
| | | 3 | 3 | 100 | B12 | 4.2 | 5 | B | <1 | B | B | A | B | B |
| | | 4 | 4 | 100 | B12 | 3.7 | 5 | B | <1 | B | B | A | B | B |
| | | 5 | 5 | 100 | B12 | 4.2 | 5 | B | <1 | B | B | A | B | B |
| | | 6 | 6 | 100 | B12 | 1.5 | 5 | B | <1 | B | B | A | B | B |
| | | 7 | 7 | 100 | B12 | 1.7 | 5 | B | <1 | B | B | A | B | B |
| | | 8 | 8 | 100 | B12 | 1.7 | 5 | B | <1 | B | B | A | B | B |
| | | 9 | 9 | 100 | B12 | 1.5 | 5 | B | <1 | B | B | A | B | B |
| | | 10 | 10 | 100 | B12 | 1.7 | 5 | B | <1 | B | B | A | B | B |
| | | 11 | 11 | 100 | B12 | 1.5 | 5 | B | <1 | B | B | A | B | B |
| | | 12 | 12 | 100 | B12 | 1.7 | 5 | B | <1 | B | B | A | B | B |
| | | 13 | 13 | 100 | B12 | 1.5 | 5 | B | <1 | B | B | A | B | B |
| | | 14 | 14 | 100 | B12 | 1.7 | 5 | B | <1 | B | B | A | B | B |
| | | 15 | 15 | 100 | B12 | 1.5 | 5 | B | <1 | B | B | A | B | B |
| | | 16 | 16 | 100 | B12 | 1.7 | 5 | B | <1 | B | B | A | B | B |
| | | 17 | 17 | 100 | B12 | 1.5 | 5 | B | <1 | B | B | A | B | B |
| | | 18 | 18 | 100 | B12 | 1.7 | 5 | B | <1 | B | B | A | B | B |
| | | 19 | 19 | 100 | B12 | 1.5 | 5 | B | <1 | B | B | A | B | B |
| | | 20 | 20 | 100 | B12 | 1.7 | 5 | B | <1 | B | B | A | B | B |
| | | 21 | 21 | 100 | B12 | 1.5 | 5 | B | <1 | B | B | A | B | B |
| | | 22 | 22 | 100 | B12 | 1.7 | 5 | B | <1 | B | B | A | B | B |
| | | 23 | 23 | 100 | B12 | 1.5 | 5 | B | <1 | B | B | A | B | B |
| | | 24 | 24 | 100 | B12 | 1.7 | 5 | B | <1 | B | B | A | B | B |
| | | 25 | 25 | 100 | B12 | 1.5 | 5 | B | <1 | B | B | A | B | B |
| | | 26 | 26 | 100 | B12 | 1.6 | 5 | B | <1 | B | B | A | B | B |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-13- | 1 | B | A | A | A | <1 | B | B | A | B | B | A |
| | | 2 | B | A | A | A | <1 | B | B | A | B | B | A |
| | | 3 | B | A | A | A | <1 | B | B | A | B | B | A |
| | | 4 | B | A | A | A | <1 | B | B | A | B | B | A |
| | | 5 | B | A | A | A | <1 | B | B | A | B | B | A |
| | | 6 | B | A | A | A | <1 | B | B | A | B | B | A |
| | | 7 | B | A | A | A | <1 | B | B | A | B | B | A |
| | | 8 | B | A | A | A | <1 | B | B | A | B | B | A |
| | | 9 | B | A | A | A | <1 | B | B | A | B | B | A |
| | | 10 | B | A | A | A | <1 | B | B | A | B | B | A |
| | | 11 | B | A | A | A | <1 | B | B | A | B | B | A |
| | | 12 | B | A | A | A | <1 | B | B | A | B | B | A |
| | | 13 | B | A | A | A | <1 | B | B | A | B | B | A |
| | | 14 | B | A | A | A | <1 | B | B | A | B | B | A |
| | | 15 | B | A | A | A | <1 | B | B | A | B | B | A |
| | | 16 | B | A | A | A | <1 | B | B | A | B | B | A |
| | | 17 | B | A | A | A | <1 | B | B | A | B | B | A |
| | | 18 | B | A | A | A | <1 | B | B | A | B | B | A |
| | | 19 | B | A | A | A | <1 | B | B | A | B | B | A |
| | | 20 | B | A | A | A | <1 | B | B | A | B | B | A |
| | | 21 | B | A | A | A | <1 | B | B | A | B | B | A |
| | | 22 | B | A | A | A | <1 | B | B | A | B | B | A |
| | | 23 | B | A | A | A | <1 | B | B | A | B | B | A |
| | | 24 | B | A | A | A | <1 | B | B | A | B | B | A |
| | | 25 | B | A | A | A | <1 | B | B | A | B | B | A |
| | | 26 | B | A | A | A | <1 | B | B | A | B | B | A |

TABLE 20
Sixth table (14)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-14- | 1 | 1 | 100 | B12 | 3.5 | 10 | B | <1 | B | A | A | A | A |
| | | 2 | 2 | 100 | B12 | 7.3 | 10 | B | <1 | B | A | A | A | A |
| | | 3 | 3 | 100 | B12 | 8.5 | 10 | B | <1 | B | A | A | A | A |
| | | 4 | 4 | 100 | B12 | 7.3 | 10 | B | <1 | B | A | A | A | A |
| | | 5 | 5 | 100 | B12 | 8.5 | 10 | B | <1 | B | A | A | A | A |
| | | 6 | 6 | 100 | B12 | 3.1 | 10 | B | <1 | B | A | A | A | A |
| | | 7 | 7 | 100 | B12 | 3.5 | 10 | B | <1 | B | A | A | A | A |
| | | 8 | 8 | 100 | B12 | 3.5 | 10 | B | <1 | B | A | A | A | A |
| | | 9 | 9 | 100 | B12 | 3.1 | 10 | B | <1 | B | A | A | A | A |
| | | 10 | 10 | 100 | B12 | 3.5 | 10 | B | <1 | B | A | A | A | A |
| | | 11 | 11 | 100 | B12 | 3.1 | 10 | B | <1 | B | A | A | A | A |
| | | 12 | 12 | 100 | B12 | 3.5 | 10 | B | <1 | B | A | A | A | A |
| | | 13 | 13 | 100 | B12 | 3.1 | 10 | B | <1 | B | A | A | A | A |
| | | 14 | 14 | 100 | B12 | 3.5 | 10 | B | <1 | B | A | A | A | A |
| | | 15 | 15 | 100 | B12 | 3.1 | 10 | B | <1 | B | A | A | A | A |
| | | 16 | 16 | 100 | B12 | 3.5 | 10 | B | <1 | B | A | A | A | A |
| | | 17 | 17 | 100 | B12 | 3.1 | 10 | B | <1 | B | A | A | A | A |
| | | 18 | 18 | 100 | B12 | 3.5 | 10 | B | <1 | B | A | A | A | A |
| | | 19 | 19 | 100 | B12 | 3.1 | 10 | B | <1 | B | A | A | A | A |
| | | 20 | 20 | 100 | B12 | 3.5 | 10 | B | <1 | B | A | A | A | A |
| | | 21 | 21 | 100 | B12 | 3.1 | 10 | B | <1 | B | A | A | A | A |
| | | 22 | 22 | 100 | B12 | 3.5 | 10 | B | <1 | B | A | A | A | A |
| | | 23 | 23 | 100 | B12 | 3.1 | 10 | B | <1 | B | A | A | A | A |
| | | 24 | 24 | 100 | B12 | 3.5 | 10 | B | <1 | B | A | A | A | A |
| | | 25 | 25 | 100 | B12 | 3.1 | 10 | B | <1 | B | A | A | A | A |
| | | 26 | 26 | 100 | B12 | 3.2 | 10 | B | <1 | B | A | A | A | A |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-14- | 1 | B | A | A | A | <1 | B | A | A | A | A | A |
| | | 2 | B | A | A | A | <1 | B | A | A | A | A | A |
| | | 3 | B | A | A | A | <1 | B | A | A | A | A | A |
| | | 4 | B | A | A | A | <1 | B | A | A | A | A | A |
| | | 5 | B | A | A | A | <1 | B | A | A | A | A | A |
| | | 6 | B | A | A | A | <1 | B | A | A | A | A | A |
| | | 7 | B | A | A | A | <1 | B | A | A | A | A | A |
| | | 8 | B | A | A | A | <1 | B | A | A | A | A | A |
| | | 9 | B | A | A | A | <1 | B | A | A | A | A | A |
| | | 10 | B | A | A | A | <1 | B | A | A | A | A | A |
| | | 11 | B | A | A | A | <1 | B | A | A | A | A | A |
| | | 12 | B | A | A | A | <1 | B | A | A | A | A | A |
| | | 13 | B | A | A | A | <1 | B | A | A | A | A | A |
| | | 14 | B | A | A | A | <1 | B | A | A | A | A | A |
| | | 15 | B | A | A | A | <1 | B | A | A | A | A | A |
| | | 16 | B | A | A | A | <1 | B | A | A | A | A | A |
| | | 17 | B | A | A | A | <1 | B | A | A | A | A | A |
| | | 18 | B | A | A | A | <1 | B | A | A | A | A | A |
| | | 19 | B | A | A | A | <1 | B | A | A | A | A | A |
| | | 20 | B | A | A | A | <1 | B | A | A | A | A | A |
| | | 21 | B | A | A | A | <1 | B | A | A | A | A | A |
| | | 22 | B | A | A | A | <1 | B | A | A | A | A | A |
| | | 23 | B | A | A | A | <1 | B | A | A | A | A | A |
| | | 24 | B | A | A | A | <1 | B | A | A | A | A | A |
| | | 25 | B | A | A | A | <1 | B | A | A | A | A | A |
| | | 26 | B | A | A | A | <1 | B | A | A | A | A | A |

TABLE 21
Sixth table (15)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-15- | 1 | 1 | 100 | B12 | 6.9 | 20 | A | <1 | A | A | A | A | A |
| | | 2 | 2 | 100 | B12 | 14.6 | 20 | A | <1 | A | A | A | A | A |
| | | 3 | 3 | 100 | B12 | 17.0 | 20 | A | <1 | A | A | A | A | A |
| | | 4 | 4 | 100 | B12 | 14.6 | 20 | A | <1 | A | A | A | A | A |
| | | 5 | 5 | 100 | B12 | 17.0 | 20 | A | <1 | A | A | A | A | A |
| | | 6 | 6 | 100 | B12 | 6.2 | 20 | A | <1 | A | A | A | A | A |
| | | 7 | 7 | 100 | B12 | 6.9 | 20 | A | <1 | A | A | A | A | A |
| | | 8 | 8 | 100 | B12 | 6.9 | 20 | A | <1 | A | A | A | A | A |
| | | 9 | 9 | 100 | B12 | 6.2 | 20 | A | <1 | A | A | A | A | A |
| | | 10 | 10 | 100 | B12 | 6.9 | 20 | A | <1 | A | A | A | A | A |
| | | 11 | 11 | 100 | B12 | 6.2 | 20 | A | <1 | A | A | A | A | A |
| | | 12 | 12 | 100 | B12 | 6.9 | 20 | A | <1 | A | A | A | A | A |
| | | 13 | 13 | 100 | B12 | 6.2 | 20 | A | <1 | A | A | A | A | A |
| | | 14 | 14 | 100 | B12 | 6.9 | 20 | A | <1 | A | A | A | A | A |
| | | 15 | 15 | 100 | B12 | 6.2 | 20 | A | <1 | A | A | A | A | A |
| | | 16 | 16 | 100 | B12 | 6.9 | 20 | A | <1 | A | A | A | A | A |
| | | 17 | 17 | 100 | B12 | 6.2 | 20 | A | <1 | A | A | A | A | A |
| | | 18 | 18 | 100 | B12 | 6.9 | 20 | A | <1 | A | A | A | A | A |
| | | 19 | 19 | 100 | B12 | 6.2 | 20 | A | <1 | A | A | A | A | A |
| | | 20 | 20 | 100 | B12 | 6.9 | 20 | A | <1 | A | A | A | A | A |
| | | 21 | 21 | 100 | B12 | 6.2 | 20 | A | <1 | A | A | A | A | A |
| | | 22 | 22 | 100 | B12 | 6.9 | 20 | A | <1 | A | A | A | A | A |
| | | 23 | 23 | 100 | B12 | 6.2 | 20 | A | <1 | A | A | A | A | A |
| | | 24 | 24 | 100 | B12 | 6.9 | 20 | A | <1 | A | A | A | A | A |
| | | 25 | 25 | 100 | B12 | 6.2 | 20 | A | <1 | A | A | A | A | A |
| | | 26 | 26 | 100 | B12 | 6.4 | 20 | A | <1 | A | A | A | A | A |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-15- | 1 | A | A | A | A | <1 | A | A | A | A | A | A |
| | | 2 | A | A | A | A | <1 | A | A | A | A | A | A |
| | | 3 | A | A | A | A | <1 | A | A | A | A | A | A |
| | | 4 | A | A | A | A | <1 | A | A | A | A | A | A |
| | | 5 | A | A | A | A | <1 | A | A | A | A | A | A |
| | | 6 | A | A | A | A | <1 | A | A | A | A | A | A |
| | | 7 | A | A | A | A | <1 | A | A | A | A | A | A |
| | | 8 | A | A | A | A | <1 | A | A | A | A | A | A |
| | | 9 | A | A | A | A | <1 | A | A | A | A | A | A |
| | | 10 | A | A | A | A | <1 | A | A | A | A | A | A |
| | | 11 | A | A | A | A | <1 | A | A | A | A | A | A |
| | | 12 | A | A | A | A | <1 | A | A | A | A | A | A |
| | | 13 | A | A | A | A | <1 | A | A | A | A | A | A |
| | | 14 | A | A | A | A | <1 | A | A | A | A | A | A |
| | | 15 | A | A | A | A | <1 | A | A | A | A | A | A |
| | | 16 | A | A | A | A | <1 | A | A | A | A | A | A |
| | | 17 | A | A | A | A | <1 | A | A | A | A | A | A |
| | | 18 | A | A | A | A | <1 | A | A | A | A | A | A |
| | | 19 | A | A | A | A | <1 | A | A | A | A | A | A |
| | | 20 | A | A | A | A | <1 | A | A | A | A | A | A |
| | | 21 | A | A | A | A | <1 | A | A | A | A | A | A |
| | | 22 | A | A | A | A | <1 | A | A | A | A | A | A |
| | | 23 | A | A | A | A | <1 | A | A | A | A | A | A |
| | | 24 | A | A | A | A | <1 | A | A | A | A | A | A |
| | | 25 | A | A | A | A | <1 | A | A | A | A | A | A |
| | | 26 | A | A | A | A | <1 | A | A | A | A | A | A |

TABLE 22
Sixth table (16)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-16- | 1 | 1 | 100 | B12 | 13.9 | 40 | A | <1 | A | A | A | A | A |
| | | 2 | 2 | 100 | B12 | 29.3 | 40 | A | <1 | A | A | A | A | A |
| | | 3 | 3 | 100 | B12 | 34.0 | 40 | A | <1 | A | A | A | A | A |
| | | 4 | 4 | 100 | B12 | 29.3 | 40 | A | <1 | A | A | A | A | A |
| | | 5 | 5 | 100 | B12 | 34.0 | 40 | A | <1 | A | A | A | A | A |
| | | 6 | 6 | 100 | B12 | 12.3 | 40 | A | <1 | A | A | A | A | A |
| | | 7 | 7 | 100 | B12 | 13.9 | 40 | A | <1 | A | A | A | A | A |
| | | 8 | 8 | 100 | B12 | 13.9 | 40 | A | <1 | A | A | A | A | A |
| | | 9 | 9 | 100 | B12 | 12.3 | 40 | A | <1 | A | A | A | A | A |
| | | 10 | 10 | 100 | B12 | 13.9 | 40 | A | <1 | A | A | A | A | A |
| | | 11 | 11 | 100 | B12 | 12.3 | 40 | A | <1 | A | A | A | A | A |
| | | 12 | 12 | 100 | B12 | 13.9 | 40 | A | <1 | A | A | A | A | A |
| | | 13 | 13 | 100 | B12 | 12.3 | 40 | A | <1 | A | A | A | A | A |
| | | 14 | 14 | 100 | B12 | 13.9 | 40 | A | <1 | A | A | A | A | A |
| | | 15 | 15 | 100 | B12 | 12.3 | 40 | A | <1 | A | A | A | A | A |
| | | 16 | 16 | 100 | B12 | 13.9 | 40 | A | <1 | A | A | A | A | A |
| | | 17 | 17 | 100 | B12 | 12.3 | 40 | A | <1 | A | A | A | A | A |
| | | 18 | 18 | 100 | B12 | 13.9 | 40 | A | <1 | A | A | A | A | A |
| | | 19 | 19 | 100 | B12 | 12.3 | 40 | A | <1 | A | A | A | A | A |
| | | 20 | 20 | 100 | B12 | 13.9 | 40 | A | <1 | A | A | A | A | A |
| | | 21 | 21 | 100 | B12 | 12.3 | 40 | A | <1 | A | A | A | A | A |
| | | 22 | 22 | 100 | B12 | 13.9 | 40 | A | <1 | A | A | A | A | A |
| | | 23 | 23 | 100 | B12 | 12.3 | 40 | A | <1 | A | A | A | A | A |
| | | 24 | 24 | 100 | B12 | 13.9 | 40 | A | <1 | A | A | A | A | A |
| | | 25 | 25 | 100 | B12 | 12.3 | 40 | A | <1 | A | A | A | A | A |
| | | 26 | 26 | 100 | B12 | 12.7 | 40 | A | <1 | A | A | A | A | A |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-16- | 1 | A | A | A | A | <1 | A | A | A | A | A | A |
| | | 2 | A | A | A | A | <1 | A | A | A | A | A | A |
| | | 3 | A | A | A | A | <1 | A | A | A | A | A | A |
| | | 4 | A | A | A | A | <1 | A | A | A | A | A | A |
| | | 5 | A | A | A | A | <1 | A | A | A | A | A | A |
| | | 6 | A | A | A | A | <1 | A | A | A | A | A | A |
| | | 7 | A | A | A | A | <1 | A | A | A | A | A | A |
| | | 8 | A | A | A | A | <1 | A | A | A | A | A | A |
| | | 9 | A | A | A | A | <1 | A | A | A | A | A | A |
| | | 10 | A | A | A | A | <1 | A | A | A | A | A | A |
| | | 11 | A | A | A | A | <1 | A | A | A | A | A | A |
| | | 12 | A | A | A | A | <1 | A | A | A | A | A | A |
| | | 13 | A | A | A | A | <1 | A | A | A | A | A | A |
| | | 14 | A | A | A | A | <1 | A | A | A | A | A | A |
| | | 15 | A | A | A | A | <1 | A | A | A | A | A | A |
| | | 16 | A | A | A | A | <1 | A | A | A | A | A | A |
| | | 17 | A | A | A | A | <1 | A | A | A | A | A | A |
| | | 18 | A | A | A | A | <1 | A | A | A | A | A | A |
| | | 19 | A | A | A | A | <1 | A | A | A | A | A | A |
| | | 20 | A | A | A | A | <1 | A | A | A | A | A | A |
| | | 21 | A | A | A | A | <1 | A | A | A | A | A | A |
| | | 22 | A | A | A | A | <1 | A | A | A | A | A | A |
| | | 23 | A | A | A | A | <1 | A | A | A | A | A | A |
| | | 24 | A | A | A | A | <1 | A | A | A | A | A | A |
| | | 25 | A | A | A | A | <1 | A | A | A | A | A | A |
| | | 26 | A | A | A | A | <1 | A | A | A | A | A | A |

TABLE 23
Sixth table (17)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-17- | 1 | 1 | 100 | B12 | 17.4 | 50 | A | <1 | A | A | A | A | A |
| | | 2 | 2 | 100 | B12 | 36.6 | 50 | A | <1 | A | A | A | A | A |
| | | 3 | 3 | 100 | B12 | 42.5 | 50 | A | <1 | A | A | A | A | A |
| | | 4 | 4 | 100 | B12 | 36.6 | 50 | A | <1 | A | A | A | A | A |
| | | 5 | 5 | 100 | B12 | 42.5 | 50 | A | <1 | A | A | A | A | A |
| | | 6 | 6 | 100 | B12 | 15.4 | 50 | A | <1 | A | A | A | A | A |
| | | 7 | 7 | 100 | B12 | 17.4 | 50 | A | <1 | A | A | A | A | A |
| | | 8 | 8 | 100 | B12 | 17.4 | 50 | A | <1 | A | A | A | A | A |
| | | 9 | 9 | 100 | B12 | 15.4 | 50 | A | <1 | A | A | A | A | A |
| | | 10 | 10 | 100 | B12 | 17.4 | 50 | A | <1 | A | A | A | A | A |
| | | 11 | 11 | 100 | B12 | 15.4 | 50 | A | <1 | A | A | A | A | A |
| | | 12 | 12 | 100 | B12 | 17.4 | 50 | A | <1 | A | A | A | A | A |
| | | 13 | 13 | 100 | B12 | 15.4 | 50 | A | <1 | A | A | A | A | A |
| | | 14 | 14 | 100 | B12 | 17.4 | 50 | A | <1 | A | A | A | A | A |
| | | 15 | 15 | 100 | B12 | 15.4 | 50 | A | <1 | A | A | A | A | A |
| | | 16 | 16 | 100 | B12 | 17.4 | 50 | A | <1 | A | A | A | A | A |
| | | 17 | 17 | 100 | B12 | 15.4 | 50 | A | <1 | A | A | A | A | A |
| | | 18 | 18 | 100 | B12 | 17.4 | 50 | A | <1 | A | A | A | A | A |
| | | 19 | 19 | 100 | B12 | 15.4 | 50 | A | <1 | A | A | A | A | A |
| | | 20 | 20 | 100 | B12 | 17.4 | 50 | A | <1 | A | A | A | A | A |
| | | 21 | 21 | 100 | B12 | 15.4 | 50 | A | <1 | A | A | A | A | A |
| | | 22 | 22 | 100 | B12 | 17.4 | 50 | A | <1 | A | A | A | A | A |
| | | 23 | 23 | 100 | B12 | 15.4 | 50 | A | <1 | A | A | A | A | A |
| | | 24 | 24 | 100 | B12 | 17.4 | 50 | A | <1 | A | A | A | A | A |
| | | 25 | 25 | 100 | B12 | 15.4 | 50 | A | <1 | A | A | A | A | A |
| | | 26 | 26 | 100 | B12 | 15.9 | 50 | A | <1 | A | A | A | A | A |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-17- | 1 | A | A | A | A | <1 | A | A | A | A | A | A |
| | | 2 | A | A | A | A | <1 | A | A | A | A | A | A |
| | | 3 | A | A | A | A | <1 | A | A | A | A | A | A |
| | | 4 | A | A | A | A | <1 | A | A | A | A | A | A |
| | | 5 | A | A | A | A | <1 | A | A | A | A | A | A |
| | | 6 | A | A | A | A | <1 | A | A | A | A | A | A |
| | | 7 | A | A | A | A | <1 | A | A | A | A | A | A |
| | | 8 | A | A | A | A | <1 | A | A | A | A | A | A |
| | | 9 | A | A | A | A | <1 | A | A | A | A | A | A |
| | | 10 | A | A | A | A | <1 | A | A | A | A | A | A |
| | | 11 | A | A | A | A | <1 | A | A | A | A | A | A |
| | | 12 | A | A | A | A | <1 | A | A | A | A | A | A |
| | | 13 | A | A | A | A | <1 | A | A | A | A | A | A |
| | | 14 | A | A | A | A | <1 | A | A | A | A | A | A |
| | | 15 | A | A | A | A | <1 | A | A | A | A | A | A |
| | | 16 | A | A | A | A | <1 | A | A | A | A | A | A |
| | | 17 | A | A | A | A | <1 | A | A | A | A | A | A |
| | | 18 | A | A | A | A | <1 | A | A | A | A | A | A |
| | | 19 | A | A | A | A | <1 | A | A | A | A | A | A |
| | | 20 | A | A | A | A | <1 | A | A | A | A | A | A |
| | | 21 | A | A | A | A | <1 | A | A | A | A | A | A |
| | | 22 | A | A | A | A | <1 | A | A | A | A | A | A |
| | | 23 | A | A | A | A | <1 | A | A | A | A | A | A |
| | | 24 | A | A | A | A | <1 | A | A | A | A | A | A |
| | | 25 | A | A | A | A | <1 | A | A | A | A | A | A |
| | | 26 | A | A | A | A | <1 | A | A | A | A | A | A |

TABLE 24
Sixth table (18)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-18- | 1 | 1 | 100 | B12 | 34.7 | 100 | A | <1 | A | A | A | B | B |
| | | 2 | 2 | 100 | B12 | 73.1 | 100 | A | <1 | A | A | A | B | B |
| | | 3 | 3 | 100 | B12 | 85.0 | 100 | A | <1 | A | A | A | B | B |
| | | 4 | 4 | 100 | B12 | 73.1 | 100 | A | <1 | A | A | A | B | B |
| | | 5 | 5 | 100 | B12 | 85.0 | 100 | A | <1 | A | A | A | B | B |
| | | 6 | 6 | 100 | B12 | 30.8 | 100 | A | <1 | A | A | A | B | B |
| | | 7 | 7 | 100 | B12 | 34.7 | 100 | A | <1 | A | A | A | B | B |
| | | 8 | 8 | 100 | B12 | 34.7 | 100 | A | <1 | A | A | A | B | B |
| | | 9 | 9 | 100 | B12 | 30.8 | 100 | A | <1 | A | A | A | B | B |
| | | 10 | 10 | 100 | B12 | 34.7 | 100 | A | <1 | A | A | A | B | B |
| | | 11 | 11 | 100 | B12 | 30.8 | 100 | A | <1 | A | A | A | B | B |
| | | 12 | 12 | 100 | B12 | 34.7 | 100 | A | <1 | A | A | A | B | B |
| | | 13 | 13 | 100 | B12 | 30.8 | 100 | A | <1 | A | A | A | B | B |
| | | 14 | 14 | 100 | B12 | 34.7 | 100 | A | <1 | A | A | A | B | B |
| | | 15 | 15 | 100 | B12 | 30.8 | 100 | A | <1 | A | A | A | B | B |
| | | 16 | 16 | 100 | B12 | 34.7 | 100 | A | <1 | A | A | A | B | B |
| | | 17 | 17 | 100 | B12 | 30.8 | 100 | A | <1 | A | A | A | B | B |
| | | 18 | 18 | 100 | B12 | 34.7 | 100 | A | <1 | A | A | A | B | B |
| | | 19 | 19 | 100 | B12 | 30.8 | 100 | A | <1 | A | A | A | B | B |
| | | 20 | 20 | 100 | B12 | 34.7 | 100 | A | <1 | A | A | A | B | B |
| | | 21 | 21 | 100 | B12 | 30.8 | 100 | A | <1 | A | A | A | B | B |
| | | 22 | 22 | 100 | B12 | 34.7 | 100 | A | <1 | A | A | A | B | B |
| | | 23 | 23 | 100 | B12 | 30.8 | 100 | A | <1 | A | A | A | B | B |
| | | 24 | 24 | 100 | B12 | 34.7 | 100 | A | <1 | A | A | A | B | B |
| | | 25 | 25 | 100 | B12 | 30.8 | 100 | A | <1 | A | A | A | B | B |
| | | 26 | 26 | 100 | B12 | 31.9 | 100 | A | <1 | A | A | A | B | B |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-18- | 1 | A | A | A | A | <1 | A | A | A | B | B | A |
| | | 2 | A | A | A | A | <1 | A | A | A | B | B | A |
| | | 3 | A | A | A | A | <1 | A | A | A | B | B | A |
| | | 4 | A | A | A | A | <1 | A | A | A | B | B | A |
| | | 5 | A | A | A | A | <1 | A | A | A | B | B | A |
| | | 6 | A | A | A | A | <1 | A | A | A | B | B | A |
| | | 7 | A | A | A | A | <1 | A | A | A | B | B | A |
| | | 8 | A | A | A | A | <1 | A | A | A | B | B | A |
| | | 9 | A | A | A | A | <1 | A | A | A | B | B | A |
| | | 10 | A | A | A | A | <1 | A | A | A | B | B | A |
| | | 11 | A | A | A | A | <1 | A | A | A | B | B | A |
| | | 12 | A | A | A | A | <1 | A | A | A | B | B | A |
| | | 13 | A | A | A | A | <1 | A | A | A | B | B | A |
| | | 14 | A | A | A | A | <1 | A | A | A | B | B | A |
| | | 15 | A | A | A | A | <1 | A | A | A | B | B | A |
| | | 16 | A | A | A | A | <1 | A | A | A | B | B | A |
| | | 17 | A | A | A | A | <1 | A | A | A | B | B | A |
| | | 18 | A | A | A | A | <1 | A | A | A | B | B | A |
| | | 19 | A | A | A | A | <1 | A | A | A | B | B | A |
| | | 20 | A | A | A | A | <1 | A | A | A | B | B | A |
| | | 21 | A | A | A | A | <1 | A | A | A | B | B | A |
| | | 22 | A | A | A | A | <1 | A | A | A | B | B | A |
| | | 23 | A | A | A | A | <1 | A | A | A | B | B | A |
| | | 24 | A | A | A | A | <1 | A | A | A | B | B | A |
| | | 25 | A | A | A | A | <1 | A | A | A | B | B | A |
| | | 26 | A | A | A | A | <1 | A | A | A | B | B | A |

TABLE 25
Sixth table (19)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-19- | 1 | 1 | 100 | B13 | 4.2 | 20 | D | <1 | C | C | C | C | C |
| | | 2 | 2 | 100 | B13 | 8.8 | 20 | D | <1 | C | C | C | C | C |
| | | 3 | 3 | 100 | B13 | 10.2 | 20 | D | <1 | C | C | C | C | C |
| | | 4 | 4 | 100 | B13 | 8.8 | 20 | D | <1 | C | C | C | C | C |
| | | 5 | 5 | 100 | B13 | 10.2 | 20 | D | <1 | C | C | C | C | C |
| | | 6 | 6 | 100 | B13 | 3.7 | 20 | D | <1 | C | C | C | C | C |
| | | 7 | 7 | 100 | B13 | 4.2 | 20 | D | <1 | C | C | C | C | C |
| | | 8 | 8 | 100 | B13 | 4.2 | 20 | D | <1 | C | C | C | C | C |
| | | 9 | 9 | 100 | B13 | 3.7 | 20 | D | <1 | C | C | C | C | C |
| | | 10 | 10 | 100 | B13 | 4.2 | 20 | D | <1 | C | C | C | C | C |
| | | 11 | 11 | 100 | B13 | 3.7 | 20 | D | <1 | C | C | C | C | C |
| | | 12 | 12 | 100 | B13 | 4.2 | 20 | D | <1 | C | C | C | C | C |
| | | 13 | 13 | 100 | B13 | 3.7 | 20 | D | <1 | C | C | C | C | C |
| | | 14 | 14 | 100 | B13 | 4.2 | 20 | D | <1 | C | C | C | C | C |
| | | 15 | 15 | 100 | B13 | 3.7 | 20 | D | <1 | C | C | C | C | C |
| | | 16 | 16 | 100 | B13 | 4.2 | 20 | D | <1 | C | C | C | C | C |
| | | 17 | 17 | 100 | B13 | 3.7 | 20 | D | <1 | C | C | C | C | C |
| | | 18 | 18 | 100 | B13 | 4.2 | 20 | D | <1 | C | C | C | C | C |
| | | 19 | 19 | 100 | B13 | 3.7 | 20 | D | <1 | C | C | C | C | C |
| | | 20 | 20 | 100 | B13 | 4.2 | 20 | D | <1 | C | C | C | C | C |
| | | 21 | 21 | 100 | B13 | 3.7 | 20 | D | <1 | C | C | C | C | C |
| | | 22 | 22 | 100 | B13 | 4.2 | 20 | D | <1 | C | C | C | C | C |
| | | 23 | 23 | 100 | B13 | 3.7 | 20 | D | <1 | C | C | C | C | C |
| | | 24 | 24 | 100 | B13 | 4.2 | 20 | D | <1 | C | C | C | C | C |
| | | 25 | 25 | 100 | B13 | 3.7 | 20 | D | <1 | C | C | C | C | C |
| | | 26 | 26 | 100 | B13 | 3.8 | 20 | D | <1 | C | C | C | C | C |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-19- | 1 | D | B | B | A | <1 | C | C | C | C | C | C |
| | | 2 | D | B | B | A | <1 | C | C | C | C | C | C |
| | | 3 | D | B | B | A | <1 | C | C | C | C | C | C |
| | | 4 | D | B | B | A | <1 | C | C | C | C | C | C |
| | | 5 | D | B | B | A | <1 | C | C | C | C | C | C |
| | | 6 | D | B | B | A | <1 | C | C | C | C | C | C |
| | | 7 | D | B | B | A | <1 | C | C | C | C | C | C |
| | | 8 | D | B | B | A | <1 | C | C | C | C | C | C |
| | | 9 | D | B | B | A | <1 | C | C | C | C | C | C |
| | | 10 | D | B | B | A | <1 | C | C | C | C | C | C |
| | | 11 | D | B | B | A | <1 | C | C | C | C | C | C |
| | | 12 | D | B | B | A | <1 | C | C | C | C | C | C |
| | | 13 | D | B | B | A | <1 | C | C | C | C | C | C |
| | | 14 | D | B | B | A | <1 | C | C | C | C | C | C |
| | | 15 | D | B | B | A | <1 | C | C | C | C | C | C |
| | | 16 | D | B | B | A | <1 | C | C | C | C | C | C |
| | | 17 | D | B | B | A | <1 | C | C | C | C | C | C |
| | | 18 | D | B | B | A | <1 | C | C | C | C | C | C |
| | | 19 | D | B | B | A | <1 | C | C | C | C | C | C |
| | | 20 | D | B | B | A | <1 | C | C | C | C | C | C |
| | | 21 | D | B | B | A | <1 | C | C | C | C | C | C |
| | | 22 | D | B | B | A | <1 | C | C | C | C | C | C |
| | | 23 | D | B | B | A | <1 | C | C | C | C | C | C |
| | | 24 | D | B | B | A | <1 | C | C | C | C | C | C |
| | | 25 | D | B | B | A | <1 | C | C | C | C | C | C |
| | | 26 | D | B | B | A | <1 | C | C | C | C | C | C |

TABLE 26
Sixth table (20)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-20- | 1 | 1 | 100 | B14 | 5.0 | 20 | D | <1 | C | C | C | C | C |
| | | 2 | 2 | 100 | B14 | 10.6 | 20 | D | <1 | C | C | C | C | C |
| | | 3 | 3 | 100 | B14 | 12.3 | 20 | D | <1 | C | C | C | C | C |
| | | 4 | 4 | 100 | B14 | 10.6 | 20 | D | <1 | C | C | C | C | C |
| | | 5 | 5 | 100 | B14 | 12.3 | 20 | D | <1 | C | C | C | C | C |
| | | 6 | 6 | 100 | B14 | 4.4 | 20 | D | <1 | C | C | C | C | C |
| | | 7 | 7 | 100 | B14 | 5.0 | 20 | D | <1 | C | C | C | C | C |
| | | 8 | 8 | 100 | B14 | 5.0 | 20 | D | <1 | C | C | C | C | C |
| | | 9 | 9 | 100 | B14 | 4.4 | 20 | D | <1 | C | C | C | C | C |
| | | 10 | 10 | 100 | B14 | 5.0 | 20 | D | <1 | C | C | C | C | C |
| | | 11 | 11 | 100 | B14 | 4.4 | 20 | D | <1 | C | C | C | C | C |
| | | 12 | 12 | 100 | B14 | 5.0 | 20 | D | <1 | C | C | C | C | C |
| | | 13 | 13 | 100 | B14 | 4.4 | 20 | D | <1 | C | C | C | C | C |
| | | 14 | 14 | 100 | B14 | 5.0 | 20 | D | <1 | C | C | C | C | C |
| | | 15 | 15 | 100 | B14 | 4.4 | 20 | D | <1 | C | C | C | C | C |
| | | 16 | 16 | 100 | B14 | 5.0 | 20 | D | <1 | C | C | C | C | C |
| | | 17 | 17 | 100 | B14 | 4.4 | 20 | D | <1 | C | C | C | C | C |
| | | 18 | 18 | 100 | B14 | 5.0 | 20 | D | <1 | C | C | C | C | C |
| | | 19 | 19 | 100 | BI4 | 4.4 | 20 | D | <1 | C | C | C | C | C |
| | | 20 | 20 | 100 | B14 | 5.0 | 20 | D | <1 | C | C | C | C | C |
| | | 21 | 21 | 100 | B14 | 4.4 | 20 | D | <1 | C | C | C | C | C |
| | | 22 | 22 | 100 | B14 | 5.0 | 20 | D | <1 | C | C | C | C | C |
| | | 23 | 23 | 100 | B14 | 4.4 | 20 | D | <1 | C | C | C | C | C |
| | | 24 | 24 | 100 | B14 | 5.0 | 20 | D | <1 | C | C | C | C | C |
| | | 25 | 25 | 100 | B14 | 4.4 | 20 | D | <1 | C | C | C | C | C |
| | | 26 | 26 | 100 | B14 | 4.6 | 20 | D | <1 | C | C | C | C | C |

Evaluation of transfer film

| | | | | | Transmit- | | | | | | | | |
|---|---|---|---|---|---|---|---|---|---|---|---|---|---|
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-20- | 1 | D | B | B | A | <1 | C | C | C | C | C | C |
| | | 2 | D | B | B | A | <1 | C | C | C | C | C | C |
| | | 3 | D | B | B | A | <1 | C | C | C | C | C | C |
| | | 4 | D | B | B | A | <1 | C | C | C | C | C | C |
| | | 5 | D | B | B | A | <1 | C | C | C | C | C | C |
| | | 6 | D | B | B | A | <1 | C | C | C | C | C | C |
| | | 7 | D | B | B | A | <1 | C | C | C | C | C | C |
| | | 8 | D | B | B | A | <1 | C | C | C | C | C | C |
| | | 9 | D | B | B | A | <1 | C | C | C | C | C | C |
| | | 10 | D | B | B | A | <1 | C | C | C | C | C | C |
| | | 11 | D | B | B | A | <1 | C | C | C | C | C | C |
| | | 12 | D | B | B | A | <1 | C | C | C | C | C | C |
| | | 13 | D | B | B | A | <1 | C | C | C | C | C | C |
| | | 14 | D | B | B | A | <1 | C | C | C | C | C | C |
| | | 15 | D | B | B | A | <1 | C | C | C | C | C | C |
| | | 16 | D | B | B | A | <1 | C | C | C | C | C | C |
| | | 17 | D | B | B | A | <1 | C | C | C | C | C | C |
| | | 18 | D | B | B | A | <1 | C | C | C | C | C | C |
| | | 19 | D | B | B | A | <1 | C | C | C | C | C | C |
| | | 20 | D | B | B | A | <1 | C | C | C | C | C | C |
| | | 21 | D | B | B | A | <1 | C | C | C | C | C | C |
| | | 22 | D | B | B | A | <1 | C | C | C | C | C | C |
| | | 23 | D | B | B | A | <1 | C | C | C | C | C | C |
| | | 24 | D | B | B | A | <1 | C | C | C | C | C | C |
| | | 25 | D | B | B | A | <1 | C | C | C | C | C | C |
| | | 26 | D | B | B | A | <1 | C | C | C | C | C | C |

TABLE 27
Sixth table (21)

| | | | | | Compound β | | | Evaluation of photosensitive material | | | | | | |
|---|---|---|---|---|---|---|---|---|---|---|---|---|---|---|
| | | | | | | | Molar ratio | | | | | | | Change in |
| Example/ | | | Polymer A | | | | with respect to | Carboxy group | | Pattern | | | | relative |
| Compar- | | | Com- | Part | | Part | carboxy group | consumption rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-21- | 51 | 2 | 50 | B6 | 14.4 | 20 | A | <1 | A | A | A | A | A |
| | (A | | 3 | 50 | | | | | | | | | | |
| | blended) | 52 | 10 | 50 | B6 | 6.0 | 20 | A | <1 | A | A | A | A | A |
| | | | 11 | 50 | | | | | | | | | | |
| | | 53 | 12 | 50 | B6 | 6.0 | 20 | A | <1 | A | A | A | A | A |
| | | | 13 | 50 | | | | | | | | | | |
| | | 54 | 16 | 50 | B6 | 6.0 | 20 | A | <1 | A | A | A | A | A |
| | | | 17 | 50 | | | | | | | | | | |
| | | 55 | 18 | 50 | B6 | 6.0 | 20 | A | <1 | A | A | A | A | A |
| | | | 19 | 50 | | | | | | | | | | |
| | | 56 | 20 | 50 | B6 | 6.0 | 20 | A | <1 | A | A | A | A | A |
| | | | 21 | 50 | | | | | | | | | | |
| | | 57 | 1 | 50 | B6 | 6.1 | 20 | A | <1 | A | A | A | A | A |
| | | | 26 | 50 | | | | | | | | | | |
| | | 58 | 8 | 33 | B6 | 6.3 | 20 | A | <1 | A | A | A | A | A |
| | | | 10 | 33 | | | | | | | | | | |
| | | | 12 | 34 | | | | | | | | | | |
| | | 59 | 15 | 33 | B6 | 5.6 | 20 | A | <1 | A | A | A | A | A |
| | | | 17 | 33 | | | | | | | | | | |
| | | | 19 | 34 | | | | | | | | | | |
| | | 60 | 20 | 33 | B6 | 6.1 | 20 | A | <1 | A | A | A | A | A |
| | | | 21 | 33 | | | | | | | | | | |
| | | | 22 | 34 | | | | | | | | | | |
| | | 61 | 1 | 33 | B6 | 6.1 | 20 | A | <1 | A | A | A | A | A |
| | | | 12 | 33 | | | | | | | | | | |
| | | | 23 | 34 | | | | | | | | | | |

| | | | Evaluation of transfer film | | | | | | | | | | |
|---|---|---|---|---|---|---|---|---|---|---|---|---|---|
| | | | | | Transmit- | | | | | | | | |
| | | | | | tance at | | | | | | | Change in | |
| Example/ | | | Carboxy group | | 365 nm/ | | | Pattern | | | | relative | |
| Compar- | | | consumption rate | Transmit- | transmit- | Laminate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-21- | 51 | A | A | A | A | <1 | A | A | A | A | A | A |
| | (A | 52 | A | A | A | A | <1 | A | A | A | A | A | A |
| | blended) | 53 | A | A | A | A | <1 | A | A | A | A | A | A |
| | | 54 | A | A | A | A | <1 | A | A | A | A | A | A |
| | | 55 | A | A | A | A | <1 | A | A | A | A | A | A |
| | | 56 | A | A | A | A | <1 | A | A | A | A | A | A |
| | | 57 | A | A | A | A | <1 | A | A | A | A | A | A |
| | | 58 | A | A | A | A | <1 | A | A | A | A | A | A |
| | | 59 | A | A | A | A | <1 | A | A | A | A | A | A |
| | | 60 | A | A | A | A | <1 | A | A | A | A | A | A |
| | | 61 | A | A | A | A | <1 | A | A | A | A | A | A |

TABLE 28
Sixth table (22)

| | | | | | Compound β | | | Evaluation of photosensitive material | | | | | | |
|---|---|---|---|---|---|---|---|---|---|---|---|---|---|---|
| | | | | | | | Molar ratio | Carboxy group | | | | | | Change in |
| Example/ | | | Polymer A | | | | with respect to | consumption | | Pattern | | | | relative |
| Compar- | | | Com- | Part | | Part | carboxy group | rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-22- | 51 | 2 | 50 | B12 | 15.8 | 20 | A | <1 | A | A | A | A | A |
| | (A | | 3 | 50 | | | | | | | | | | |
| | blended) | 52 | 10 | 50 | B12 | 6.6 | 20 | A | <1 | A | A | A | A | A |
| | | | 11 | 50 | | | | | | | | | | |
| | | 53 | 12 | 50 | B12 | 6.6 | 20 | A | <1 | A | A | A | A | A |
| | | | 13 | 50 | | | | | | | | | | |
| | | 54 | 16 | 50 | B12 | 6.6 | 20 | A | <1 | A | A | A | A | A |
| | | | 17 | 50 | | | | | | | | | | |
| | | 55 | 18 | 50 | B12 | 6.6 | 20 | A | <1 | A | A | A | A | A |
| | | | 19 | 50 | | | | | | | | | | |
| | | 56 | 20 | 50 | B12 | 6.6 | 20 | A | <1 | A | A | A | A | A |
| | | | 21 | 50 | | | | | | | | | | |
| | | 57 | 1 | 50 | B12 | 6.7 | 20 | A | <1 | A | A | A | A | A |
| | | | 26 | 50 | | | | | | | | | | |
| | | 58 | 8 | 33 | B12 | 6.9 | 20 | A | <1 | A | A | A | A | A |
| | | | 10 | 33 | | | | | | | | | | |
| | | | 12 | 34 | | | | | | | | | | |
| | | 59 | 15 | 33 | B12 | 6.2 | 20 | A | <1 | A | A | A | A | A |
| | | | 17 | 33 | | | | | | | | | | |
| | | | 19 | 34 | | | | | | | | | | |
| | | 60 | 20 | 33 | B12 | 6.7 | 20 | A | <1 | A | A | A | A | A |
| | | | 21 | 33 | | | | | | | | | | |
| | | | 22 | 34 | | | | | | | | | | |
| | | 61 | 1 | 33 | B12 | 6.7 | 20 | A | <1 | A | A | A | A | A |
| | | | 12 | 33 | | | | | | | | | | |
| | | | 23 | 34 | | | | | | | | | | |

| | | | Evaluation of transfer film | | | | | | | | | | |
|---|---|---|---|---|---|---|---|---|---|---|---|---|---|
| | | | | | Transmit- | | | | | | | | |
| | | | Carboxy group | | tance at | | | | | | | Change in | |
| Example/ | | | consumption | | 365 nm/ | Lami- | | Pattern | | | | relative | |
| Compar- | | | rate | Transmit- | transmit- | nate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-22- | 51 | A | A | A | A | <1 | A | A | A | A | A | A |
| | (A | 52 | A | A | A | A | <1 | A | A | A | A | A | A |
| | blended) | 53 | A | A | A | A | <1 | A | A | A | A | A | A |
| | | 54 | A | A | A | A | <1 | A | A | A | A | A | A |
| | | 55 | A | A | A | A | <1 | A | A | A | A | A | A |
| | | 56 | A | A | A | A | <1 | A | A | A | A | A | A |
| | | 57 | A | A | A | A | <1 | A | A | A | A | A | A |
| | | 58 | A | A | A | A | <1 | A | A | A | A | A | A |
| | | 59 | A | A | A | A | <1 | A | A | A | A | A | A |
| | | 60 | A | A | A | A | <1 | A | A | A | A | A | A |
| | | 61 | A | A | A | A | <1 | A | A | A | A | A | A |

TABLE 29
Sixth table (23)

| | | | | | Compound β | | | Evaluation of photosensitive material | | | | | | |
|---|---|---|---|---|---|---|---|---|---|---|---|---|---|---|
| | | | | | | | Molar ratio | Carboxy group | | | | | | Change in |
| Example/ | | | Polymer A | | | | with respect to | consumption | | Pattern | | | | relative |
| Compar- | | | Com- | Part | | Part | carboxy group | rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-23- | 51 | 2 | 50 | B12 | 7.9 | 10 | B | <1 | B | A | A | A | A |
| | (A | | 3 | 50 | | | | | | | | | | |
| | blended) | 52 | 10 | 50 | B12 | 3.3 | 10 | B | <1 | B | A | A | A | A |
| | | | 11 | 50 | | | | | | | | | | |
| | | 53 | 12 | 50 | B12 | 3.3 | 10 | B | <1 | B | A | A | A | A |
| | | | 13 | 50 | | | | | | | | | | |
| | | 54 | 16 | 50 | B12 | 3.3 | 10 | B | <1 | B | A | A | A | A |
| | | | 17 | 50 | | | | | | | | | | |
| | | 55 | 18 | 50 | B12 | 3.3 | 10 | B | <1 | B | A | A | A | A |
| | | | 19 | 50 | | | | | | | | | | |
| | | 56 | 20 | 50 | B12 | 3.3 | 10 | B | <1 | B | A | A | A | A |
| | | | 21 | 50 | | | | | | | | | | |
| | | 57 | 1 | 50 | B12 | 3.3 | 10 | B | <1 | B | A | A | A | A |
| | | | 26 | 50 | | | | | | | | | | |
| | | 58 | 8 | 33 | B12 | 3.5 | 10 | B | <1 | B | A | A | A | A |
| | | | 10 | 33 | | | | | | | | | | |
| | | | 12 | 34 | | | | | | | | | | |
| | | 59 | 15 | 33 | B12 | 3.1 | 10 | B | <1 | B | A | A | A | A |
| | | | 17 | 33 | | | | | | | | | | |
| | | | 19 | 34 | | | | | | | | | | |
| | | 60 | 20 | 33 | B12 | 3.3 | 10 | B | <1 | B | A | A | A | A |
| | | | 21 | 33 | | | | | | | | | | |
| | | | 22 | 34 | | | | | | | | | | |
| | | 61 | 1 | 33 | B12 | 3.3 | 10 | B | <1 | B | A | A | A | A |
| | | | 12 | 33 | | | | | | | | | | |
| | | | 23 | 34 | | | | | | | | | | |

| | | | Evaluation of transfer film | | | | | | | | | | |
|---|---|---|---|---|---|---|---|---|---|---|---|---|---|
| | | | | | Transmit- | | | | | | | | |
| | | | Carboxy group | | tance at | | | | | | | Change in | |
| Example/ | | | consumption | | 365 nm/ | Lami- | | Pattern | | | | relative | |
| Compar- | | | rate | Transmit- | transmit- | nate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-23- | 51 | B | A | A | A | <1 | B | A | A | A | A | A |
| | (A | 52 | B | A | A | A | <1 | B | A | A | A | A | A |
| | blended) | 53 | B | A | A | A | <1 | B | A | A | A | A | A |
| | | 54 | B | A | A | A | <1 | B | A | A | A | A | A |
| | | 55 | B | A | A | A | <1 | B | A | A | A | A | A |
| | | 56 | B | A | A | A | <1 | B | A | A | A | A | A |
| | | 57 | B | A | A | A | <1 | B | A | A | A | A | A |
| | | 58 | B | A | A | A | <1 | B | A | A | A | A | A |
| | | 59 | B | A | A | A | <1 | B | A | A | A | A | A |
| | | 60 | B | A | A | A | <1 | B | A | A | A | A | A |
| | | 61 | B | A | A | A | <1 | B | A | A | A | A | A |

TABLE 30
Sixth table (24)

| | | | | | Compound β | | | Evaluation of photosensitive material | | | | | | |
|---|---|---|---|---|---|---|---|---|---|---|---|---|---|---|
| | | | | | | | Molar ratio | Carboxy group | | | | | | Change in |
| Example/ | | | Polymer A | | | | with respect to | consumption | | Pattern | | | | relative |
| Compar- | | | Com- | Part | | Part | carboxy group | rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-24- | 1 | 1 | 100 | B6 | 3.2 | 10 | A | <1 | A | A | A | A | A |
| | (B | | | | B12 | 3.5 | 10 | | | | | | | |
| | blended) | 2 | 2 | 100 | B6 | 6.7 | 10 | A | <1 | A | A | A | A | A |
| | | | | | B12 | 7.3 | 10 | | | | | | | |
| | | 3 | 3 | 100 | B6 | 7.7 | 10 | A | <1 | A | A | A | A | A |
| | | | | | B12 | 8.5 | 10 | | | | | | | |
| | | 4 | 4 | 100 | B6 | 6.7 | 10 | A | <1 | A | A | A | A | A |
| | | | | | B12 | 7.3 | 10 | | | | | | | |
| | | 5 | 5 | 100 | B6 | 7.7 | 10 | A | <1 | A | A | A | A | A |
| | | | | | B12 | 8.5 | 10 | | | | | | | |
| | | 6 | 6 | 100 | B6 | 2.8 | 10 | A | <1 | A | A | A | A | A |
| | | | | | B12 | 3.1 | 10 | | | | | | | |
| | | 7 | 7 | 100 | B6 | 3.2 | 10 | A | <1 | A | A | A | A | A |
| | | | | | B12 | 3.5 | 10 | | | | | | | |
| | | 8 | 8 | 100 | B6 | 3.2 | 10 | A | <1 | A | A | A | A | A |
| | | | | | B12 | 3.5 | 10 | | | | | | | |
| | | 9 | 9 | 100 | B6 | 2.8 | 10 | A | <1 | A | A | A | A | A |
| | | | | | B12 | 3.1 | 10 | | | | | | | |
| | | 10 | 10 | 100 | B6 | 3.2 | 10 | A | <1 | A | A | A | A | A |
| | | | | | B12 | 3.5 | 10 | | | | | | | |
| | | 11 | 11 | 100 | B6 | 2.8 | 10 | A | <1 | A | A | A | A | A |
| | | | | | B12 | 3.1 | 10 | | | | | | | |
| | | 12 | 12 | 100 | B6 | 3.2 | 10 | A | <1 | A | A | A | A | A |
| | | | | | B12 | 3.5 | 10 | | | | | | | |
| | | 13 | 13 | 100 | B6 | 2.8 | 10 | A | <1 | A | A | A | A | A |
| | | | | | B12 | 3.1 | 10 | | | | | | | |

| | | | Evaluation of transfer film | | | | | | | | | | |
|---|---|---|---|---|---|---|---|---|---|---|---|---|---|
| | | | | | Transmit- | | | | | | | | |
| | | | Carboxy group | | tance at | | | | | | | Change in | |
| Example/ | | | consumption | | 365 nm/ | Lami- | | Pattern | | | | relative | |
| Compar- | | | rate | Transmit- | transmit- | nate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-24- | 1 | A | A | A | A | <1 | A | A | A | A | A | A |
| | (B | 2 | A | A | A | A | <1 | A | A | A | A | A | A |
| | blended) | 3 | A | A | A | A | <1 | A | A | A | A | A | A |
| | | 4 | A | A | A | A | <1 | A | A | A | A | A | A |
| | | 5 | A | A | A | A | <1 | A | A | A | A | A | A |
| | | 6 | A | A | A | A | <1 | A | A | A | A | A | A |
| | | 7 | A | A | A | A | <1 | A | A | A | A | A | A |
| | | 8 | A | A | A | A | <1 | A | A | A | A | A | A |
| | | 9 | A | A | A | A | <1 | A | A | A | A | A | A |
| | | 10 | A | A | A | A | <1 | A | A | A | A | A | A |
| | | 11 | A | A | A | A | <1 | A | A | A | A | A | A |
| | | 12 | A | A | A | A | <1 | A | A | A | A | A | A |
| | | 13 | A | A | A | A | <1 | A | A | A | A | A | A |

TABLE 31
Sixth table (25)

| | | | | | Compound β | | | Evaluation of photosensitive material | | | | | | |
|---|---|---|---|---|---|---|---|---|---|---|---|---|---|---|
| | | | | | | | Molar ratio | Carboxy group | | | | | | Change in |
| Example/ | | | Polymer A | | | | with respect to | consumption | | Pattern | | | | relative |
| Compar- | | | Com- | Part | | Part | carboxy group | rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-24- | 14 | 14 | 100 | B6 | 3.2 | 10 | A | <1 | A | A | A | A | A |
| | (B | | | | B12 | 3.5 | 10 | | | | | | | |
| | blended) | 15 | 15 | 100 | B6 | 2.8 | 10 | A | <1 | A | A | A | A | A |
| | | | | | B12 | 3.1 | 10 | | | | | | | |
| | | 16 | 16 | 100 | B6 | 3.2 | 10 | A | <1 | A | A | A | A | A |
| | | | | | B12 | 3.5 | 10 | | | | | | | |
| | | 17 | 17 | 100 | B6 | 2.8 | 10 | A | <1 | A | A | A | A | A |
| | | | | | B12 | 3.1 | 10 | | | | | | | |
| | | 18 | 18 | 100 | B6 | 3.2 | 10 | A | <1 | A | A | A | A | A |
| | | | | | B12 | 3.5 | 10 | | | | | | | |
| | | 19 | 19 | 100 | B6 | 2.8 | 10 | A | <1 | A | A | A | A | A |
| | | | | | B12 | 3.1 | 10 | | | | | | | |
| | | 20 | 20 | 100 | B6 | 3.2 | 10 | A | <1 | A | A | A | A | A |
| | | | | | B12 | 3.5 | 10 | | | | | | | |
| | | 21 | 21 | 100 | B6 | 2.8 | 10 | A | <1 | A | A | A | A | A |
| | | | | | B12 | 3.1 | 10 | | | | | | | |
| | | 22 | 22 | 100 | B6 | 3.2 | 10 | A | <1 | A | A | A | A | A |
| | | | | | B12 | 3.5 | 10 | | | | | | | |
| | | 23 | 23 | 100 | B6 | 2.8 | 10 | A | <1 | A | A | A | A | A |
| | | | | | B12 | 3.1 | 10 | | | | | | | |
| | | 24 | 24 | 100 | B6 | 3.2 | 10 | A | <1 | A | A | A | A | A |
| | | | | | B12 | 3.5 | 10 | | | | | | | |
| | | 25 | 25 | 100 | B6 | 2.8 | 10 | A | <1 | A | A | A | A | A |
| | | | | | B12 | 3.1 | 10 | | | | | | | |
| | | 26 | 26 | 100 | B6 | 2.9 | 10 | A | <1 | A | A | A | A | A |
| | | | | | B12 | 3.2 | 10 | | | | | | | |

| | | | Evaluation of transfer film | | | | | | | | | | |
|---|---|---|---|---|---|---|---|---|---|---|---|---|---|
| | | | | | Transmit- | | | | | | | | |
| | | | Carboxy group | | tance at | | | | | | | Change in | |
| Example/ | | | consumption | | 365 nm/ | Lami- | | Pattern | | | | relative | |
| Compar- | | | rate | Transmit- | transmit- | nate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-24- | 14 | A | A | A | A | <1 | A | A | A | A | A | A |
| | (B | 15 | A | A | A | A | <1 | A | A | A | A | A | A |
| | blended) | 16 | A | A | A | A | <1 | A | A | A | A | A | A |
| | | 17 | A | A | A | A | <1 | A | A | A | A | A | A |
| | | 18 | A | A | A | A | <1 | A | A | A | A | A | A |
| | | 19 | A | A | A | A | <1 | A | A | A | A | A | A |
| | | 20 | A | A | A | A | <1 | A | A | A | A | A | A |
| | | 21 | A | A | A | A | <1 | A | A | A | A | A | A |
| | | 22 | A | A | A | A | <1 | A | A | A | A | A | A |
| | | 23 | A | A | A | A | <1 | A | A | A | A | A | A |
| | | 24 | A | A | A | A | <1 | A | A | A | A | A | A |
| | | 25 | A | A | A | A | <1 | A | A | A | A | A | A |
| | | 26 | A | A | A | A | <1 | A | A | A | A | A | A |

TABLE 32
Sixth table (26)

| | | | | | Compound β | | | Evaluation of photosensitive material | | | | | | |
|---|---|---|---|---|---|---|---|---|---|---|---|---|---|---|
| | | | | | | | Molar ratio | Carboxy group | | | | | | Change in |
| Example/ | | | Polymer A | | | | with respect to | consumption | | Pattern | | | | relative |
| Compar- | | | Com- | Part | | Part | carboxy group | rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-25- | 1 | 1 | 100 | B6 | 1.6 | 5 | B | <1 | B | A | A | A | A |
| | (B | | | | B12 | 1.7 | 5 | | | | | | | |
| | blended) | 2 | 2 | 100 | B6 | 3.3 | 5 | B | <1 | B | A | A | A | A |
| | | | | | B12 | 3.7 | 5 | | | | | | | |
| | | 3 | 3 | 100 | B6 | 3.9 | 5 | B | <1 | B | A | A | A | A |
| | | | | | B12 | 4.2 | 5 | | | | | | | |
| | | 4 | 4 | 100 | B6 | 3.3 | 5 | B | <1 | B | A | A | A | A |
| | | | | | B12 | 3.7 | 5 | | | | | | | |
| | | 5 | 5 | 100 | B6 | 3.9 | 5 | B | <1 | B | A | A | A | A |
| | | | | | B12 | 4.2 | 5 | | | | | | | |
| | | 6 | 6 | 100 | B6 | 1.4 | 5 | B | <1 | B | A | A | A | A |
| | | | | | B12 | 1.5 | 5 | | | | | | | |
| | | 7 | 7 | 100 | B6 | 1.6 | 5 | B | <1 | B | A | A | A | A |
| | | | | | B12 | 1.7 | 5 | | | | | | | |
| | | 8 | 8 | 100 | B6 | 1.6 | 5 | B | <1 | B | A | A | A | A |
| | | | | | B12 | 1.7 | 5 | | | | | | | |
| | | 9 | 9 | 100 | B6 | 1.4 | 5 | B | <1 | B | A | A | A | A |
| | | | | | B12 | 1.5 | 5 | | | | | | | |
| | | 10 | 10 | 100 | B6 | 1.6 | 5 | B | <1 | B | A | A | A | A |
| | | | | | B12 | 1.7 | 5 | | | | | | | |
| | | 11 | 11 | 100 | B6 | 1.4 | 5 | B | <1 | B | A | A | A | A |
| | | | | | B12 | 1.5 | 5 | | | | | | | |
| | | 12 | 12 | 100 | B6 | 1.6 | 5 | B | <1 | B | A | A | A | A |
| | | | | | B12 | 1.7 | 5 | | | | | | | |
| | | 13 | 13 | 100 | B6 | 1.4 | 5 | B | <1 | B | A | A | A | A |
| | | | | | B12 | 1.5 | 5 | | | | | | | |

| | | | Evaluation of transfer film | | | | | | | | | | |
|---|---|---|---|---|---|---|---|---|---|---|---|---|---|
| | | | | | Transmit- | | | | | | | | |
| | | | Carboxy group | | tance at | | | | | | | Change in | |
| Example/ | | | consumption | | 365 nm/ | Lami- | | Pattern | | | | relative | |
| Compar- | | | rate | Transmit- | transmit- | nate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-25- | 1 | B | A | A | A | <1 | B | A | A | A | A | A |
| | (B | 2 | B | A | A | A | <1 | B | A | A | A | A | A |
| | blended) | 3 | B | A | A | A | <1 | B | A | A | A | A | A |
| | | 4 | B | A | A | A | <1 | B | A | A | A | A | A |
| | | 5 | B | A | A | A | <1 | B | A | A | A | A | A |
| | | 6 | B | A | A | A | <1 | B | A | A | A | A | A |
| | | 7 | B | A | A | A | <1 | B | A | A | A | A | A |
| | | 8 | B | A | A | A | <1 | B | A | A | A | A | A |
| | | 9 | B | A | A | A | <1 | B | A | A | A | A | A |
| | | 10 | B | A | A | A | <1 | B | A | A | A | A | A |
| | | 11 | B | A | A | A | <1 | B | A | A | A | A | A |
| | | 12 | B | A | A | A | <1 | B | A | A | A | A | A |
| | | 13 | B | A | A | A | <1 | B | A | A | A | A | A |

TABLE 33
Sixth table (27)

| | | | | | Compound β | | | Evaluation of photosensitive material | | | | | | |
|---|---|---|---|---|---|---|---|---|---|---|---|---|---|---|
| | | | | | | | Molar ratio | Carboxy group | | | | | | Change in |
| Example/ | | | Polymer A | | | | with respect to | consumption | | Pattern | | | | relative |
| Compar- | | | Com- | Part | | Part | carboxy group | rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-25- | 14 | 14 | 100 | B6 | 1.6 | 5 | B | <1 | B | A | A | A | A |
| | (B | | | | B12 | 1.7 | 5 | | | | | | | |
| | blended) | 15 | 15 | 100 | B6 | 1.4 | 5 | B | <1 | B | A | A | A | A |
| | | | | | B12 | 1.5 | 5 | | | | | | | |
| | | 16 | 16 | 100 | B6 | 1.6 | 5 | B | <1 | B | A | A | A | A |
| | | | | | B12 | 1.7 | 5 | | | | | | | |
| | | 17 | 17 | 100 | B6 | 1.4 | 5 | B | <1 | B | A | A | A | A |
| | | | | | B12 | 1.5 | 5 | | | | | | | |
| | | 18 | 18 | 100 | B6 | 1.6 | 5 | B | <1 | B | A | A | A | A |
| | | | | | B12 | 1.7 | 5 | | | | | | | |
| | | 19 | 19 | 100 | B6 | 1.4 | 5 | B | <1 | B | A | A | A | A |
| | | | | | B12 | 1.5 | 5 | | | | | | | |
| | | 20 | 20 | 100 | B6 | 1.6 | 5 | B | <1 | B | A | A | A | A |
| | | | | | B12 | 1.7 | 5 | | | | | | | |
| | | 21 | 21 | 100 | B6 | 1.4 | 5 | B | <1 | B | A | A | A | A |
| | | | | | B12 | 1.5 | 5 | | | | | | | |
| | | 22 | 22 | 100 | B6 | 1.6 | 5 | B | <1 | B | A | A | A | A |
| | | | | | B12 | 1.7 | 5 | | | | | | | |
| | | 23 | 23 | 100 | B6 | 1.4 | 5 | B | <1 | B | A | A | A | A |
| | | | | | B12 | 1.5 | 5 | | | | | | | |
| | | 24 | 24 | 100 | B6 | 1.6 | 5 | B | <1 | B | A | A | A | A |
| | | | | | B12 | 1.7 | 5 | | | | | | | |
| | | 25 | 25 | 100 | B6 | 1.4 | 5 | B | <1 | B | A | A | A | A |
| | | | | | B12 | 1.5 | 5 | | | | | | | |
| | | 26 | 26 | 100 | B6 | 1.5 | 5 | B | <1 | B | A | A | A | A |
| | | | | | B12 | 1.6 | 5 | | | | | | | |

| | | | Evaluation of transfer film | | | | | | | | | | |
|---|---|---|---|---|---|---|---|---|---|---|---|---|---|
| | | | | | Transmit- | | | | | | | | |
| | | | Carboxy group | | tance at | | | | | | | Change in | |
| Example/ | | | consumption | | 365 nm/ | Lami- | | Pattern | | | | relative | |
| Compar- | | | rate | Transmit- | transmit- | nate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-25- | 14 | B | A | A | A | <1 | B | A | A | A | A | A |
| | (B | 15 | B | A | A | A | <1 | B | A | A | A | A | A |
| | blended) | 16 | B | A | A | A | <1 | B | A | A | A | A | A |
| | | 17 | B | A | A | A | <1 | B | A | A | A | A | A |
| | | 18 | B | A | A | A | <1 | B | A | A | A | A | A |
| | | 19 | B | A | A | A | <1 | B | A | A | A | A | A |
| | | 20 | B | A | A | A | <1 | B | A | A | A | A | A |
| | | 21 | B | A | A | A | <1 | B | A | A | A | A | A |
| | | 22 | B | A | A | A | <1 | B | A | A | A | A | A |
| | | 23 | B | A | A | A | <1 | B | A | A | A | A | A |
| | | 24 | B | A | A | A | <1 | B | A | A | A | A | A |
| | | 25 | B | A | A | A | <1 | B | A | A | A | A | A |
| | | 26 | B | A | A | A | <1 | B | A | A | A | A | A |

TABLE 34
Sixth table (28)

| | | | | | Compound β | | | Evaluation of photosensitive material | | | | | | |
|---|---|---|---|---|---|---|---|---|---|---|---|---|---|---|
| | | | | | | | Molar ratio | Carboxy group | | | | | | Change in |
| Example/ | | | Polymer A | | | | with respect to | consumption | | Pattern | | | | relative |
| Compar- | | | Com- | Part | | Part | carboxy group | rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-26- | 51 | 2 | 50 | B6 | 7.9 | 10 | A | <1 | A | A | A | A | A |
| | (A not | | 3 | 50 | B12 | 7.9 | 10 | | | | | | | |
| | blended, | 52 | 10 | 50 | B6 | 3.3 | 10 | A | <1 | A | A | A | A | A |
| | B | | 11 | 50 | B12 | 3.3 | 10 | | | | | | | |
| | blended) | 53 | 12 | 50 | B6 | 3.3 | 10 | A | <1 | A | A | A | A | A |
| | | | 13 | 50 | B12 | 3.3 | 10 | | | | | | | |
| | | 54 | 16 | 50 | B6 | 3.3 | 10 | A | <1 | A | A | A | A | A |
| | | | 17 | 50 | B12 | 3.3 | 10 | | | | | | | |
| | | 55 | 18 | 50 | B6 | 3.3 | 10 | A | <1 | A | A | A | A | A |
| | | | 19 | 50 | B12 | 3.3 | 10 | | | | | | | |
| | | 56 | 20 | 50 | B6 | 3.3 | 10 | A | <1 | A | A | A | A | A |
| | | | 21 | 50 | B12 | 3.3 | 10 | | | | | | | |
| | | 57 | 1 | 50 | B6 | 3.3 | 10 | A | <1 | A | A | A | A | A |
| | | | 26 | 50 | B12 | 3.3 | 10 | | | | | | | |
| | | 58 | 8 | 33 | B6 | 3.5 | 10 | A | <1 | A | A | A | A | A |
| | | | 10 | 33 | B12 | 3.5 | 10 | | | | | | | |
| | | | 12 | 34 | | | | | | | | | | |
| | | 59 | 15 | 33 | B6 | 3.1 | 10 | A | <1 | A | A | A | A | A |
| | | | 17 | 33 | B12 | 3.1 | 10 | | | | | | | |
| | | | 19 | 34 | | | | | | | | | | |
| | | 60 | 20 | 33 | B6 | 3.3 | 10 | A | <1 | A | A | A | A | A |
| | | | 21 | 33 | B12 | 3.3 | 10 | | | | | | | |
| | | | 22 | 34 | | | | | | | | | | |
| | | 61 | 1 | 33 | B6 | 3.3 | 10 | A | <1 | A | A | A | A | A |
| | | | 12 | 33 | B12 | 3.3 | 10 | | | | | | | |
| | | | 23 | 34 | | | | | | | | | | |

| | | | Evaluation of transfer film | | | | | | | | | | |
|---|---|---|---|---|---|---|---|---|---|---|---|---|---|
| | | | | | Transmit- | | | | | | | | |
| | | | Carboxy group | | tance at | | | | | | | Change in | |
| Example/ | | | consumption | | 365 nm/ | Lami- | | Pattern | | | | relative | |
| Compar- | | | rate | Transmit- | transmit- | nate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-26- | 51 | A | A | A | A | <1 | A | A | A | A | A | A |
| | (A not | 52 | A | A | A | A | <1 | A | A | A | A | A | A |
| | blended, | 53 | A | A | A | A | <1 | A | A | A | A | A | A |
| | B | 54 | A | A | A | A | <1 | A | A | A | A | A | A |
| | blended) | 55 | A | A | A | A | <1 | A | A | A | A | A | A |
| | | 56 | A | A | A | A | <1 | A | A | A | A | A | A |
| | | 57 | A | A | A | A | <1 | A | A | A | A | A | A |
| | | 58 | A | A | A | A | <1 | A | A | A | A | A | A |
| | | 59 | A | A | A | A | <1 | A | A | A | A | A | A |
| | | 60 | A | A | A | A | <1 | A | A | A | A | A | A |
| | | 61 | A | A | A | A | <1 | A | A | A | A | A | A |

TABLE 35
Sixth table (29)

| | | | | | Compound β | | | Evaluation of photosensitive material | | | | | | |
|---|---|---|---|---|---|---|---|---|---|---|---|---|---|---|
| | | | | | | | Molar ratio | Carboxy group | | | | | | Change in |
| Example/ | | | Polymer A | | | | with respect to | consumption | | Pattern | | | | relative |
| Compar- | | | Com- | Part | | Part | carboxy group | rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Example | 4-27- | 51 | 2 | 50 | B6 | 4.0 | 5 | A | <1 | A | A | A | A | A |
| | (A not | | 3 | 50 | B12 | 4.0 | 5 | | | | | | | |
| | blended, | 52 | 10 | 50 | B6 | 1.6 | 5 | A | <1 | A | A | A | A | A |
| | B | | 11 | 50 | B12 | 1.6 | 5 | | | | | | | |
| | blended) | 53 | 12 | 50 | B6 | 1.6 | 5 | A | <1 | A | A | A | A | A |
| | | | 13 | 50 | B12 | 1.6 | 5 | | | | | | | |
| | | 54 | 16 | 50 | B6 | 1.6 | 5 | A | <1 | A | A | A | A | A |
| | | | 17 | 50 | B12 | 1.6 | 5 | | | | | | | |
| | | 55 | 18 | 50 | B6 | 1.6 | 5 | A | <1 | A | A | A | A | A |
| | | | 19 | 50 | B12 | 1.6 | 5 | | | | | | | |
| | | 56 | 20 | 50 | B6 | 1.6 | 5 | A | <1 | A | A | A | A | A |
| | | | 21 | 50 | B12 | 1.6 | 5 | | | | | | | |
| | | 57 | 1 | 50 | B6 | 1.7 | 5 | A | <1 | A | A | A | A | A |
| | | | 26 | 50 | B12 | 1.7 | 5 | | | | | | | |
| | | 58 | 8 | 33 | B6 | 1.7 | 5 | A | <1 | A | A | A | A | A |
| | | | 10 | 33 | B12 | 1.7 | 5 | | | | | | | |
| | | | 12 | 34 | | | | | | | | | | |
| | | 59 | 15 | 33 | B6 | 1.5 | 5 | A | <1 | A | A | A | A | A |
| | | | 17 | 33 | B12 | 1.5 | 5 | | | | | | | |
| | | | 19 | 34 | | | | | | | | | | |
| | | 60 | 20 | 33 | B6 | 1.7 | 5 | A | <1 | A | A | A | A | A |
| | | | 21 | 33 | B12 | 1.7 | 5 | | | | | | | |
| | | | 22 | 34 | | | | | | | | | | |
| | | 61 | 1 | 33 | B6 | 1.7 | 5 | A | <1 | A | A | A | A | A |
| | | | 12 | 33 | B12 | 1.7 | 5 | | | | | | | |
| | | | 23 | 34 | | | | | | | | | | |

| | | | Evaluation of transfer film | | | | | | | | | | |
|---|---|---|---|---|---|---|---|---|---|---|---|---|---|
| | | | | | Transmit- | | | | | | | | |
| | | | Carboxy group | | tance at | | | | | | | Change in | |
| Example/ | | | consumption | | 365 nm/ | Lami- | | Pattern | | | | relative | |
| Compar- | | | rate | Transmit- | transmit- | nate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Example | 4-27- | 51 | A | A | A | A | <1 | A | A | A | A | A | A |
| | (A not | 52 | A | A | A | A | <1 | A | A | A | A | A | A |
| | blended, | 53 | A | A | A | A | <1 | A | A | A | A | A | A |
| | B | 54 | A | A | A | A | <1 | A | A | A | A | A | A |
| | blended) | 55 | A | A | A | A | <1 | A | A | A | A | A | A |
| | | 56 | A | A | A | A | <1 | A | A | A | A | A | A |
| | | 57 | A | A | A | A | <1 | A | A | A | A | A | A |
| | | 58 | A | A | A | A | <1 | A | A | A | A | A | A |
| | | 59 | A | A | A | A | <1 | A | A | A | A | A | A |
| | | 60 | A | A | A | A | <1 | A | A | A | A | A | A |
| | | 61 | A | A | A | A | <1 | A | A | A | A | A | A |

TABLE 36
Sixth table (30)

| | | | | | Compound β | | | Evaluation of photosensitive material | | | | | | |
|---|---|---|---|---|---|---|---|---|---|---|---|---|---|---|
| | | | | | | | Molar ratio | Carboxy group | | | | | | Change in |
| Example/ | | | Polymer A | | | | with respect to | consumption | | Pattern | | | | relative |
| Compar- | | | Com- | Part | | Part | carboxy group | rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Compar- | 4A | 1 | 1 | 100 | None | — | — | E | — | D | D | D | Standard | D |
| ative | ※ | 2 | 2 | 100 | None | — | — | E | — | D | D | D | Standard | D |
| Example | Compar- | 3 | 3 | 100 | None | — | — | E | — | D | D | D | Standard | D |
| | ative | 4 | 4 | 100 | None | — | — | E | — | D | D | D | Standard | D |
| | Example | 5 | 5 | 100 | None | — | — | E | — | D | D | D | Standard | D |
| | (standard) | 6 | 6 | 100 | None | — | — | E | — | D | D | D | Standard | D |
| | with the | 7 | 7 | 100 | None | — | — | E | — | D | D | D | Standard | D |
| | same | 8 | 8 | 100 | None | — | — | E | — | D | D | D | Standard | D |
| | serial | 9 | 9 | 100 | None | — | — | E | — | D | D | D | Standard | D |
| | number | 10 | 10 | 100 | None | — | — | E | — | D | D | D | Standard | D |
| Compar- | 4A | 11 | 11 | 100 | None | — | — | E | — | D | D | D | Standard | D |
| ative | ※ | 12 | 12 | 100 | None | — | — | E | — | D | D | D | Standard | D |
| Example | Compar- | 13 | 13 | 100 | None | — | — | E | — | D | D | D | Standard | D |
| | ative | 14 | 14 | 100 | None | — | — | E | — | D | D | D | Standard | D |
| | Example | 15 | 15 | 100 | None | — | — | E | — | D | D | D | Standard | D |
| | (standard) | 16 | 16 | 100 | None | — | — | E | — | D | D | D | Standard | D |
| | with the | 17 | 17 | 100 | None | — | — | E | — | D | D | D | Standard | D |
| | same | 18 | 18 | 100 | None | — | — | E | — | D | D | D | Standard | D |
| | serial | 19 | 19 | 100 | None | — | — | E | — | D | D | D | Standard | D |
| | number | 20 | 20 | 100 | None | — | — | E | — | D | D | D | Standard | D |
| Compar- | 4A | 21 | 21 | 100 | None | — | — | E | — | D | D | D | Standard | D |
| ative | ※ | 22 | 22 | 100 | None | — | — | E | — | D | D | D | Standard | D |
| Example | Compar- | 23 | 23 | 100 | None | — | — | E | — | D | D | D | Standard | D |
| | ative | 24 | 24 | 100 | None | — | — | E | — | D | D | D | Standard | D |
| | Example | 25 | 25 | 100 | None | — | — | E | — | D | D | D | Standard | D |
| | (standard) | 26 | 26 | 100 | None | — | — | E | — | D | D | D | Standard | D |
| | with the | | | | | | | | | | | | | |
| | same | | | | | | | | | | | | | |
| | serial | | | | | | | | | | | | | |
| | number | | | | | | | | | | | | | |

Evaluation of transfer film

| | | | | | Transmit- | | | | | | | | |
|---|---|---|---|---|---|---|---|---|---|---|---|---|---|
| | | | Carboxy group | | tance at | | | | | | | Change in | |
| Example/ | | | consumption | | 365 nm/ | Lami- | | Pattern | | | | relative | |
| Compar- | | | rate | Transmit- | transmit- | nate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Compar- | 4A | 1 | E | A | B | A | — | D | D | D | Standard | D | Standard |
| ative | ※ | 2 | E | A | B | A | — | D | D | D | Standard | D | Standard |
| Example | Compar- | 3 | E | A | B | A | — | D | D | D | Standard | D | Standard |
| | ative | 4 | E | A | B | A | — | D | D | D | Standard | D | Standard |
| | Example | 5 | E | A | B | A | — | D | D | D | Standard | D | Standard |
| | (standard) | 6 | E | A | B | A | — | D | D | D | Standard | D | Standard |
| | with the | 7 | E | A | B | A | — | D | D | D | Standard | D | Standard |
| | same | 8 | E | A | B | A | — | D | D | D | Standard | D | Standard |
| | serial | 9 | E | A | B | A | — | D | D | D | Standard | D | Standard |
| | number | 10 | E | A | B | A | — | D | D | D | Standard | D | Standard |
| Compar- | 4A | 11 | E | A | B | A | — | D | D | D | Standard | D | Standard |
| ative | ※ | 12 | E | A | B | A | — | D | D | D | Standard | D | Standard |
| Example | Compar- | 13 | E | A | B | A | — | D | D | D | Standard | D | Standard |
| | ative | 14 | E | A | B | A | — | D | D | D | Standard | D | Standard |
| | Example | 15 | E | A | B | A | — | D | D | D | Standard | D | Standard |
| | (standard) | 16 | E | A | B | A | — | D | D | D | Standard | D | Standard |
| | with the | 17 | E | A | B | A | — | D | D | D | Standard | D | Standard |
| | same | 18 | E | A | B | A | — | D | D | D | Standard | D | Standard |
| | serial | 19 | E | A | B | A | — | D | D | D | Standard | D | Standard |
| | number | 20 | E | A | B | A | — | D | D | D | Standard | D | Standard |
| Compar- | 4A | 21 | E | A | B | A | — | D | D | D | Standard | D | Standard |
| ative | ※ | 22 | E | A | B | A | — | D | D | D | Standard | D | Standard |
| Example | Compar- | 23 | E | A | B | A | — | D | D | D | Standard | D | Standard |
| | ative | 24 | E | A | B | A | — | D | D | D | Standard | D | Standard |
| | Example | 25 | E | A | B | A | — | D | D | D | Standard | D | Standard |
| | (standard) | 26 | E | A | B | A | — | D | D | D | Standard | D | Standard |
| | with the | | | | | | | | | | | | |
| | same | | | | | | | | | | | | |
| | serial | | | | | | | | | | | | |
| | number | | | | | | | | | | | | |

TABLE 37
Sixth table (31)

| | | | | | Compound β | | | Evaluation of photosensitive material | | | | | | |
|---|---|---|---|---|---|---|---|---|---|---|---|---|---|---|
| | | | | | | | Molar ratio | Carboxy group | | | | | | Change in |
| Example/ | | | Polymer A | | | | with respect to | consumption | | Pattern | | | | relative |
| Compar- | | | Com- | Part | | Part | carboxy group | rate | | formability | | | Relative | permittivity |
| ative | Head | Serial | pound | by | | by | of polymer A | [measurement | ε365/ | 25 | 50 | 250 | permit- | before and |
| Example | number | number | No. | mass | No. | mass | (mol %) | of ashing] | ε313 | μm | μm | μm | tivity | after exposure |
| Compar- | 4A | 51 | 2 | 50 | None | — | — | E | — | D | D | D | Standard | D |
| ative | ※ | | 3 | 50 | | | | | | | | | | |
| Example | Compar- | 52 | 10 | 50 | None | — | — | E | — | D | D | D | Standard | D |
| | ative | | 11 | 50 | | | | | | | | | | |
| | Example | 53 | 12 | 50 | None | — | — | E | — | D | D | D | Standard | D |
| | (standard) | | 13 | 50 | | | | | | | | | | |
| | with the | 54 | 16 | 50 | None | — | — | E | — | D | D | D | Standard | D |
| | same | | 17 | 50 | | | | | | | | | | |
| | serial | 55 | 18 | 50 | None | — | — | E | — | D | D | D | Standard | D |
| | number | | 19 | 50 | | | | | | | | | | |
| | | 56 | 20 | 50 | None | — | — | E | — | D | D | D | Standard | D |
| | | | 21 | 50 | | | | | | | | | | |
| | | 57 | 1 | 50 | None | — | — | E | — | D | D | D | Standard | D |
| | | | 26 | 50 | | | | | | | | | | |
| Compar- | 4A | 58 | 8 | 33 | None | — | — | E | — | D | D | D | Standard | D |
| ative | ※ | | 10 | 33 | | | | | | | | | | |
| Example | Compar- | | 12 | 34 | | | | | | | | | | |
| | ative | 59 | 15 | 33 | None | — | — | E | — | D | D | D | Standard | D |
| | Example | | 17 | 33 | | | | | | | | | | |
| | (standard) | | 19 | 34 | | | | | | | | | | |
| | with the | 60 | 20 | 33 | None | — | — | E | — | D | D | D | Standard | D |
| | same | | 21 | 33 | | | | | | | | | | |
| | serial | | 22 | 34 | | | | | | | | | | |
| | number | 61 | 1 | 33 | None | — | — | E | — | D | D | D | Standard | D |
| | | | 12 | 33 | | | | | | | | | | |
| | | | 23 | 34 | | | | | | | | | | |

Evaluation of transfer film

| | | | | | Transmit- | | | | | | | | |
|---|---|---|---|---|---|---|---|---|---|---|---|---|---|
| | | | Carboxy group | | tance at | | | | | | | Change in | |
| Example/ | | | consumption | | 365 nm/ | Lami- | | Pattern | | | | relative | |
| Compar- | | | rate | Transmit- | transmit- | nate | | formability | | | Relative | permittivity | Moisture |
| ative | Head | Serial | [measurement | tance at | tance at | suit- | ε365/ | 25 | 50 | 250 | permit- | before and | perme- |
| Example | number | number | of ashing] | 365 nm | 313 nm | ability | ε313 | μm | μm | μm | tivity | after exposure | ability |
| Compar- | 4A | 51 | E | A | B | A | — | D | D | D | Standard | D | Standard |
| ative | ※ | 52 | E | A | B | A | — | D | D | D | Standard | D | Standard |
| Example | Compar- | 53 | E | A | B | A | — | D | D | D | Standard | D | Standard |
| | ative | 54 | E | A | B | A | — | D | D | D | Standard | D | Standard |
| | Example | 55 | E | A | B | A | — | D | D | D | Standard | D | Standard |
| | (standard) | 56 | E | A | B | A | — | D | D | D | Standard | D | Standard |
| | with the | 57 | E | A | B | A | — | D | D | D | Standard | D | Standard |
| | same | | | | | | | | | | | | |
| | serial | | | | | | | | | | | | |
| | number | | | | | | | | | | | | |
| Compar- | 4A | 58 | E | A | B | A | — | D | D | D | Standard | D | Standard |
| ative | ※ | 59 | E | A | B | A | — | D | D | D | Standard | D | Standard |
| Example | Compar- | 60 | E | A | B | A | — | D | D | D | Standard | D | Standard |
| | ative | 61 | E | A | B | A | — | D | D | D | Standard | D | Standard |
| | Example | | | | | | | | | | | | |
| | (standard) | | | | | | | | | | | | |
| | with the | | | | | | | | | | | | |
| | same | | | | | | | | | | | | |
| | serial | | | | | | | | | | | | |
| | number | | | | | | | | | | | | |

From the results in the above tables, it was confirmed that the objects of the present invention could be achieved with the transfer film according to the embodiment of the present invention.

In addition, it was confirmed that conditions under which the effects of the present invention are more excellent were the same as those confirmed for Example 1 system.

### Example 5 System

<Preparation and Evaluation of Photosensitive Material>

Materials shown in Seventh table shown in the latter part were mixed and dissolved in a mixed solvent of propylene glycol monomethyl ether acetate/methyl ethyl ketone=50/50 (mass ratio) so that a concentration of solid contents of the finally obtained photosensitive material was 25% by mass, thereby obtaining a photosensitive material.

In addition, for the obtained photosensitive material of each of Examples and Comparative Examples in Example 5 system, the carboxy group consumption rate, pattern formability of the photosensitive material, relative permittivity, and change in relative permittivity before and after exposure, and the laminate suitability of the transfer film, pattern formability, relative permittivity, change in relative permittivity before and after exposure, and moisture permeability were evaluated in the same manner as shown in Example 1 system. In addition, the carboxy group consumption rate, transmittance to light at 365 nm, and ratio of the transmittance to light at 365 nm to the transmittance to light at 313 nm of the photosensitive layer in the transfer film were also evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Example 5A.

Hereinafter, Seventh table below shows blending of the solid content of the photosensitive material of each of Examples and Comparative Examples in Example 5 system, and the test results thereof.

The solid content of the photosensitive material of each of Examples shown in Example 5 system was 100% by mass of the polymer A. In addition, the polymer A used in each of Examples shown in Example 5 system corresponded to the polymer Ab.

In the table, the column of “x/y/z” indicates a mass ratio of each structural unit constituting the polymer A.

As shown in Seventh table, the weight-average molecular weight of the polymer A shown in Seventh table was all 10,000 to 50,000.

In addition, the column of “Transmittance at 365 nm” in the evaluation of the transfer film indicates the transmittance of the photosensitive layer to light having a wavelength of 365 nm.

In addition, the column of “Transmittance at 365 nm/transmittance at 313 nm” in the evaluation of the transfer film indicates a value obtained by dividing the transmittance of the photosensitive layer to light having a wavelength of 365 nm by the transmittance of the photosensitive layer to light having a wavelength of 313 nm.

In addition, in the table, the description of St/AA means a styrene/acrylic acid copolymer (compositional ratio: styrene-based repeating unit/acrylic acid-based repeating unit=80/20 (mass ratio)).

TABLE 38

| | | | | Evaluation of photosensitive material | | | | | | Evaluation of transfer film | | | | | | | | | |
|---|---|---|---|---|---|---|---|---|---|---|---|---|---|---|---|---|---|---|---|
| | | | | | | | | | | Carboxy | | | | | | | | | |
| | | | | Carboxy | | | | | Change | group | | | | | | | | | |
| | | | | group | | | | | in | con- | | Trans- | | | | | | Change | |
| | | | | con- | | | | | relative | sump- | | mittance | | | | | | in relative | |
| | | | | sumption | | | | | permit- | tion rate | | at 365 | | | | | | permit- | |
| | Polymer A | | | rate | Pattern | | | Rela- | tivity | [measure | Trans- | nm/trans- | Lami- | Pattern | | | Rela- | tivity | Mois- |
| | (polymer Ab) | | | [measure- | formability | | | tive | before | ment | mittance | mittance | nate | formability | | | tive | before | ture |
| Seventh | | x, y, z | | ment | 25 | 50 | 250 | permit- | and after | of | at 365 | at 313 | suit- | 25 | 50 | 250 | permit- | and after | perme- |
| table | Structure | (mass ratio) | Mw | of asking] | μm | μm | μm | tivity | exposure | asking] | nm | nm | ability | μm | μm | μm | tivity | exposure | ability |
| Example 5-1 | 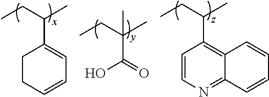 | 62.5/20/7.5 | 20000 | B | B | A | A | A | A | B | A | A | A | B | A | A | A | A | B |
| Example 5-2 | 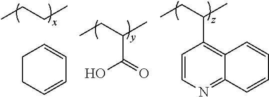 | 61.5/20/8.5 | 22000 | B | B | A | A | A | A | B | A | A | A | B | A | A | A | A | B |
| Example 5-3 | 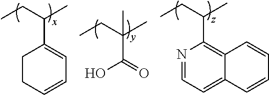 | 62.5/20/7.5 | 25000 | A | B | A | A | A | A | A | A | A | A | B | A | A | A | A | B |
| Example 5-4 | 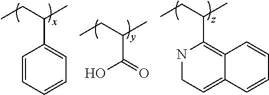 | 61.5/20/8.5 | 24000 | A | B | A | A | A | A | A | A | A | A | B | A | A | A | A | B |
| Example 5-5 | 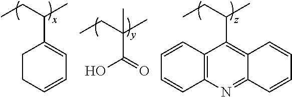 | 70/20/10 | 20000 | C | B | B | A | B | B | C | C | C | A | B | B | A | B | B | B |
| Example 5-6 | 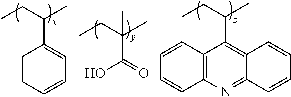 | 58.5/20/11.5 | 22000 | C | B | B | A | B | B | C | C | C | A | B | B | A | B | B | B |
| Compar- | St/AA | 80/20 | 11000 | E | D | D | D | Stan- | D | E | A | B | A | D | D | D | Stan- | D | Stan- |
| ative | | | | | | | | dard | | | | | | | | | dard | | dard |
| Exam- | | | | | | | | | | | | | | | | | | | |
| ple 5A | | | | | | | | | | | | | | | | | | | |

From the results in the above tables, it was confirmed that the objects of the present invention could be achieved with the transfer film according to the embodiment of the present invention.

### Example 6 System

<Preparation and Evaluation of Photosensitive Material>

Materials shown in Eighth table shown in the latter part were mixed and dissolved in a mixed solvent of propylene glycol monomethyl ether acetate/methyl ethyl ketone=50/50 (mass ratio) so that a blending amount shown in Eighth table shown in the latter part was satisfied and a concentration of solid contents of the finally obtained photosensitive material was 25% by mass, thereby obtaining a photosensitive material.

In addition, for the obtained photosensitive material of each of Examples and Comparative Examples in Example 6 system, the carboxy group consumption rate, pattern formability of the photosensitive material, relative permittivity, and change in relative permittivity before and after exposure, and the laminate suitability of the transfer film, pattern formability, relative permittivity, change in relative permittivity before and after exposure, and moisture permeability were evaluated in the same manner as shown in Example 1 system. In addition, the carboxy group consumption rate, transmittance to light at 365 nm, and ratio of the transmittance to light at 365 nm to the transmittance to light at 313 nm of the photosensitive layer in the transfer film were also evaluated in the same manner as shown in Example 1 system. In addition, the physical properties of ε365/ε313 of the compound β included in the photosensitive material and the photosensitive layer were evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Example 6A.

Eighth table below shows blending of the solid content of the photosensitive material of each of Examples and Comparative Examples in Example 6 system, and the test results thereof.

In the table, the value described in the column of “Solid content blending” indicates the content (part by mass) of each solid content component included in the photosensitive material of each of Examples or Comparative Examples. The value in parentheses in the compound β indicates a proportion (mol %) of the total number of structures (structures b0) included in the compound β, in which the amount of the carboxy group of the polymer A is reduced (preferably, structures (structures b) capable of accepting an electron from the carboxy group included in the polymer A in a photoexcited state) to the total number of carboxy groups included in the polymer A in the photosensitive material.

In addition, in the tables, the method for measuring “pKa of compound β in ground state” is as described above.

In addition, in the tables, the column of “ε365 of compound β” indicates a molar absorption coefficient ((cm mol/L)⁻¹) of the compound β to light having a wavelength of 365 nm in acetonitrile.

In addition, the column of “ε365/ε313” in the evaluation of the photosensitive material and the evaluation of the transfer film indicates a value obtained by dividing the molar absorption coefficient ((cm·mol/L)⁻¹) of the compound β to light having a wavelength of 365 nm by a molar absorption coefficient ((cm·mol/L)⁻¹) of the compound β to light having a wavelength of 313 nm. All molar absorption coefficients are values in acetonitrile.

In addition, the column of “Transmittance at 365 nm” in the evaluation of the transfer film indicates the transmittance of the photosensitive layer to light having a wavelength of 365 nm.

In addition, the column of “Transmittance at 365 nm/transmittance at 313 nm” in the evaluation of the transfer film indicates a value obtained by dividing the transmittance of the photosensitive layer to light having a wavelength of 365 nm by the transmittance of the photosensitive layer to light having a wavelength of 313 nm.

TABLE 39
Eighth table (1)

| | | | Mw of | pKa of | | | | |
|---|---|---|---|---|---|---|---|---|
| | | | polymer | Compound β | ε365 of | Example | | |
| | | | A | in ground state | Compound β | 6-1 | 6-2 | 6-3 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | 3.5 (20) | | |
| | β (in | Quinoline | | 4.15 | <10 | | 3.5 (20) | |
| | parentheses: | Acridine | | 4.67 | 4900 | | | 4.9 (20) |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | B | B | D |
| of photo- | [measurement of ashing] | | | | | | | |
| sensitive | ε365/ε313 | | | — | — | <1 | <1 | >3 |
| material | Pattern | 25 μm | | — | — | B | B | C |
| | formability | 50 μm | | — | — | A | A | B |
| | | 250 μm | | — | — | A | A | A |
| | Relative permittivity | | | — | — | A | A | B |
| | Change in relative permittivity | | | — | — | A | A | B |
| | before and after exposure | | | | | | | |
| Evaluation | Carboxy group consumption rate | | | — | — | B | B | D |
| of transfer | [measurement of ashing] | | | | | | | |
| film | ε365/ε313 | | | — | — | <1 | <1 | >3 |
| | Transmittance at 365 nm | | | — | — | A | A | C |
| | Transmittance at 365 nm/ | | | — | — | A | A | C |
| | transmittance at 313 nm | | | | | | | |
| | Laminate suitability | | | — | — | A | A | A |
| | Pattern | 25 μm | | — | — | B | B | C |
| | formability | 50 μm | | — | — | A | A | B |
| | | 250 μm | | — | — | A | A | A |

| | | | | | |
|---|---|---|---|---|---|
| Relative permittivity | — | — | A | A | B |
| Change in relative permittivity | — | — | A | A | B |
| before and after exposure | | | | | |
| Moisture permeability | — | — | A | B | B |

Example

| | | | 6-4 | 6-5 | 6-6 | 6-7 | 6-8 | 6-9 | 6-10 |
|---|---|---|---|---|---|---|---|---|---|
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | 5.0 (20) | | | | | | |
| | with respect | 1-n-Butyl-4-methylisoquinoline | | 5.4 (20) | | | | | |
| | to carboxy | 1-Me-isoquinoline | | | 3.9 (20) | | | | |
| | group of | 2,4,5,7-Tetramethylquinoline | | | | 5.0 (20) | | | |
| | polymer A | 2-Methyl-4-methoxyquinoline | | | | | 4.7 (20) | | |
| | having acid | 9-Methylacridine | | | | | | 5.2 (20) | |
| | group | 9-Phenylacridine | | | | | | | 5.9 (20) |
| | (mol %)) | Pyridine | | | | | | | |
| | | 2,4-Dimethylquinoline | | | | | | | |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | A | A | A | C | D |
| of photo- | [measurement of ashing] | | | | | | | | |
| sensitive | ε365/ε313 | | <1 | <1 | <1 | <1 | <1 | >3 | >3 |
| material | Pattern | 25 μm | A | A | A | A | A | B | B |
| | formability | 50 μm | A | A | A | A | A | B | B |
| | | 250 μm | A | A | A | A | A | A | B |
| | Relative permittivity | | A | A | A | A | A | B | C |
| | Change in relative permittivity | | A | A | A | A | A | B | C |
| | before and after exposure | | | | | | | | |
| Evaluation | Carboxy group consumption rate | | A | A | A | A | A | C | D |
| of transfer | [measurement of ashing] | | | | | | | | |
| film | ε365/ε313 | | <1 | <1 | <1 | <1 | <1 | >3 | >3 |
| | Transmittance at 365 nm | | A | A | A | A | A | C | C |
| | Transmittance at 365 nm/ | | A | A | A | A | A | C | C |
| | transmittance at 313 nm | | | | | | | | |
| | Laminate suitability | | A | A | A | A | A | A | A |
| | Pattern | 25 μm | A | A | A | A | A | B | B |
| | formability | 50 μm | A | A | A | A | A | B | B |
| | | 250 μm | A | A | A | A | A | A | B |
| | Relative permittivity | | A | A | A | A | A | B | C |
| | Change in relative permittivity | | A | A | A | A | A | B | C |
| | before and after exposure | | | | | | | | |
| | Moisture permeability | | A | A | A | A | A | B | B |
| | | | Example | | | | | | |
| | | | 6-11 | 6-12 | 6-13 | 6-14 | 6-15 | 6-16 | 6-17 |
| Solid | Polymer A | St/MAA/MMA/GMA-MAA = | 60 | 60 | 60 | 60 | 60 | | |
| content | | 47.7/19.0/1.3/32.0 (mass ratio) | | | | | | | |
| blending | | CHMA/MAA/BzMA = | | | | | | 60 | 60 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | 3.5 (20) | |
| | β (in | Quinoline | | | | | | | 3.5 (20) |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | | | | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | 2.1 (20) | | | | | | |
| | | 2,4-Dimethylquinoline | | 4.3 (20) | 2.1 (10) | | | | |
| | | 4-Aminopyridine | | | | 2.6 (20) | | | |
| | | 2-Chloropyridine | | | | | 3.1 (20) | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | D | A | B | D | D | B | B |
| of photo- | [measurement of ashing] | | | | | | | | |
| sensitive | ε365/ε313 | | <1 | <1 | <1 | <1 | <1 | <1 | <1 |
| material | Pattern | 25 μm | C | A | B | C | C | B | B |
| | formability | 50 μm | C | A | A | C | C | A | A |
| | | 250 μm | C | A | A | C | C | A | A |
| | Relative permittivity | | C | A | A | C | C | A | A |
| | Change in relative permittivity | | C | A | A | C | C | A | A |
| | before and after exposure | | | | | | | | |
| Evaluation | Carboxy group consumption rate | | D | A | B | D | D | B | B |
| of transfer | [measurement of ashing] | | | | | | | | |
| film | ε365/ε313 | | <1 | <1 | <1 | <1 | <1 | <1 | <1 |
| | Transmittance at 365 nm | | B | A | A | B | B | A | A |
| | Transmittance at 365 nm/ | | B | A | A | B | B | A | A |
| | transmittance at 313 nm | | | | | | | | |
| | Laminate suitability | | A | A | A | A | A | A | A |
| | Pattern | 25 μm | C | A | B | C | C | B | B |
| | formability | 50 μm | C | A | A | C | C | A | A |
| | | 250 μm | C | A | A | C | C | A | A |

| | | | | | | | |
|---|---|---|---|---|---|---|---|
| Relative permittivity | C | A | A | C | C | A | A |
| Change in relative permittivity | C | A | A | C | C | A | A |
| before and after exposure | | | | | | | |
| Moisture permeability | B | A | A | C | C | A | B |

TABLE 40
Eighth table (2)

| | | | Mw of | pKa of | | | | |
|---|---|---|---|---|---|---|---|---|
| | | | polymer | Compound β in | ε365 of | Example | | |
| | | | A | ground state | Compound β | 6-18 | 6-19 | 6-20 |
| Solid | Polymer A | St/MAA/MMA/GMA-MAA = | 18000 | — | — | | | |
| content | | 47.7/19.0/1.3/32.0 (mass ratio) | | | | | | |
| blending | | CHMA/MAA/BzMA = | 24000 | — | — | 60 | 60 | 60 |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | 4.9 (20) | | |
| | molar ratio | 1-n-Butylisoquinoline | | 5.27 | <10 | | 5.0 (20) | |
| | with respect | 1-n-Butyl-4-methylisoquinoline | | 5.9 | <10 | | | 5.4 (20) |
| | to carboxy | 1-Me-isoquinoline | | 5.31 | <10 | | | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | D | A | A |
| of photo- | [measurement of ashing] | | | | | | | |
| sensitive | ε365/ε313 | | | — | — | >3 | <1 | <1 |
| material | Pattern | 25 μm | | — | — | C | A | A |
| | formability | 50 μm | | — | — | B | A | A |
| | | 250 μm | | — | — | A | A | A |
| | Relative permittivity | | | — | — | B | A | A |
| | Change in relative permittivity | | | — | — | B | A | A |
| | before and after exposure | | | | | | | |
| Evaluation | Carboxy group consumption rate | | | — | — | D | A | A |
| of transfer | [measurement of ashing] | | | | | | | |
| film | ε365/ε313 | | | — | — | >3 | <1 | <1 |
| | Transmittance at 365 nm | | | — | — | C | A | A |
| | Transmittance at 365 nm/ | | | — | — | C | A | A |
| | transmittance at 313 nm | | | | | | | |
| | Laminate suitability | | | — | — | A | A | A |
| | Pattern | 25 μm | | — | — | C | A | A |
| | formability | 50 μm | | — | — | B | A | A |
| | | 250 μm | | — | — | A | A | A |

| | | | | | |
|---|---|---|---|---|---|
| Relative permittivity | — | — | B | A | A |
| Change in relative permittivity | — | — | B | A | A |
| before and after exposure | | | | | |
| Moisture permeability | — | — | B | A | A |

Example

| | | | 6-21 | 6-22 | 6-23 | 6-24 | 6-25 | 6-26 | 6-27 |
|---|---|---|---|---|---|---|---|---|---|
| Solid | Polymer A | St/MAA/MMA/GMA-MAA = | | | | | | | |
| content | | 47.7/19.0/1.3/32.0 (mass ratio) | | | | | | | |
| blending | | CHMA/MAA/BzMA = | 60 | 60 | 60 | 60 | 60 | 60 | 60 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 3.9 (20 | | | | | | |
| | group of | 2,4,5,7-Tetramethylquinoline | | 5.0 (20) | | | | | |
| | polymer A | 2-Methyl-4-methoxyquinoline | | | 4.7 (20) | | | | |
| | having acid | 9-Methylacridine | | | | 5.2 (20) | | | |
| | group | 9-Phenylacridine | | | | | 6.9 (20) | | |
| | (mol %)) | Pyridine | | | | | | 2.1 (20) | |
| | | 2,4-Dimethylquinoline | | | | | | | 4.3 (20) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | A | C | D | D | A |
| of photo- | [measurement of ashing] | | | | | | | | |
| sensitive | ε365/ε313 | | <1 | <1 | <1 | >3 | >3 | <1 | <1 |
| material | Pattern | 25 μm | A | A | A | B | B | C | A |
| | formability | 50 μm | A | A | A | B | B | C | A |
| | | 250 μm | A | A | A | A | B | C | A |
| | Relative permittivity | | A | A | A | B | C | C | A |
| | Change in relative permittivity | | A | A | A | B | C | C | A |
| | before and after exposure | | | | | | | | |
| Evaluation | Carboxy group consumption rate | | A | A | A | C | D | D | A |
| of transfer | [measurement of ashing] | | | | | | | | |
| film | ε365/ε313 | | <1 | <1 | <1 | >3 | >3 | <1 | <1 |
| | Transmittance at 365 nm | | A | A | A | C | C | B | A |
| | Transmittance at 365 nm/ | | A | A | A | C | C | B | A |
| | transmittance at 313 nm | | | | | | | | |
| | Laminate suitability | | A | A | A | A | A | A | A |
| | Pattern | 25 μm | A | A | A | B | B | C | A |
| | formability | 50 μm | A | A | A | B | B | C | A |
| | | 250 μm | A | A | A | A | B | C | A |
| | Relative permittivity | | A | A | A | B | C | C | A |
| | Change in relative permittivity | | A | A | A | B | C | C | A |
| | before and after exposure | | | | | | | | |
| | Moisture permeability | | A | A | A | B | B | B | A |
| | | | Example | | | | | | |
| | | | 6-28 | 6-29 | 6-30 | 6-31 | 6-32 | 6-33 | 6-34 |
| Solid | Polymer A | St/MAA/MMA/GMA-MAA = | | | | | | | |
| content | | 47.7/19.0/1.3/32.0 (mass ratio) | | | | | | | |
| blending | | CHMA/MAA/BzMA = | 60 | 60 | 60 | | | | |
| | | 49/19/32 (mass ratio) | | | | | | | |
| | | St/AA/AA-GMA = | | | | 60 | 60 | 60 | 60 |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | 3.1 (20) | | | |
| | β (in | Quinoline | | | | | 3.1 (20) | | |
| | parentheses: | Acridine | | | | | | 4.3 (20) | |
| | molar ratio | 1-n-Butylisoquinoline | | | | | | | 4.5 (20) |
| | with respect | 1-n-Butyl-4-methylisoquinoline | | | | | | | |
| | to carboxy | 1-Me-isoquinoline | | | | | | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 2.1 (10) | | | | | | |
| | | 4-Aminopyridine | | 2.6 (20) | | | | | |
| | | 2-Chloropyridine | | | 3.1 (20) | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | B | D | D | B | B | D | A |
| of photo- | [measurement of ashing] | | | | | | | | |
| sensitive | ε365/ε313 | | <1 | <1 | <1 | <1 | <1 | >3 | <1 |
| material | Pattern | 25 μm | B | C | C | B | B | C | A |
| | formability | 50 μm | A | C | C | A | A | B | A |
| | | 250 μm | A | C | C | A | A | A | A |
| | Relative permittivity | | A | C | C | A | A | B | A |
| | Change in relative permittivity | | A | C | C | A | A | B | A |
| | before and after exposure | | | | | | | | |
| Evaluation | Carboxy group consumption rate | | B | D | D | B | B | D | A |
| of transfer | [measurement of ashing] | | | | | | | | |
| film | ε365/ε313 | | <1 | <1 | <1 | <1 | <1 | >3 | <1 |
| | Transmittance at 365 nm | | A | B | B | A | A | C | A |
| | Transmittance at 365 nm/ | | A | B | B | A | A | C | A |
| | transmittance at 313 nm | | | | | | | | |
| | Laminate suitability | | A | A | A | A | A | A | A |
| | Pattern | 25 μm | B | C | C | B | B | C | A |
| | formability | 50 μm | A | C | C | A | A | B | A |
| | | 250 μm | A | C | C | A | A | A | A |

| | | | | | | | |
|---|---|---|---|---|---|---|---|
| Relative permittivity | A | C | C | A | A | B | A |
| Change in relative permittivity | A | C | C | A | A | B | A |
| before and after exposure | | | | | | | |
| Moisture permeability | A | C | C | A | B | B | A |

TABLE 41
Eighth table (3)

| | | | Mw of | pKa of | | | | |
|---|---|---|---|---|---|---|---|---|
| | | | polymer | Compound β in | ε365 of | Example | | |
| | | | A | ground state | Compound β | 6-35 | 6-36 | 6-37 |
| Solid | Polymer A | St/MAA/MMA/GMA-MAA = | 18000 | — | — | | | |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | 60 | 60 | 60 |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | 4.8 (20) | | |
| | to carboxy | 1-Me-isoquinoline | | 5.31 | <10 | | 3.5 (20) | |
| | group of | 2,4,5,7-Tetramethylquinoline | | 6.23 | <10 | | | 4.5 (20) |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | A | A | A |
| of photo- | [measurement of ashing] | | | | | | | |
| sensitive | ε365/ε313 | | | — | — | <1 | <1 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | A | A | A |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

Example

| | | | 6-38 | 6-39 | 6-40 | 6-41 | 6-42 | 6-43 | 6-44 |
|---|---|---|---|---|---|---|---|---|---|
| Solid | Polymer A | St/MAA/MMA/GMA-MAA = | | | | | | | |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | 60 | 60 | 60 | 60 | 60 | 60 | 60 |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | | | | | |
| | group of | 2,4,5,7-Tetramethylquinoline | | | | | | | |
| | polymer A | 2-Methyl-4-methoxyquinoline | 4.2 (20) | | | | | | |
| | having acid | 9-Methylacridine | | 4.7 (20) | | | | | |
| | group | 9-Phenylacridine | | | 6.2 (20) | | | | |
| | (mol %)) | Pyridine | | | | 1.9 (20) | | | |
| | | 2,4-Dimethylquinoline | | | | | 3.8 (20) | 1.9 (10) | |
| | | 4-Aminopyridine | | | | | | | 2.3 (20) |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | C | D | D | A | B | D |
| of photo- | [measurement of ashing] | | | | | | | | |
| sensitive | ε365/ε313 | | <1 | >3 | >3 | <1 | <1 | <1 | <1 |
| material | Pattern | 25 μm | A | B | B | C | A | B | C |
| | formability | 50 μm | A | B | B | C | A | A | C |
| | | 250 μm | A | A | B | C | A | A | C |
| | Relative permittivity | | A | B | C | C | A | A | C |
| | Change in relative permittivity | | A | B | C | C | A | A | C |
| | before and after exposure | | | | | | | | |
| Evaluation | Carboxy group consumption rate | | A | C | D | D | A | B | D |
| of transfer | [measurement of ashing] | | | | | | | | |
| film | ε365/ε313 | | <1 | >3 | >3 | <1 | <1 | <1 | <1 |
| | Transmittance at 365 nm | | A | C | C | B | A | A | B |
| | Transmittance at 365 nm/ | | A | C | C | B | A | A | B |
| | transmittance at 313 nm | | | | | | | | |
| | Laminate suitability | | A | A | A | A | A | A | A |
| | Pattern | 25 μm | A | B | B | C | A | B | C |
| | formability | 50 μm | A | B | B | C | A | A | C |
| | | 250 μm | A | A | B | C | A | A | C |
| | Relative permittivity | | A | B | C | C | A | A | C |
| | Change in relative permittivity | | A | B | C | C | A | A | C |
| | before and after exposure | | | | | | | | |
| | Moisture permeability | | A | B | B | B | A | A | C |
| | | | Example | | | | | | |
| | | | 6-45 | 6-46 | 6-47 | 6-48 | 6-49 | 6-50 | 6-51 |
| Solid | Polymer A | St/MAA/MMA/GMA-MAA = | | | | | | | |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | 60 | | | | | | |
| | | 53.5/14.5/32 (mass ratio) | | | | | | | |
| | | CHA/AA/HEA = | | 60 | 60 | 60 | 60 | 60 | 60 |
| | | 53.5/14.5/32 (mass ratio) | | | | | | | |
| | Compound | Isoquinoline | | 3.1 (20) | | | | | |
| | β (in | Quinoline | | | 3.1 (20) | | | | |
| | parentheses: | Acridine | | | | 4.3 (20) | | | |
| | molar ratio | 1-n-Butylisoquinoline | | | | | 4.5 (20) | | |
| | with respect | 1-n-Butyl-4-methylisoquinoline | | | | | | 4.8 (20) | |
| | to carboxy | 1-Me-isoquinoline | | | | | | | 3.5 (20) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | | | | | | | |
| | | 4-Aminopyridine | | | | | | | |
| | | 2-Chloropyridine | 2.7 (20) | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | D | B | B | D | A | A | A |
| of photo- | [measurement of ashing] | | | | | | | | |
| sensitive | ε365/ε313 | | <1 | <1 | <1 | >3 | <1 | <1 | <1 |
| material | Pattern | 25 μm | C | B | B | C | A | A | A |
| | formability | 50 μm | C | A | A | B | A | A | A |
| | | 250 μm | C | A | A | A | A | A | A |
| | Relative permittivity | | C | A | A | B | A | A | A |
| | Change in relative permittivity | | C | A | A | B | A | A | A |
| | before and after exposure | | | | | | | | |
| Evaluation | Carboxy group consumption rate | | D | B | B | D | A | A | A |
| of transfer | [measurement of ashing] | | | | | | | | |
| film | ε365/ε313 | | <1 | <1 | <1 | >3 | <1 | <1 | <1 |
| | Transmittance at 365 nm | | B | A | A | C | A | A | A |
| | Transmittance at 365 nm/ | | B | A | A | C | A | A | A |
| | transmittance at 313 nm | | | | | | | | |
| | Laminate suitability | | A | A | A | A | A | A | A |
| | Pattern | 25 μm | C | B | B | C | A | A | A |
| | formability | 50 μm | C | A | A | B | A | A | A |
| | | 250 μm | C | A | A | A | A | A | A |

| | | | | | | | |
|---|---|---|---|---|---|---|---|
| Relative permittivity | C | A | A | B | A | A | A |
| Change in relative permittivity | C | A | A | B | A | A | A |
| before and after exposure | | | | | | | |
| Moisture permeability | C | A | B | B | A | A | A |

TABLE 42
Eighth table (4)

| | | | Mw of | pKa of | | | | |
|---|---|---|---|---|---|---|---|---|
| | | | polymer | Compound β in | ε365 of | Example | | |
| | | | A | ground state | Compound β | 6-52 | 6-53 | 6-54 |
| Solid | Polymer A | St/MAA/MMA/GMA-MAA = | 18000 | — | — | | | |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | 60 | 60 | 60 |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | | |
| | group of | 2,4,5,7-Tetramethylquinoline | | 6.23 | <10 | 4.5 (20) | | |
| | polymer A | 2-Methyl-4-methoxyquinoline | | 6.51 | <10 | | 4.2 (20) | |
| | having acid | 9-Methylacridine | | 5.4 | 6300 | | | 4.7 (20) |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | A | A | C |
| of photo- | [measurement of ashing] | | | | | | | |
| sensitive | ε365/ε313 | | | — | — | <1 | <1 | >3 |
| material | Pattern | 25 μm | | — | — | A | A | B |
| | formability | 50 μm | | — | — | A | A | B |
| | | 250 μm | | — | — | A | A | A |
| | Relative permittivity | | | — | — | A | A | B |
| | Change in relative permittivity | | | — | — | A | A | B |
| | before and after exposure | | | | | | | |
| Evaluation | Carboxy group consumption rate | | | — | — | A | A | C |
| of transfer | [measurement of ashing] | | | | | | | |
| film | ε365/ε313 | | | — | — | <1 | <1 | >3 |
| | Transmittance at 365 nm | | | — | — | A | A | C |
| | Transmittance at 365 nm/ | | | — | — | A | A | C |
| | transmittance at 313 nm | | | | | | | |
| | Laminate suitability | | | — | — | A | A | A |
| | Pattern | 25 μm | | — | — | A | A | B |
| | formability | 50 μm | | — | — | A | A | B |
| | | 250 μm | | — | — | A | A | A |

| | | | | | |
|---|---|---|---|---|---|
| Relative permittivity | — | — | A | A | B |
| Change in relative permittivity | — | — | A | A | B |
| before and after exposure | | | | | |
| Moisture permeability | — | — | A | A | B |

Example

| | | | 6-55 | 6-56 | 6-57 | 6-58 | 6-59 | 6-60 | 6-61 |
|---|---|---|---|---|---|---|---|---|---|
| Solid | Polymer A | St/MAA/MMA/GMA-MAA = | | | | | | | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | 60 | 60 | 60 | 60 | 60 | 60 | |
| | | 53.5/14.5/32 (mass ratio) | | | | | | | |
| | Compound | Isoquinoline | | | | | | | 3.5 (20) |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | | | | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | 6.2 (20) | | | | | | |
| | (mol %)) | Pyridine | | 1.9 (20) | | | | | |
| | | 2,4-Dimethylquinoline | | | 3.8 (20) | 1.9 (10) | | | |
| | | 4-Aminopyridine | | | | | 2.3 (20) | | |
| | | 2-Chloropyridine | | | | | | 2.7 (20) | |
| | Polymerizable | DPHA | 12.6 | 12.6 | 12.6 | 12.6 | 12.6 | 12.6 | |
| | compound | A-NOD-N | 25.0 | 25.0 | 25.0 | 25.0 | 25.0 | 25.0 | |
| | | DTMPT | | | | | | | 18.8 |
| | | A-DCP | | | | | | | |
| | | TMPT | | | | | | | 18.8 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | D | D | A | B | D | D | B |
| of photo- | [measurement of ashing] | | | | | | | | |
| sensitive | ε365/ε313 | | >3 | <1 | <1 | <1 | <1 | <1 | <1 |
| material | Pattern | 25 μm | B | C | A | B | C | C | B |
| | formability | 50 μm | B | C | A | A | C | C | A |
| | | 250 μm | B | C | A | A | C | C | A |
| | Relative permittivity | | C | C | A | A | C | C | A |
| | Change in relative permittivity | | C | C | A | A | C | C | A |
| | before and after exposure | | | | | | | | |
| Evaluation | Carboxy group consumption rate | | D | D | A | B | D | D | B |
| of transfer | [measurement of ashing] | | | | | | | | |
| film | ε365/ε313 | | >3 | <1 | <1 | <1 | <1 | <1 | <1 |
| | Transmittance at 365 nm | | C | B | A | A | B | B | A |
| | Transmittance at 365 nm/ | | C | B | A | A | B | B | A |
| | transmittance at 313 nm | | | | | | | | |
| | Laminate suitability | | A | A | A | A | A | A | A |
| | Pattern | 25 μm | B | C | A | B | C | C | B |
| | formability | 50 μm | B | C | A | A | C | C | A |
| | | 250 μm | B | C | A | A | C | C | A |
| | Relative permittivity | | C | C | A | A | C | C | A |
| | Change in relative permittivity | | C | C | A | A | C | C | A |
| | before and after exposure | | | | | | | | |
| | Moisture permeability | | B | B | A | A | C | C | A |
| | | | Example | | | | | | |
| | | | 6-62 | 6-63 | 6-64 | 6-65 | 6-66 | 6-67 | 6-68 |
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | 3.5 (20) | | | | | | |
| | parentheses: | Acridine | | 4.9 (20) | | | | | |
| | molar ratio | 1-n-Butylisoquinoline | | | 5.0 (20) | | | | |
| | with respect | 1-n-Butyl-4-methylisoquinoline | | | | 5.4 (20) | | | |
| | to carboxy | 1-Me-isoquinoline | | | | | 3.9 (20) | | |
| | group of | 2,4,5,7-Tetramethylquinoline | | | | | | 5.0 (20) | |
| | polymer A | 2-Methyl-4-methoxyquinoline | | | | | | | 4.7 (20) |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | | | | | | | |
| | | 4-Aminopyridine | | | | | | | |
| | | 2-Chloropyridine | | | | | | | |
| | Polymerizable | DPHA | | | | | | | |
| | compound | A-NOD-N | | | | | | | |
| | | DTMPT | 18.8 | 18.8 | 18.8 | 18.8 | 18.8 | 18.8 | 18.8 |
| | | A-DCP | | | | | | | |
| | | TMPT | 18.8 | 18.8 | 18.8 | 18.8 | 18.8 | 18.8 | 18.8 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | B | D | A | A | A | A | A |
| of photo- | [measurement of ashing] | | | | | | | | |
| sensitive | ε365/ε313 | | <1 | >3 | <1 | <1 | <1 | <1 | <1 |
| material | Pattern | 25 μm | B | C | A | A | A | A | A |
| | formability | 50 μm | A | B | A | A | A | A | A |
| | | 250 μm | A | A | A | A | A | A | A |
| | Relative permittivity | | A | B | A | A | A | A | A |
| | Change in relative permittivity | | A | B | A | A | A | A | A |
| | before and after exposure | | | | | | | | |
| Evaluation | Carboxy group consumption rate | | B | D | A | A | A | A | A |
| of transfer | [measurement of ashing] | | | | | | | | |
| film | ε365/ε313 | | <1 | >3 | <1 | <1 | <1 | <1 | <1 |
| | Transmittance at 365 nm | | A | C | A | A | A | A | A |
| | Transmittance at 365 nm/ | | A | C | A | A | A | A | A |
| | transmittance at 313 nm | | | | | | | | |
| | Laminate suitability | | A | A | A | A | A | A | A |
| | Pattern | 25 μm | B | C | A | A | A | A | A |
| | formability | 50 μm | A | B | A | A | A | A | A |
| | | 250 μm | A | A | A | A | A | A | A |

| | | | | | | | |
|---|---|---|---|---|---|---|---|
| Relative permittivity | A | B | A | A | A | A | A |
| Change in relative permittivity | A | B | A | A | A | A | A |
| before and after exposure | | | | | | | |
| Moisture permeability | B | B | A | A | A | A | A |

TABLE 43
Eighth table (5)

| | | | Mw of | pKa of | | | | |
|---|---|---|---|---|---|---|---|---|
| | | | polymer | Compound β | ε365 of | Example | | |
| | | | A | in ground state | Compound β | 6-69 | 6-70 | 6-71 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | 5.2 (20) | | |
| | group | 9-Phenylacridine | | 4.04 | >10000 | | 6.9 (20) | |
| | (mol %)) | Pyridine | | 5.25 | <10 | | | 2.1 (20) |
| | | 2,4-Dimethylquinolme | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | | | |
| | compound | A-NOD-N | | — | — | | | |
| | | DTMPT | | — | — | 18.8 | 18.8 | 18.8 |
| | | A-DCP | | — | — | | | |
| | | TMPT | | — | — | 18.8 | 18.8 | 18.8 |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | C | D | D |
| of photo- | [measurement of ashing] | | | | | | | |
| sensitive | ε365/ε313 | | | — | — | >3 | >3 | <1 |
| material | Pattern | 25 μm | | — | — | B | B | C |
| | formability | 50 μm | | — | — | B | B | C |
| | | 250 μm | | — | — | A | B | C |
| | Relative permittivity | | | — | — | B | C | C |
| | Change in relative permittivity | | | — | — | B | C | C |
| | before and after exposure | | | | | | | |
| Evaluation | Carboxy group consumption rate | | | — | — | C | D | D |
| of transfer | [measurement of ashing] | | | | | | | |
| film | ε365/ε313 | | | — | — | >3 | >3 | <1 |
| | Transmittance at 365 nm | | | — | — | C | C | B |
| | Transmittance at 365 nm/ | | | — | — | C | C | B |
| | transmittance at 313 nm | | | | | | | |
| | Laminate suitability | | | — | — | A | A | A |
| | Pattern | 25 μm | | — | — | B | B | C |
| | formability | 50 μm | | — | — | B | B | C |
| | | 250 μm | | — | — | A | B | C |

| | | | | | |
|---|---|---|---|---|---|
| Relative permittivity | — | — | B | C | C |
| Change in relative permittivity | — | — | B | C | C |
| before and after exposure | | | | | |
| Moisture permeability | — | — | B | B | B |

Example

| | | | 6-72 | 6-73 | 6-74 | 6-75 | 6-76 | 6-77 | 6-78 |
|---|---|---|---|---|---|---|---|---|---|
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | | | 3.9 (20) | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinolme | 4.3 (20) | 2.1 (10) | | | | 4.3 (20) | 2.1 (10) |
| | | 4-Aminopyridine | | | 2.6 (20) | | | | |
| | | 2-Chloropyridine | | | | 3.1 (20) | | | |
| | Polymerizable | DPHA | | | | | | | |
| | compound | A-NOD-N | | | | | | | |
| | | DTMPT | 18.8 | 18.8 | 18.8 | 18.8 | | | |
| | | A-DCP | | | | | 25.0 | 25.0 | 25.0 |
| | | TMPT | 18.8 | 18.8 | 18.8 | 18.8 | 12.6 | 12.6 | 12.6 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | B | D | D | A | A | B |
| of photo- | [measurement of ashing] | | | | | | | | |
| sensitive | ε365/ε313 | | <1 | <1 | <1 | <1 | <1 | <1 | <1 |
| material | Pattern | 25 μm | A | B | C | C | A | A | B |
| | formability | 50 μm | A | A | C | C | A | A | A |
| | | 250 μm | A | A | C | C | A | A | A |
| | Relative permittivity | | A | A | C | C | A | A | A |
| | Change in relative permittivity | | A | A | C | C | A | A | A |
| | before and after exposure | | | | | | | | |
| Evaluation | Carboxy group consumption rate | | A | B | D | D | A | A | B |
| of transfer | [measurement of ashing] | | | | | | | | |
| film | ε365/ε313 | | <1 | <1 | <1 | <1 | <1 | <1 | <1 |
| | Transmittance at 365 nm | | A | A | B | B | A | A | A |
| | Transmittance at 365 nm/ | | A | A | B | B | A | A | A |
| | transmittance at 313 nm | | | | | | | | |
| | Laminate suitability | | A | A | A | A | A | A | A |
| | Pattern | 25 μm | A | B | C | C | A | A | B |
| | formability | 50 μm | A | A | C | C | A | A | A |
| | | 250 μm | A | A | C | C | A | A | A |
| | Relative permittivity | | A | A | C | C | A | A | A |
| | Change in relative permittivity | | A | A | C | C | A | A | A |
| | before and after exposure | | | | | | | | |
| | Moisture permeability | | A | A | C | C | A | A | A |
| | | | Example | | | | | | |
| | | | 6-79 | 6-80 | 6-81 | 6-82 | 6-83 | 6-84 | 6-85 |
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 3.9 (20) | | | 3.9 (20) | | | 3.9 (20) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinolme | | 4.3 (20) | 2.1 (10) | | 4.3 (20) | 2.1 (10) | |
| | | 4-Aminopyridine | | | | | | | |
| | | 2-Chloropyridine | | | | | | | |
| | Polymerizable | DPHA | | | | | | | 12.6 |
| | compound | A-NOD-N | | | | 12.6 | 12.6 | 12.6 | 12.6 |
| | | DTMPT | 12.6 | 12.6 | 12.6 | | | | 12.6 |
| | | A-DCP | 12.6 | 12.6 | 12.6 | 12.6 | 12.6 | 12.6 | |
| | | TMPT | 12.6 | 12.6 | 12.6 | 12.6 | 12.6 | 12.6 | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | B | A | A | B | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | B | A | A | B | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | A | B | A | A | B | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | B | A | A | B | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 44
Eighth table (6)

| | | | Mw of | pKa of | | | | |
|---|---|---|---|---|---|---|---|---|
| | | | polymer | Compound β | ε365 of | Example | | |
| | | | A | in ground state | Compound β | 6-86 | 6-87 | 6-88 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | | 3.9 (20) |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | 4.3 (20) | 2.1 (10) | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 12.6 | 12.6 | 12.6 |
| | | DTMPT | | — | — | 12.6 | 12.6 | |
| | | A-DCP | | — | — | | | |
| | | TMPT | | — | — | | | |
| | | SR601 | | — | — | | | 12.6 |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | A | B | A |
| of photo- | [measurement of ashing] | | | | | | | |
| sensitive | ε365/ε313 | | | — | — | <1 | <1 | <1 |
| material | Pattern | 25 μm | | — | — | A | B | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | A | B | A |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | B | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

Example

| | | | 6-89 | 6-90 | 6-91 | 6-92 | 6-93 | 6-94 | 6-95 |
|---|---|---|---|---|---|---|---|---|---|
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | 3.9 (20) | | | 3.9 (20) | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 4.3 (20) | 2.1 (10) | | 4.3 (20) | 2.1 (10) | | 4.3 (20) |
| | | 4-Aminopyridine | | | | | | | |
| | | 2-Chloropyridine | | | | | | | |
| | Polymerizable | DPHA | 12.6 | 12.6 | | | | | |
| | compound | A-NOD-N | 12.6 | 12.6 | 12.6 | 12.6 | 12.6 | 12.6 | 12.6 |
| | | DTMPT | | | 12.6 | 12.6 | 12.6 | 12.6 | 12.6 |
| | | A-DCP | | | | | | | |
| | | TMPT | | | | | | | |
| | | SR601 | 12.6 | 12.6 | | | | | |
| | | KRM8904 | | | | | | 12.6 | 12.6 |
| | | KRM8452 | | | 12.6 | 12.6 | 12.6 | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | B | A | A | B | A | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | B | A | A | B | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | B | A | A | B | A | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | B | A | A | B | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | | | Example | | | | | | |
| | | | 6-96 | 6-97 | 6-98 | 6-99 | 6-100 | 6-101 | 6-102 |
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | 3.9 (20) | | | 3.9 (20) | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 2.1 (10) | | 4.3 (20) | 2.1 (10) | | 4.3 (20) | 2.1 (10) |
| | | 4-Aminopyridine | | | | | | | |
| | | 2-Chloropyridine | | | | | | | |
| | Polymerizable | DPHA | | 12.6 | 12.6 | 12.6 | 12.6 | 12.6 | 12.6 |
| | compound | A-NOD-N | 12.6 | 25.0 | 25.0 | 25.0 | 25.0 | 25.0 | 25.0 |
| | | DTMPT | 12.6 | | | | | | |
| | | A-DCP | | | | | | | |
| | | TMPT | | | | | | | |
| | | SR601 | | | | | | | |
| | | KRM8904 | 12.6 | | | | | | |
| | | KRM8452 | | | | | | | |
| | Surfactant | F551A | 0.1 | | | | 0.2 | 0.2 | 0.2 |
| | | R41 | | | | | | | |
| | | 710FL | | | | | | | |
| Evaluation | Carboxy group consumption rate | | B | A | A | B | A | A | B |
| of photo- | [measurement of ashing] | | | | | | | | |
| sensitive | ε365/ε313 | | <1 | <1 | <1 | <1 | <1 | <1 | <1 |
| material | Pattern | 25 μm | B | A | A | B | A | A | B |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | B | A | A | B | A | A | B |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | B | A | A | B | A | A | B |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 45
Eighth table (7)

| | | | Mw of | pKa of | | | | |
|---|---|---|---|---|---|---|---|---|
| | | | polymer | Compound β | ε365 of | Example | | |
| | | | A | in ground state | Compound β | 6-103 | 6-104 | 6-105 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | 3.9 (20) | | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | | 4.3 (20) | 2.1 (10) |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.5 | 0.5 | 0.5 |
| | | R41 | | — | — | | | |
| | | 710FL | | — | — | | | |
| Evaluation | Carboxy group consumption rate | | | — | — | A | A | B |
| of photo- | [measurement of ashing] | | | | | | | |
| sensitive | ε365/ε313 | | | — | — | <1 | <1 | <1 |
| material | Pattern | 25 μm | | — | — | A | A | B |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | A | A | B |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | B |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

Example

| | | | 6-106 | 6-107 | 6-108 | 6-109 | 6-110 | 6-111 | 6-112 |
|---|---|---|---|---|---|---|---|---|---|
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 3.9 (20) | | | 3.9 (20) | | | 3.9 (20) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | | 4.3 (20) | 2.1 (10) | | 4.3 (20) | 2.1 (10) | |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 10.0 |
| | compound | A-NOD-N | 25.0 | 25.0 | 25.0 | 25.0 | 25.0 | 25.0 | 20.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | | | | | | | 0.1 |
| | | R41 | 0.1 | 0.1 | 0.1 | | | | |
| | | 710FL | | | | 0.1 | 0.1 | 0.1 | |
| Evaluation | Carboxy group consumption rate | | A | A | B | A | A | B | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | B | A | A | B | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | A | B | A | A | B | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | B | A | A | B | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | | | Example | | | | | | |
| | | | 6-113 | 6-114 | 6-115 | 6-116 | 6-117 | 6-118 | 6-119 |
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | 3.9 (20) | | | 3.9 (20) | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 4.3 (20) | 2.1 (10) | | 4.3 (20) | 2.1 (10) | | 4.3 (20) |
| | | 4-Aminopyridine | | | | | | | |
| | | 2-Chloropyridine | | | | | | | |
| | Polymerizable | DPHA | 10.0 | 10.0 | 14.0 | 14.0 | 14.0 | 28.0 | 28.0 |
| | compound | A-NOD-N | 20.0 | 20.0 | 28.0 | 28.0 | 28.0 | 14.0 | 14.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | B | A | A | B | A | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | B | A | A | B | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | B | A | A | B | A | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | B | A | A | B | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 46
Eighth table (8)

| | | | Mw of | pKa of | | | | |
|---|---|---|---|---|---|---|---|---|
| | | | polymer | Compound β | ε365 of | Example | | |
| | | | A | in ground state | Compound β | 6-120 | 6-121 | 6-122 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | 3.9 (20) | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | 2.1 (10) | | 4.3 (20) |
| | | 4-Aminopyridine | | 9.20 | <100 | | | |
| | | 2-Chloropyridine | | 0.70 | <10 | | | |
| | Polymerizable | DPHA | | — | — | 28.0 | | |
| | compound | A-NOD-N | | — | — | 14.0 | | |
| | | DTMPT | | — | — | | 21.0 | 21.0 |
| | | A-DCP | | — | — | | | |
| | | TMPT | | — | — | | 21.0 | 21.0 |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | B | A | A |
| of photo- | [measurement of ashing] | | | | | | | |
| sensitive | ε365/ε313 | | | — | — | <1 | <1 | <1 |
| material | Pattern | 25 μm | | — | — | B | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | B | A | A |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | B | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

Example

| | | | 6-123 | 6-124 | 6-125 | 6-126 | 6-127 | 6-128 | 6-129 |
|---|---|---|---|---|---|---|---|---|---|
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | 3.9 (20) | | | 3.9 (20) | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 2.1 (10) | | 4.3 (20) | 2.1 (10) | | 4.3 (20) | 2.1 (10) |
| | | 4-Aminopyridine | | | | | | | |
| | | 2-Chloropyridine | | | | | | | |
| | Polymerizable | DPHA | | | | | | | |
| | compound | A-NOD-N | | | | | | | |
| | | DTMPT | 21.0 | 10.0 | 10.0 | 10.0 | 30.0 | 30.0 | 30.0 |
| | | A-DCP | | | | | | | |
| | | TMPT | 21.0 | 32.0 | 32.0 | 32.0 | 12.0 | 12.0 | 12.0 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | B | A | A | B | A | A | B |
| of photo- | [measurement of ashing] | | | | | | | | |
| sensitive | ε365/ε313 | | <1 | <1 | <1 | <1 | <1 | <1 | <1 |
| material | Pattern | 25 μm | B | A | A | B | A | A | B |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | B | A | A | B | A | A | B |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | B | A | A | B | A | A | B |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | | | Example | | | | | | |
| | | | 6-130 | 6-131 | 6-132 | 6-133 | 6-134 | 6-135 | 6-136 |
| Solid | Polymer A | St/MAA/MMA/GMA-MAA = | | | | 60 | 60 | 60 | 30 |
| content | | 47.7/19.0/1.3/32.0 (mass ratio) | | | | | | | |
| blending | | CHMA/MAA/BzMA = | | | | | | | 30 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | 60 | 60 | 60 | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 3.5 (20) | | | 3.9 (20) | | | 3.9 (20) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | | 3.8 (20) | 1.9 (10) | | 4.3 (20) | 2.1 (10) | |
| | | 4-Aminopyridine | | | | | | | |
| | | 2-Chloropyridine | | | | | | | |
| | Polymerizable | DPHA | | | | 16.0 | 16.0 | 16.0 | 12.6 |
| | compound | A-NOD-N | | | | 32.0 | 32.0 | 32.0 | 25.0 |
| | | DTMPT | 21.0 | 21.0 | 21.0 | | | | |
| | | A-DCP | | | | | | | |
| | | TMPT | 21.0 | 21.0 | 21.0 | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | B | A | A | B | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | B | A | A | B | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | A | B | A | A | B | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | B | A | A | B | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 47
Eighth table (9)

| | | | Mw of | pKa of | | | | |
|---|---|---|---|---|---|---|---|---|
| | | | polymer | Compound β | ε365 of | Example | | |
| | | | A | in ground state | Compound β | 6-137 | 6-138 | 6-139 |
| Solid | Polymer A | St/MAA/MMA/GMA-MAA = | 18000 | — | — | 30 | 30 | |
| content | | 47.7/19.0/1.3/32.0 (mass ratio) | | | | | | |
| blending | | CHMA/MAA/BzMA = | 24000 | — | — | 30 | 30 | |
| | | 49/19/32 (mass ratio) | | | | | | |
| | | St/AA/AA-GMA = | 16000 | — | — | | | 30 |
| | | 53.5/14.5/32 (mass ratio) | | | | | | |
| | | CHA/AA/HEA = | 40000 | — | — | | | 30 |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | | 3.5 (20) |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | 4.3 (20) | 2.1 (10) | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | A | B | A |
| of photo- | [measurement of ashing] | | | | | | | |
| sensitive | ε365/ε313 | | | — | — | <1 | <1 | <1 |
| material | Pattern | 25 μm | | — | — | A | B | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | A | B | A |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | B | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

Example

| | | | 6-140 | 6-141 | 6-142 | 6-143 | 6-144 | 6-145 | 6-146 |
|---|---|---|---|---|---|---|---|---|---|
| Solid | Polymer A | St/MAA/MMA/GMA-MAA = | | | 60 | 60 | 60 | | |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | 30 | 30 | | | | | |
| | | 53.5/14.5/32 (mass ratio) | | | | | | | |
| | | CHA/AA/HEA = | 30 | 30 | | | | 60 | 60 |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | 1.9 (10) | 1.0 (5) | 1.0 (5) | 1.7 (10) | 0.8 (5) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 3.8 (20) | 1.9 (10) | 2.1 (10) | 3.1 (15) | 1.0 (5) | 1.9 (10) | 2.8 (15) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | B | A | A | B | A | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | B | A | A | B | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | B | A | A | B | A | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | B | A | A | B | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | | | Example | | | | | | |
| | | | 6-147 | 6-148 | 6-149 | 6-150 | 6-151 | 6-152 | 6-153 |
| Solid | Polymer A | St/MAA/MMA/GMA-MAA = | | 30 | 30 | 30 | | | |
| content | | 47.7/19.0/1.3/32.0 (mass ratio) | | | | | | | |
| blending | | CHMA/MAA/BzMA = | | 30 | 30 | 30 | | | |
| | | 49/19/32 (mass ratio) | | | | | | | |
| | | St/AA/AA-GMA = | | | | | 30 | 30 | 30 |
| | | 53.5/14.5/32 (mass ratio) | | | | | | | |
| | | CHA/AA/HEA = | 60 | | | | 30 | 30 | 30 |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 0.8 (5) | 3.9 (20) | | | 3.5 (20) | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 0.9 (5) | | 4.3 (20) | 2.1 (10) | | 3.8 (20) | 1.9 (10) |
| | | 4-Aminopyridine | | | | | | | |
| | | 2-Chloropyridine | | | | | | | |
| | Polymerizable | DPHA | 12.6 | | | | | | |
| | compound | A-NOD-N | 25.0 | | | | | | |
| | | DTMPT | | 21.0 | 21.0 | 21.0 | 21.0 | 21.0 | 21.0 |
| | | A-DCP | | | | | | | |
| | | TMPT | | 21.0 | 21.0 | 21.0 | 21.0 | 21.0 | 21.0 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | B | A | A | B | A | A | B |
| of photo- | [measurement of ashing] | | | | | | | | |
| sensitive | ε365/ε313 | | <1 | <1 | <1 | <1 | <1 | <1 | <1 |
| material | Pattern | 25 μm | B | A | A | B | A | A | B |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | B | A | A | B | A | A | B |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | B | A | A | B | A | A | B |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 48
Eighth table (10)

| | | | Mw of | pKa of | | | | |
|---|---|---|---|---|---|---|---|---|
| | | | polymer | Compound β | ε365 of | Example | | |
| | | | A | in ground state | Compound β | 6-154 | 6-155 | 6-156 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | 1.9 (10) | 1.0 (5) | 1.0 (5) |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | 2.1 (10) | 3.1 (15) | 1.0 (5) |
| | | 4-Aminopyridine | | 9.20 | <100 | | | |
| | | 2-Chloropyridine | | 0.70 | <10 | | | |
| | Polymerizable | DPHA | | — | — | | | |
| | compound | A-NOD-N | | — | — | | | |
| | | DTMPT | | — | — | 21.0 | 21.0 | 21.0 |
| | | A-DCP | | — | — | | | |
| | | TMPT | | — | — | 21.0 | 21.0 | 21.0 |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | A | A | B |
| of photo- | [measurement of ashing] | | | | | | | |
| sensitive | ε365/ε313 | | | — | — | <1 | <1 | <1 |
| material | Pattern | 25 μm | | — | — | A | A | B |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | A | A | B |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | B |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

Example

| | | | 6-157 | 6-158 | 6-159 | 6-160 | 6-161 | 6-162 | 6-163 |
|---|---|---|---|---|---|---|---|---|---|
| Solid | Polymer A | St/MAA/MMA/GMA-MAA = | | | | 30 | 30 | 30 | |
| content | | 47.7/19.0/1.3/32.0 (mass ratio) | | | | | | | |
| blending | | CHMA/MAA/BzMA = | | | | 30 | 30 | 30 | |
| | | 49/19/32 (mass ratio) | | | | | | | |
| | | St/AA/AA-GMA = | | | | | | | 30 |
| | | 53.5/14.5/32 (mass ratio) | | | | | | | |
| | | CHA/AA/HEA = | 60 | 60 | 60 | | | | 30 |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 1.7 (10) | 0.8 (5) | 0.8 (5) | 1.9 (10) | 1.0 (5) | 1.0 (5) | 1.7 (10) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 1.9 (10) | 2.8 (15) | 0.9 (5) | 2.1 (10) | 3.1 (15) | 1.0 (5) | 1.9 (10) |
| | | 4-Aminopyridine | | | | | | | |
| | | 2-Chloropyridine | | | | | | | |
| | Polymerizable | DPHA | | | | 12.6 | 12.6 | 12.6 | 12.6 |
| | compound | A-NOD-N | | | | 25.0 | 25.0 | 25.0 | 25.0 |
| | | DTMPT | 21.0 | 21.0 | 21.0 | | | | |
| | | A-DCP | | | | | | | |
| | | TMPT | 21.0 | 21.0 | 21.0 | | | | |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | B | A | A | B | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | B | A | A | B | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | A | B | A | A | B | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | B | A | A | B | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | | | Example | | | | | | |
| | | | 6-164 | 6-165 | 6-166 | 6-167 | 6-168 | 6-169 | 6-170 |
| Solid | Polymer A | St/MAA/MMA/GMA-MAA = | | | 30 | 30 | 30 | | |
| content | | 47.7/19.0/1.3/32.0 (mass ratio) | | | | | | | |
| blending | | CHMA/MAA/BzMA = | | | 30 | 30 | 30 | | |
| | | 49/19/32 (mass ratio) | | | | | | | |
| | | St/AA/AA-GMA = | 30 | 30 | | | | 30 | 30 |
| | | 53.5/14.5/32 (mass ratio) | | | | | | | |
| | | CHA/AA/HEA = | 30 | 30 | | | | 30 | 30 |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 0.8 (5) | 0.8 (5) | 1.9 (10) | 1.0 (5) | 1.0 (5) | 1.7 (10) | 0.8 (5) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 2.8 (15) | 0.9 (5) | 2.1 (10) | 3.1 (15) | 1.0 (5) | 1.9 (10) | 2.8 (15) |
| | | 4-Aminopyridine | | | | | | | |
| | | 2-Chloropyridine | | | | | | | |
| | Polymerizable | DPHA | 12.6 | 12.6 | | | | | |
| | compound | A-NOD-N | 25.0 | 25.0 | | | | | |
| | | DTMPT | | | 21.0 | 21.0 | 21.0 | 21.0 | 21.0 |
| | | A-DCP | | | | | | | |
| | | TMPT | | | 21.0 | 21.0 | 21.0 | 21.0 | 21.0 |
| | | SR601 | | | | | | | |
| | | KRM8904 | | | | | | | |
| | | KRM8452 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | B | A | A | B | A | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | B | A | A | B | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | B | A | A | B | A | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | B | A | A | B | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |

TABLE 49
Eighth table (11)

| | | | Mw of | pKa of | | | | |
|---|---|---|---|---|---|---|---|---|
| | | | polymer | Compound β | ε365 of | Example | | |
| | | | A | in ground state | Compound β | 6-171 | 6-172 | 6-173 |
| Solid | Polymer A | St/MAA/MMA/GMA-MAA = | 18000 | — | — | | 30 | 30 |
| content | | 47.7/19.0/1.3/32.0 (mass ratio) | | | | | | |
| blending | | CHMA/MAA/BzMA = | 24000 | — | — | | 30 | 30 |
| | | 49/19/32 (mass ratio) | | | | | | |
| | | St/AA/AA-GMA = | 16000 | — | — | 30 | | |
| | | 53.5/14.5/32 (mass ratio) | | | | | | |
| | | CHA/AA/HEA = | 40000 | — | — | 30 | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | 0.8 (5) | 1.9 (10) | 1.0 (5) |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | 0.9 (5) | 2.1 (10) | 3.1 (15) |
| | | 4-Aminopyridine | | 9.20 | <100 | | | |
| | | 2-Chloropyridine | | 0.70 | <10 | | | |
| | Polymerizable | DPHA | | — | — | | 12.0 | 12.0 |
| | compound | A-NOD-N | | — | — | | 12.0 | 12.0 |
| | | DTMPT | | — | — | 21.0 | 12.0 | 12.0 |
| | | A-DCP | | — | — | | | |
| | | TMPT | | — | — | 21.0 | 12.0 | 12.0 |
| | | SR601 | | — | — | | | |
| | | KRM8904 | | — | — | | | |
| | | KRM8452 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | B | A | A |
| of photo- | [measurement of ashing] | | | | | | | |
| sensitive | ε365/ε313 | | | — | — | <1 | <1 | <1 |
| material | Pattern | 25 μm | | — | — | B | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | B | A | A |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | B | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |

| | | | | | | | Comparative |
|---|---|---|---|---|---|---|---|
| | | | Example | | | | Example |
| | | | 6-174 | 6-175 | 6-176 | 6-177 | 6A |
| Solid | Polymer A | St/MAA/MMA/GMA-MAA = | 30 | | | | 60 |
| content | | 47.7/19.0/1.3/32.0 (mass ratio) | | | | | |
| blending | | CHMA/MAA/BzMA = | 30 | | | | |
| | | 49/19/32 (mass ratio) | | | | | |
| | | St/AA/AA-GMA = | | 30 | 30 | 30 | |
| | | 53.5/14.5/32 (mass ratio) | | | | | |
| | | CHA/AA/HEA = | | 30 | 30 | 30 | |
| | | 53.5/14.5/32 (mass ratio) | | | | | |
| | Compound | Isoquinoline | | | | | |
| | β (in | Quinoline | | | | | |
| | parentheses: | Acridine | | | | | |
| | molar ratio | 1-n-Butylisoquinoline | | | | | |
| | with respect | 1-n-Butyl-4-methylisoquinoline | | | | | |
| | to carboxy | 1-Me-isoquinoline | 1.0 (5) | 1.7 (10) | 0.8 (5) | 0.8 (5) | |
| | group of | 2,4,5,7-Tetramethylquinoline | | | | | |
| | polymer A | 2-Methyl-4-methoxyquinoline | | | | | |
| | having acid | 9-Methylacridine | | | | | |
| | group | 9-Phenylacridine | | | | | |
| | (mol %)) | Pyridine | | | | | |
| | | 2,4-Dimethylquinoline | 1.0 (5) | 1.9 (10) | 2.8 (15) | 0.9 (5) | |
| | | 4-Aminopyridine | | | | | |
| | | 2-Chloropyridine | | | | | |
| | Polymerizable | DPHA | 12.0 | 12.0 | 12.0 | 12.0 | 12.6 |
| | compound | A-NOD-N | 12.0 | 12.0 | 12.0 | 12.0 | 25.0 |
| | | DTMPT | 12.0 | 12.0 | 12.0 | 12.0 | |
| | | A-DCP | | | | | |
| | | TMPT | 12.0 | 12.0 | 12.0 | 12.0 | |
| | | SR601 | | | | | |
| | | KRM8904 | | | | | |
| | | KRM8452 | | | | | |
| | Surfactant | F551A | 0.1 | 0.1 | 0.1 | 0.1 | 0.1 |
| | | R41 | | | | | |
| | | 710FL | | | | | |
| Evaluation | Carboxy group consumption rate | | B | A | A | B | E |
| of photo- | [measurement of ashing] | | | | | | |
| sensitive | ε365/ε313 | | <1 | <1 | <1 | <1 | — |
| material | Pattern | 25 μm | B | A | A | B | D |
| | formability | 50 μm | A | A | A | A | D |
| | | 250 μm | A | A | A | A | D |

| | | | | | | |
|---|---|---|---|---|---|---|
| | Relative permittivity | A | A | A | A | Standard |
| | Change in relative permittivity | A | A | A | A | D |
| | before and after exposure | | | | | |
| Evaluation | Carboxy group consumption rate | B | A | A | B | E |
| of transfer | [measurement of ashing] | | | | | |
| film | ε365/ε313 | <1 | <1 | <1 | <1 | — |
| | Transmittance at 365 nm | A | A | A | A | A |
| | Transmittance at 365 nm/ | A | A | A | A | B |
| | transmittance at 313 nm | | | | | |
| | Laminate suitability | A | A | A | A | A |

| | | | | | | |
|---|---|---|---|---|---|---|
| Pattern | 25 μm | B | A | A | B | D |
| formability | 50 μm | A | A | A | A | D |
| | 250 μm | A | A | A | A | D |

| | | | | | |
|---|---|---|---|---|---|
| Relative permittivity | A | A | A | A | Standard |
| Change in relative permittivity | A | A | A | A | D |
| before and after exposure | | | | | |
| Moisture permeability | A | A | A | A | Standard |

(Polymer A)

Polymers 1 to 4 corresponding the polymer A were synthesized by the same method as in Example 4 system described above. Abbreviations for the monomer forming each structural unit of the polymers are as described above.

Polymer 1: St/MAA/MMA/GMA-MAA=47.7/19.0/1.3/32.0 (mass ratio)

Polymer 2: CHMA/MAA/BzMA=49/19/32 (mass ratio)

Polymer 3: St/AA/AA-GMA=53.5/14.5/32 (mass ratio)

Polymer 4: CHA/AA/HEA=53.5/14.5/32 (mass ratio)

As shown in Eighth table, the weight-average molecular weight of the polymer A shown in Eighth table was all in a range of 10,000 to 50,000.

(Polymerizable Compound)

DPHA: dipentaerythritol hexaacrylate (A-DPH manufactured by Shin-Nakamura Chemical Co., Ltd.)

A-NOD-N: 1,9-nonanediol diacrylate (A-NOD-N manufactured by Shin-Nakamura Chemical Co., Ltd.)

DTMPT: ditrimethylolpropane tetraacrylate (KAYARAD T-1420 (T) manufactured by Nippon Kayaku Co., Ltd.)

A-DCPP: dicyclopentane dimethanol diacrylate (A-DCP manufactured by Shin-Nakamura Chemical Co., Ltd.)

TMPT: trimethylolpropane triacrylate (A-TMPT manufactured by Shin-Nakamura Chemical Co., Ltd.)

SR601: ethoxylated (4) bisphenol A diacrylate (SR601 manufactured by TOMOE Engineering Co., Ltd.)

KRMR904: 9-functional aliphatic urethane acrylate (KRM8904 manufactured by Daicel-Allnex Ltd.)

KRM8452: 10-functional aliphatic urethane acrylate (KRM8452 manufactured by Daicel-Allnex Ltd.)

(Surfactant)

F551: MEGAFACE F551 (manufactured by DIC Corporation)

R41: MEGAFACE R-41 (manufactured by DIC Corporation)

710FL: FTERGENT 710FL (manufactured by NEOS COMPANY LIMITED)

From the results in the above tables, it was confirmed that, even in a case where the photosensitive material included a polymerizable compound, the objects of the present invention could be achieved with the transfer film according to the embodiment of the present invention.

### Example 7 System

<Preparation and Evaluation of Photosensitive Material>

Materials shown in Ninth table shown in the latter part were mixed and dissolved in a mixed solvent of propylene glycol monomethyl ether acetate/methyl ethyl ketone=50/50 (mass ratio) so that a blending ratio shown in Ninth table shown in the latter part was satisfied and a concentration of solid contents of the finally obtained photosensitive material was 25% by mass, thereby obtaining a photosensitive material.

In addition, for the obtained photosensitive material of each of Examples or Comparative Examples in Example 7 system, the carboxy group consumption rate, pattern formability of the photosensitive material, relative permittivity, and change in relative permittivity before and after exposure, and the laminate suitability of the transfer film, pattern formability, relative permittivity, change in relative permittivity before and after exposure, moisture permeability, and change in relative permittivity after double exposure were evaluated in the same manner as shown in Example 3 system. In addition, the carboxy group consumption rate, transmittance to light at 365 nm, and ratio of the transmittance to light at 365 nm to the transmittance to light at 313 nm of the photosensitive layer in the transfer film were also evaluated in the same manner as shown in Example 3 system. In addition, the physical properties of 365/313 of the compound β included in the photosensitive material and the photosensitive layer were evaluated in the same manner as shown in Example 1 system.

However, the standard of the reduction rate in the evaluation of the relative permittivity with regard to the photosensitive material and in the evaluation of the relative permittivity and moisture permeability with regard to the transfer film was the relative permittivity or the moisture permeability of Comparative Example 7A.

Ninth table below shows blending of the solid content of the photosensitive material of each of Examples and Comparative Examples in Example 7 system, and the test results thereof.

In the table, the value described in the column of “Solid content blending” indicates the content (part by mass) of each solid content component included in the photosensitive material of each of Examples or Comparative Examples. The value in parentheses in the compound β indicates a proportion (mol %) of the total number of structures (structures b0) included in the compound β, in which the amount of the carboxy group of the polymer A is reduced (preferably, structures (structures b) capable of accepting an electron from the carboxy group included in the polymer A in a photoexcited state) to the total number of carboxy groups included in the polymer A in the photosensitive material.

In addition, in the tables, the method for measuring “pKa of compound β in ground state” is as described above.

In addition, in the tables, the column of “ε365 of compound β” indicates a molar absorption coefficient ((cm·mol/L)⁻¹) of the compound β to light having a wavelength of 365 nm in acetonitrile.

In addition, the column of “ε365/ε313” in the evaluation of the photosensitive material and the evaluation of the transfer film indicates a value obtained by dividing the molar absorption coefficient ((cm·mol/L)⁻¹) of the compound 3 to light having a wavelength of 365 nm by a molar absorption coefficient ((cm·mol/L)⁻¹) of the compound β to light having a wavelength of 313 nm. All molar absorption coefficients are values in acetonitrile.

In addition, the column of “Transmittance at 365 nm” in the evaluation of the transfer film indicates the transmittance of the photosensitive layer to light having a wavelength of 365 nm.

In addition, the column of “Transmittance at 365 nm/transmittance at 313 nm” in the evaluation of the transfer film indicates a value obtained by dividing the transmittance of the photosensitive layer to light having a wavelength of 365 nm by the transmittance of the photosensitive layer to light having a wavelength of 313 nm.

TABLE 50
Ninth table (1)

| | | | Mw of | pKa of | | | | |
|---|---|---|---|---|---|---|---|---|
| | | | polymer | Compound β | ε365 of | Example | | |
| | | | A | in ground state | Compound β | 7-1 | 7-2 | 7-3 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | 3.5 (20) | | |
| | β (in | Quinoline | | 4.15 | <10 | | 3.5 (20) | |
| | parentheses: | Acridine | | 4.67 | 4900 | | | 4.9 (20) |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | B | B | D |
| of photo- | [measurement of ashing] | | | | | | | |
| sensitive | ε365/ε313 | | | — | — | <1 | <1 | >3 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | B |
| | Change in relative permittivity | | | — | — | A | A | B |
| | before and after exposure | | | | | | | |
| Evaluation | Carboxy group consumption rate | | | — | — | B | B | D |
| of transfer | [measurement of ashing] | | | | | | | |
| film | ε365/ε313 | | | — | — | <1 | <1 | >3 |
| | Transmittance at 365 nm | | | — | — | A | A | C |
| | Transmittance at 365 nm/ | | | — | — | A | A | C |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | B |
| Change in relative permittivity | — | — | A | A | B |
| before and after exposure | | | | | |
| Moisture permeability | — | — | A | B | B |
| Change in relative permittivity | — | — | A | A | B |
| after double exposure | | | | | |

Example

| | | | 7-4 | 7-5 | 7-6 | 7-7 | 7-8 | 7-9 | 7-10 |
|---|---|---|---|---|---|---|---|---|---|
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | 5.0 (20) | | | | | | |
| | with respect | 1-n-Butyl-4-methylisoquinoline | | 5.4 (20) | | | | | |
| | to carboxy | 1-Me-isoquinoline | | | 3.9 (20) | | | | |
| | group of | 2,4,5,7-Tetramethylquinoline | | | | 5.0 (20) | | | |
| | polymer A | 2-Methyl-4-methoxyquinoline | | | | | 4.7 (20) | | |
| | having acid | 9-Methylacridine | | | | | | 5.2 (20) | |
| | group | 9-Phenylacridine | | | | | | | 6.9 (20) |
| | (mol %)) | Pyridine | | | | | | | |
| | | 2,4-Dimethylquinoline | | | | | | | |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | A | A | A | C | D |
| of photo- | [measurement of ashing] | | | | | | | | |
| sensitive | ε365/ε313 | | <1 | <1 | <1 | <1 | <1 | >3 | >3 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | B | C |
| | Change in relative permittivity | | A | A | A | A | A | B | C |
| | before and after exposure | | | | | | | | |
| Evaluation | Carboxy group consumption rate | | A | A | A | A | A | C | D |
| of transfer | [measurement of ashing] | | | | | | | | |
| film | ε365/ε313 | | <1 | <1 | <1 | <1 | <1 | >3 | >3 |
| | Transmittance at 365 nm | | A | A | A | A | A | C | C |
| | Transmittance at 365 nm/ | | A | A | A | A | A | C | C |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | B | C |
| | Change in relative permittivity | | A | A | A | A | A | B | C |
| | before and after exposure | | | | | | | | |
| | Moisture permeability | | A | A | A | A | A | B | B |
| | Change in relative permittivity | | A | A | A | A | A | B | C |
| | after double exposure | | | | | | | | |
| | | | Example | | | | | | |
| | | | 7-11 | 7-12 | 7-13 | 7-14 | 7-15 | 7-16 | 7-17 |
| Solid | Polymer A | St/MAA/MMA/GMA-MAA = | 60 | 60 | 60 | 60 | 60 | | |
| content | | 47.7/19.0/1.3/32.0 (mass ratio) | | | | | | | |
| blending | | CHMA/MAA/BzMA = | | | | | | 60 | 60 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | 3.5 (20) | |
| | β (in | Quinoline | | | | | | | 3.5 (20) |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | | | | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | 2.1 (20) | | | | | | |
| | | 2,4-Dimethylquinoline | | 4.3 (20) | 2.1 (10) | | | | |
| | | 4-Aminopyridine | | | | 2.6 (20) | | | |
| | | 2-Chloropyridine | | | | | 3.1 (20) | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | D | A | B | D | D | B | B |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | C | A | A | C | C | A | A |
| | Change in relative permittivity | | C | A | A | C | C | A | A |
| | before and after exposure | | | | | | | | |
| Evaluation | Carboxy group consumption rate | | D | A | B | D | D | B | B |
| of transfer | [measurement of ashing] | | | | | | | | |
| film | ε365/ε313 | | <1 | <1 | <1 | <1 | <1 | <1 | <1 |
| | Transmittance at 365 nm | | B | A | A | B | B | A | A |
| | Transmittance at 365 nm/ | | B | A | A | B | B | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | C | A | A | C | C | A | A |
| Change in relative permittivity | C | A | A | C | C | A | A |
| before and after exposure | | | | | | | |
| Moisture permeability | B | A | A | C | C | A | B |
| Change in relative permittivity | C | A | A | C | C | A | A |
| after double exposure | | | | | | | |

TABLE 51
Ninth table (2)

| | | | Mw of | pKa of | | | | |
|---|---|---|---|---|---|---|---|---|
| | | | polymer | Compound β | ε365 of | Example | | |
| | | | A | in ground state | Compound β | 7-18 | 7-19 | 7-20 |
| Solid | Polymer A | St/MAA/MMA/GMA-MAA = | 18000 | — | — | | | |
| content | | 47.7/19.0/1.3/32.0 (mass ratio) | | | | | | |
| blending | | CHMA/MAA/BzMA = | 24000 | — | — | 60 | 60 | 60 |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | 4.9 (20) | | |
| | molar ratio | 1-n-Butylisoquinoline | | 5.27 | <10 | | 5.0 (20) | |
| | with respect | 1-n-Butyl-4-methylisoquinoline | | 5.9 | <10 | | | 5.4 (20) |
| | to carboxy | 1-Me-isoquinoline | | 5.31 | <10 | | | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | D | A | A |
| of photo- | [measurement of ashing] | | | | | | | |
| sensitive | ε365/ε313 | | | — | — | >3 | <1 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | B | A | A |
| | Change in relative permittivity | | | — | — | B | A | A |
| | before and after exposure | | | | | | | |
| Evaluation | Carboxy group consumption rate | | | — | — | D | A | A |
| of transfer | [measurement of ashing] | | | | | | | |
| film | ε365/ε313 | | | — | — | >3 | <1 | <1 |
| | Transmittance at 365 nm | | | — | — | C | A | A |
| | Transmittance at 365 nm/ | | | — | — | C | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | B | A | A |
| Change in relative permittivity | — | — | B | A | A |
| before and after exposure | | | | | |
| Moisture permeability | — | — | B | A | A |
| Change in relative permittivity | — | — | B | A | A |
| after double exposure | | | | | |

Example

| | | | 7-21 | 7-22 | 7-23 | 7-24 | 7-25 | 7-26 | 7-27 |
|---|---|---|---|---|---|---|---|---|---|
| Solid | Polymer A | St/MAA/MMA/GMA-MAA = | | | | | | | |
| content | | 47.7/19.0/1.3/32.0 (mass ratio) | | | | | | | |
| blending | | CHMA/MAA/BzMA = | 60 | 60 | 60 | 60 | 60 | 60 | 60 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 3.9 (20) | | | | | | |
| | group of | 2,4,5,7-Tetramethylquinoline | | 5.0 (20) | | | | | |
| | polymer A | 2-Methyl-4-methoxyquinoline | | | 4.7 (20) | | | | |
| | having acid | 9-Methylacridine | | | | 5.2 (20) | | | |
| | group | 9-Phenylacridine | | | | | 6.9 (20) | | |
| | (mol %)) | Pyridine | | | | | | 2.1 (20) | |
| | | 2,4-Dimethylquinoline | | | | | | | 4.3 (20) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | A | C | D | D | A |
| of photo- | [measurement of ashing] | | | | | | | | |
| sensitive | ε365/ε313 | | <1 | <1 | <1 | >3 | >3 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | B | C | C | A |
| | Change in relative permittivity | | A | A | A | B | C | C | A |
| | before and after exposure | | | | | | | | |
| Evaluation | Carboxy group consumption rate | | A | A | A | C | D | D | A |
| of transfer | [measurement of ashing] | | | | | | | | |
| film | ε365/ε313 | | <1 | <1 | <1 | >3 | >3 | <1 | <1 |
| | Transmittance at 365 nm | | A | A | A | C | C | B | A |
| | Transmittance at 365 nm/ | | A | A | A | C | C | B | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | B | C | C | A |
| | Change in relative permittivity | | A | A | A | B | C | C | A |
| | before and after exposure | | | | | | | | |
| | Moisture permeability | | A | A | A | B | B | B | A |
| | Change in relative permittivity | | A | A | A | B | C | C | A |
| | after double exposure | | | | | | | | |
| | | | Example | | | | | | |
| | | | 7-28 | 7-29 | 7-30 | 7-31 | 7-32 | 7-33 | 7-34 |
| Solid | Polymer A | St/MAA/MMA/GMA-MAA = | | | | | | | |
| content | | 47.7/19.0/1.3/32.0 (mass ratio) | | | | | | | |
| blending | | CHMA/MAA/BzMA = | 60 | 60 | 60 | | | | |
| | | 49/19/32 (mass ratio) | | | | | | | |
| | | St/AA/AA-GMA = | | | | 60 | 60 | 60 | 60 |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | 3.1 (20) | | | |
| | β (in | Quinoline | | | | | 3.1 (20) | | |
| | parentheses: | Acridine | | | | | | 4.3 (20) | |
| | molar ratio | 1-n-Butylisoquinoline | | | | | | | 4.5 (20) |
| | with respect | 1-n-Butyl-4-methylisoquinoline | | | | | | | |
| | to carboxy | 1-Me-isoquinoline | | | | | | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 2.1 (10) | | | | | | |
| | | 4-Aminopyridine | | 2.6 (20) | | | | | |
| | | 2-Chloropyridine | | | 3.1 (20) | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | B | D | D | B | B | D | A |
| of photo- | [measurement of ashing] | | | | | | | | |
| sensitive | ε365/ε313 | | <1 | <1 | <1 | <1 | <1 | >3 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | C | C | A | A | B | A |
| | Change in relative permittivity | | A | C | C | A | A | B | A |
| | before and after exposure | | | | | | | | |
| Evaluation | Carboxy group consumption rate | | B | D | D | B | B | D | A |
| of transfer | [measurement of ashing] | | | | | | | | |
| film | ε365/ε313 | | <1 | <1 | <1 | <1 | <1 | >3 | <1 |
| | Transmittance at 365 nm | | A | B | B | A | A | C | A |
| | Transmittance at 365 nm/ | | A | B | B | A | A | C | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | C | C | A | A | B | A |
| Change in relative permittivity | A | C | C | A | A | B | A |
| before and after exposure | | | | | | | |
| Moisture permeability | A | C | C | A | B | B | A |
| Change in relative permittivity | A | C | C | A | A | B | A |
| after double exposure | | | | | | | |

TABLE 52
Ninth table (3)

| | | | Mw of | pKa of | | | | |
|---|---|---|---|---|---|---|---|---|
| | | | polymer | Compound β | ε365 of | Example | | |
| | | | A | in ground state | Compound β | 7-35 | 7-36 | 7-37 |
| Solid | Polymer A | St/MAA/MMA/GMA-MAA = | 18000 | — | — | | | |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | 60 | 60 | 60 |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | 4.8 (20) | | |
| | to carboxy | 1-Me-isoquinoline | | 5.31 | <10 | | 3.5 (20) | |
| | group of | 2,4,5,7-Tetramethylquinoline | | 6.23 | <10 | | | 4.5 (20) |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | A | A | A |
| of photo- | [measurement of ashing] | | | | | | | |
| sensitive | ε365/ε313 | | | — | — | <1 | <1 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | A | A | A |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

Example

| | | | 7-38 | 7-39 | 7-40 | 7-41 | 7-42 | 7-43 | 7-44 |
|---|---|---|---|---|---|---|---|---|---|
| Solid | Polymer A | St/MAA/MMA/GMA-MAA = | | | | | | | |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | 60 | 60 | 60 | 60 | 60 | 60 | 60 |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | | | | | |
| | group of | 2,4,5,7-Tetramethylquinoline | | | | | | | |
| | polymer A | 2-Methyl-4-methoxyquinoline | 4.2 (20) | | | | | | |
| | having acid | 9-Methylacridine | | 4.7 (20) | | | | | |
| | group | 9-Phenylacridine | | | 6.2 (20) | | | | |
| | (mol %)) | Pyridine | | | | 1.9 (20) | | | |
| | | 2,4-Dimethylquinoline | | | | | 3.8 (20) | 1.9 (10) | |
| | | 4-Aminopyridine | | | | | | | 2.3 (20) |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | C | D | D | A | B | D |
| of photo- | [measurement of ashing] | | | | | | | | |
| sensitive | ε365/ε313 | | <1 | >3 | >3 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | B | C | C | A | A | C |
| | Change in relative permittivity | | A | B | C | C | A | A | C |
| | before and after exposure | | | | | | | | |
| Evaluation | Carboxy group consumption rate | | A | C | D | D | A | B | D |
| of transfer | [measurement of ashing] | | | | | | | | |
| film | ε365/ε313 | | <1 | >3 | >3 | <1 | <1 | <1 | <1 |
| | Transmittance at 365 nm | | A | C | C | B | A | A | B |
| | Transmittance at 365 nm/ | | A | C | C | B | A | A | B |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | B | C | C | A | A | C |
| | Change in relative permittivity | | A | B | C | C | A | A | C |
| | before and after exposure | | | | | | | | |
| | Moisture permeability | | A | B | B | B | A | A | C |
| | Change in relative permittivity | | A | B | C | C | A | A | C |
| | after double exposure | | | | | | | | |
| | | | Example | | | | | | |
| | | | 7-45 | 7-46 | 7-47 | 7-48 | 7-49 | 7-50 | 7-51 |
| Solid | Polymer A | St/MAA/MMA/GMA-MAA = | | | | | | | |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | 60 | | | | | | |
| | | 53.5/14.5/32 (mass ratio) | | | | | | | |
| | | CHA/AA/HEA = | | 60 | 60 | 60 | 60 | 60 | 60 |
| | | 53.5/14.5/32 (mass ratio) | | | | | | | |
| | Compound | Isoquinoline | | 3.1 (20) | | | | | |
| | β (in | Quinoline | | | 3.1 (20) | | | | |
| | parentheses: | Acridine | | | | 4.3 (20) | | | |
| | molar ratio | 1-n-Butylisoquinoline | | | | | 4.5 (20) | | |
| | with respect | 1-n-Butyl-4-methylisoquinoline | | | | | | 4.8 (20) | |
| | to carboxy | 1-Me-isoquinoline | | | | | | | 3.5 (20) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | | | | | | | |
| | | 4-Aminopyridine | | | | | | | |
| | | 2-Chloropyridine | 2.7 (20) | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | D | B | B | D | A | A | A |
| of photo- | [measurement of ashing] | | | | | | | | |
| sensitive | ε365/ε313 | | <1 | <1 | <1 | >3 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | C | A | A | B | A | A | A |
| | Change in relative permittivity | | C | A | A | B | A | A | A |
| | before and after exposure | | | | | | | | |
| Evaluation | Carboxy group consumption rate | | D | B | B | D | A | A | A |
| of transfer | [measurement of ashing] | | | | | | | | |
| film | ε365/ε313 | | <1 | <1 | <1 | >3 | <1 | <1 | <1 |
| | Transmittance at 365 nm | | B | A | A | C | A | A | A |
| | Transmittance at 365 nm/ | | B | A | A | C | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | C | A | A | B | A | A | A |
| Change in relative permittivity | C | A | A | B | A | A | A |
| before and after exposure | | | | | | | |
| Moisture permeability | C | A | B | B | A | A | A |
| Change in relative permittivity | C | A | A | B | A | A | A |
| after double exposure | | | | | | | |

TABLE 53
Ninth table (4)

| | | | Mw of | pKa of | | | | |
|---|---|---|---|---|---|---|---|---|
| | | | polymer | Compound β | ε365 of | Example | | |
| | | | A | in ground state | Compound β | 7-52 | 7-53 | 7-54 |
| Solid | Polymer A | St/MAA/MMA/GMA-MAA = | 18000 | — | — | | | |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | 60 | 60 | 60 |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | | |
| | group of | 2,4,5,7-Tetramethylquinoline | | 6.23 | <10 | 4.5 (20) | | |
| | polymer A | 2-Methyl-4-methoxyquinoline | | 6.51 | <10 | | 4.2 (20) | |
| | having acid | 9-Methylacridine | | 5.4 | 6300 | | | 4.7 (20) |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | A | A | C |
| of photo- | [measurement of ashing] | | | | | | | |
| sensitive | ε365/ε313 | | | — | — | <1 | <1 | >3 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | B |
| | Change in relative permittivity | | | — | — | A | A | B |
| | before and after exposure | | | | | | | |
| Evaluation | Carboxy group consumption rate | | | — | — | A | A | C |
| of transfer | [measurement of ashing] | | | | | | | |
| film | ε365/ε313 | | | — | — | <1 | <1 | >3 |
| | Transmittance at 365 nm | | | — | — | A | A | C |
| | Transmittance at 365 nm/ | | | — | — | A | A | C |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | B |
| Change in relative permittivity | — | — | A | A | B |
| before and after exposure | | | | | |
| Moisture permeability | — | — | A | A | B |
| Change in relative permittivity | — | — | A | A | B |
| after double exposure | | | | | |

Example

| | | | 7-55 | 7-56 | 7-57 | 7-58 | 7-59 | 7-60 | 7-61 |
|---|---|---|---|---|---|---|---|---|---|
| Solid | Polymer A | St/MAA/MMA/GMA-MAA = | | | | | | | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | 60 | 60 | 60 | 60 | 60 | 60 | |
| | | 53.5/14.5/32 (mass ratio) | | | | | | | |
| | Compound | Isoquinoline | | | | | | | 3.5 (20) |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | | | | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | 6.2 (20) | | | | | | |
| | (mol %)) | Pyridine | | 1.9 (20) | | | | | |
| | | 2,4-Dimethylquinoline | | | 3.8 (20) | 1.9 (10) | | | |
| | | 4-Aminopyridine | | | | | 2.3 (20) | | |
| | | 2-Chloropyridine | | | | | | 2.7 (20) | |
| | Polymerizable | DPHA | 12.6 | 12.6 | 12.6 | 12.6 | 12.6 | 12.6 | |
| | compound | A-NOD-N | 25.0 | 25.0 | 25.0 | 25.0 | 25.0 | 25.0 | |
| | | DTMPT | | | | | | | 18.8 |
| | | A-DCP | | | | | | | |
| | | TMPT | | | | | | | 18.8 |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | D | D | A | B | D | D | B |
| of photo- | [measurement of ashing] | | | | | | | | |
| sensitive | ε365/ε313 | | >3 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | C | C | A | A | C | C | A |
| | Change in relative permittivity | | C | C | A | A | C | C | A |
| | before and after exposure | | | | | | | | |
| Evaluation | Carboxy group consumption rate | | D | D | A | B | D | D | B |
| of transfer | [measurement of ashing] | | | | | | | | |
| film | ε365/ε313 | | >3 | <1 | <1 | <1 | <1 | <1 | <1 |
| | Transmittance at 365 nm | | C | B | A | A | B | B | A |
| | Transmittance at 365 nm/ | | C | B | A | A | B | B | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | C | C | A | A | C | C | A |
| | Change in relative permittivity | | C | C | A | A | C | C | A |
| | before and after exposure | | | | | | | | |
| | Moisture permeability | | B | B | A | A | C | C | A |
| | Change in relative permittivity | | C | C | A | A | C | C | A |
| | after double exposure | | | | | | | | |
| | | | Example | | | | | | |
| | | | 7-62 | 7-63 | 7-64 | 7-65 | 7-66 | 7-67 | 7-68 |
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | 3.5 (20) | | | | | | |
| | parentheses: | Acridine | | 4.9 (20) | | | | | |
| | molar ratio | 1-n-Butylisoquinoline | | | 5.0 (20) | | | | |
| | with respect | 1-n-Butyl-4-methylisoquinoline | | | | 5.4 (20) | | | |
| | to carboxy | 1-Me-isoquinoline | | | | | 3.9 (20) | | |
| | group of | 2,4,5,7-Tetramethylquinoline | | | | | | 5.0 (20) | |
| | polymer A | 2-Methyl-4-methoxyquinoline | | | | | | | 4.7 (20) |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | | | | | | | |
| | | 4-Aminopyridine | | | | | | | |
| | | 2-Chloropyridine | | | | | | | |
| | Polymerizable | DPHA | | | | | | | |
| | compound | A-NOD-N | | | | | | | |
| | | DTMPT | 18.8 | 18.8 | 18.8 | 18.8 | 18.8 | 18.8 | 18.8 |
| | | A-DCP | | | | | | | |
| | | TMPT | 18.8 | 18.8 | 18.8 | 18.8 | 18.8 | 18.8 | 18.8 |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | B | D | A | A | A | A | A |
| of photo- | [measurement of ashing] | | | | | | | | |
| sensitive | ε365/ε313 | | <1 | >3 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | B | A | A | A | A | A |
| | Change in relative permittivity | | A | B | A | A | A | A | A |
| | before and after exposure | | | | | | | | |
| Evaluation | Carboxy group consumption rate | | B | D | A | A | A | A | A |
| of transfer | [measurement of ashing] | | | | | | | | |
| film | ε365/ε313 | | <1 | >3 | <1 | <1 | <1 | <1 | <1 |
| | Transmittance at 365 nm | | A | C | A | A | A | A | A |
| | Transmittance at 365 nm/ | | A | C | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | B | A | A | A | A | A |
| Change in relative permittivity | A | B | A | A | A | A | A |
| before and after exposure | | | | | | | |
| Moisture permeability | B | B | A | A | A | A | A |
| Change in relative permittivity | A | B | A | A | A | A | A |
| after double exposure | | | | | | | |

TABLE 54
Ninth table (5)

| | | | Mw of | pKa of | | | | |
|---|---|---|---|---|---|---|---|---|
| | | | polymer | Compound β | ε365 of | Example | | |
| | | | A | in ground state | Compound β | 7-69 | 7-70 | 7-71 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | 5.2 (20) | | |
| | group | 9-Phenylacridine | | 4.04 | >10000 | | 6.9 (20) | |
| | (mol %)) | Pyridine | | 5.25 | <10 | | | 2.1 (20) |
| | | 2,4-Dimethylquinoline | | 5.67 | <10 | | | |
| | | 4-Aminopyridine | | 9.20 | <100 | | | |
| | | 2-Chloropyridine | | 0.70 | <10 | | | |
| | Polymerizable | DPHA | | — | — | | | |
| | compound | A-NOD-N | | — | — | | | |
| | | DTMPT | | — | — | 18.8 | 18.8 | 18.8 |
| | | A-DCP | | — | — | | | |
| | | TMPT | | — | — | 18.8 | 18.8 | 18.8 |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | C | D | D |
| of photo- | [measurement of ashing] | | | | | | | |
| sensitive | ε365/ε313 | | | — | — | >3 | >3 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | B | C | C |
| | Change in relative permittivity | | | — | — | B | C | C |
| | before and after exposure | | | | | | | |
| Evaluation | Carboxy group consumption rate | | | — | — | C | D | D |
| of transfer | [measurement of ashing] | | | | | | | |
| film | ε365/ε313 | | | — | — | >3 | >3 | <1 |
| | Transmittance at 365 nm | | | — | — | C | C | B |
| | Transmittance at 365 nm/ | | | — | — | C | C | B |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | B | C | C |
| Change in relative permittivity | — | — | B | C | C |
| before and after exposure | | | | | |
| Moisture permeability | — | — | B | B | B |
| Change in relative permittivity | — | — | B | C | C |
| after double exposure | | | | | |

Example

| | | | 7-72 | 7-73 | 7-74 | 7-75 | 7-76 | 7-77 | 7-78 |
|---|---|---|---|---|---|---|---|---|---|
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | | | 3.9 (20) | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 4.3 (20) | 2.1 (10) | | | | 4.3 (20) | 2.1 (10) |
| | | 4-Aminopyridine | | | 2.6 (20) | | | | |
| | | 2-Chloropyridine | | | | 3.1 (20) | | | |
| | Polymerizable | DPHA | | | | | | | |
| | compound | A-NOD-N | | | | | | | |
| | | DTMPT | 18.8 | 18.8 | 18.8 | 18.8 | | | |
| | | A-DCP | | | | | 25.0 | 25.0 | 25.0 |
| | | TMPT | 18.8 | 18.8 | 18.8 | 18.8 | 12.6 | 12.6 | 12.6 |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | B | D | D | A | A | B |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | C | C | A | A | A |
| | Change in relative permittivity | | A | A | C | C | A | A | A |
| | before and after exposure | | | | | | | | |
| Evaluation | Carboxy group consumption rate | | A | B | D | D | A | A | B |
| of transfer | [measurement of ashing] | | | | | | | | |
| film | ε365/ε313 | | <1 | <1 | <1 | <1 | <1 | <1 | <1 |
| | Transmittance at 365 nm | | A | A | B | B | A | A | A |
| | Transmittance at 365 nm/ | | A | A | B | B | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | C | C | A | A | A |
| Change in relative permittivity | A | A | C | C | A | A | A |
| before and after exposure | | | | | | | |
| Moisture permeability | A | A | C | C | A | A | A |
| Change in relative permittivity | A | A | C | C | A | A | A |
| after double exposure | | | | | | | |

| | | | Example | | | | | | |
|---|---|---|---|---|---|---|---|---|---|
| | | | 7-79 | 7-80 | 7-81 | 7-82 | 7-83 | 7-84 | 7-85 |
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 3.9 (20) | | | | 3.9 (20) | | 3.9 (20) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | | 4.3 (20) | 2.1 (10) | | 4.3 (20) | 2.1 (10) | |
| | | 4-Aminopyridine | | | | | | | |
| | | 2-Chloropyridine | | | | | | | |
| | Polymerizable | DPHA | | | | | | | 12.6 |
| | compound | A-NOD-N | | | | 12.6 | 12.6 | 12.6 | 12.6 |
| | | DTMPT | 12.6 | 12.6 | 12.6 | | | | 12.6 |
| | | A-DCP | 12.6 | 12.6 | 12.6 | 12.6 | 12.6 | 12.6 | |
| | | TMPT | 12.6 | 12.6 | 12.6 | 12.6 | 12.6 | 12.6 | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | B | A | A | B | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |

| | | | | | | | | |
|---|---|---|---|---|---|---|---|---|
| | Relative permittivity | A | A | A | A | A | A | A |
| | Change in relative permittivity | A | A | A | A | A | A | A |
| | before and after exposure | | | | | | | |
| Evaluation | Carboxy group consumption rate | A | A | B | A | A | B | A |
| of transfer | [measurement of ashing] | | | | | | | |
| film | ε365/ε313 | <1 | <1 | <1 | <1 | <1 | <1 | <1 |
| | Transmittance at 365 nm | A | A | A | A | A | A | A |
| | Transmittance at 365 nm/ | A | A | A | A | A | A | A |
| | transmittance at 313 nm | | | | | | | |
| | Laminate suitability | A | A | A | A | A | A | A |

| | | | | | | | | |
|---|---|---|---|---|---|---|---|---|
| Pattern | 25 μm | A | A | A | A | A | A | A |
| formability | 50 μm | A | A | A | A | A | A | A |
| | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 55
Ninth table (6)

| | | | Mw of | pKa of | | | | |
|---|---|---|---|---|---|---|---|---|
| | | | polymer | Compound β | ε365 of | Example | | |
| | | | A | in ground state | Compound β | 7-86 | 7-87 | 7-88 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | | 3.9 (20) |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | 4.3 (20) | 2.1 (10) | |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 12.6 | 12.6 | 12.6 |
| | | DTMPT | | — | — | 12.6 | 12.6 | |
| | | A-DCP | | — | — | | | |
| | | TMPT | | — | — | | | |
| | | SR601 | | — | — | | | 12.6 |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | A | B | A |
| of photo- | [measurement of ashing] | | | | | | | |
| sensitive | ε365/ε313 | | | — | — | <1 | <1 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | A | B | A |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

Example

| | | | 7-89 | 7-90 | 7-91 | 7-92 | 7-93 | 7-94 | 7-95 |
|---|---|---|---|---|---|---|---|---|---|
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | 3.9 (20) | | | 3.9 (20) | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 4.3 (20) | 2.1 (10) | | 4.3 (20) | 2.1 (10) | | 4.3 (20) |
| | | 4-Aminopyridine | | | | | | | |
| | | 2-Chloropyridine | | | | | | | |
| | Polymerizable | DPHA | 12.6 | 12.6 | | | | | |
| | compound | A-NOD-N | 12.6 | 12.6 | 12.6 | 12.6 | 12.6 | 12.6 | 12.6 |
| | | DTMPT | | | 12.6 | 12.6 | 12.6 | 12.6 | 12.6 |
| | | A-DCP | | | | | | | |
| | | TMPT | | | | | | | |
| | | SR601 | 12.6 | 12.6 | | | | | |
| | | KRM8904 | | | 12.6 | 12.6 | 12.6 | | |
| | | KRM8452 | | | | | | 12.6 | 12.6 |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | B | A | A | B | A | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | B | A | A | B | A | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | Change in relative permittivity | | A | A | A | A | A | A | A |
| | after double exposure | | | | | | | | |
| | | | Example | | | | | | |
| | | | 7-96 | 7-97 | 7-98 | 7-99 | 7-100 | 7-101 | 7-102 |
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | 3.9 (20) | | | 3.9 (20) | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 2.1 (10) | | 4.3 (20) | 2.1 (10) | | 4.3 (20) | 2.1 (10) |
| | | 4-Aminopyridine | | | | | | | |
| | | 2-Chloropyridine | | | | | | | |
| | Polymerizable | DPHA | | 12.6 | 12.6 | 12.6 | 12.6 | 12.6 | 12.6 |
| | compound | A-NOD-N | 12.6 | 25.0 | 25.0 | 25.0 | 25.0 | 25.0 | 25.0 |
| | | DTMPT | 12.6 | | | | | | |
| | | A-DCP | | | | | | | |
| | | TMPT | | | | | | | |
| | | SR601 | | | | | | | |
| | | KRM8904 | | | | | | | |
| | | KRM8452 | 12.6 | | | | | | |
| | Photopolymerization | Omn379 | 0.8 | 0.8 | 0.8 | 0.8 | 0.8 | 0.8 | 0.8 |
| | initiator | Oxe02 | | | | | | | |
| | | Api307 | | | | | | | |
| | Surfactant | F551A | 0.1 | | | | 0.2 | 0.2 | 0.2 |
| | | R41 | | | | | | | |
| | | 710FL | | | | | | | |
| Evaluation | Carboxy group consumption rate | | B | A | A | B | A | A | B |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | B | A | A | B | A | A | B |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 56
Ninth table (7)

| | | | Mw of | pKa of | | | | |
|---|---|---|---|---|---|---|---|---|
| | | | polymer | Compound β | ε365 of | Example | | |
| | | | A | in ground state | Compound β | 7-103 | 7-104 | 7-105 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | 3.9 (20) | | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | | 4.3 (20) | 2.1 (10) |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.5 | 0.5 | 0.5 |
| | | R41 | | — | — | | | |
| | | 710FL | | — | — | | | |
| Evaluation | Carboxy group consumption rate | | | — | — | A | A | B |
| of photo- | [measurement of ashing] | | | | | | | |
| sensitive | ε365/ε313 | | | — | — | <1 | <1 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | A | A | B |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

Example

| | | | 7-106 | 7-107 | 7-108 | 7-109 | 7-110 | 7-111 | 7-112 |
|---|---|---|---|---|---|---|---|---|---|
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 3.9 (20) | | | 3.9 (20) | | | 3.9 (20) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | | 4.3 (20) | 2.1 (10) | | 4.3 (20) | 2.1 (10) | |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.8 | 0.8 | |
| | initiator | Oxe02 | | | | | | | 0.8 |
| | | Api307 | | | | | | | |
| | Surfactant | F551A | | | | | | | |
| | | R41 | 0.1 | 0.1 | 0.1 | | | | |
| | | 710FL | | | | 0.1 | 0.1 | 0.1 | 0.1 |
| Evaluation | Carboxy group consumption rate | | A | A | B | A | A | B | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | A | B | A | A | B | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | Change in relative permittivity | | A | A | A | A | A | A | A |
| | after double exposure | | | | | | | | |
| | | | Example | | | | | | |
| | | | 7-113 | 7-114 | 7-115 | 7-116 | 7-117 | 7-118 | 7-119 |
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | 3.9 (20) | | | 3.9 (20) | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 4.3 (20) | 2.1 (10) | | 4.3 (20) | 2.1 (10) | | 4.3 (20) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | | | 0.8 | 0.8 | 0.8 | | |
| | initiator | Oxe02 | 0.8 | 0.8 | | | | 0.8 | 0.8 |
| | | Api307 | | | 1.5 | 1.5 | 1.5 | 1.5 | 1.5 |
| | Surfactant | F551A | | | | | | | |
| | | R41 | | | | | | | |
| | | 710FL | 0.1 | 0.1 | 0.1 | 0.1 | 0.1 | 0.1 | 0.1 |
| Evaluation | Carboxy group consumption rate | | A | B | A | A | B | A | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | B | A | A | B | A | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 57
Ninth table (8)

| | | | Mw of | pKa of | | | | |
|---|---|---|---|---|---|---|---|---|
| | | | polymer | Compound β | ε365 of | Example | | |
| | | | A | in ground state | Compound β | 7-120 | 7-121 | 7-122 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | 3.9 (20) | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | 2.1 (10) | | 4.3 (20) |
| | | 4-Aminopyridine | | 9.20 | <100 | | | |
| | | 2-Chloropyridine | | 0.70 | <10 | | | |
| | Polymerizable | DPHA | | — | — | 12.6 | 10.0 | 10.0 |
| | compound | A-NOD-N | | — | — | 25.0 | 20.0 | 20.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | | 0.8 | 0.8 |
| | initiator | Oxe02 | | — | — | 0.8 | | |
| | | Api307 | | — | — | 1.5 | | |
| | Surfactant | F551A | | — | — | | 0.1 | 0.1 |
| | | R41 | | — | — | | | |
| | | 710FL | | — | — | 0.1 | | |
| Evaluation | Carboxy group consumption rate | | | — | — | B | A | A |
| of photo- | [measurement of ashing] | | | | | | | |
| sensitive | ε365/ε313 | | | — | — | <1 | <1 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | B | A | A |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

Example

| | | | 7-123 | 7-124 | 7-125 | 7-126 | 7-127 | 7-128 | 7-129 |
|---|---|---|---|---|---|---|---|---|---|
| Solid | Polymer A | St/MAA/MMA/GMA-MAA = | 60 | 60 | 60 | 60 | 60 | 60 | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | | | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | 3.9 (20) | | | 3.9 (20) | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 2.1 (10) | | 4.3 (20) | 2.1 (10) | | 4.3 (20) | 2.1 (10) |
| | | 4-Aminopyridine | | | | | | | |
| | | 2-Chloropyridine | | | | | | | |
| | Polymerizable | DPHA | 10.0 | 14.0 | 14.0 | 14.0 | 28.0 | 28.0 | 28.0 |
| | compound | A-NOD-N | 20.0 | 28.0 | 28.0 | 28.0 | 14.0 | 14.0 | 14.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.8 | 0.9 | 0.9 | 0.9 | 0.9 | 0.9 | 0.9 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | B | A | A | B | A | A | B |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | B | A | A | B | A | A | B |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

| | | | Example | | | | | |
|---|---|---|---|---|---|---|---|---|
| | | | 7-130 | 7-131 | 7-132 | 7-133 | 7-134 | 7-135 |
| Solid | Polymer A | St/MAA/MMA/GMA-MAA = | 60 | 60 | 60 | 60 | 60 | 60 |
| content | | 47.7/19.0/1.3/32.0 (mass ratio) | | | | | | |
| blending | | CHMA/MAA/BzMA = | | | | | | |
| | | 49/19/32 (mass ratio) | | | | | | |
| | | St/AA/AA-GMA = | | | | | | |
| | | 53.5/14.5/32 (mass ratio) | | | | | | |
| | | CHA/AA/HEA = | | | | | | |
| | | 53.5/14.5/32 (mass ratio) | | | | | | |
| | Compound | Isoquinoline | | | | | | |
| | β (in | Quinoline | | | | | | |
| | parentheses: | Acridine | | | | | | |
| | molar ratio | 1-n-Butylisoquinoline | | | | | | |
| | with respect | 1-n-Butyl-4-methylisoquinoline | | | | | | |
| | to carboxy | 1-Me-isoquinoline | 3.9 (20) | | | 3.9 (20) | | |
| | group of | 2,4,5,7-Tetramethylquinoline | | | | | | |
| | polymer A | 2-Methyl-4-methoxyquinoline | | | | | | |
| | having acid | 9-Methylacridine | | | | | | |
| | group | 9-Phenylacridine | | | | | | |
| | (mol %)) | Pyridine | | | | | | |
| | | 2,4-Dimethylquinoline | | 4.3 (20) | 2.1 (10) | | 4.3 (20) | 2.1 (10) |
| | | 4-Aminopyridine | | | | | | |
| | | 2-Chloropyridine | | | | | | |
| | Polymerizable | DPHA | | | | | | |
| | compound | A-NOD-N | | | | | | |
| | | DTMPT | 21.0 | 21.0 | 21.0 | 10.0 | 10.0 | 10.0 |
| | | A-DCP | | | | | | |
| | | TMPT | 21.0 | 21.0 | 21.0 | 32.0 | 32.0 | 32.0 |
| | | SR601 | | | | | | |
| | | KRM8904 | | | | | | |
| | | KRM8452 | | | | | | |
| | Photopolymerization | Omn379 | 0.9 | 0.9 | 0.9 | 0.9 | 0.9 | 0.9 |
| | initiator | Oxe02 | | | | | | |
| | | Api307 | | | | | | |
| | Surfactant | F551A | 0.1 | 0.1 | 0.1 | 0.1 | 0.1 | 0.1 |
| | | R41 | | | | | | |
| | | 710FL | | | | | | |
| Evaluation | Carboxy group consumption rate | | A | A | B | A | A | B |
| of photo- | [measurement of ashing] | | | | | | | |
| sensitive | ε365/ε313 | | <1 | <1 | <1 | <1 | <1 | <1 |
| material | Pattern | 25 μm | A | A | A | A | A | A |
| | formability | 50 μm | A | A | A | A | A | A |
| | | 250 μm | A | A | A | A | A | A |

| | | | | | | | |
|---|---|---|---|---|---|---|---|
| | Relative permittivity | A | A | A | A | A | A |
| | Change in relative permittivity | A | A | A | A | A | A |
| | before and after exposure | | | | | | |
| Evaluation | Carboxy group consumption rate | A | A | B | A | A | B |
| of transfer | [measurement of ashing] | | | | | | |
| film | ε365/ε313 | <1 | <1 | <1 | <1 | <1 | <1 |
| | Transmittance at 365 nm | A | A | A | A | A | A |
| | Transmittance at 365 nm/ | A | A | A | A | A | A |
| | transmittance at 313 nm | | | | | | |
| | Laminate suitability | A | A | A | A | A | A |

| | | | | | | | |
|---|---|---|---|---|---|---|---|
| Pattern | 25 μm | A | A | A | A | A | A |
| formability | 50 μm | A | A | A | A | A | A |
| | 250 μm | A | A | A | A | A | A |

| | | | | | | |
|---|---|---|---|---|---|---|
| Relative permittivity | A | A | A | A | A | A |
| Change in relative permittivity | A | A | A | A | A | A |
| before and after exposure | | | | | | |
| Moisture permeability | A | A | A | A | A | A |
| Change in relative permittivity | A | A | A | A | A | A |
| after double exposure | | | | | | |

TABLE 58
Ninth table (9)

| | | | Mw of | pKa of | | | | |
|---|---|---|---|---|---|---|---|---|
| | | | polymer | Compound β | ε365 of | Example | | |
| | | | A | in ground state | Compound β | 7-136 | 7-137 | 7-138 |
| Solid | Polymer A | St/MAA/MMA/GMA-MAA = | 18000 | — | — | 60 | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | 3.9 (20) | | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | | 4.3 (20) | 2.1 (10) |
| | | 4-Aminopyridine | | 9.20 | <100 | | | |
| | | 2-Chloropyridine | | 0.70 | <10 | | | |
| | Polymerizable | DPHA | | — | — | | | |
| | compound | A-NOD-N | | — | — | | | |
| | | DTMPT | | — | — | 30.0 | 30.0 | 30.0 |
| | | A-DCP | | — | — | | | |
| | | TMPT | | — | — | 12.0 | 12.0 | 12.0 |
| | | SR601 | | — | — | | | |
| | | KRM8904 | | — | — | | | |
| | | KRM8452 | | — | — | | | |
| | Photopolymerization | Omn379 | | — | — | 0.9 | 0.9 | 0.9 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | A | A | B |
| of photo- | [measurement of ashing] | | | | | | | |
| sensitive | ε365/ε313 | | | — | — | <1 | <1 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | A | A | B |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

Example

| | | | 7-139 | 7-140 | 7-141 | 7-142 | 7-143 | 7-144 | 7-145 |
|---|---|---|---|---|---|---|---|---|---|
| Solid | Polymer A | St/MAA/MMA/GMA-MAA = | | | | | | | 60 |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | 60 | 60 | 60 | 60 | 60 | 60 | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 3.5 (20) | | | 3.5 (20) | | | 3.9 (20) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | | 3.8 (20) | 1.9 (10) | | 3.8 (20) | 1.9 (10) | |
| | | 4-Aminopyridine | | | | | | | |
| | | 2-Chloropyridine | | | | | | | |
| | Polymerizable | DPHA | | | | | | | 16.0 |
| | compound | A-NOD-N | | | | | | | 32.0 |
| | | DTMPT | 21.0 | 21.0 | 21.0 | 21.0 | 21.0 | 21.0 | |
| | | A-DCP | | | | | | | |
| | | TMPT | 21.0 | 21.0 | 21.0 | 21.0 | 21.0 | 21.0 | |
| | | SR601 | | | | | | | |
| | | KRM8904 | | | | | | | |
| | | KRM8452 | | | | | | | |
| | Photopolymerization | Omn379 | 0.9 | 0.9 | 0.9 | 2.4 | 2.4 | 2.4 | 1.0 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | B | A | A | B | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | A | B | A | A | B | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | Change in relative permittivity | | A | A | A | A | A | A | A |
| | after double exposure | | | | | | | | |
| | | | Example | | | | | | |
| | | | 7-146 | 7-147 | 7-148 | 7-149 | 7-150 | 7-151 | 7-152 |
| Solid | Polymer A | St/MAA/MMA/GMA-MAA = | 60 | 60 | 30 | 30 | 30 | | |
| content | | 47.7/19.0/1.3/32.0 (mass ratio) | | | | | | | |
| blending | | CHMA/MAA/BzMA = | | | 30 | 30 | 30 | | |
| | | 49/19/32 (mass ratio) | | | | | | | |
| | | St/AA/AA-GMA = | | | | | | 30 | 30 |
| | | 53.5/14.5/32 (mass ratio) | | | | | | | |
| | | CHA/AA/HEA = | | | | | | 30 | 30 |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | | 3.9 (20) | | | 3.5 (20) | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 4.3 (20) | 2.1 (10) | | 4.3 (20) | 2.1 (10) | | 3.8 (20) |
| | | 4-Aminopyridine | | | | | | | |
| | | 2-Chloropyridine | | | | | | | |
| | Polymerizable | DPHA | 16.0 | 16.0 | 12.6 | 12.6 | 12.6 | 12.6 | 12.6 |
| | compound | A-NOD-N | 32.0 | 32.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 1.0 | 1.0 | 0.8 | 0.8 | 0.8 | 0.8 | 0.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | B | A | A | B | A | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | B | A | A | B | A | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 59
Ninth table (10)

| | | | Mw of | pKa of | | | | |
|---|---|---|---|---|---|---|---|---|
| | | | polymer | Compound β | ε365 of | Example | | |
| | | | A | in ground state | Compound β | 7-153 | 7-154 | 7-155 |
| Solid | Polymer A | St/MAA/MMA/GMA-MAA = | 18000 | — | — | | 60 | 60 |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | 30 | | |
| | | 53.5/14.5/32 (mass ratio) | | | | | | |
| | | CHA/AA/HEA = | 40000 | — | — | 30 | | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | 1.9 (10) | 1.0 (5) |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | 1.9 (10) | 2.1 (10) | 3.1 (15) |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.8 | 0.8 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | B | A | A |
| of photo- | [measurement of ashing] | | | | | | | |
| sensitive | ε365/ε313 | | | — | — | <1 | <1 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | B | A | A |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

Example

| | | | 7-156 | 7-157 | 7-158 | 7-159 | 7-160 | 7-161 | 7-162 |
|---|---|---|---|---|---|---|---|---|---|
| Solid | Polymer A | St/MAA/MMA/GMA-MAA = | 60 | | | | 30 | 30 | 30 |
| content | | 47.7/19.0/1.3/32.0 (mass ratio) | | | | | | | |
| blending | | CHMA/MAA/BzMA = | | | | | 30 | 30 | 30 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | 60 | 60 | 60 | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 1.0 (5) | 1.7 (10) | 0.8 (5) | 0.8 (5) | 3.9 (20) | | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 1.0 | 1.9 (10) | 2.8 (15) | 0.9 (5) | | 4.3 (20) | 2.1 (10) |
| | | 4-Aminopyridine | | | | | | | |
| | | 2-Chloropyridine | | | | | | | |
| | Polymerizable | DPHA | 12.6 | 12.6 | 12.6 | 12.6 | | | |
| | compound | A-NOD-N | 25.0 | 25.0 | 25.0 | 25.0 | | | |
| | | DTMPT | | | | | 21.0 | 21.0 | 21.0 |
| | | A-DCP | | | | | | | |
| | | TMPT | | | | | 21.0 | 21.0 | 21.0 |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.8 | 0.9 | 0.9 | 0.9 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | B | A | A | B | A | A | B |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | B | A | A | B | A | A | B |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | Change in relative permittivity | | A | A | A | A | A | A | A |
| | after double exposure | | | | | | | | |
| | | | Example | | | | | | |
| | | | 7-163 | 7-164 | 7-165 | 7-166 | 7-167 | 7-168 | 7-169 |
| Solid | Polymer A | St/MAA/MMA/GMA-MAA = | | | | 60 | 60 | 60 | |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | 30 | 30 | 30 | | | | |
| | | 53.5/14.5/32 (mass ratio) | | | | | | | |
| | | CHA/AA/HEA = | 30 | 30 | 30 | | | | 60 |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 3.5 (20) | | | 1.9 (10) | 1.0 (5) | 1.0 (5) | 1.7 (10) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | | 3.8 (20) | 1.9 (10) | 2.1 (10) | 3.1 (15) | 1.0 (5) | 1.9 (10) |
| | | 4-Aminopyridine | | | | | | | |
| | | 2-Chloropyridine | | | | | | | |
| | Polymerizable | DPHA | | | | | | | |
| | compound | A-NOD-N | | | | | | | |
| | | DTMPT | 21.0 | 21.0 | 21.0 | 21.0 | 21.0 | 21.0 | 21.0 |
| | | A-DCP | | | | | | | |
| | | TMPT | 21.0 | 21.0 | 21.0 | 21.0 | 21.0 | 21.0 | 21.0 |
| | | SR601 | | | | | | | |
| | | KRM8904 | | | | | | | |
| | | KRM8452 | | | | | | | |
| | Photopolymerization | Omn379 | 0.9 | 0.9 | 0.9 | 0.9 | 0.9 | 0.9 | 0.9 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | B | A | A | B | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | A | B | A | A | B | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 60
Ninth table (11)

| | | | Mw of | pKa of | | | | |
|---|---|---|---|---|---|---|---|---|
| | | | polymer | Compound β | ε365 of | Example | | |
| | | | A | in ground state | Compound β | 7-170 | 7-171 | 7-172 |
| Solid | Polymer A | St/MAA/MMA/GMA-MAA = | 18000 | — | — | | | 30 |
| content | | 47.7/19.0/1.3/32.0 (mass ratio) | | | | | | |
| blending | | CHMA/MAA/BzMA = | 24000 | — | — | | | 30 |
| | | 49/19/32 (mass ratio) | | | | | | |
| | | St/AA/AA-GMA = | 16000 | — | — | | | |
| | | 53.5/14.5/32 (mass ratio) | | | | | | |
| | | CHA/AA/HEA = | 40000 | — | — | 60 | 60 | |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | 0.8 (5) | 0.8 (5) | 1.9 (10) |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | 2.8 (15) | 0.9 (5) | 2.1 (10) |
| | | 4-Aminopyridine | | 9.20 | <100 | | | |
| | | 2-Chloropyridine | | 0.70 | <10 | | | |
| | Polymerizable | DPHA | | — | — | | | 12.6 |
| | compound | A-NOD-N | | — | — | | | 25.0 |
| | | DTMPT | | — | — | 21.0 | 21.0 | |
| | | A-DCP | | — | — | | | |
| | | TMPT | | — | — | 21.0 | 21.0 | |
| | | SR601 | | — | — | | | |
| | | KRM8904 | | — | — | | | |
| | | KRM8452 | | — | — | | | |
| | Photopolymerization | Omn379 | | — | — | 0.9 | 0.9 | 0.8 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | A | B | A |
| of photo- | [measurement of ashing] | | | | | | | |
| sensitive | ε365/ε313 | | | — | — | <1 | <1 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | A | B | A |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

Example

| | | | 7-173 | 7-174 | 7-175 | 7-176 | 7-177 | 7-178 | 7-179 |
|---|---|---|---|---|---|---|---|---|---|
| Solid | Polymer A | St/MAA/MMA/GMA-MAA = | 30 | 30 | | | | 30 | 30 |
| content | | 47.7/19.0/1.3/32.0 (mass ratio) | | | | | | | |
| blending | | CHMA/MAA/BzMA = | 30 | 30 | | | | 30 | 30 |
| | | 49/19/32 (mass ratio) | | | | | | | |
| | | St/AA/AA-GMA = | | | 30 | 30 | 30 | | |
| | | 53.5/14.5/32 (mass ratio) | | | | | | | |
| | | CHA/AA/HEA = | | | 30 | 30 | 30 | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 1.0 (5) | 1.0 (5) | 1.7 (10) | 0.8 (5) | 0.8 (5) | 1.9 (10) | 1.0 (5) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 3.1 (15) | 1.0 (5) | 1.9 (10) | 2.8 (15) | 0.9 (5) | 2.1 (10) | 3.1 (15) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | | |
| | compound | A-NOD-N | 25.0 | 25.0 | 25.0 | 25.0 | 25.0 | | |
| | | DTMPT | | | | | 21.0 | 21.0 | 21.0 |
| | | A-DCP | | | | | | | |
| | | TMPT | | | | | 21.0 | 21.0 | 21.0 |
| | | SR601 | | | | | | | |
| | | KRM8904 | | | | | | | |
| | | KRM8452 | | | | | | | |
| | Photopolymerization | Omn379 | 0.8 | 0.8 | 0.8 | 0.9 | 0.9 | 0.9 | 0.9 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | B | A | A | B | A | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | B | A | A | B | A | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | Change in relative permittivity | | A | A | A | A | A | A | A |
| | after double exposure | | | | | | | | |
| | | | Example | | | | | | |
| | | | 7-180 | 7-181 | 7-182 | 7-183 | 7-184 | 7-185 | 7-186 |
| Solid | Polymer A | St/MAA/MMA/GMA-MAA = | 30 | | | | 30 | 30 | 30 |
| content | | 47.7/19.0/1.3/32.0 (mass ratio) | | | | | | | |
| blending | | CHMA/MAA/BzMA = | 30 | | | | 30 | 30 | 30 |
| | | 49/19/32 (mass ratio) | | | | | | | |
| | | St/AA/AA-GMA = | | 30 | 30 | 30 | | | |
| | | 53.5/14.5/32 (mass ratio) | | | | | | | |
| | | CHA/AA/HEA = | | 30 | 30 | 30 | | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 1.0 (5) | 1.7 (10) | 0.8 (5) | 0.8 (5) | 1.9 (10) | 1.0 (5) | 1.0 (5) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 1.0 (5) | 1.9 (10) | 2.8 (15) | 0.9 (5) | 2.1 (10) | 3.1 (15) | 1.0 (5) |
| | | 4-Aminopyridine | | | | | | | |
| | | 2-Chloropyridine | | | | | | | |
| | Polymerizable | DPHA | | | | | 12.0 | 12.0 | 12.0 |
| | compound | A-NOD-N | | | | | 12.0 | 12.0 | 12.0 |
| | | DTMPT | 21.0 | 21.0 | 21.0 | 21.0 | 12.0 | 12.0 | 12.0 |
| | | A-DCP | | | | | | | |
| | | TMPT | 21.0 | 21.0 | 21.0 | 21.0 | 12.0 | 12.0 | 12.0 |
| | | SR601 | | | | | | | |
| | | KRM8904 | | | | | | | |
| | | KRM8452 | | | | | | | |
| | Photopolymerization | Omn379 | 0.9 | 0.9 | 0.9 | 0.9 | 1.0 | 1.0 | 1.0 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | B | A | A | B | A | A | B |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | B | A | A | B | A | A | B |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 61
Ninth table (12)

| | | | Mw of | pKa of | | | | |
|---|---|---|---|---|---|---|---|---|
| | | | polymer | Compound β | ε365 of | Example | | |
| | | | A | in ground state | Compound β | 7-187 | 7-188 | 7-189 |
| Solid | Polymer A | St/MAA/MMA/GMA-MAA = | 18000 | — | — | | | |
| content | | 47.7/19.0/1.3/32.0 (mass ratio) | | | | | | |
| blending | | CHMA/MAA/BzMA = | 24000 | — | — | | | |
| | | 49/19/32 (mass ratio) | | | | | | |
| | | St/AA/AA-GMA = | 16000 | — | — | 30 | 30 | 30 |
| | | 53.5/14.5/32 (mass ratio) | | | | | | |
| | | CHA/AA/HEA = | 40000 | — | — | 30 | 30 | 30 |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | 1.7 (10) | 0.8 (5) | 0.8 (5) |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | 1.9 (10) | 2.8 (15) | 0.9 (5) |
| | | 4-Aminopyridine | | 9.20 | <100 | | | |
| | | 2-Chloropyridine | | 0.70 | <10 | | | |
| | Polymerizable | DPHA | | — | — | 12.0 | 12.0 | 12.0 |
| | compound | A-NOD-N | | — | — | 12.0 | 12.0 | 12.0 |
| | | DTMPT | | — | — | 12.0 | 12.0 | 12.0 |
| | | A-DCP | | — | — | | | |
| | | TMPT | | — | — | 12.0 | 12.0 | 12.0 |
| | | SR601 | | — | — | | | |
| | | KRM8904 | | — | — | | | |
| | | KRM8452 | | — | — | | | |
| | Photopolymerization | Omn379 | | — | — | 1.0 | 1.0 | 1.0 |
| | initiator | Oxe02 | | — | — | | | |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | A | A | B |
| of photo- | [measurement of ashing] | | | | | | | |
| sensitive | ε365/ε313 | | | — | — | <1 | <1 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | A | A | B |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

Example

| | | | 7-190 | 7-191 | 7-192 | 7-193 | 7-194 | 7-195 | 7-196 |
|---|---|---|---|---|---|---|---|---|---|
| Solid | Polymer A | St/MAA/MMA/GMA-MAA = | 30 | 30 | 30 | | | | 60 |
| content | | 47.7/19.0/1.3/32.0 (mass ratio) | | | | | | | |
| blending | | CHMA/MAA/BzMA = | 30 | 30 | 30 | | | | |
| | | 49/19/32 (mass ratio) | | | | | | | |
| | | St/AA/AA-GMA = | | | | 30 | 30 | 30 | |
| | | 53.5/14.5/32 (mass ratio) | | | | | | | |
| | | CHA/AA/HEA = | | | | 30 | 30 | 30 | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 3.9 (20) | | | 3.5 (20) | | | 1.9 (10) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | | 4.3 (20) | 2.1 (10) | | 3.8 (20) | 1.9 (10) | 2.1 (10) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 1.6 | 1.6 | 1.6 | 1.6 | 1.6 | 1.6 | 1.6 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | B | A | A | B | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | A | B | A | A | B | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | Change in relative permittivity | | A | A | A | A | A | A | A |
| | after double exposure | | | | | | | | |
| | | | Example | | | | | | |
| | | | 7-197 | 7-198 | 7-199 | 7-200 | 7-201 | 7-202 | 7-203 |
| Solid | Polymer A | St/MAA/MMA/GMA-MAA = | 60 | 60 | | | | 30 | 30 |
| content | | 47.7/19.0/1.3/32.0 (mass ratio) | | | | | | | |
| blending | | CHMA/MAA/BzMA = | | | | | | 30 | 30 |
| | | 49/19/32 (mass ratio) | | | | | | | |
| | | St/AA/AA-GMA = | | | | | | | |
| | | 53.5/14.5/32 (mass ratio) | | | | | | | |
| | | CHA/AA/HEA = | | | 60 | 60 | 60 | | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 1.0 (5) | 1.0 (5) | 1.7 (10) | 0.8 (5) | 0.8 (5) | 3.9 (20) | |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 3.1 (15) | 1.0 (5) | 1.9 (10) | 2.8 (15) | 0.9 (5) | | 4.3 (20) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 1.6 | 1.6 | 1.6 | 1.6 | 1.6 | 0.4 | 0.4 |
| | initiator | Oxe02 | | | | | | 0.4 | 0.4 |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | B | A | A | B | A | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | B | A | A | B | A | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 62
Ninth table (13)

| | | | Mw of | pKa of | | | | |
|---|---|---|---|---|---|---|---|---|
| | | | polymer | Compound β | ε365 of | Example | | |
| | | | A | in ground state | Compound β | 7-204 | 7-205 | 7-206 |
| Solid | Polymer A | St/MAA/MMA/GMA-MAA = | 18000 | — | — | 30 | | |
| content | | 47.7/19.0/1.3/32.0 (mass ratio) | | | | | | |
| blending | | CHMA/MAA/BzMA = | 24000 | — | — | 30 | | |
| | | 49/19/32 (mass ratio) | | | | | | |
| | | St/AA/AA-GMA = | 16000 | — | — | | 30 | 30 |
| | | 53.5/14.5/32 (mass ratio) | | | | | | |
| | | CHA/AA/HEA = | 40000 | — | — | | 30 | 30 |
| | | 53.5/14.5/32 (mass ratio) | | | | | | |
| | Compound | Isoquinoline | | 4.69 | <10 | | | |
| | β (in | Quinoline | | 4.15 | <10 | | | |
| | parentheses: | Acridine | | 4.67 | 4900 | | | |
| | molar ratio | 1-n-Butylisoquinoline | | 5.27 | <10 | | | |
| | with respect | 1-n-Butyl-4-methylisoquinoline | | 5.9 | <10 | | | |
| | to carboxy | 1-Me-isoquinoline | | 5.31 | <10 | | 3.5 (20) | |
| | group of | 2,4,5,7-Tetramethylquinoline | | 6.23 | <10 | | | |
| | polymer A | 2-Methyl-4-methoxyquinoline | | 6.51 | <10 | | | |
| | having acid | 9-Methylacridine | | 5.4 | 6300 | | | |
| | group | 9-Phenylacridine | | 4.04 | >10000 | | | |
| | (mol %)) | Pyridine | | 5.25 | <10 | | | |
| | | 2,4-Dimethylquinoline | | 5.67 | <10 | 2.1 (10) | | 3.8 (20) |
| | | 4-Aminopyridine | | 9.20 | <100 | | | |
| | | 2-Chloropyridine | | 0.70 | <10 | | | |
| | Polymerizable | DPHA | | — | — | 12.6 | 12.6 | 12.6 |
| | compound | A-NOD-N | | — | — | 25.0 | 25.0 | 25.0 |
| | | DTMPT | | — | — | | | |
| | | A-DCP | | — | — | | | |
| | | TMPT | | — | — | | | |
| | | SR601 | | — | — | | | |
| | | KRM8904 | | — | — | | | |
| | | KRM8452 | | — | — | | | |
| | Photopolymerization | Omn379 | | — | — | 0.4 | 0.4 | 0.4 |
| | initiator | Oxe02 | | — | — | 0.4 | 0.4 | 0.4 |
| | | Api307 | | — | — | | | |
| | Surfactant | F551A | | — | — | 0.1 | 0.1 | 0.1 |
| | | R41 | | — | — | | | |
| | | 710FL | | — | — | | | |
| Evaluation | Carboxy group consumption rate | | | — | — | B | A | A |
| of photo- | [measurement of ashing] | | | | | | | |
| sensitive | ε365/ε313 | | | — | — | <1 | <1 | <1 |
| material | Pattern | 25 μm | | — | — | A | A | A |
| | formability | 50 μm | | — | — | A | A | A |
| | | 250 μm | | — | — | A | A | A |
| | Relative permittivity | | | — | — | A | A | A |
| | Change in relative permittivity | | | — | — | A | A | A |
| | before and after exposure | | | | | | | |
| Evaluation | Carboxy group consumption rate | | | — | — | B | A | A |
| of transfer | [measurement of ashing] | | | | | | | |
| film | ε365/ε313 | | | — | — | <1 | <1 | <1 |
| | Transmittance at 365 nm | | | — | — | A | A | A |
| | Transmittance at 365 nm/ | | | — | — | A | A | A |
| | transmittance at 313 nm | | | | | | | |
| | Laminate suitability | | | — | — | A | A | A |
| | Pattern | 25 μm | | — | — | A | A | A |
| | formability | 50 μm | | — | — | A | A | A |
| | | 250 μm | | — | — | A | A | A |

| | | | | | |
|---|---|---|---|---|---|
| Relative permittivity | — | — | A | A | A |
| Change in relative permittivity | — | — | A | A | A |
| before and after exposure | | | | | |
| Moisture permeability | — | — | A | A | A |
| Change in relative permittivity | — | — | A | A | A |
| after double exposure | | | | | |

Example

| | | | 7-207 | 7-208 | 7-209 | 7-210 | 7-211 | 7-212 | 7-213 |
|---|---|---|---|---|---|---|---|---|---|
| Solid | Polymer A | St/MAA/MMA/GMA-MAA = | | 60 | 60 | 60 | | | |
| content | | 47.7/19.0/1.3/32.0 (mass ratio) | | | | | | | |
| blending | | CHMA/MAA/BzMA = | | | | | | | |
| | | 49/19/32 (mass ratio) | | | | | | | |
| | | St/AA/AA-GMA = | 30 | | | | | | |
| | | 53.5/14.5/32 (mass ratio) | | | | | | | |
| | | CHA/AA/HEA = | 30 | | | | 60 | 60 | 60 |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | | 1.9 (10) | 1.0 (5) | 1.0 (5) | 1.7 (10) | 0.8 (5) | 0.8 (5) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 1.9 (10) | 2.1 (10) | 3.1 (15) | 1.0 (5) | 1.9 (10) | 2.8 (15) | 0.9 (5) |
| | | 4-Aminopyridine | | | | | | | |
| | | 2-Chloropyridine | | | | | | | |
| | Polymerizable | DPHA | 12.6 | 12.6 | 12.6 | 12.6 | 12.6 | 12.6 | 12.6 |
| | compound | A-NOD-N | 25.0 | 25.0 | 25.0 | 25.0 | 25.0 | 25.0 | 25.0 |
| | | DTMPT | | | | | | | |
| | | A-DCP | | | | | | | |
| | | TMPT | | | | | | | |
| | | SR601 | | | | | | | |
| | | KRM8904 | | | | | | | |
| | | KRM8452 | | | | | | | |
| | Photopolymerization | Omn379 | 0.4 | 0.4 | 0.4 | 0.4 | 0.4 | 0.4 | 0.4 |
| | initiator | Oxe02 | 0.4 | 0.4 | 0.4 | 0.4 | 0.4 | 0.4 | 0.4 |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | B | A | A | B | A | A | B |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | B | A | A | B | A | A | B |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| | Moisture permeability | | A | A | A | A | A | A | A |
| | Change in relative permittivity | | A | A | A | A | A | A | A |
| | after double exposure | | | | | | | | |
| | | | Example | | | | | | |
| | | | 7-214 | 7-215 | 7-216 | 7-217 | 7-218 | 7-219 | 7-220 |
| Solid | Polymer A | St/MAA/MMA/GMA-MAA = | 30 | 30 | 30 | | | | 30 |
| content | | 47.7/19.0/1.3/32.0 (mass ratio) | | | | | | | |
| blending | | CHMA/MAA/BzMA = | 30 | 30 | 30 | | | | 30 |
| | | 49/19/32 (mass ratio) | | | | | | | |
| | | St/AA/AA-GMA = | | | | 30 | 30 | 30 | |
| | | 53.5/14.5/32 (mass ratio) | | | | | | | |
| | | CHA/AA/HEA = | | | | 30 | 30 | 30 | |
| | | 53.5/14.5/32 (mass ratio) | | | | | | | |
| | Compound | Isoquinoline | | | | | | | |
| | β (in | Quinoline | | | | | | | |
| | parentheses: | Acridine | | | | | | | |
| | molar ratio | 1-n-Butylisoquinoline | | | | | | | |
| | with respect | 1-n-Butyl-4-methylisoquinoline | | | | | | | |
| | to carboxy | 1-Me-isoquinoline | 1.9 (10) | 1.0 (5) | 1.0 (5) | 1.7 (10) | 0.8 (5) | 0.8 (5) | 1.9 (10) |
| | group of | 2,4,5,7-Tetramethylquinoline | | | | | | | |
| | polymer A | 2-Methyl-4-methoxyquinoline | | | | | | | |
| | having acid | 9-Methylacridine | | | | | | | |
| | group | 9-Phenylacridine | | | | | | | |
| | (mol %)) | Pyridine | | | | | | | |
| | | 2,4-Dimethylquinoline | 2.1 (10) | 3.1 (15) | 1.0 (5) | 1.9 (10) | 2.8 (15) | 0.9 (5) | 2.1 (10) |
| | | 4-Aminopyridine | | | | | | | |
| | | 2-Chloropyridine | | | | | | | |
| | Polymerizable | DPHA | | | | | | | |
| | compound | A-NOD-N | | | | | | | |
| | | DTMPT | 21.0 | 21.0 | 21.0 | 21.0 | 21.0 | 14.0 | 14.0 |
| | | A-DCP | | | | | | | |
| | | TMPT | 21.0 | 21.0 | 21.0 | 21.0 | 21.0 | 14.0 | 14.0 |
| | | SR601 | | | | | | 14.0 | 14.0 |
| | | KRM8904 | | | | | | | |
| | | KRM8452 | | | | | | | |
| | Photopolymerization | Omn379 | 1.2 | 1.2 | 1.2 | 1.2 | 1.2 | 1.2 | 1.8 |
| | initiator | Oxe02 | | | | | | | |
| | | Api307 | | | | | | | |
| | Surfactant | F551A | 0.1 | 0.1 | 0.1 | 0.1 | 0.1 | 0.1 | 0.1 |
| | | R41 | | | | | | | |
| | | 710FL | | | | | | | |
| Evaluation | Carboxy group consumption rate | | A | A | B | A | A | B | A |
| of photo- | [measurement of ashing] | | | | | | | | |
| sensitive | ε365/ε313 | | <1 | <1 | <1 | <1 | <1 | <1 | <1 |
| material | Pattern | 25 μm | A | A | A | A | A | A | A |
| | formability | 50 μm | A | A | A | A | A | A | A |
| | | 250 μm | A | A | A | A | A | A | A |
| | Relative permittivity | | A | A | A | A | A | A | A |
| | Change in relative permittivity | | A | A | A | A | A | A | A |
| | before and after exposure | | | | | | | | |
| Evaluation | Carboxy group consumption rate | | A | A | B | A | A | B | A |
| of transfer | [measurement of ashing] | | | | | | | | |
| film | ε365/ε313 | | <1 | <1 | <1 | <1 | <1 | <1 | <1 |
| | Transmittance at 365 nm | | A | A | A | A | A | A | A |
| | Transmittance at 365 nm/ | | A | A | A | A | A | A | A |
| | transmittance at 313 nm | | | | | | | | |
| | Laminate suitability | | A | A | A | A | A | A | A |
| | Pattern | 25 μm | A | A | A | A | A | A | A |
| | formability | 50 μm | A | A | A | A | A | A | A |
| | | 250 μm | A | A | A | A | A | A | A |

| | | | | | | | |
|---|---|---|---|---|---|---|---|
| Relative permittivity | A | A | A | A | A | A | A |
| Change in relative permittivity | A | A | A | A | A | A | A |
| before and after exposure | | | | | | | |
| Moisture permeability | A | A | A | A | A | A | A |
| Change in relative permittivity | A | A | A | A | A | A | A |
| after double exposure | | | | | | | |

TABLE 63
Ninth table (14)

| | | | Mw of | pKa of | | | |
|---|---|---|---|---|---|---|---|
| | | | polymer | Compound β | ε365 of | Example | |
| | | | A | in ground state | Compound β | 7-221 | 7-222 |
| Solid | Polymer A | St/MAA/MMA/GMA-MAA = | 18000 | — | — | 30 | 30 |
| content | | 47.7/19.0/1.3/32.0 (mass ratio) | | | | | |
| blending | | CHMA/MAA/BzMA = | 24000 | — | — | 30 | 30 |
| | | 49/19/32 (mass ratio) | | | | | |
| | | St/AA/AA-GMA = | 16000 | — | — | | |
| | | 53.5/14.5/32 (mass ratio) | | | | | |
| | | CHA/AA/HEA = | 40000 | — | — | | |
| | | 53.5/14.5/32 (mass ratio) | | | | | |
| | Compound | Isoquinoline | | 4.69 | <10 | | |
| | β (in | Quinoline | | 4.15 | <10 | | |
| | parentheses: | Acridine | | 4.67 | 4900 | | |
| | molar ratio | 1-n-Butylisoquinoline | | 5.27 | <10 | | |
| | with respect | 1-n-Butyl-4-methylisoquinoline | | 5.9 | <10 | | |
| | to carboxy | 1-Me-isoquinoline | | 5.31 | <10 | 1.0 (5) | 1.0 (5) |
| | group of | 2,4,5,7-Tetramethylquinoline | | 6.23 | <10 | | |
| | polymer A | 2-Methyl-4-methoxyquinoline | | 6.51 | <10 | | |
| | having acid | 9-Methylacridine | | 5.4 | 6300 | | |
| | group | 9-Phenylacridine | | 4.04 | >10000 | | |
| | (mol %)) | Pyridine | | 5.25 | <10 | | |
| | | 2,4-Dimethylquinoline | | 5.67 | <10 | 3.1 (15) | 1.0 (5) |
| | | 4-Aminopyridine | | 9.20 | <100 | | |
| | | 2-Chloropyridine | | 0.70 | <10 | | |
| | Polymerizable | DPHA | | — | — | | |
| | compound | A-NOD-N | | — | — | | |
| | | DTMPT | | — | — | 14.0 | 14.0 |
| | | A-DCP | | — | — | | |
| | | TMPT | | — | — | 14.0 | 14.0 |
| | | SR601 | | — | — | 14.0 | 14.0 |
| | | KRM8904 | | — | — | | |
| | | KRM8452 | | — | — | | |
| | Photopolymerization | Omn379 | | — | — | 1.8 | 1.8 |
| | initiator | Oxe02 | | — | — | | |
| | | Api307 | | — | — | | |
| | Surfactant | F551A | | — | — | 0.1 | 0.1 |
| | | R41 | | — | — | | |
| | | 710FL | | — | — | | |
| Evaluation | Carboxy group consumption rate | | | — | — | A | B |
| of photo- | [measurement of ashing] | | | | | | |
| sensitive | ε365/ε313 | | | — | — | <1 | <1 |
| material | Pattern | 25 μm | | — | — | A | A |
| | formability | 50 μm | | — | — | A | A |
| | | 250 μm | | — | — | A | A |
| | Relative permittivity | | | — | — | A | A |
| | Change in relative permittivity | | | — | — | A | A |
| | before and after exposure | | | | | | |
| Evaluation | Carboxy group consumption rate | | | — | — | A | B |
| of transfer | [measurement of ashing] | | | | | | |
| film | ε365/ε313 | | | — | — | <1 | <1 |
| | Transmittance at 365 nm | | | — | — | A | A |
| | Transmittance at 365 nm/ | | | — | — | A | A |
| | transmittance at 313 nm | | | | | | |
| | Laminate suitability | | | — | — | A | A |
| | Pattern | 25 μm | | — | — | A | A |
| | formability | 50 μm | | — | — | A | A |
| | | 250 μm | | — | — | A | A |

| | | | | |
|---|---|---|---|---|
| Relative permittivity | — | — | A | A |
| Change in relative permittivity | — | — | A | A |
| before and after exposure | | | | |
| Moisture permeability | — | — | A | A |
| Change in relative permittivity | — | — | A | A |
| after double exposure | | | | |

| | | | | | | Comparative |
|---|---|---|---|---|---|---|
| | | | Example | | | Example |
| | | | 7-223 | 7-224 | 7-225 | 7A |
| Solid | Polymer A | St/MAA/MMA/GMA-MAA = | | | | 60 |
| content | | 47.7/19.0/1.3/32.0 (mass ratio) | | | | |
| blending | | CHMA/MAA/BzMA = | | | | |
| | | 49/19/32 (mass ratio) | | | | |
| | | St/AA/AA-GMA = | 30 | 30 | 30 | |
| | | 53.5/14.5/32 (mass ratio) | | | | |
| | | CHA/AA/HEA = | 30 | 30 | 30 | |
| | | 53.5/14.5/32 (mass ratio) | | | | |
| | Compound | Isoquinoline | | | | |
| | β (in | Quinoline | | | | |
| | parentheses: | Acridine | | | | |
| | molar ratio | 1-n-Butylisoquinoline | | | | |
| | with respect | 1-n-Butyl-4-methylisoquinoline | | | | |
| | to carboxy | 1-Me-isoquinoline | 1.7 (10) | 0.8 (5) | 0.8 (5) | |
| | group of | 2,4,5,7-Tetramethylquinoline | | | | |
| | polymer A | 2-Methyl-4-methoxyquinoline | | | | |
| | having acid | 9-Methylacridine | | | | |
| | group | 9-Phenylacridine | | | | |
| | (mol %)) | Pyridine | | | | |
| | | 2,4-Dimethylquinoline | 1.9 (10) | 2.8 (15) | 0.9 (5) | |
| | | 4-Aminopyridine | | | | |
| | | 2-Chloropyridine | | | | |
| | Polymerizable | DPHA | | | | 12.6 |
| | compound | A-NOD-N | | | | 25.0 |
| | | DTMPT | 14.0 | 14.0 | 14.0 | |
| | | A-DCP | | | | |
| | | TMPT | 14.0 | 14.0 | 14.0 | |
| | | SR601 | 14.0 | 14.0 | 14.0 | |
| | | KRM8904 | | | | |
| | | KRM8452 | | | | |
| | Photopolymerization | Omn379 | 1.8 | 1.8 | 1.8 | 1.8 |
| | initiator | Oxe02 | | | | |
| | | Api307 | | | | |
| | Surfactant | F551A | 0.1 | 0.1 | 0.1 | 0.1 |
| | | R41 | | | | |
| | | 710FL | | | | |
| Evaluation | Carboxy group consumption rate | | A | A | B | E |
| of photo- | [measurement of ashing] | | | | | |
| sensitive | ε365/ε313 | | <1 | <1 | <1 | — |
| material | Pattern | 25 μm | A | A | A | B |
| | formability | 50 μm | A | A | A | B |
| | | 250 μm | A | A | A | B |

| | | | | | |
|---|---|---|---|---|---|
| | Relative permittivity | A | A | A | Standard |
| | Change in relative permittivity | A | A | A | D |
| | before and after exposure | | | | |
| Evaluation | Carboxy group consumption rate | A | A | B | E |
| of transfer | [measurement of ashing] | | | | |
| film | ε365/ε313 | <1 | <1 | <1 | — |
| | Transmittance at 365 nm | A | A | A | A |
| | Transmittance at 365 nm/ | A | A | A | B |
| | transmittance at 313 nm | | | | |
| | Laminate suitability | A | A | A | A |

| | | | | | |
|---|---|---|---|---|---|
| Pattern | 25 μm | A | A | A | B |
| formability | 50 μm | A | A | A | B |
| | 250 μm | A | A | A | B |

| | | | | |
|---|---|---|---|---|
| Relative permittivity | A | A | A | Standard |
| Change in relative permittivity | A | A | A | D |
| before and after exposure | | | | |
| Moisture permeability | A | A | A | Standard |
| Change in relative permittivity | A | A | A | D |
| after double exposure | | | | |

### Polymer A

Polymers 1 to 4 corresponding the polymer A were synthesized by the same method as in Example 4 system described above. Abbreviations for the monomer forming each structural unit of the polymers are as described above.

Polymer 1: St/MAA/MMA/GMA-MAA=47.7/19.0/1.3/32.0 (mass ratio)

Polymer 2: CHMA/MAA/BzMA=49/19/32 (mass ratio)

Polymer 3: St/AA/AA-GMA=53.5/14.5/32 (mass ratio)

Polymer 4: CHA/AA/HEA=53.5/14.5/32 (mass ratio)

As shown in Ninth table, the weight-average molecular weight of the polymer A shown in Ninth table was in a range of 10,000 to 50,000.

(Polymerizable Compound)

DPHA: dipentaerythritol hexaacrylate (A-DPH manufactured by Shin-Nakamura Chemical Co., Ltd.)

A-NOD-N: 1,9-nonanediol diacrylate (A-NOD-N manufactured by Shin-Nakamura Chemical Co., Ltd.)

DTMPT: ditrimethylolpropane tetraacrylate (KAYARAD T-1420 (T) manufactured by Nippon Kayaku Co., Ltd.)

A-DCPP: dicyclopentane dimethanol diacrylate (A-DCP manufactured by Shin-Nakamura Chemical Co., Ltd.)

TMPT: trimethylolpropane triacrylate (A-TMPT manufactured by Shin-Nakamura Chemical Co., Ltd.)

SR601: ethoxylated (4) bisphenol A diacrylate (SR601 manufactured by TOMOE Engineering Co., Ltd.)

KRM8904: 9-functional aliphatic urethane acrylate (KRM8904 manufactured by Daicel-Allnex Ltd.)

KRM8452: 10-functional aliphatic urethane acrylate (KRM8452 manufactured by Daicel-Allnex Ltd.)

(Photopolymerization Initiator)

Omn379: Omnirad 379 (manufactured by IGM Resins B.V., alkylphenone-based compound)

Oxe02: Irgacure OXE02 (manufactured by BASF SE, oxime ester compound)

Api307: (1-(biphenyl-4-yl)-2-methyl-2-morpholinopropan-1-one (manufactured by Shenzhen UV-ChemTech Co., Ltd.)

(Surfactant)

F551: MEGAFACE F551 (manufactured by DIC Corporation)

R41: MEGAFACE R-41 (manufactured by DIC Corporation)

710FL: FTERGENT 710FL (manufactured by NEOS COMPANY LIMITED)

### Examples 201 to 218 and Comparative Example 201: Evaluation of Physical Properties of Compound β

For the compound β used in Examples 1 to 7 systems described above, volatilization resistance in the coating process during the formation of the photosensitive layer (residual rate in the photosensitive layer after the coating process) was evaluated by the following procedure.

<Preparation of Photosensitive Material>

Photosensitive materials of Examples 201 to 218 were prepared in the same manner as in the photosensitive material of Example 1-1 in Example 1 system described above, except that the compound β was changed to compounds exemplified below, and the blending amount of the compound β was set to 0.2 equivalent with respect to the molar amount of the carboxy group of the polymer A.

In addition, a photosensitive material of Comparative Example 201 was prepared in the same manner as in the photosensitive material of Example 1-1 in Example 1 system described above, except that the 5,6,7,8-tetrahydroquinoline was not added.

<Evaluation of Photosensitive Material>

(Production of Photosensitive Layer)

The photosensitive material of each of Examples or Comparative Examples was spin-coated on 10×10 cm² glass (Eagle XG manufactured by Corning), and then the obtained coating film was dried using a hot plate at 80° C. to obtain a photosensitive layer having a film thickness of 5 μm.

The obtained photosensitive layer was evaluated as follows.

(Measurement of Residual Ratio of Compound β)

First, the following two types of samples were prepared.

(1) sample in which the photosensitive material was diluted 2-fold with deuterated acetone (sample A)

(2) sample obtained by scraping off approximately 5 mg of the obtained photosensitive layer and dissolving it in deuterated acetone (sample B)

Next, using AVANCE III manufactured by Bruker, ¹H-NMR (lock solvent: deuterated acetone, pulse program: zg30, number of integrations: 32 times) of each sample was measured, and based on a peak surface area of styrene and the compound β, a residual rate (%) of the compound β was calculated from the following expression (H).

Residual rate=(Content of compound β in sample A−Content of compound β in sample B)/content of compound β in sample A×100[%] Expression (H):

Next, the evaluation was performed based on the following evaluation standard. The results are shown in Tenth table. In Tenth table shown below, the molecular weight of the compound β is also shown.

(Evaluation Standard)

A: residual rate was 85% or more.

B: residual rate was 60% or more and less than 85%.

C: residual rate was 20% or more and less than 60%.

D: residual rate was less than 20%.

TABLE 64
Tenth table

| | Compound β (decarboxylator) | | |
|---|---|---|---|
| | (blending amount: 0.2 eq.) | | |
| | | | Volatility |
| | | Molecular | in coating |
| | Type | weight | process |
| Example 201 | Isoquinoline | 129 | C |
| Example 202 | Quinoline | 129 | C |
| Example 203 | Acridine | 179 | B |
| Example 204 | 1-Me-isoquinoline | 143 | B |
| Example 205 | 1-n-Butylisoquinoline | 185 | A |
| Example 206 | 1-n-Butyl-4-methylisoquinoline | 199 | A |
| Example 207 | 2,4-Dimethylquinoline | 157 | B |
| Example 208 | 2-Methyl-4-t-butylquinoline | 199 | A |
| Example 209 | 2,4,5,7-Tetramethylquinoline | 185 | A |
| Example 210 | 2-Methyl-4-methoxyquinoline | 173 | B |
| Example 211 | 9-Methylacridine | 193 | A |
| Example 212 | 9-Phenylacridine | 255 | A |
| Example 213 | Pyridine | 79 | D |
| Example 214 | 5,6,7,8-Tetrahydroquinoline | 133 | B |
| Example 215 | 4-Acetylpyridine | 121 | C |
| Example 216 | 4-Benzoylpyridine | 183 | A |
| Example 217 | 4-Aminopyridine | 94 | D |
| Example 218 | 2-Chloropyridine | 114 | D |
| Comparative | None | — | — |
| Example 201 | | | |

From the results of Tenth table, in a case where the molecular weight of the compound β was 120 or more (preferably, a case of being 130 or more, and more preferably, a case of being 180 or more, it is clear that volatility in the coating process is low (residual rate of the compound β in the photosensitive layer after the coating process is high).

<Evaluation of Transfer Film>

(Production of Transfer Film)

To a polyethylene terephthalate film (manufactured by Toray Industries, Inc., 16KS40 (16QS62)) having a thickness of 16 μm (temporary support), the photosensitive material of each of Examples or Comparative Examples was applied using a slit-shaped nozzle such that a thickness after drying was adjusted to 5 μm, and the photosensitive material was dried at 100° C. for 2 minutes to form a photosensitive layer.

A polyethylene terephthalate film (manufactured by Toray Industries, Inc., 16KS40 (16QS62)) having a thickness of 16 μm (cover film) was pressure-bonded onto the obtained photosensitive layer to produce transfer films of Examples and Comparative Examples.

By peeling off the cover film from the transfer film produced above and laminating the transfer film on 10×10 cm² glass (Eagle XG manufactured by Corning), the photosensitive layer of the transfer film was transferred to a surface of the glass. Laminating conditions were that a temperature of a substrate for a touch panel was 40° C., a temperature of a rubber roller (that is, a laminating temperature) was 110° C., a linear pressure was 3 N/cm, and a transportation speed was 2 m/min.

Approximately 5 mg of the photosensitive layer in the obtained glass with the photosensitive layer was scraped off to produce a sample dissolved in deuterated acetone (sample C).

In a case where volatility of the compound 3 in the coating process (residual ratio of the compound β in the photosensitive layer after the coating process) was obtained by the same method according to (Measurement of residual rate of compound β) described above, except that the sample B was changed to the sample C, the results were the same as those shown in Tenth table described above.

### Example 1001 (Production and Evaluation of Device)

<Manufacturing of Transparent Laminate>

A substrate in which an ITO transparent electrode pattern and copper lead wire were formed on a cycloolefin transparent film was prepared.

Using the transfer film of Example 1-1 in Example 1 system from which the protective film was peeled off, the ITO transparent electrode pattern and the copper lead wire were laminated at a position covered by the transfer film. The laminating was performed using a vacuum laminator manufactured by MCK under conditions of a cycloolefin transparent film temperature: 40° C., a rubber roller temperature: 100° C., a linear pressure: 3 N/cm, and a transportation speed: 2 m/min.

Then, after the temporary support was peeled off, an exposure was performed in a patterned manner using an exposure mask (quartz exposure mask having a pattern for forming an overcoat) and a high-pressure mercury lamp. As the exposure condition, the integrated exposure amount measured with a 365 nm illuminance meter was 1000 mJ/cm².

After the exposure, the photosensitive layer of the laminate, from which the temporary support was peeled off, was developed for 40 seconds using a 1% by mass sodium carbonate aqueous solution (liquid temperature: 32° C.) as a developer.

Thereafter, the residue was removed by injecting ultrapure water from an ultrapure water washing nozzle onto the transparent film substrate after the development treatment. Subsequently, air was blown to remove water on the transparent film substrate to form a transparent laminate in which the ITO transparent electrode pattern, the copper lead wire, and the cured film were laminated in this order on the transparent film substrate.

Using the produced transparent laminate, a touch panel was produced by a known method. The produced touch panel was attached to a liquid crystal display element produced by a method described in paragraphs 0097 to 0119 of JP2009-47936A, thereby producing a liquid crystal display device equipped with a touch panel.

It was confirmed that all of the obtained liquid crystal display devices equipped with the touch panel had excellent display characteristics and operated without problems.

### Example 1002 (Production and Evaluation of Device)

A liquid crystal display device equipped with a touch panel was produced by the same method as in Example 1001, except that the above-described transfer film was changed to any of the transfer films other than Example 1-1 in Example 1 system described above or the transfer films of Examples in Example 2 system, Example 4 system, Example 5 system, and Example 6 system described above.

It was confirmed that all of the obtained liquid crystal display devices equipped with the touch panel had excellent display characteristics and operated without problems.

### Example 1003 (Production and Evaluation of Device)

<Manufacturing of Transparent Laminate>

A substrate in which an ITO transparent electrode pattern and copper lead wire were formed on a cycloolefin transparent film was prepared.

Using the transfer film of Examples in Example 3 system from which the protective film was peeled off, the ITO transparent electrode pattern and the copper lead wire were laminated at a position covered by the transfer film. The laminating was performed using a vacuum laminator manufactured by MCK under conditions of a cycloolefin transparent film temperature: 40° C., a rubber roller temperature: 100° C., a linear pressure: 3 N/cm, and a transportation speed: 2 m/min.

Thereafter, the temporary support of the obtained base material with a photosensitive layer was closely attached to an exposure mask (quartz exposure mask having a pattern for forming an overcoat), and using a proximity type exposure machine (Hitachi High-Technologies Corporation) equipped with an ultra-high pressure mercury lamp, an exposure was performed in a patterned manner through the temporary support through a filter which cuts wavelengths of 350 nm or less. As the exposure condition, the integrated exposure amount measured with a 365 nm illuminance meter was 80 mJ/cm².

After the exposure, the temporary support was peeled off, and the photosensitive layer of the laminate, from which the temporary support was peeled off, was developed for 40 seconds using a 1% by mass sodium carbonate aqueous solution (liquid temperature: 32° C.) as a developer.

Thereafter, the residue was removed by injecting ultrapure water from an ultrapure water washing nozzle onto the transparent film substrate after the development treatment. Subsequently, air was blown to remove water on the transparent film substrate.

Next, the formed pattern was subjected to a second exposure using a high-pressure mercury lamp. In the second exposure using a high-pressure mercury lamp, the integrated exposure amount measured with a 365 nm illuminance meter was 1000 mJ/cm².

By the above-described procedure, a transparent laminate in which the ITO transparent electrode pattern, the copper lead wire, and the cured film were laminated in this order on the transparent film substrate was formed.

Using the produced transparent laminate, a touch panel was produced by a known method. The produced touch panel was attached to a liquid crystal display element produced by a method described in paragraphs 0097 to 0119 of JP2009-47936A, thereby producing a liquid crystal display device equipped with a touch panel.

It was confirmed that all of the obtained liquid crystal display devices equipped with the touch panel had excellent display characteristics and operated without problems.

### Example 1004 (Production and Evaluation of Device)

A liquid crystal display device equipped with a touch panel was produced by the same method as in Example 1003, except that the above-described transfer film was changed to the transfer film of Examples in Example 7 system described above.

It was confirmed that all of the obtained liquid crystal display devices equipped with the touch panel had excellent display characteristics and operated without problems.

### EXPLANATION OF REFERENCES

12: temporary support
14: photosensitive layer
16: cover film
100: transfer film

What is claimed is:

1. A photosensitive material which satisfies at least one requirement of the following requirement (V01) or the following requirement (WO1),
(V01) the photosensitive material includes a polymer A having a carboxy group and a compound β which has a structure b0 in which an amount of the carboxy group included in the polymer A is reduced by exposure,
(W01) the photosensitive material includes a polymer Ab0 which is the polymer A and further has the structure b0 in which the amount of the carboxy group included in the polymer A is reduced by exposure.

2. The photosensitive material according to claim 1,
wherein, in the requirement (V01), the compound β is a compound B, and the compound B is a compound in which the structure b0 is a structure b capable of accepting an electron from the carboxy group in a photoexcited state, and
in the requirement (W01), the polymer Ab0 is a polymer Ab, and the polymer Ab is a polymer in which the structure b0 is a structure b capable of accepting an electron from the carboxy group in a photoexcited state.

3. The photosensitive material according to claim 1,
wherein at least the requirement (V01) is satisfied, and
the compound β is an aromatic compound.

4. The photosensitive material according to claim 1,
wherein at least the requirement (V01) is satisfied, and
the compound β is an aromatic compound having a substituent.

5. The photosensitive material according to claim 1,
wherein at least the requirement (V01) is satisfied, and
the compound β is a compound satisfying one or more of the following requirements (1) to (4),
(1) the compound β has a polycyclic aromatic ring,
(2) the compound β has a heteroaromatic ring,
(3) the compound β has an aromatic carbonyl group,
(4) the compound β has an aromatic imide group.

6. The photosensitive material according to claim 1,
wherein at least the requirement (V01) is satisfied, and
a molar absorption coefficient ε of the compound β at 365 nm is 1×10³ (cm·mol/L)⁻¹ or less.

7. The photosensitive material according to claim 1,
wherein at least the requirement (V01) is satisfied, and
a ratio of a molar absorption coefficient ε of the compound β at 365 nm to a molar absorption coefficient ε′ of the compound β at 313 nm is 3 or less.

8. The photosensitive material according to claim 1,
wherein at least the requirement (V01) is satisfied, and
a pKa of the compound β in a ground state is 2.0 or more.

9. The photosensitive material according to claim 1,
wherein at least the requirement (V01) is satisfied, and
a pKa of the compound β in a ground state is 9.0 or less.

10. The photosensitive material according to claim 1,
wherein at least the requirement (V01) is satisfied, and
the compound β is one or more kinds selected from the group consisting of pyridine and a pyridine derivative, quinoline and a quinoline derivative, and isoquinoline and an isoquinoline derivative.

11. The photosensitive material according to claim 1,
wherein the polymer A has a repeating unit based on (meth)acrylic acid.

12. The photosensitive material according to claim 1,
wherein the polymer A has a repeating unit having a polymerizable group.

13. The photosensitive material according to claim 1,
wherein at least the requirement (V01) is satisfied,
in the requirement (V01), the compound β is a compound B, and the compound B is a compound in which the structure b0 is a structure b capable of accepting an electron from the carboxy group in a photoexcited state, and
in the photosensitive material, a total number of the structures b included in the compound B is 5 mol % or more with respect to a total number of carboxy groups included in the polymer A.

14. The photosensitive material according to claim 13,
wherein in the photosensitive material, a total number of the structure b included in the compound B is 10 mol % or more and 100 mol % or less with respect to a total number of carboxy groups included in the polymer A.

15. The photosensitive material according to claim 1,
wherein at least the requirement (V01) is satisfied,
in the requirement (V01), the compound β is a compound B, and the compound B is a compound in which the structure b0 is a structure b capable of accepting an electron from the carboxy group in a photoexcited state, and
in the photosensitive material, a content of the compound B is 4% to 35% by mass.

16. The photosensitive material according to claim 1, further comprising:
a polymerizable compound.

17. The photosensitive material according to claim 1, further comprising:
a photopolymerization initiator.

18. The photosensitive material according to claim 17,
wherein the photopolymerization initiator is one or more kinds selected from the group consisting of an oxime ester compound and an aminoacetophenone compound.

19. A pattern forming method comprising, in the following order:
a step of forming a photosensitive layer on a base material using the photosensitive material according to claim 17;
a step of exposing the photosensitive layer in a patterned manner;
a step of developing the exposed photosensitive layer with an alkali developer to form a patterned photosensitive layer; and
a step of exposing the patterned photosensitive layer.

20. A manufacturing method of a circuit wiring, comprising, in the following order:
a step of forming a photosensitive layer on a base material having a conductive layer using the photosensitive material according to claim 17;
a step of exposing the photosensitive layer in a patterned manner;
a step of developing the exposed photosensitive layer with an alkali developer to form a patterned photosensitive layer;
a step of exposing the patterned photosensitive layer to form an etching resist film; and
a step of etching the conductive layer in a region on which the etching resist film is not disposed.

21. A manufacturing method of a touch panel, comprising, in the following order:
a step of forming a photosensitive layer on a base material having a conductive layer using the photosensitive material according to claim 17;
a step of exposing the photosensitive layer in a patterned manner;
a step of developing the exposed photosensitive layer with an alkali developer to form a patterned photosensitive layer; and
a step of exposing the patterned photosensitive layer to form a protective film or an insulating film of the conductive layer.

22. A transfer film comprising:
a temporary support; and
a photosensitive layer formed of the photosensitive material according to claim 1.

23. The transfer film according to claim 22,
wherein a transmittance of the photosensitive layer at 365 nm is 65% or more.

24. The transfer film according to claim 22,
wherein a ratio of a transmittance of the photosensitive layer at 365 nm to a transmittance of the photosensitive layer at 313 nm is 1.5 or more.

25. The transfer film according to claim 22,
wherein a content of a carboxy group in the photosensitive layer is reduced at a reduction rate of 5 mol % or more by irradiation with an actinic ray or a radiation.
